(19) United States
(12) Patent Application Publication
(10) Pub. No.: US 2025/0248295 A1
(43) Pub. Date: Jul. 31, 2025

(54) ORGANIC ELECTROLUMINESCENT MATERIALS AND DEVICES

(71) Applicant: Universal Display Corporation, Ewing, NJ (US)

(72) Inventors: Hsiao-Fan CHEN, Lawrence Township, NJ (US); George FITZGERALD, Lambertville, NJ (US); Tyler FLEETHAM, Newtown, PA (US); Peter WOLOHAN, Princeton Junction, NJ (US); Joseph A. MACOR, Morrisville, PA (US); Morgan C. MACINNIS, Yardley, PA (US); Wystan Neil PALMER, Princeton, NJ (US); Geza SZIGETHY, Newtown, PA (US); Noah HORWITZ, Ewing, NJ (US)

(73) Assignee: Universal Display Corporation, Ewing, NJ (US)

(21) Appl. No.: 19/020,145

(22) Filed: Jan. 14, 2025

Related U.S. Application Data
(63) Continuation of application No. 18/504,375, filed on Nov. 8, 2023, now Pat. No. 12,250,875.
Application No. 18/504,375 is a continuation of application No. 16/983,572, filed on Aug. 3, 2020, now Pat. No. 11,930,699.
(60) Provisional application No. 62/887,200, filed on Aug. 15, 2019.

(51) Int. Cl. H10K 85/30; C07F 15/00; C07F 19/00; C09K 11/06; C09K 11/87; H10K 85/40; H10K 85/60

(52) U.S. Cl. CPC H10K 85/346; C07F 15/0033; C07F 15/0086; C07F 19/00; C09K 11/06; C09K 11/87; H10K 85/40; H10K 85/615; H10K 85/654; H10K 85/6572; H10K 85/6574; C09K 2211/1007; C09K 2211/1029; C09K 2211/1044; C09K 2211/185

(57) ABSTRACT

Provided are compounds comprising a ligand L_{A} of Formula I

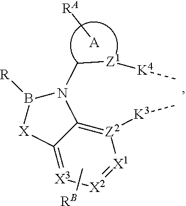

where the ligand L_{A} is coordinated to Pt.

### CROSS-REFERENCE TO RELATED APPLICATIONS

This application is a continuation of co-pending U.S. patent application Ser. No. 18/504,375, filed on Nov. 8, 2023, which is a continuation of U.S. patent application Ser. No. 16/983,572, filed on Aug. 3, 2020, which claims priority under 35 U.S.C. § 119 (e) to U.S. Provisional Application No. 62/887,200, filed on Aug. 15, 2019, the entire contents of which are incorporated herein by reference.

### FIELD

The present disclosure generally relates to organometallic compounds and formulations and their various uses including as emitters in devices such as organic light emitting diodes and related electronic devices.

### BACKGROUND

Opto-electronic devices that make use of organic materials are becoming increasingly desirable for various reasons. Many of the materials used to make such devices are relatively inexpensive, so organic opto-electronic devices have the potential for cost advantages over inorganic devices. In addition, the inherent properties of organic materials, such as their flexibility, may make them well suited for particular applications such as fabrication on a flexible substrate. Examples of organic opto-electronic devices include organic light emitting diodes/devices (OLEDs), organic phototransistors, organic photovoltaic cells, and organic photodetectors. For OLEDs, the organic materials may have performance advantages over conventional materials.

OLEDs make use of thin organic films that emit light when voltage is applied across the device. OLEDs are becoming an increasingly interesting technology for use in applications such as flat panel displays, illumination, and backlighting.

One application for phosphorescent emissive molecules is a full color display. Industry standards for such a display call for pixels adapted to emit particular colors, referred to as “saturated” colors. In particular, these standards call for saturated red, green, and blue pixels. Alternatively, the OLED can be designed to emit white light. In conventional liquid crystal displays emission from a white backlight is filtered using absorption filters to produce red, green and blue emission. The same technique can also be used with OLEDs. The white OLED can be either a single emissive layer (EML) device or a stack structure. Color may be measured using CIE coordinates, which are well known to the art.

### SUMMARY

Provided are organometallic complexes based on benzodiazaborole that possess high triplet energies. These complexes are believed to be useful as deep blue-emitting phosphorescent emitters in OLEDs.

In one aspect, the present disclosure provides a compound comprising a ligand L_{A} of Formula I

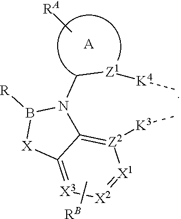

wherein: A is a 5-membered or 6-membered carbocyclic or heterocyclic ring; Z¹ and Z² are each independently C or N; K³ and K⁴ are each independently a direct bond, O, or S; X¹, X², and X³ are each independently C or N, at least one of X¹, X², and X³ is C; X is O or NR′; R^{A} and R^{B} each represent zero, mono, or up to the maximum number of allowed substitutions to its associated ring; each R, R′, R^{A}, and R^{B} is independently a hydrogen or a substituent selected from the group consisting of the general substituents defined herein; and two adjacent groups can be joined or fused to form a ring wherever chemically feasible, wherein the ligand L_{A} is complexed to a metal M to form a chelate ring as indicated by the two dashed lines; wherein the metal M can be coordinated to other ligands; and wherein the ligand L_{A} can be linked with other ligands to form a tridentate, tetradentate, pentadentate, or hexadentate ligand.

In another aspect, the present disclosure provides a formulation of the compound of the present disclosure.

In yet another aspect, the present disclosure provides an OLED having an organic layer comprising the compound of the present disclosure.

In yet another aspect, the present disclosure provides a consumer product comprising an OLED with an organic layer comprising the compound of the present disclosure.

### BRIEF DESCRIPTION OF THE DRAWINGS

FIG. 1 shows an organic light emitting device.

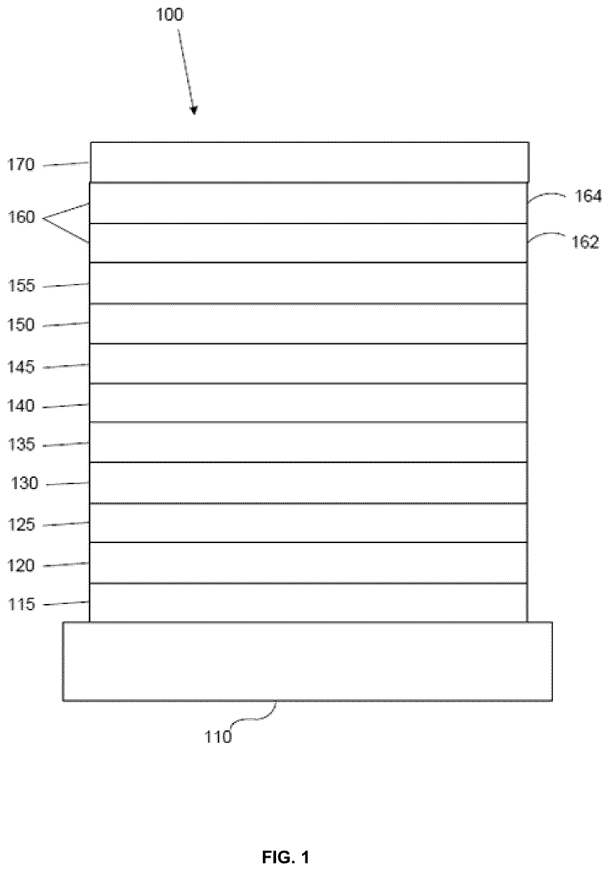

FIG. 2 shows an inverted organic light emitting device that does not have a separate electron transport layer.

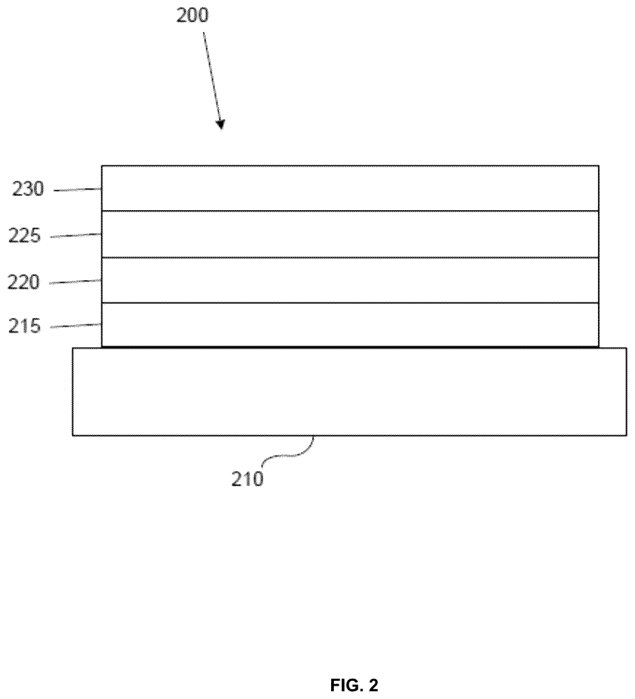

### DETAILED DESCRIPTION

### A. Terminology

Unless otherwise specified, the below terms used herein are defined as follows:

As used herein, the term “organic” includes polymeric materials as well as small molecule organic materials that may be used to fabricate organic opto-electronic devices. “Small molecule” refers to any organic material that is not a polymer, and “small molecules” may actually be quite large. Small molecules may include repeat units in some circumstances. For example, using a long chain alkyl group as a substituent does not remove a molecule from the “small molecule” class. Small molecules may also be incorporated into polymers, for example as a pendent group on a polymer backbone or as a part of the backbone. Small molecules may also serve as the core moiety of a dendrimer, which consists of a series of chemical shells built on the core moiety. The core moiety of a dendrimer may be a fluorescent or phosphorescent small molecule emitter. A dendrimer may be a “small molecule,” and it is believed that all dendrimers currently used in the field of OLEDs are small molecules.

As used herein, “top” means furthest away from the substrate, while “bottom” means closest to the substrate. Where a first layer is described as “disposed over” a second layer, the first layer is disposed further away from substrate. There may be other layers between the first and second layer, unless it is specified that the first layer is “in contact with” the second layer. For example, a cathode may be described as “disposed over” an anode, even though there are various organic layers in between.

As used herein, “solution processable” means capable of being dissolved, dispersed, or transported in and/or deposited from a liquid medium, either in solution or suspension form.

A ligand may be referred to as “photoactive” when it is believed that the ligand directly contributes to the photoactive properties of an emissive material. A ligand may be referred to as “ancillary” when it is believed that the ligand does not contribute to the photoactive properties of an emissive material, although an ancillary ligand may alter the properties of a photoactive ligand.

As used herein, and as would be generally understood by one skilled in the art, a first “Highest Occupied Molecular Orbital” (HOMO) or “Lowest Unoccupied Molecular Orbital” (LUMO) energy level is “greater than” or “higher than” a second HOMO or LUMO energy level if the first energy level is closer to the vacuum energy level. Since ionization potentials (IP) are measured as a negative energy relative to a vacuum level, a higher HOMO energy level corresponds to an IP having a smaller absolute value (an IP that is less negative). Similarly, a higher LUMO energy level corresponds to an electron affinity (EA) having a smaller absolute value (an EA that is less negative). On a conventional energy level diagram, with the vacuum level at the top, the LUMO energy level of a material is higher than the HOMO energy level of the same material. A “higher” HOMO or LUMO energy level appears closer to the top of such a diagram than a “lower” HOMO or LUMO energy level.

As used herein, and as would be generally understood by one skilled in the art, a first work function is “greater than” or “higher than” a second work function if the first work function has a higher absolute value. Because work functions are generally measured as negative numbers relative to vacuum level, this means that a “higher” work function is more negative. On a conventional energy level diagram, with the vacuum level at the top, a “higher” work function is illustrated as further away from the vacuum level in the downward direction. Thus, the definitions of HOMO and LUMO energy levels follow a different convention than work functions.

The terms “halo,” “halogen,” and “halide” are used interchangeably and refer to fluorine, chlorine, bromine, and iodine.

The term “acyl” refers to a substituted carbonyl radical (C(O)—Rₛ).

The term “ester” refers to a substituted oxycarbonyl (—O—C(O)—Rₛ or —C(O)—O—Rₛ) radical.

The term “ether” refers to an —ORₛ radical.

The terms “sulfanyl” or “thio-ether” are used interchangeably and refer to a —SR radical.

The term “sulfinyl” refers to a —S(O)—Rₛ radical.

The term “sulfonyl” refers to a —SO₂—Rₛ radical.

The term “phosphino” refers to a —P(Rₛ)₃ radical, wherein each Rₛ can be same or different.

The term “silyl” refers to a —Si(Rₛ)₃ radical, wherein each Rₛ can be same or different.

The term “boryl” refers to a —B(Rₛ)₂ radical or its Lewis adduct —B(Rₛ)₃ radical, wherein Rₛ can be same or different.

In each of the above, Rₛ can be hydrogen or a substituent selected from the group consisting of deuterium, halogen, alkyl, cycloalkyl, heteroalkyl, heterocycloalkyl, arylalkyl, alkoxy, aryloxy, amino, silyl, alkenyl, cycloalkenyl, heteroalkenyl, alkynyl, aryl, heteroaryl, and combination thereof. Preferred Rₛ is selected from the group consisting of alkyl, cycloalkyl, aryl, heteroaryl, and combination thereof.

The term “alkyl” refers to and includes both straight and branched chain alkyl radicals. Preferred alkyl groups are those containing from one to fifteen carbon atoms and includes methyl, ethyl, propyl, 1-methylethyl, butyl, 1-methylpropyl, 2-methylpropyl, pentyl, 1-methylbutyl, 2-methylbutyl, 3-methylbutyl, 1,1-dimethylpropyl, 1,2-dimethylpropyl, 2,2-dimethylpropyl, and the like. Additionally, the alkyl group may be optionally substituted.

The term “cycloalkyl” refers to and includes monocyclic, polycyclic, and spiro alkyl radicals. Preferred cycloalkyl groups are those containing 3 to 12 ring carbon atoms and includes cyclopropyl, cyclopentyl, cyclohexyl, bicyclo[3.1.1]heptyl, spiro[4.5]decyl, spiro[5.5]undecyl, adamantyl, and the like. Additionally, the cycloalkyl group may be optionally substituted.

The terms “heteroalkyl” or “heterocycloalkyl” refer to an alkyl or a cycloalkyl radical, respectively, having at least one carbon atom replaced by a heteroatom. Optionally the at least one heteroatom is selected from O, S, N, P, B, Si and Se, preferably, O, S or N. Additionally, the heteroalkyl or heterocycloalkyl group may be optionally substituted.

The term “alkenyl” refers to and includes both straight and branched chain alkene radicals. Alkenyl groups are essentially alkyl groups that include at least one carbon-carbon double bond in the alkyl chain. Cycloalkenyl groups are essentially cycloalkyl groups that include at least one carbon-carbon double bond in the cycloalkyl ring. The term “heteroalkenyl” as used herein refers to an alkenyl radical having at least one carbon atom replaced by a heteroatom. Optionally the at least one heteroatom is selected from O, S, N, P, B, Si, and Se, preferably, O, S, or N. Preferred alkenyl, cycloalkenyl, or heteroalkenyl groups are those containing two to fifteen carbon atoms. Additionally, the alkenyl, cycloalkenyl, or heteroalkenyl group may be optionally substituted.

The term “alkynyl” refers to and includes both straight and branched chain alkyne radicals. Alkynyl groups are essentially alkyl groups that include at least one carbon-carbon triple bond in the alkyl chain. Preferred alkynyl groups are those containing two to fifteen carbon atoms. Additionally, the alkynyl group may be optionally substituted.

The terms “aralkyl” or “arylalkyl” are used interchangeably and refer to an alkyl group that is substituted with an aryl group. Additionally, the aralkyl group may be optionally substituted.

The term “heterocyclic group” refers to and includes aromatic and non-aromatic cyclic radicals containing at least one heteroatom. Optionally the at least one heteroatom is selected from O, S, N, P, B, Si, and Se, preferably, O, S, or N. Hetero-aromatic cyclic radicals may be used interchangeably with heteroaryl. Preferred hetero-non-aromatic cyclic groups are those containing 3 to 7 ring atoms which includes at least one hetero atom, and includes cyclic amines such as morpholino, piperidino, pyrrolidino, and the like, and cyclic ethers/thio-ethers, such as tetrahydrofuran, tetrahydropyran, tetrahydrothiophene, and the like. Additionally, the heterocyclic group may be optionally substituted.

The term “aryl” refers to and includes both single-ring aromatic hydrocarbyl groups and polycyclic aromatic ring systems. The polycyclic rings may have two or more rings in which two carbons are common to two adjoining rings (the rings are “fused”) wherein at least one of the rings is an aromatic hydrocarbyl group, e.g., the other rings can be cycloalkyls, cycloalkenyls, aryl, heterocycles, and/or heteroaryls. Preferred aryl groups are those containing six to thirty carbon atoms, preferably six to twenty carbon atoms, more preferably six to twelve carbon atoms. Especially preferred is an aryl group having six carbons, ten carbons or twelve carbons. Suitable aryl groups include phenyl, biphenyl, triphenyl, triphenylene, tetraphenylene, naphthalene, anthracene, phenalene, phenanthrene, fluorene, pyrene, chrysene, perylene, and azulene, preferably phenyl, biphenyl, triphenyl, triphenylene, fluorene, and naphthalene. Additionally, the aryl group may be optionally substituted.

The term “heteroaryl” refers to and includes both single-ring aromatic groups and polycyclic aromatic ring systems that include at least one heteroatom. The heteroatoms include, but are not limited to O, S, N, P, B, Si, and Se. In many instances, O, S, or N are the preferred heteroatoms. Hetero-single ring aromatic systems are preferably single rings with 5 or 6 ring atoms, and the ring can have from one to six heteroatoms. The hetero-polycyclic ring systems can have two or more rings in which two atoms are common to two adjoining rings (the rings are “fused”) wherein at least one of the rings is a heteroaryl, e.g., the other rings can be cycloalkyls, cycloalkenyls, aryl, heterocycles, and/or heteroaryls. The hetero-polycyclic aromatic ring systems can have from one to six heteroatoms per ring of the polycyclic aromatic ring system. Preferred heteroaryl groups are those containing three to thirty carbon atoms, preferably three to twenty carbon atoms, more preferably three to twelve carbon atoms. Suitable heteroaryl groups include dibenzothiophene, dibenzofuran, dibenzoselenophene, furan, thiophene, benzofuran, benzothiophene, benzoselenophene, carbazole, indolocarbazole, pyridylindole, pyrrolodipyridine, pyrazole, imidazole, triazole, oxazole, thiazole, oxadiazole, oxatriazole, dioxazole, thiadiazole, pyridine, pyridazine, pyrimidine, pyrazine, triazine, oxazine, oxathiazine, oxadiazine, indole, benzimidazole, indazole, indoxazine, benzoxazole, benzisoxazole, benzothiazole, quinoline, isoquinoline, cinnoline, quinazoline, quinoxaline, naphthyridine, phthalazine, pteridine, xanthene, acridine, phenazine, phenothiazine, phenoxazine, benzofuropyridine, furodipyridine, benzothienopyridine, thienodipyridine, benzoselenophenopyridine, and selenophenodipyridine, preferably dibenzothiophene, dibenzofuran, dibenzoselenophene, carbazole, indolocarbazole, imidazole, pyridine, triazine, benzimidazole, 1,2-azaborine, 1,3-azaborine, 1,4-azaborine, borazine, and aza-analogs thereof. Additionally, the heteroaryl group may be optionally substituted.

Of the aryl and heteroaryl groups listed above, the groups of triphenylene, naphthalene, anthracene, dibenzothiophene, dibenzofuran, dibenzoselenophene, carbazole, indolocarbazole, imidazole, pyridine, pyrazine, pyrimidine, triazine, and benzimidazole, and the respective aza-analogs of each thereof are of particular interest.

The terms alkyl, cycloalkyl, heteroalkyl, heterocycloalkyl, alkenyl, cycloalkenyl, heteroalkenyl, alkynyl, aralkyl, heterocyclic group, aryl, and heteroaryl, as used herein, are independently unsubstituted, or independently substituted, with one or more general substituents.

In many instances, the general substituents are selected from the group consisting of deuterium, halogen, alkyl, cycloalkyl, heteroalkyl, heterocycloalkyl, arylalkyl, alkoxy, aryloxy, amino, silyl, alkenyl, cycloalkenyl, heteroalkenyl, alkynyl, aryl, heteroaryl, acyl, carboxylic acid, ether, ester, nitrile, isonitrile, sulfanyl, sulfinyl, sulfonyl, phosphino, boryl, and combinations thereof.

In some instances, the preferred general substituents are selected from the group consisting of deuterium, fluorine, alkyl, cycloalkyl, heteroalkyl, alkoxy, aryloxy, amino, silyl, alkenyl, cycloalkenyl, heteroalkenyl, aryl, heteroaryl, nitrile, isonitrile, sulfanyl, boryl, and combinations thereof.

In some instances, the more preferred general substituents are selected from the group consisting of deuterium, fluorine, alkyl, cycloalkyl, alkoxy, aryloxy, amino, silyl, boryl, aryl, heteroaryl, sulfanyl, and combinations thereof.

In yet other instances, the most preferred general substituents are selected from the group consisting of deuterium, fluorine, alkyl, cycloalkyl, aryl, heteroaryl, and combinations thereof.

The terms “substituted” and “substitution” refer to a substituent other than H that is bonded to the relevant position, e.g., a carbon or nitrogen. For example, when R¹ represents mono-substitution, then one R¹ must be other than H (i.e., a substitution). Similarly, when R¹ represents di-substitution, then two of R¹ must be other than H. Similarly, when R¹ represents zero or no substitution, R¹, for example, can be a hydrogen for available valencies of ring atoms, as in carbon atoms for benzene and the nitrogen atom in pyrrole, or simply represents nothing for ring atoms with fully filled valencies, e.g., the nitrogen atom in pyridine. The maximum number of substitutions possible in a ring structure will depend on the total number of available valencies in the ring atoms.

As used herein, “combinations thereof” indicates that one or more members of the applicable list are combined to form a known or chemically stable arrangement that one of ordinary skill in the art can envision from the applicable list. For example, an alkyl and deuterium can be combined to form a partial or fully deuterated alkyl group; a halogen and alkyl can be combined to form a halogenated alkyl substituent; and a halogen, alkyl, and aryl can be combined to form a halogenated arylalkyl. In one instance, the term substitution includes a combination of two to four of the listed groups. In another instance, the term substitution includes a combination of two to three groups. In yet another instance, the term substitution includes a combination of two groups. Preferred combinations of substituent groups are those that contain up to fifty atoms that are not hydrogen or deuterium, or those which include up to forty atoms that are not hydrogen or deuterium, or those that include up to thirty atoms that are not hydrogen or deuterium. In many instances, a preferred combination of substituent groups will include up to twenty atoms that are not hydrogen or deuterium.

The “aza” designation in the fragments described herein, i.e. aza-dibenzofuran, aza-dibenzothiophene, etc. means that one or more of the C—H groups in the respective aromatic ring can be replaced by a nitrogen atom, for example, and without any limitation, azatriphenylene encompasses both dibenzo[f,h]quinoxaline and dibenzo[f,h]quinoline. One of ordinary skill in the art can readily envision other nitrogen analogs of the aza-derivatives described above, and all such analogs are intended to be encompassed by the terms as set forth herein.

As used herein, “deuterium” refers to an isotope of hydrogen. Deuterated compounds can be readily prepared using methods known in the art. For example, U.S. Pat. No. 8,557,400, Patent Pub. No. WO 2006/095951, and U.S. Pat. Application Pub. No. US 2011/0037057, which are hereby incorporated by reference in their entireties, describe the making of deuterium-substituted organometallic complexes. Further reference is made to Ming Yan, et al., Tetrahedron 2015, 71, 1425-30 and Atzrodt et al., Angew. Chem. Int. Ed. (Reviews) 2007, 46, 7744-65, which are incorporated by reference in their entireties, describe the deuteration of the methylene hydrogens in benzyl amines and efficient pathways to replace aromatic ring hydrogens with deuterium, respectively.

It is to be understood that when a molecular fragment is described as being a substituent or otherwise attached to another moiety, its name may be written as if it were a fragment (e.g. phenyl, phenylene, naphthyl, dibenzofuryl) or as if it were the whole molecule (e.g. benzene, naphthalene, dibenzofuran). As used herein, these different ways of designating a substituent or attached fragment are considered to be equivalent.

In some instance, a pair of adjacent substituents can be optionally joined or fused into a ring. The preferred ring is a five, six, or seven-membered carbocyclic or heterocyclic ring, includes both instances where the portion of the ring formed by the pair of substituents is saturated and where the portion of the ring formed by the pair of substituents is unsaturated. As used herein, “adjacent” means that the two substituents involved can be on the same ring next to each other, or on two neighboring rings having the two closest available substitutable positions, such as 2, 2′ positions in a biphenyl, or 1, 8 position in a naphthalene, as long as they can form a stable fused ring system.

### B. The Compounds of the Present Disclosure

The present disclosure provides a compound comprising a ligand L_{A} of Formula I

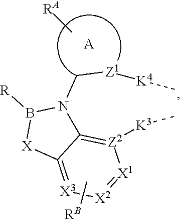

wherein A is a 5-membered or 6-membered carbocyclic or heterocyclic ring; Z¹ and Z² are each independently C or N; K³ and K⁴ are each independently a direct bond, O, or S; X¹, X², and X³ are each independently C or N, at least one of X¹, X², and X³ is C; X is O or NR′; R^{A} and R^{B} each represent zero, mono, or up to the maximum number of allowed substitutions to its associated ring; each R, R′, R^{A}, and R^{B} are independently a hydrogen or a substituent selected from the group consisting of the general substituents defined herein; and two adjacent groups can be joined or fused to form a ring wherever chemically feasible, wherein the ligand L_{A} is complexed to a metal M to form a chelate ring as indicated by the two dashed lines; wherein the metal M can be coordinated to other ligands; and wherein the ligand L_{A} can be linked with other ligands to form a tridentate, tetradentate, pentadentate, or hexadentate ligand.

In some embodiments, each R, R′, R^{A} and R^{B} can be independently selected from the group consisting of the preferred general substituents defined herein.

In some embodiments, Z¹ is N, and Z² is C. In some embodiments, Z¹ is C, and Z² is N.

In some embodiments, X¹-X³ are all C.

In some embodiments, ring A is pyridine, pyrimidine, pyrazine, imidazole, pyrazole, oxazole, thiazole, or imidazole derived carbene.

In some embodiments, X is NR′.

In some embodiments, R′ and R can be joined to form a ring wherever chemically feasible.

In some embodiments, Z² and X¹-X³ are all C.

In some embodiments, each of K³ and K⁴ is a direct bond. In some embodiments, one of K³ and K⁴ is O.

In some embodiments, the metal M is selected from the group consisting of Os, Ir, Pd, Pt, Au, Ag, and Cu.

In some embodiments, the metal M is Ir or Pt.

In some embodiments, the ligand L_{A} is selected from the group consisting of:

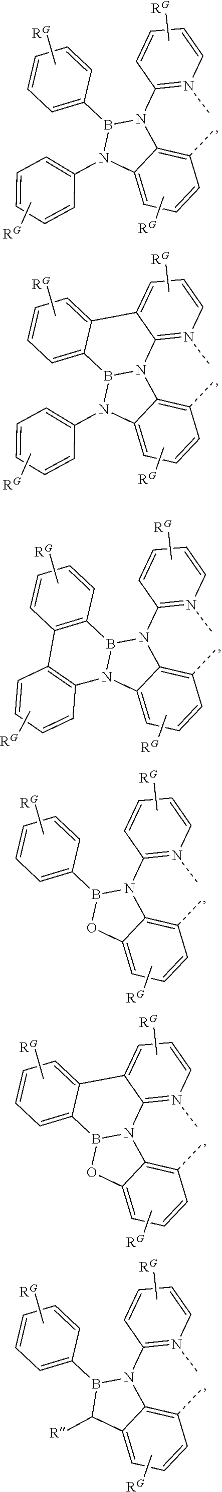

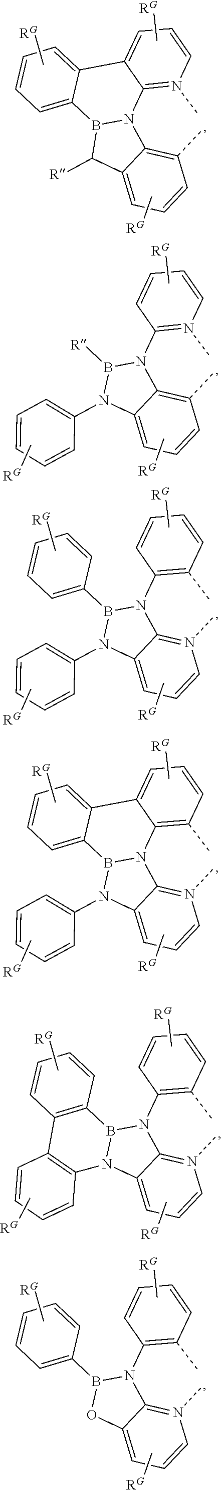

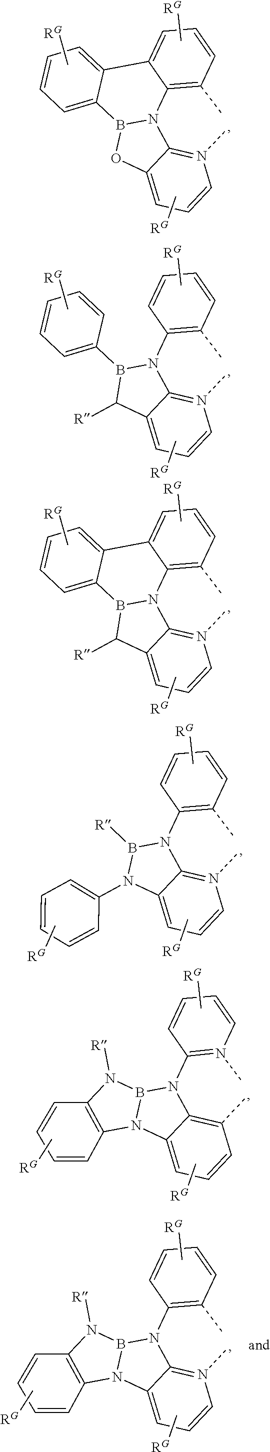

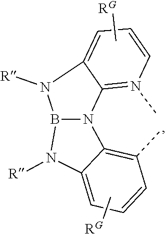

wherein R^{G} for each occurrence represents zero, mono, or up to the maximum number of allowed substitutions to its associated ring; and each of R″ and R^{G} is independently a hydrogen or a substituent selected from the group consisting of the general substituents defined herein; and two adjacent R^{G} groups can be joined together to form a ring wherever chemically feasible.

In some embodiments, the ligand L_{A} is selected from the group consisting of the ligand structures in LIST1 below:

| Ligand naming convention | Structure | |
|---|---|---|
| L_{A}1-(j)(k)(p)(z), wherein each of j, k, p, and z is independently an integer from 1 to 55, wherein L_{A}1-(1)(1)(1)(1) to L_{A}1-(55)(55)(55)(55) having the structure | 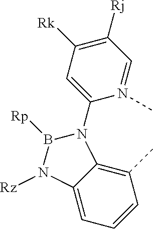 | wherein Rj = Bj, Rk = Bk, Rp = Bp, and Rz = Bz, and |
| L_{A}2-(j)(k)(p), wherein each of j, k, and p is independently an integer from 1 to 55, wherein L_{A}2-(1)(1)(1) to L_{A}2-(55)(55)(55) having the structure | 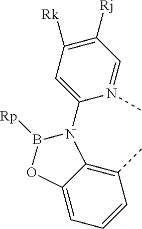 | wherein Rj = Bj, Rk = Bk, and Rp = Bp, and |
| L_{A}3-(j)(z), wherein each of j, and z is independently an integer from 1 to 55, wherein L_{A}3-(1)(1) to L_{A}3-(55)(55) having the structure | 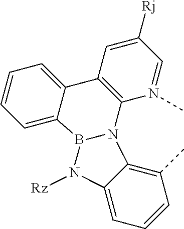 | wherein Rj = Bj, and Rz = Bz, and |
| L_{A}4-(j), wherein j is an integer from 1 to 55, wherein L_{A}4-(1) to L_{A}4-(55) having the structure | 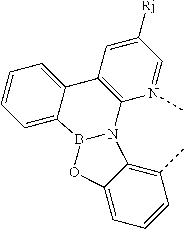 | wherein Rj = Bj, and |
| L_{A}5-(j)(k), wherein each of j, and k is independently an integer from 1 to 55, wherein L_{A}5-(1)(1) to L_{A}5-(55)(55) having the structure | 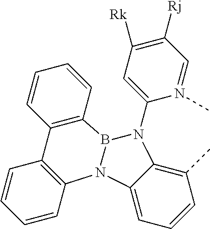 | wherein Rj = Bj, and Rk = Bk, and |
| L_{A}6-(j)(k)(p)(z), wherein each of j, k, p, and z is independently an integer from 1 to 55, wherein L_{A}6-(1)(1)(1)(1) to L_{A}6-(55)(55)(55)(55) having the structure | 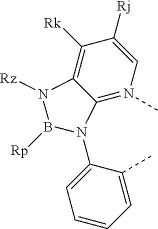 | wherein Rj = Bj, Rk = Bk, Rp = Bp, and Rz = Bz, and |
| L_{A}7-(j)(k)(p), wherein each of j, k, and p is independently an integer from 1 to 55, wherein L_{A}7-(1)(1)(1) to L_{A}7-(55)(55)(55) having the structure | 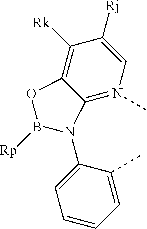 | wherein Rj = Bj, Rk = Bk, and Rp = Bp, and |
| L_{A}8-(j)(k)(z), wherein each of j, k, and z is independently an integer from 1 to 55, wherein L_{A}8-(1)(1)(1) to L_{A}8-(55)(55)(55) having the structure | 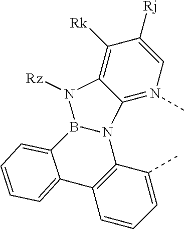 | wherein Rj = Bj, Rk = Bk, and Rz = Bz, and |
| L_{A}9-(j)(k), wherein each of j, and k is independently an integer from 1 to 55, wherein L_{A}9-(1)(1) to L_{A}9-(55)(55) having the structure | 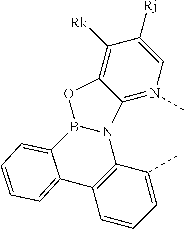 | wherein Rj = Bj, and Rk = Bk, and |
| L_{A}10-(j), wherein j is an integer from 1 to 55, wherein L_{A}10-(1) to L_{A}10-(55) having the structure | 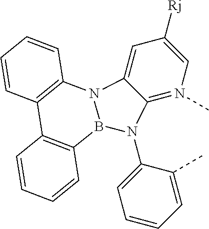 | wherein Rj = Bj, and |
| L_{A}11-(j)(k)(z), wherein each of j, k, and z is independently an integer from 1 to 55, wherein L_{A}11-(1)(1)(1) to L_{A}11-(55)(55)(55) having the structure | 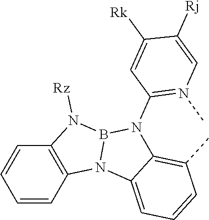 | wherein Rj = Bj, Rk = Bk, and Rz = Bz, and |
| L_{A}12-(j)(k)(z), wherein each of j, k, and z is independently an integer from 1 to 55, wherein L_{A}12-(1)(1)(1) to L_{A}12-(55)(55)(55) having the structure | 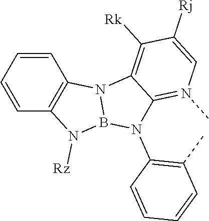 | wherein Rj = Bj, Rk = Bk, and Rz = Bz, and |
| L_{A}13-(j)(k)(p)(z), wherein each of j, k, p, and z is independently an integer from 1 to 55, wherein L_{A}13-(1)(1)(1)(1) to L_{A}13-(55)(55)(55)(55) having the structure | 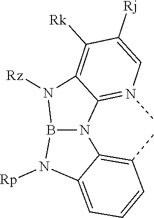 | wherein Rj = Bj, Rk = Bk, Rp = Bp, and Rz = Bz, and |

wherein B1 to B55 have the following structures:

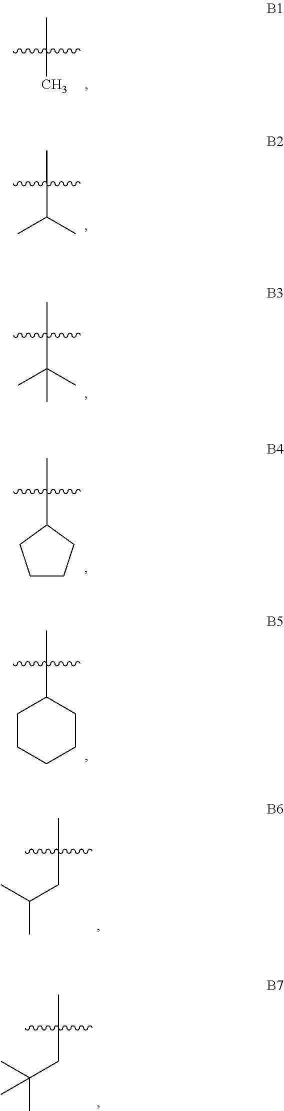

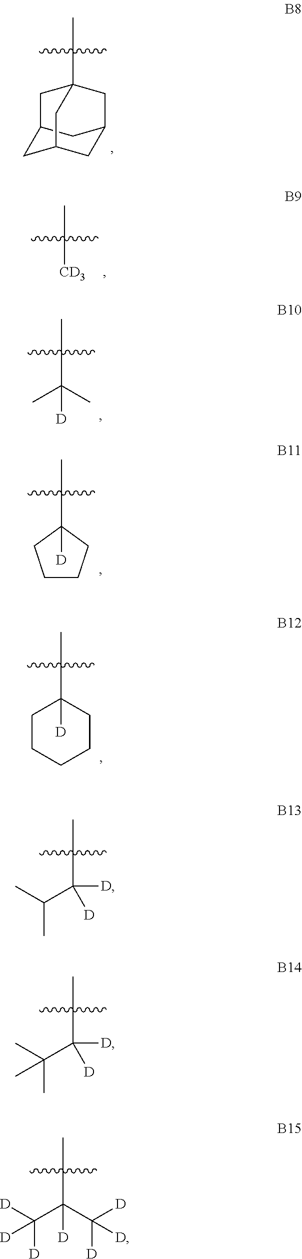

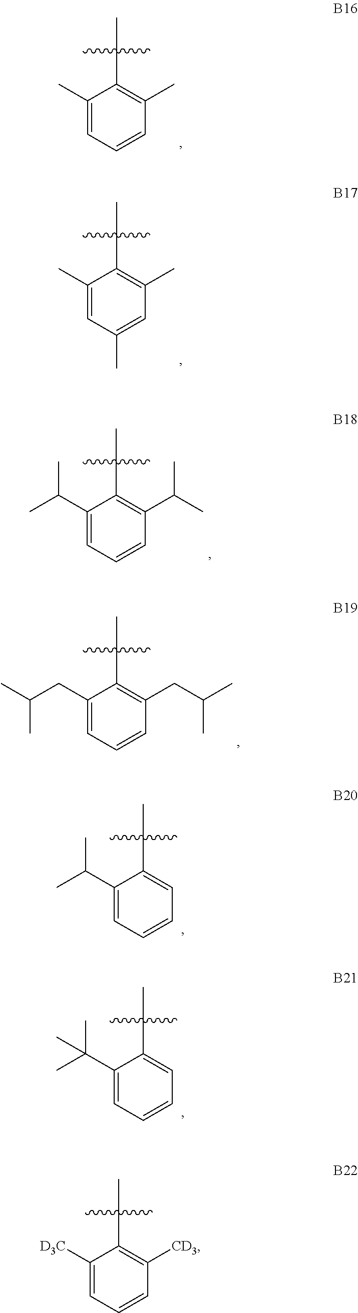

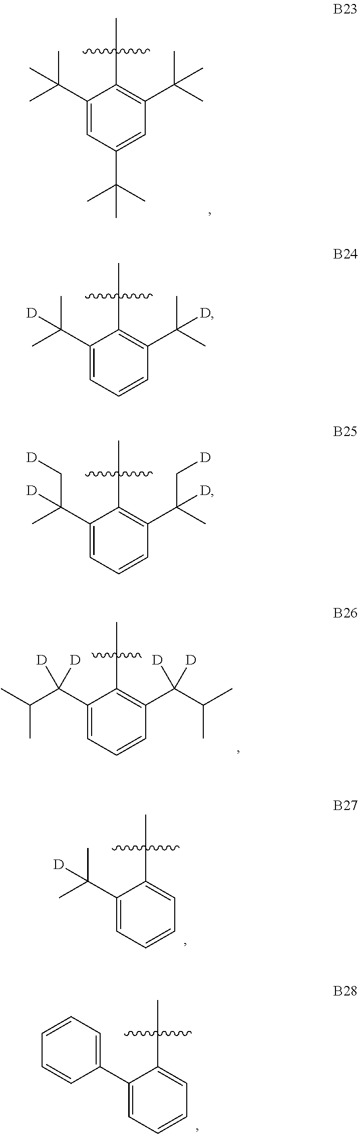

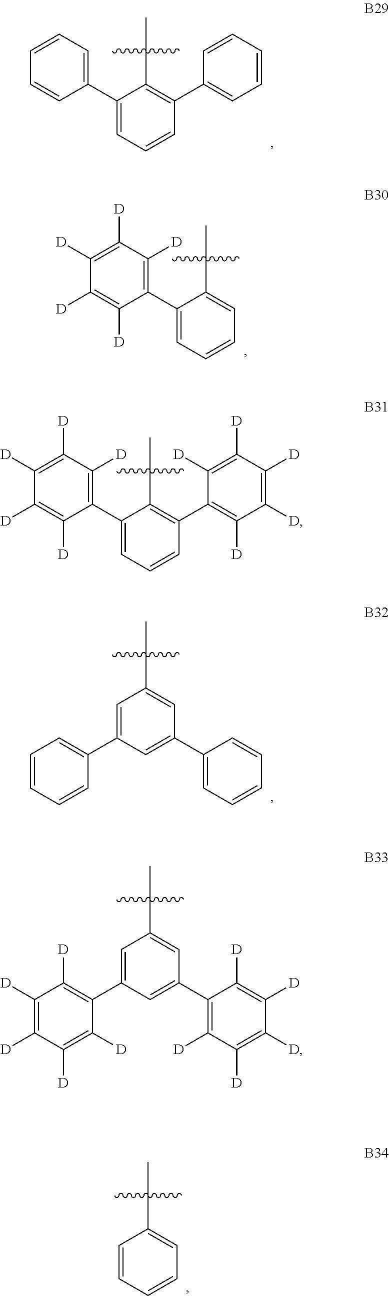

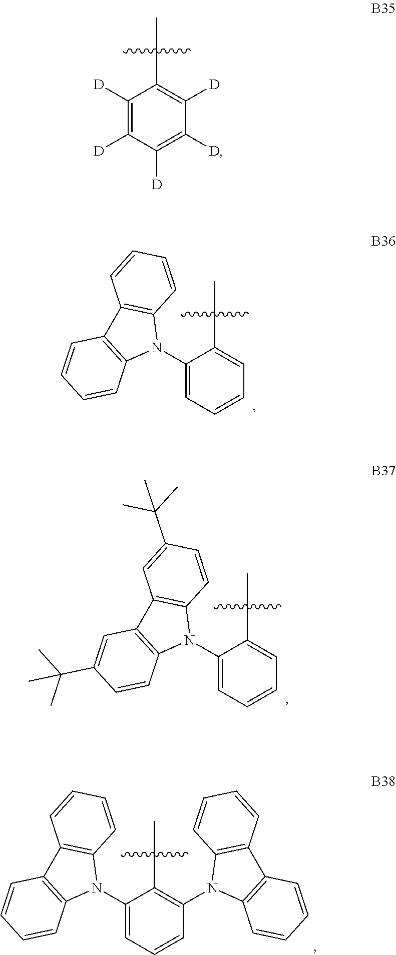

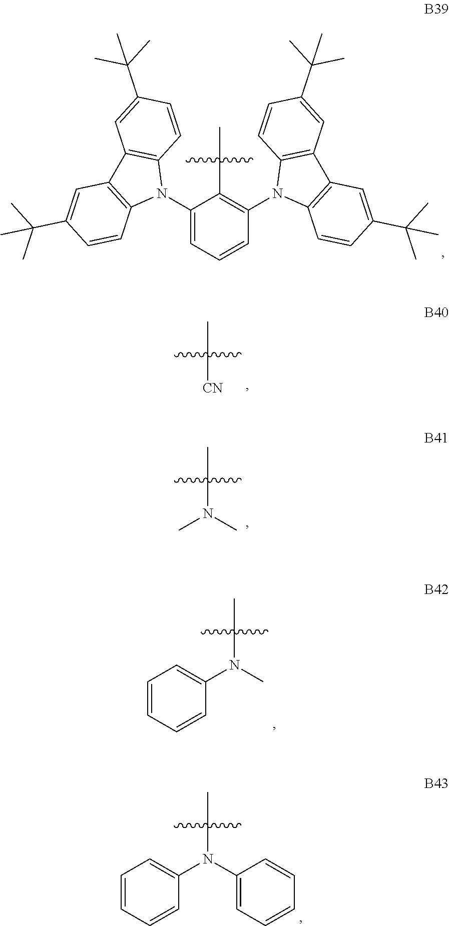

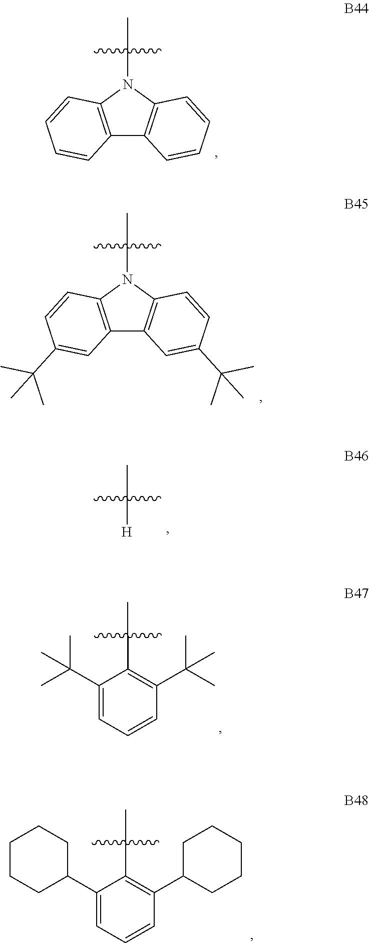

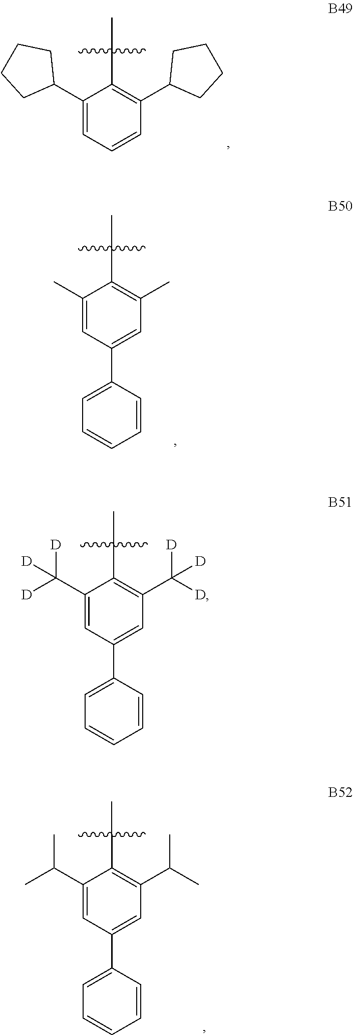

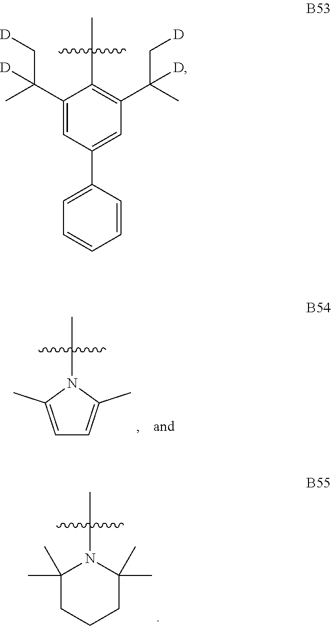

In some embodiments of L_{A}, L_{A} is selected from the group consisting of those ligands from LIST1 whose Ri, Rj, and Rk are one of the following structures: B1, B2, B3, B9, B10, B16, B18, B20, B22, B24, B25, B27, B29, B31, B32, B33, B34, B34, B40, B44, B45, and B46.

In some embodiments of the compound, the compound has a formula of M(L_{A})ₓ(L_{B})_{y}(L_{C})_{z} wherein: L_{A} can be any of the structures for L_{A} defined above; L_{B} and L_{C} are each a bidentate ligand; and wherein x is 1, 2, or 3; y is 0, 1, or 2; z is 0, 1, or 2; and x+y+z is the oxidation state of the metal M.

In some embodiments of the compound, the compound has a formula selected from the group consisting of Ir(L_{A})₃, Ir(L_{A})(L_{B})₂, Ir(L_{A})₂(L_{B}), Ir(L_{A})₂(L_{C}), and Ir(L_{A})(L_{B})(L_{C}); wherein L_{A} can be any of the structures for L_{A} defined above; and L_{A}, L_{B}, and L_{C} are different from each other.

In some embodiments, the compound has a formula of Pt(L_{A})(L_{B}); wherein L_{A} can be any of the structures for L_{A} defined above; and L_{A} and L_{B} can be the same or different.

In some embodiments, L_{A} and L_{B} are connected to form a tetradentate ligand.

In some embodiments, L_{B} and L_{C} are each independently selected from the group consisting of the structures in LIST2 below:

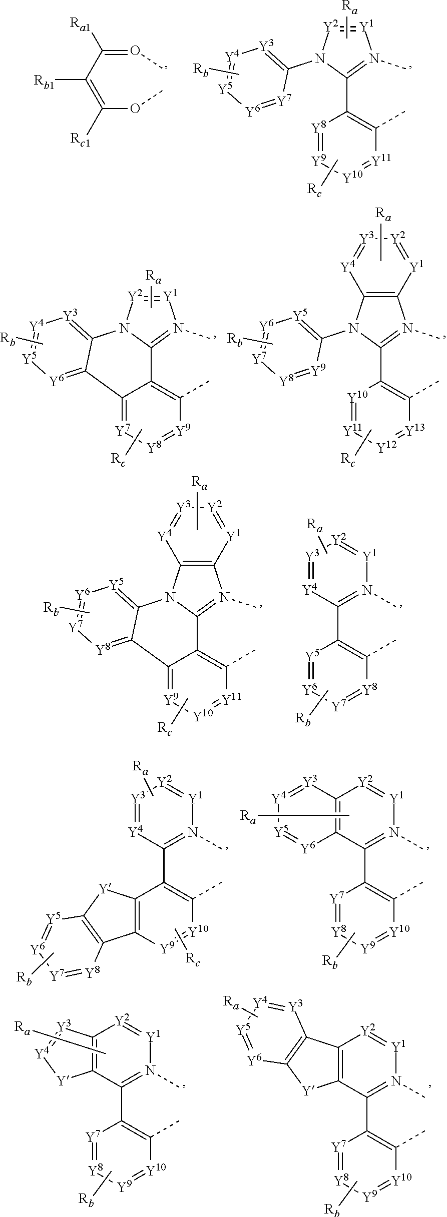

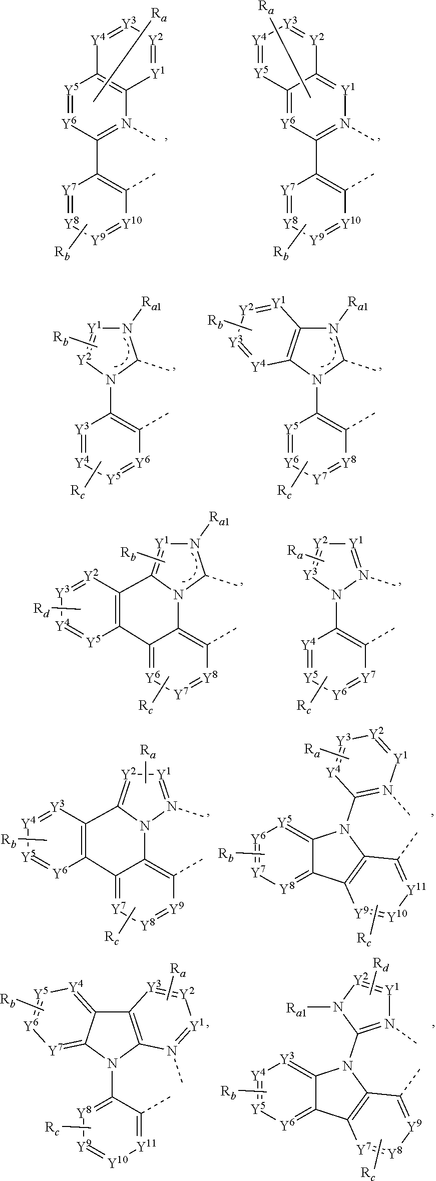

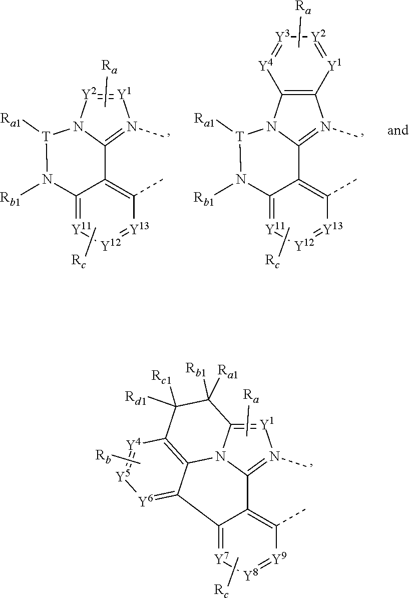

wherein T is selected from the group consisting of B, Al, Ga, and In; each of Y¹ to Y¹³ is independently selected from the group consisting of C and N; Y′ is selected from the group consisting of BRₑ, NRₑ, PRₑ, O, S, Se, C═O, S═O, SO₂, CRₑR_{f}, SiRₑR_{f}, and GeRₑR_{f}; Rₑ and R_{f} can be fused or joined to form a ring; each Rₐ, R_{b}, R_{c}, and Rₐ independently represents zero, mono, or up to the maximum number of allowed substitutions to its associated ring; each of Rₐ₁, R_{b1}, R_{c1}, R_{d1}, Rₐ, R_{b}, R_{c}, R_{d}, Rₑ and R_{f} is independently a hydrogen or a subsituent selected from the group consisting of the general substituents defined herein; and any two adjacent substituents can be fused or joined to form a ring or form a multidentate ligand.

In some embodiments, L_{B} and L_{C} are each independently selected from the group consisting of the compounds in LIST3 below:

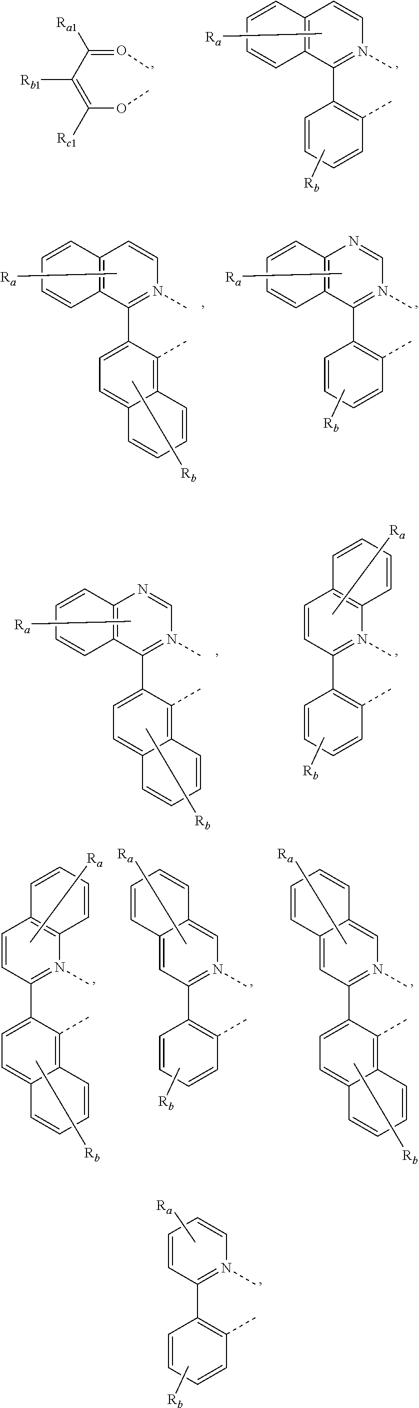

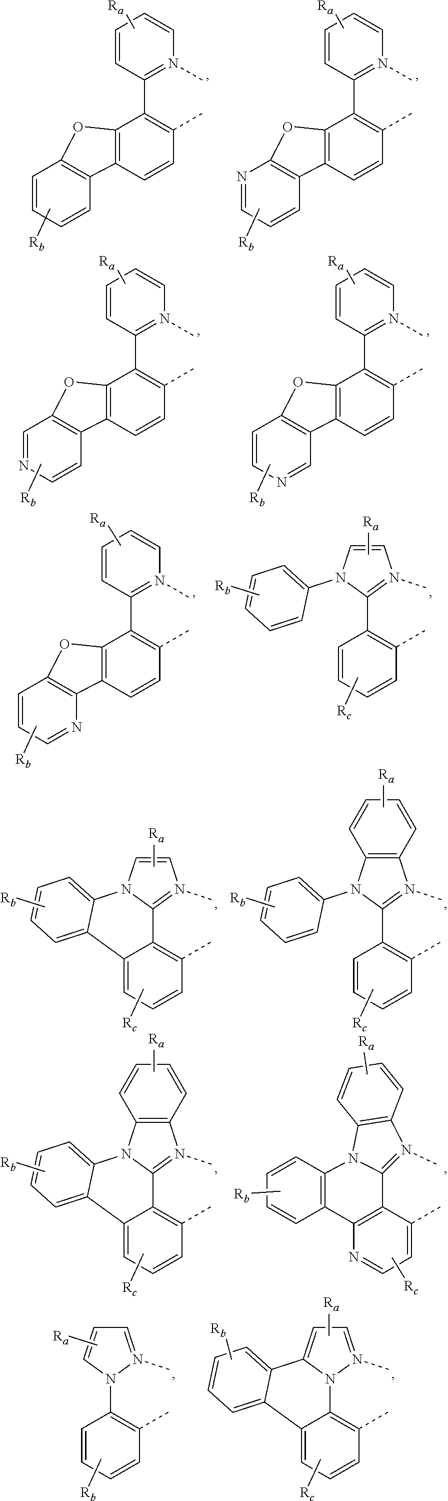

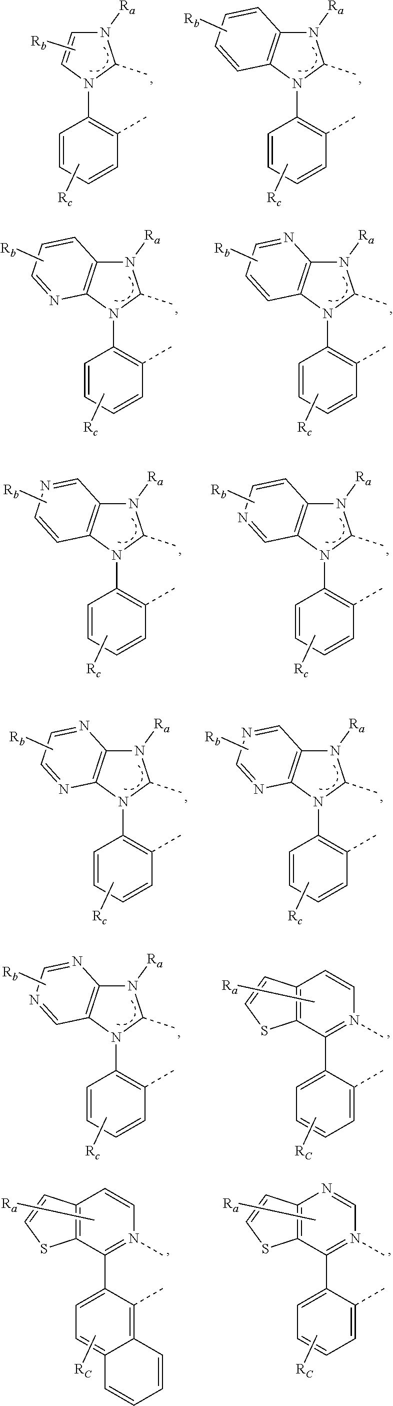

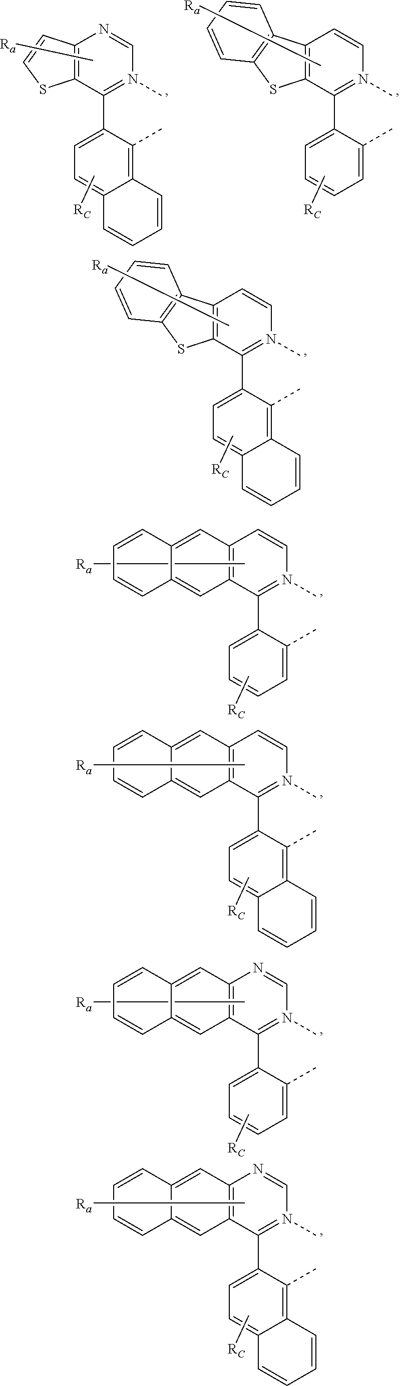

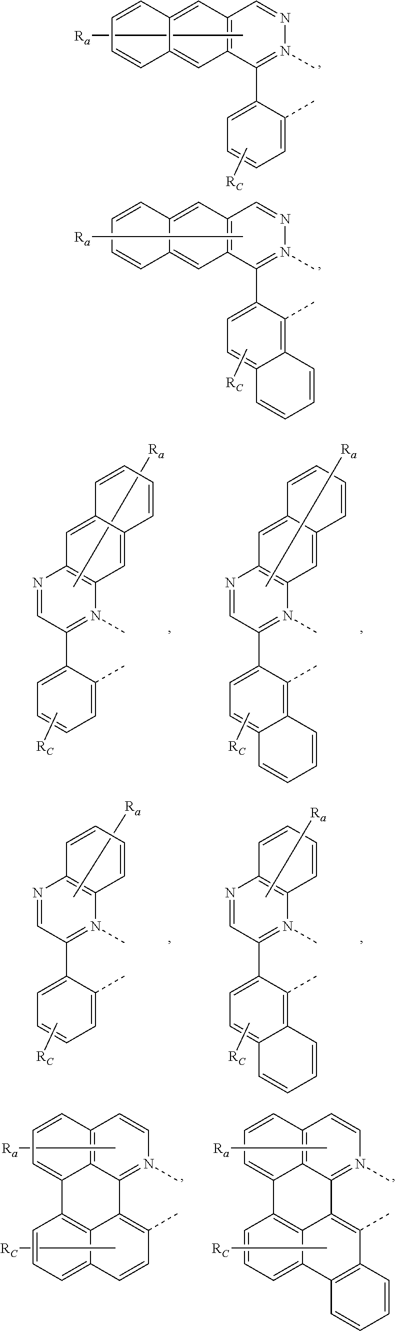

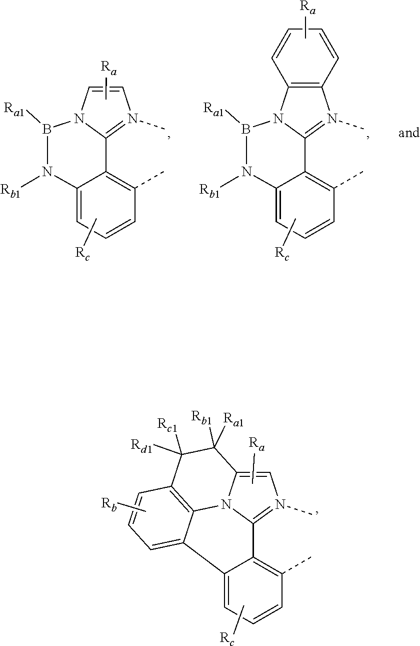

wherein Rₐ₁, R_{b1}, R_{c1}, Rₐ₁, Rₐ, R_{b}, and R_{c} are all as defined above for LIST2, wherein each of them can form a ring with another wherever chemically feasible.

In some embodiments, the compound is Compound A having the formula Ir(L_{A})₃, Compound B having the formula Ir(L_{A})(L_{B})₂, or Compound C having the formula Ir(L_{A})₂(L_{C}), wherein L_{A} can be any of the structures for L_{A} defined above; L_{B} is selected from the group consisting of L_{B1} through L_{B483} shown in LIST4 below:

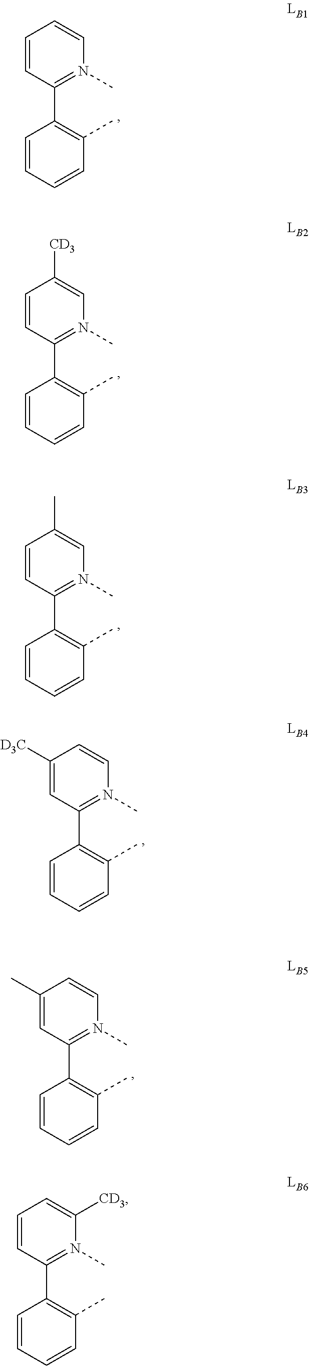

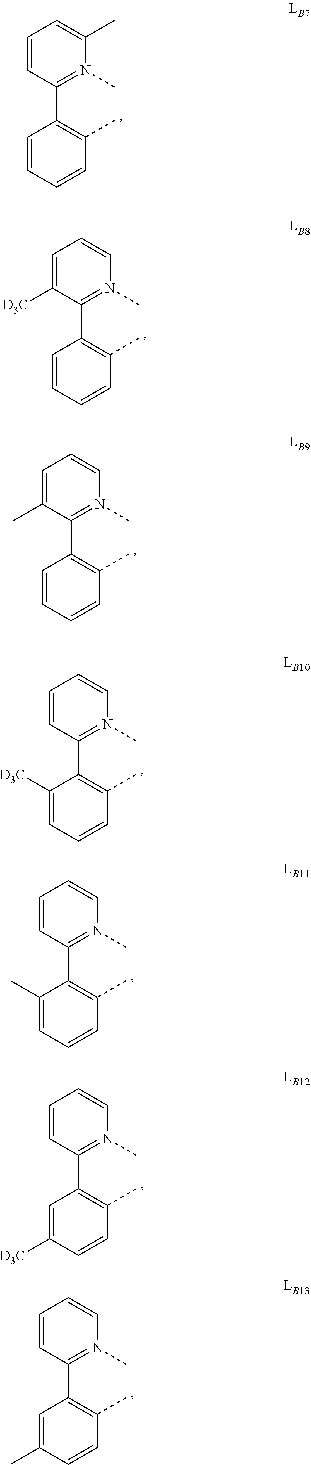

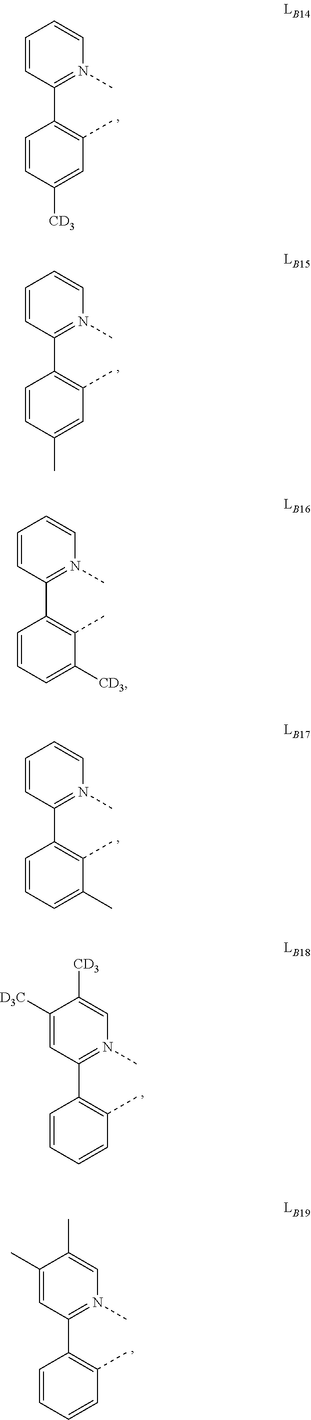

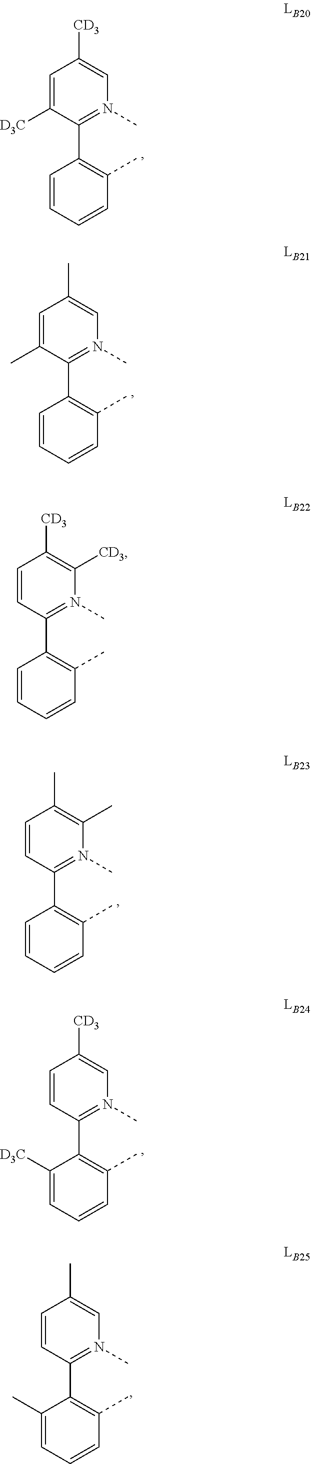

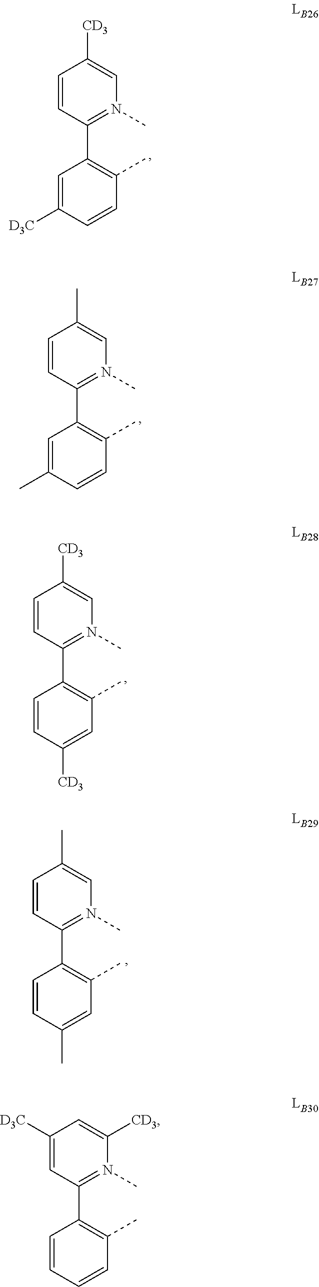

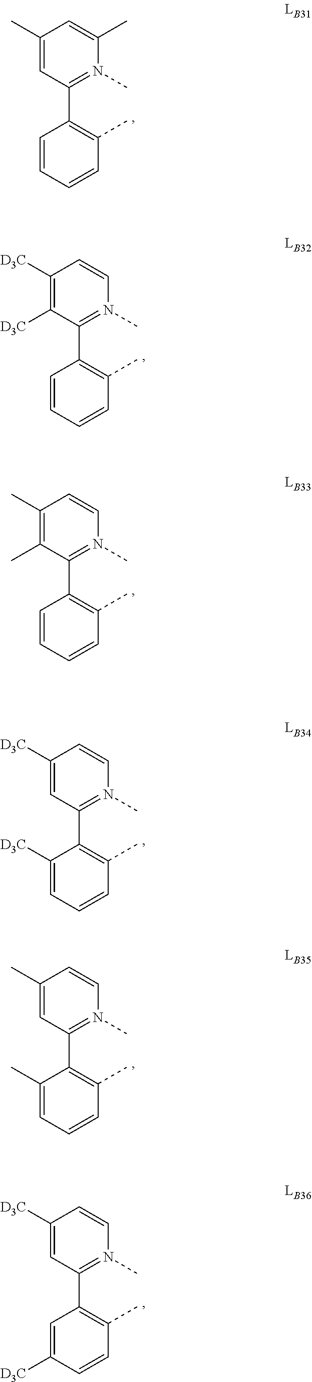

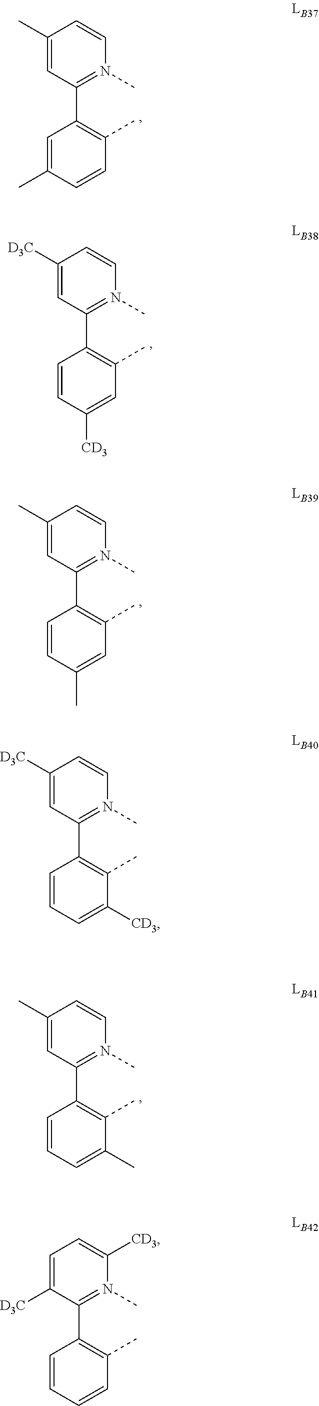

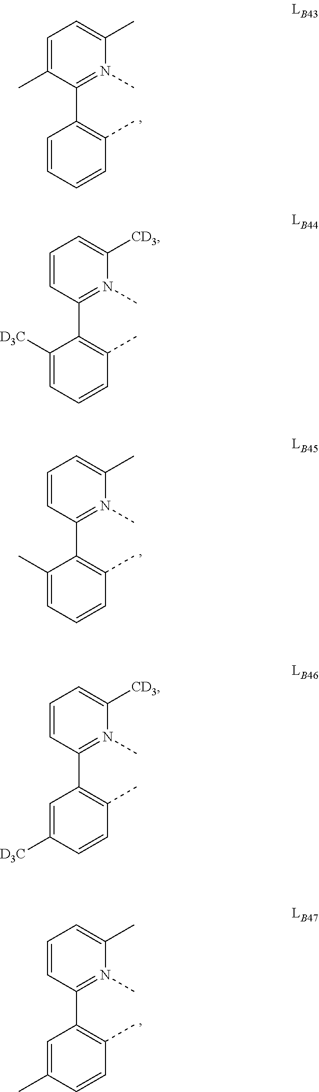

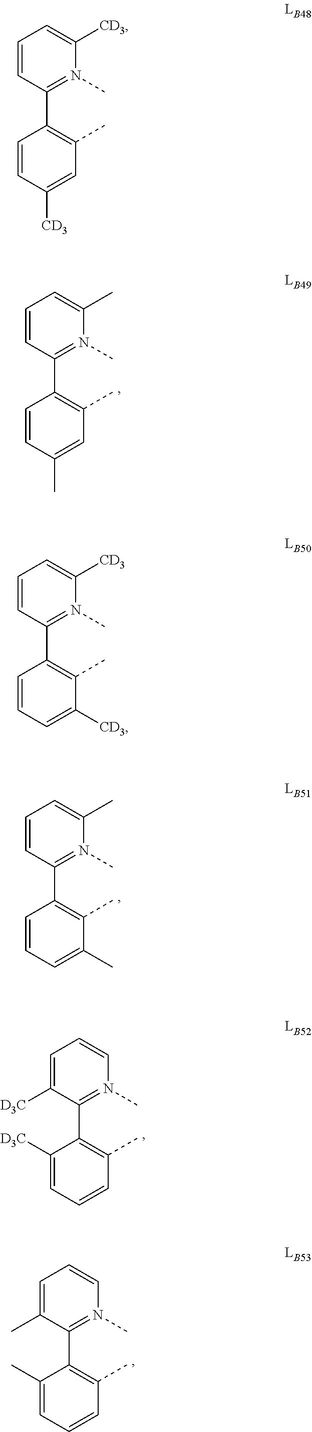

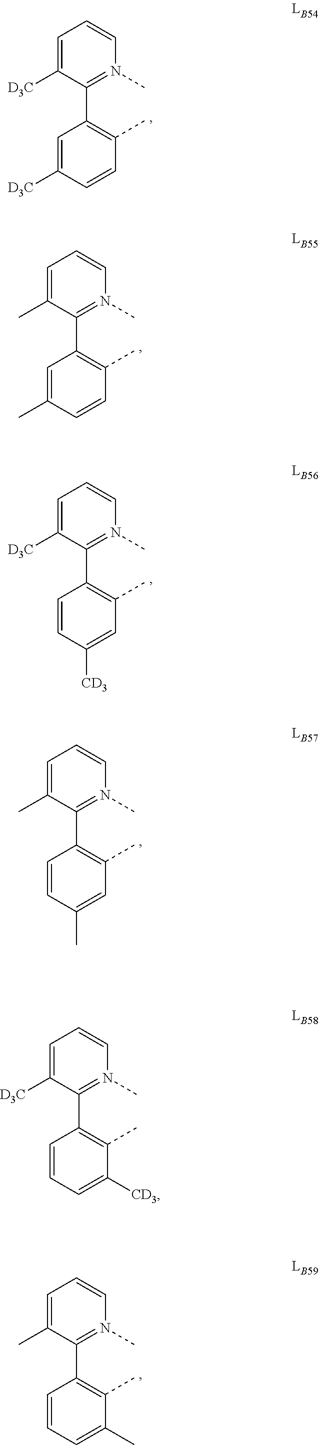

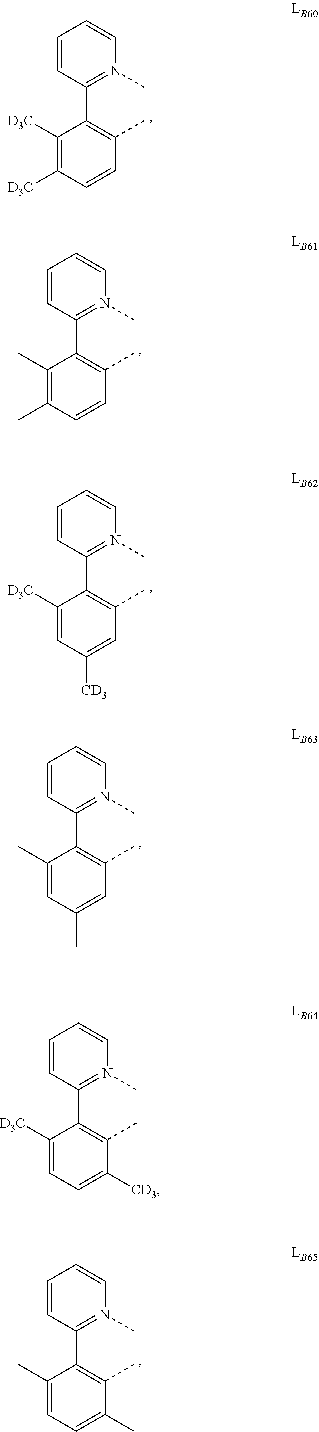

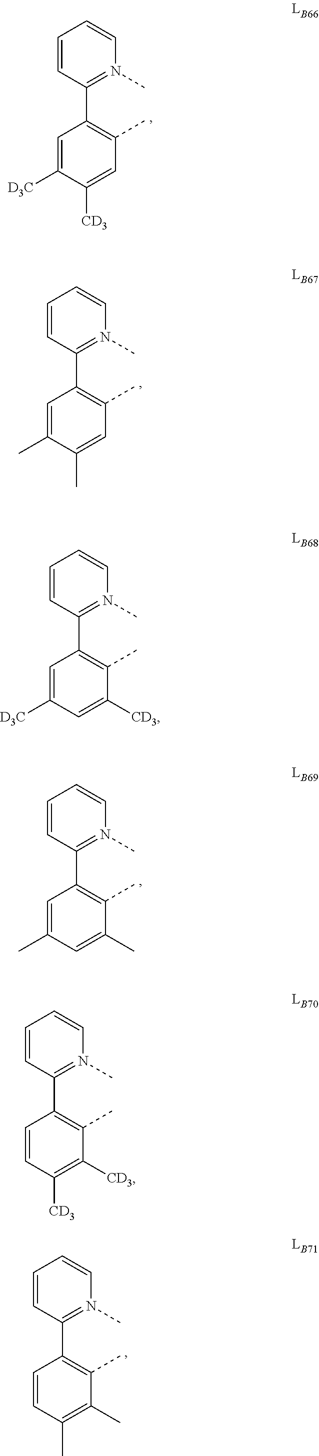

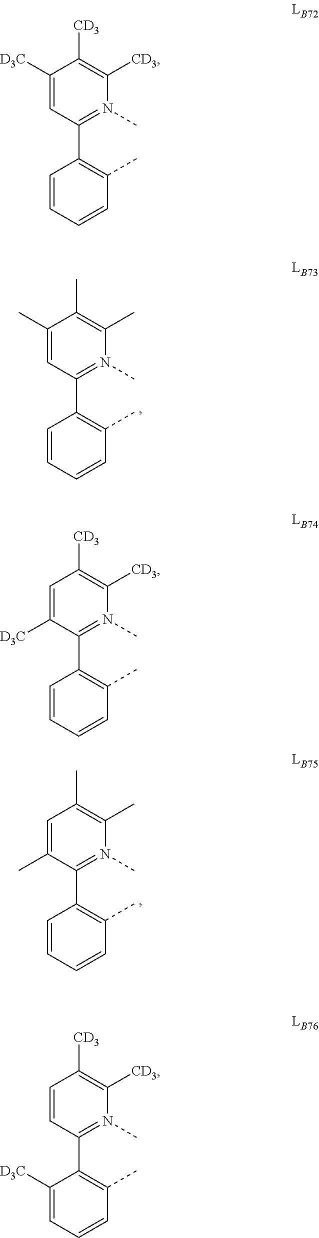

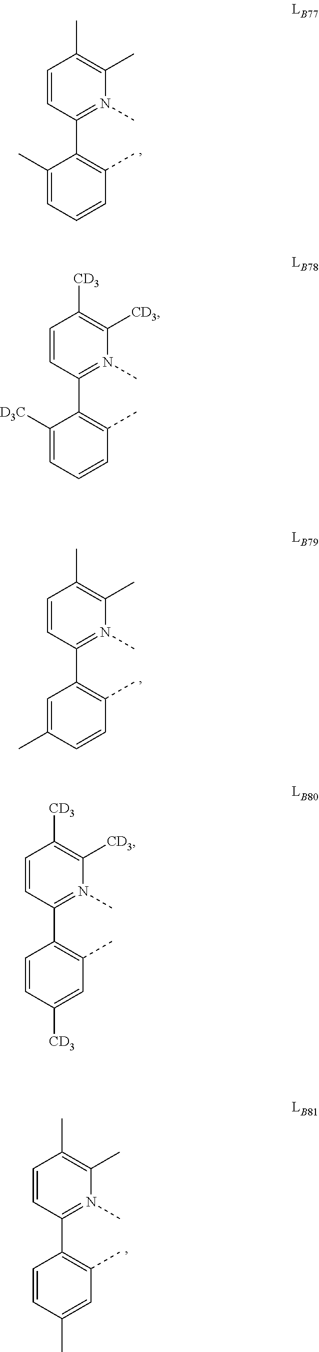

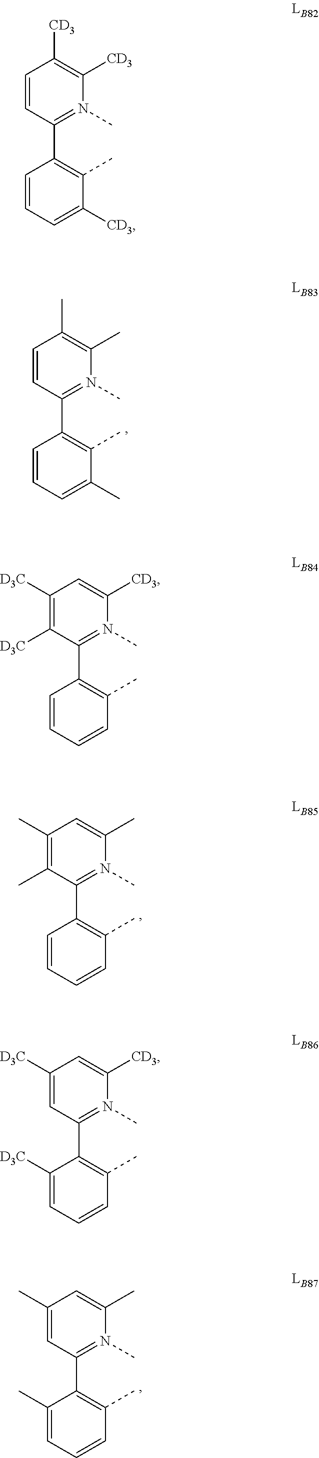

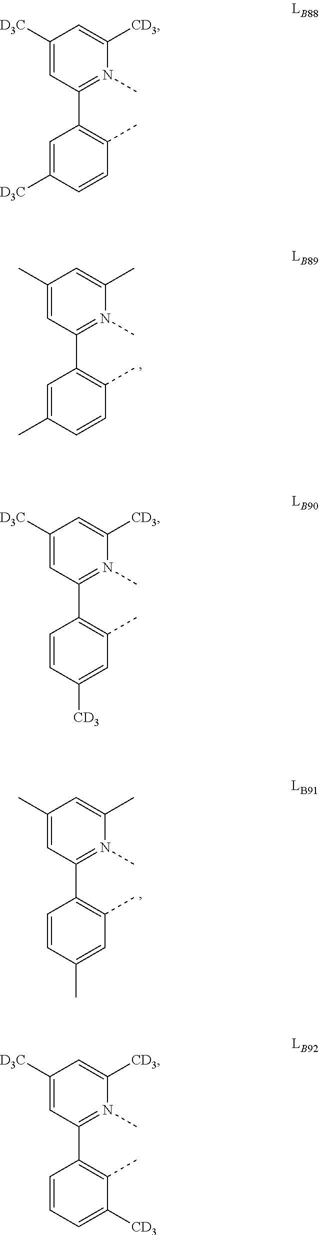

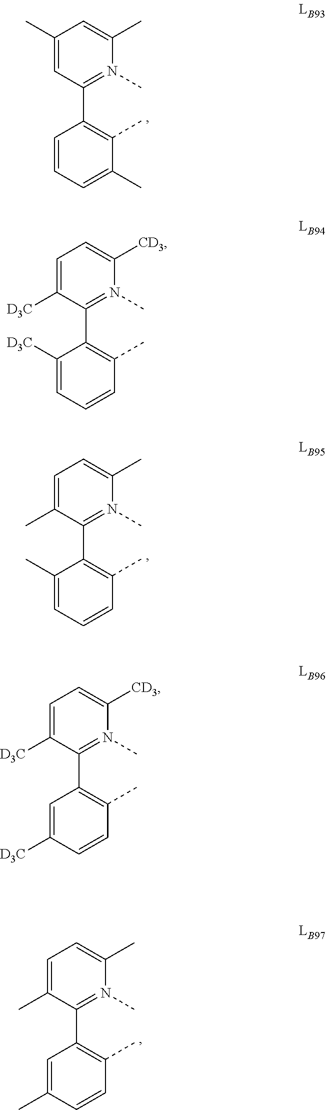

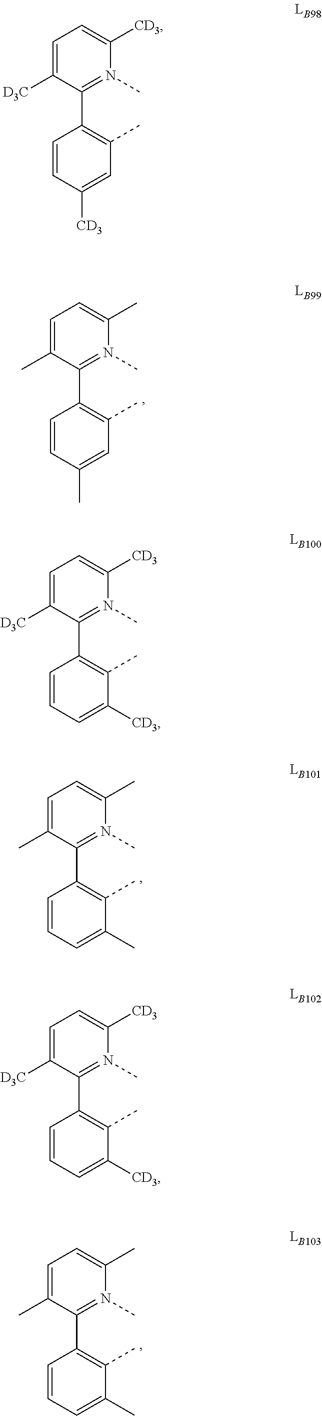

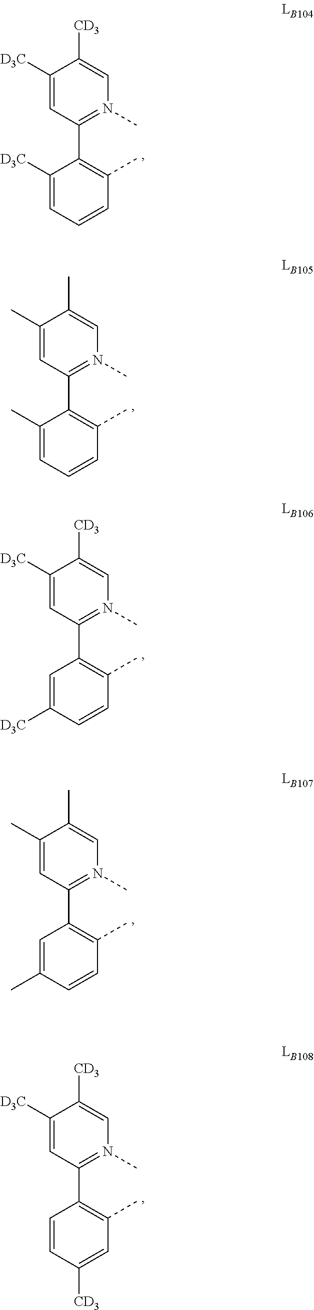

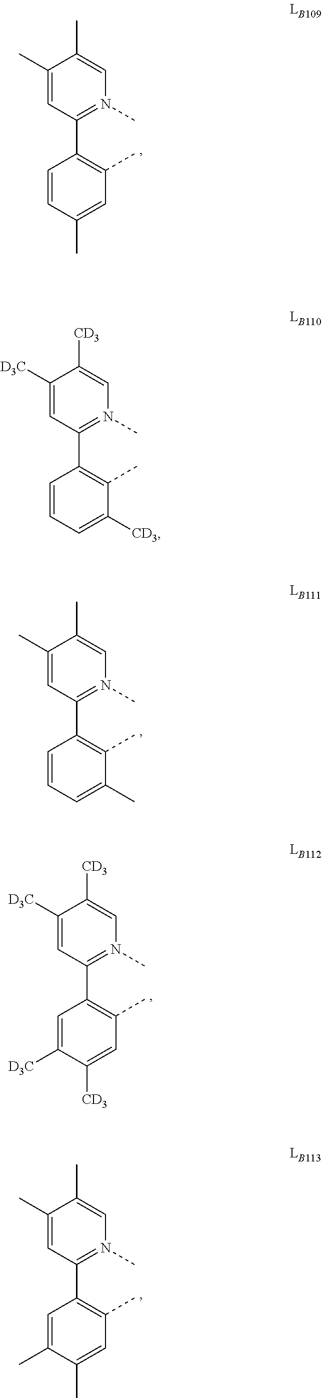

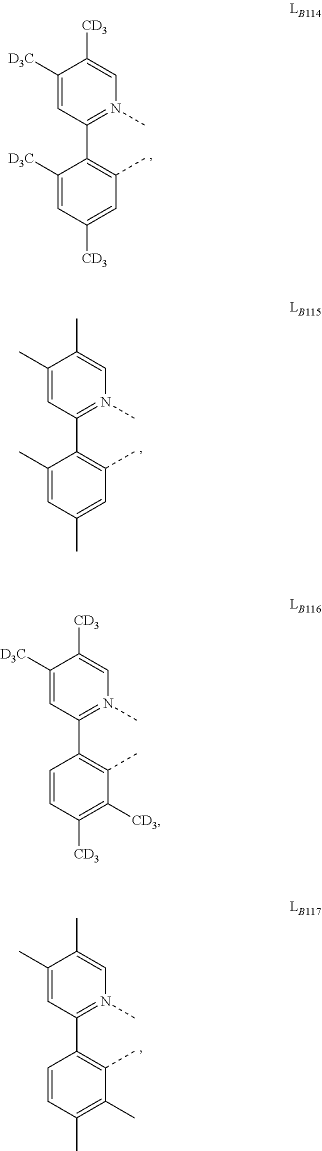

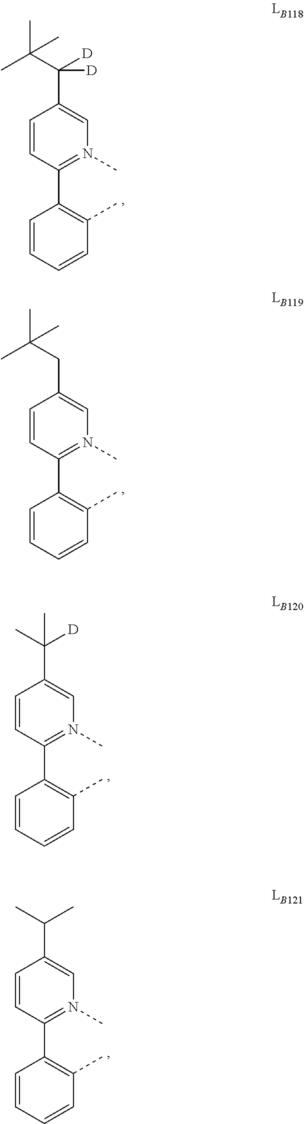

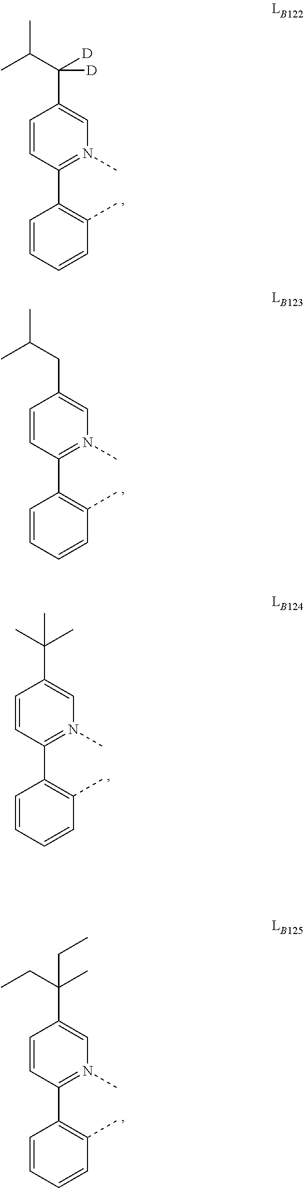

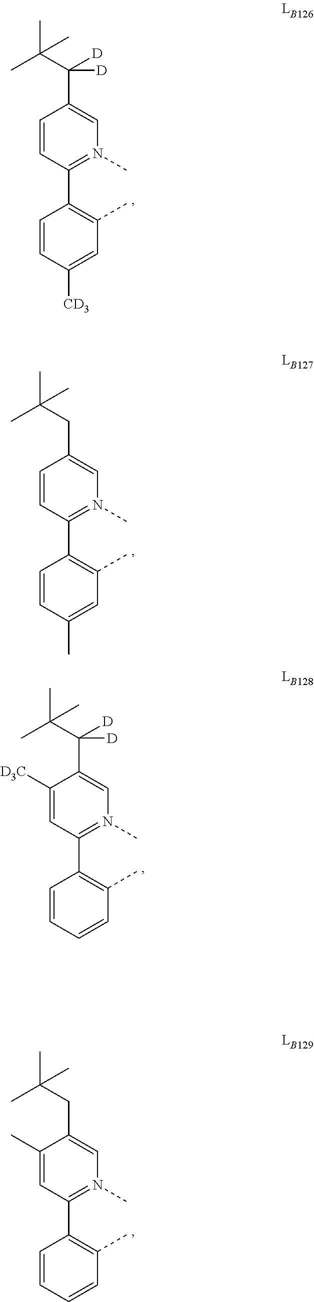

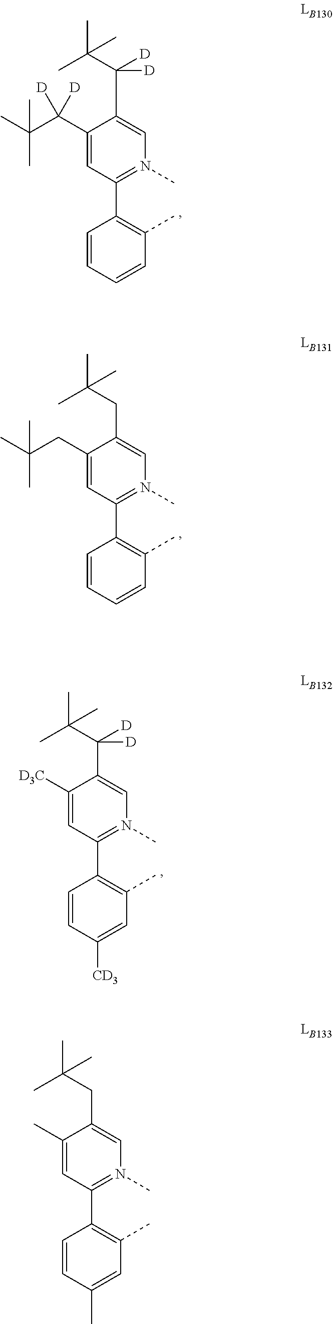

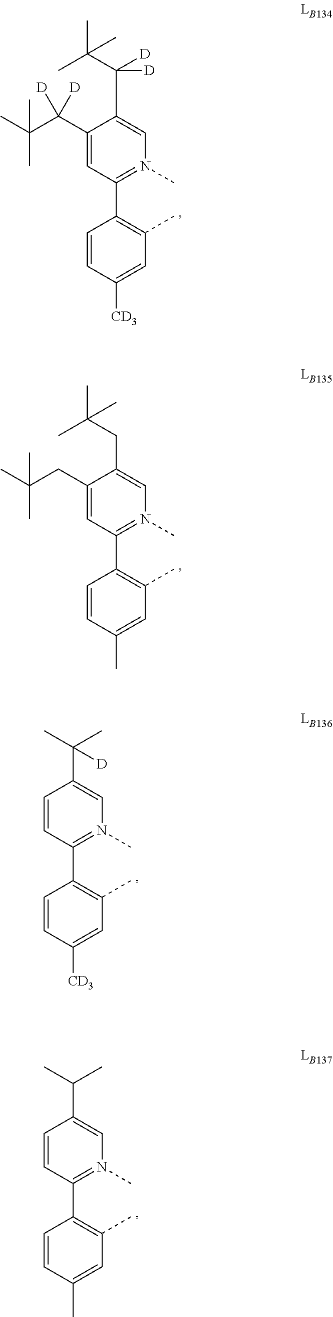

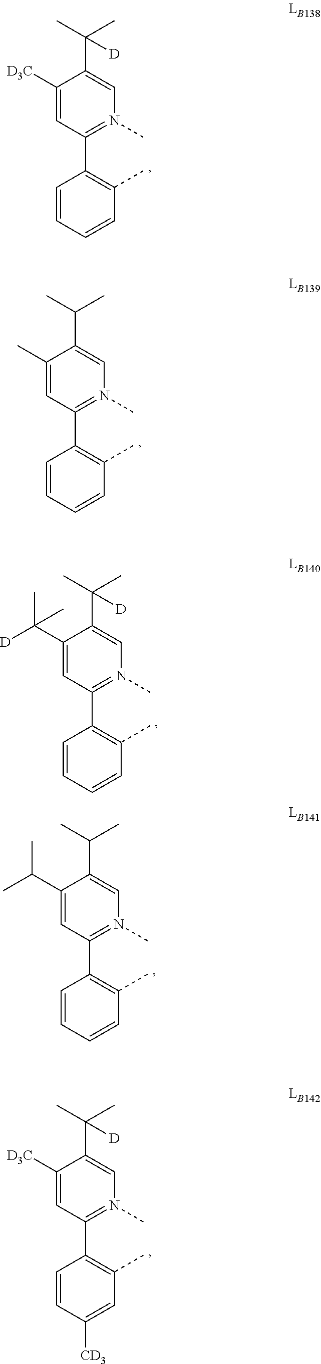

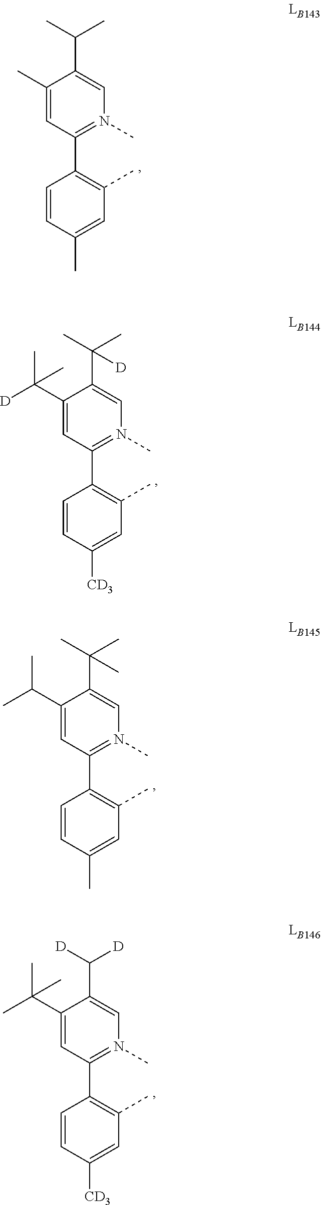

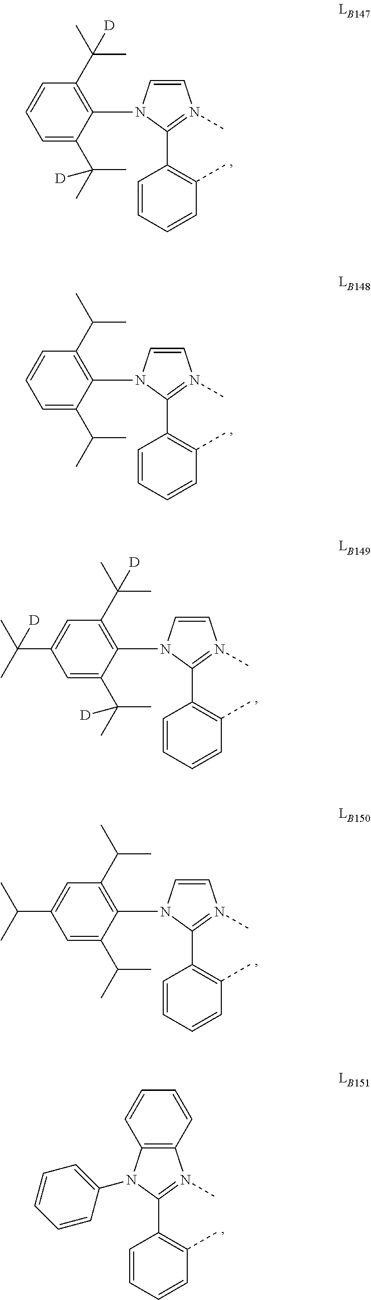

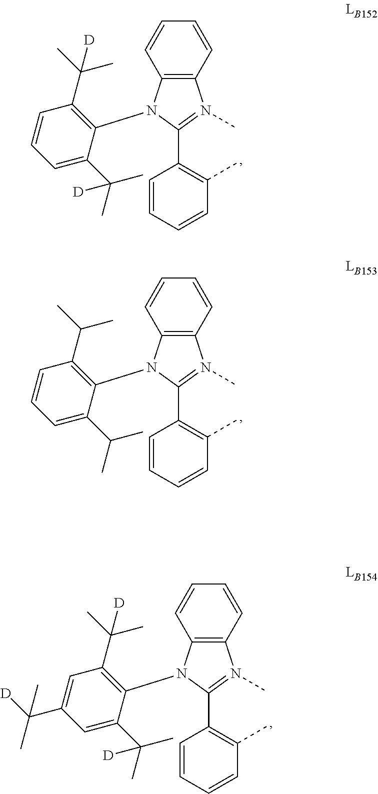

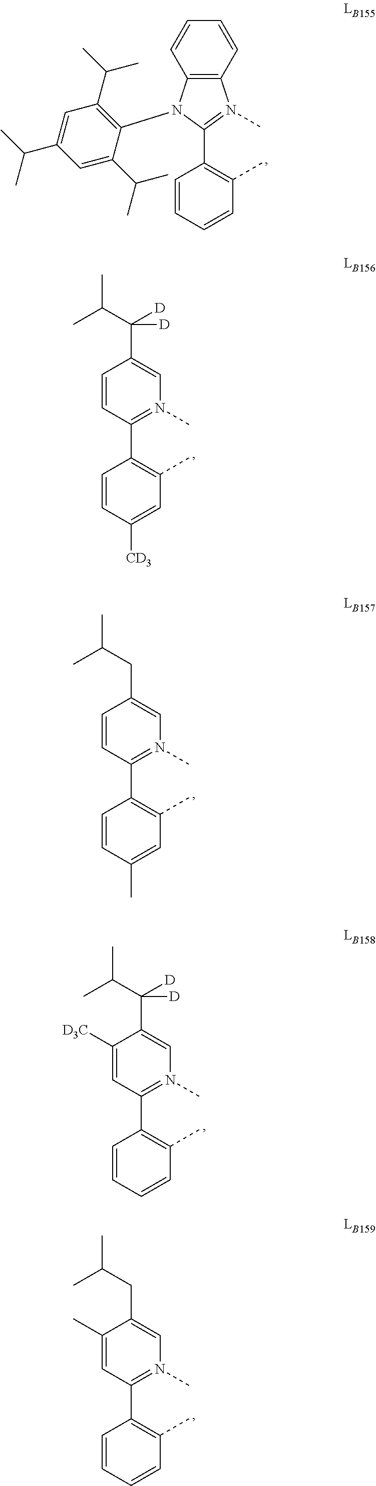

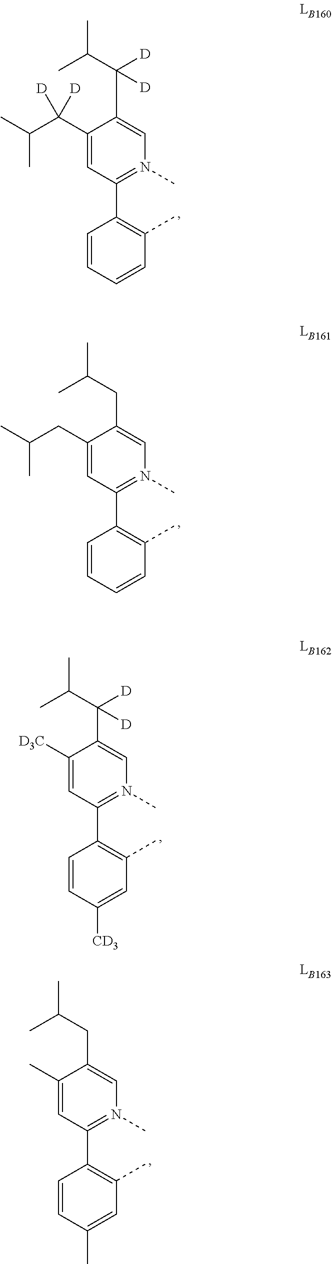

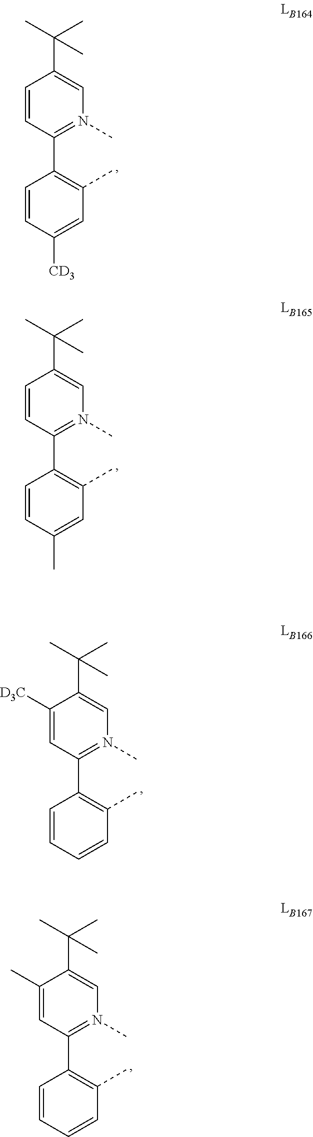

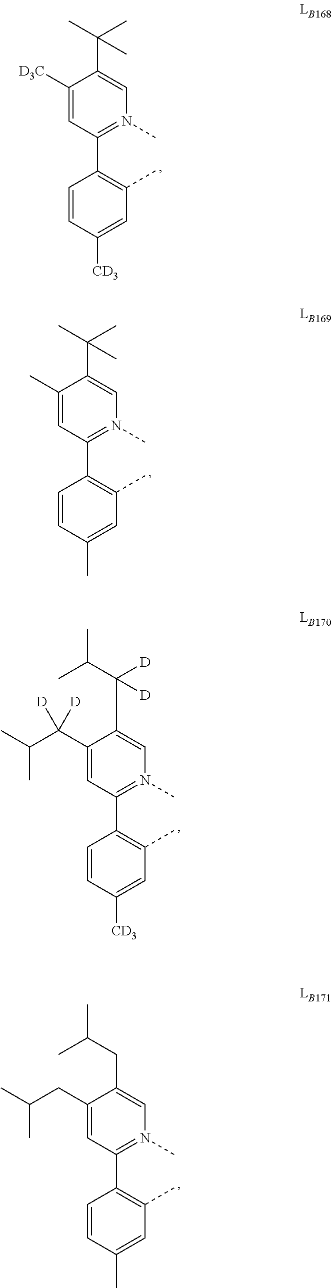

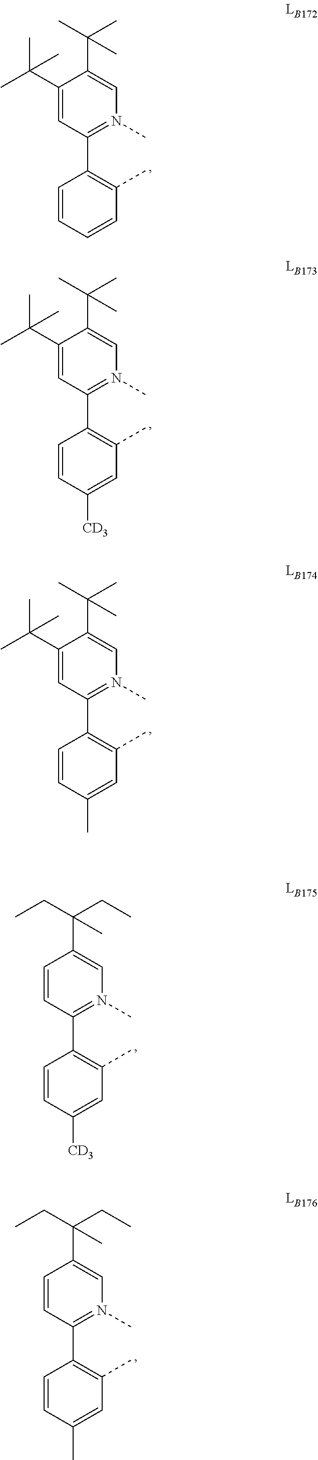

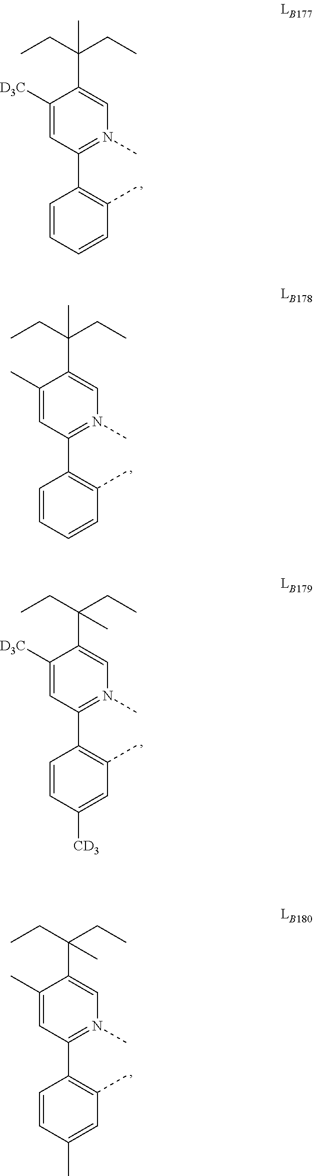

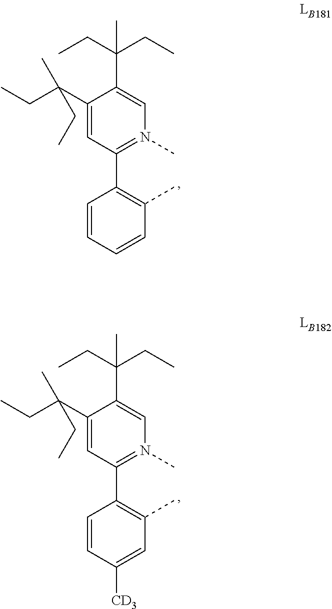

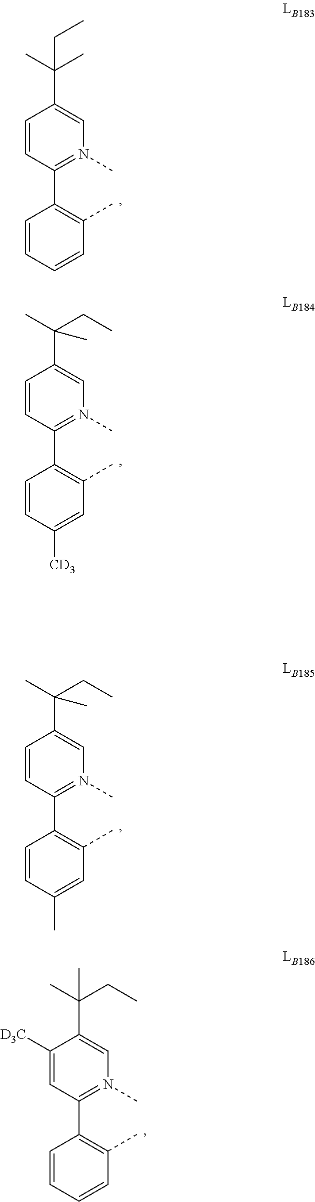

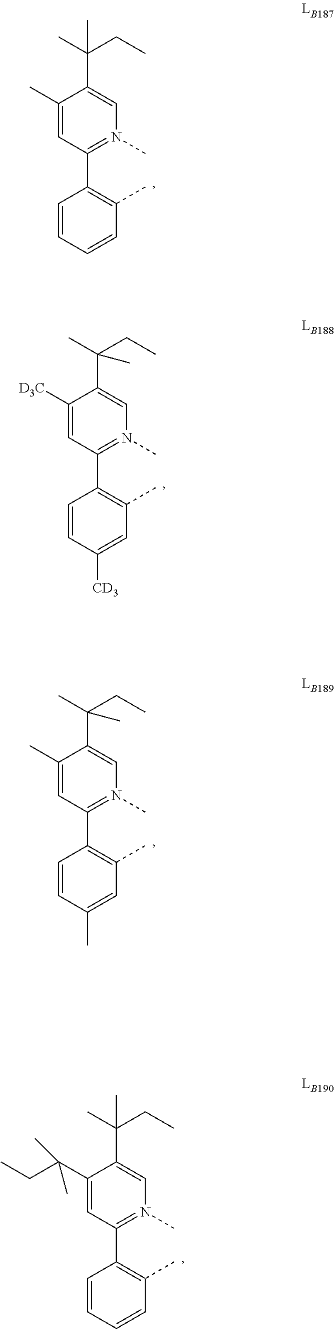

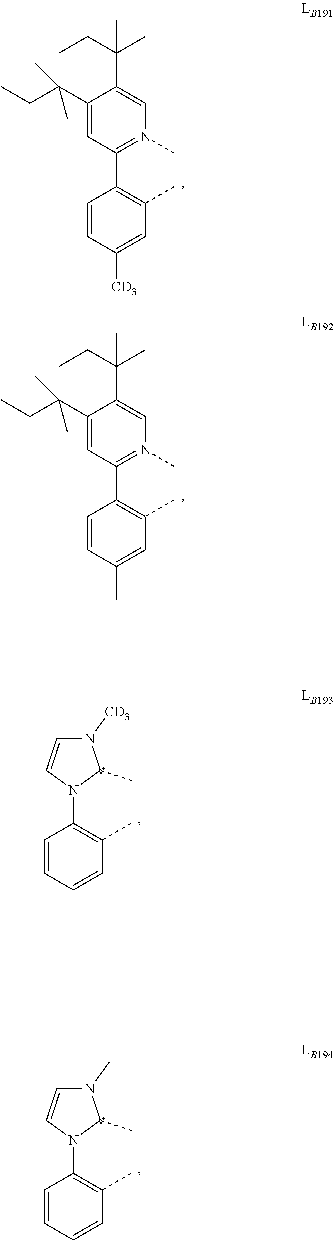

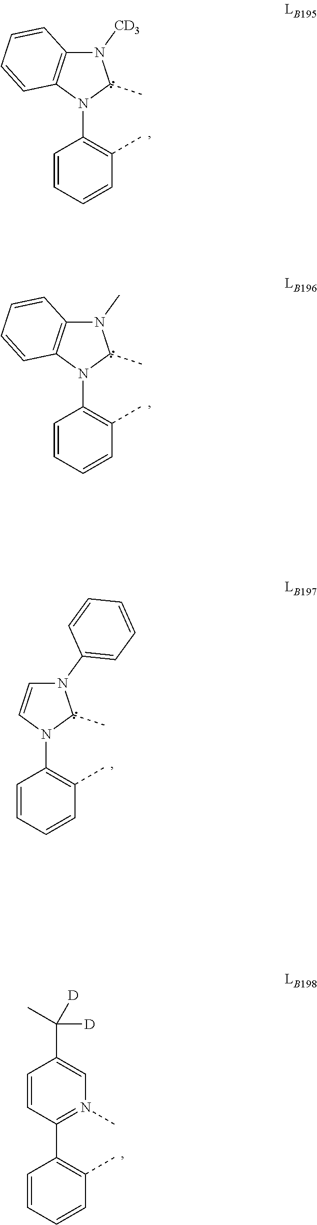

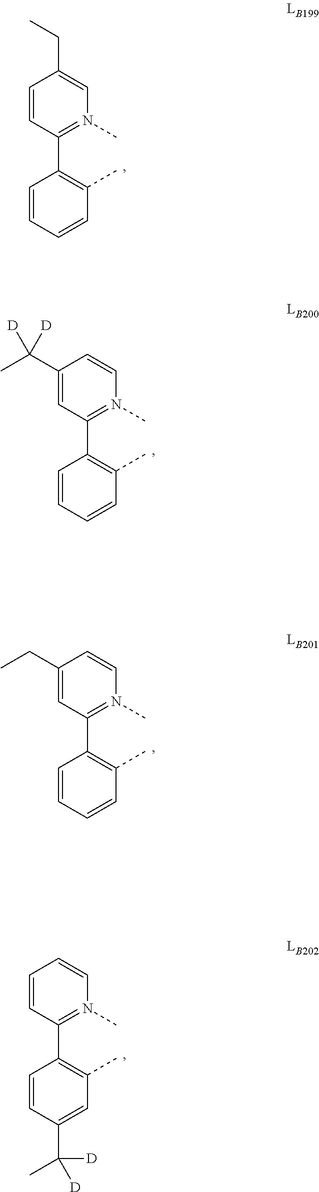

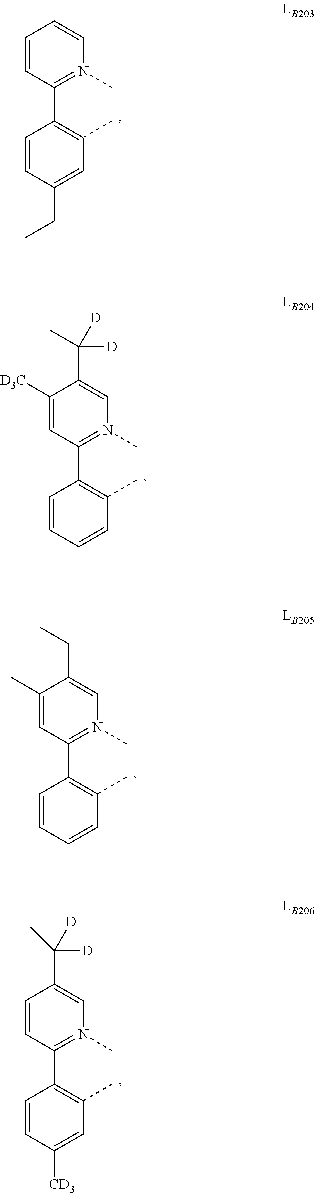

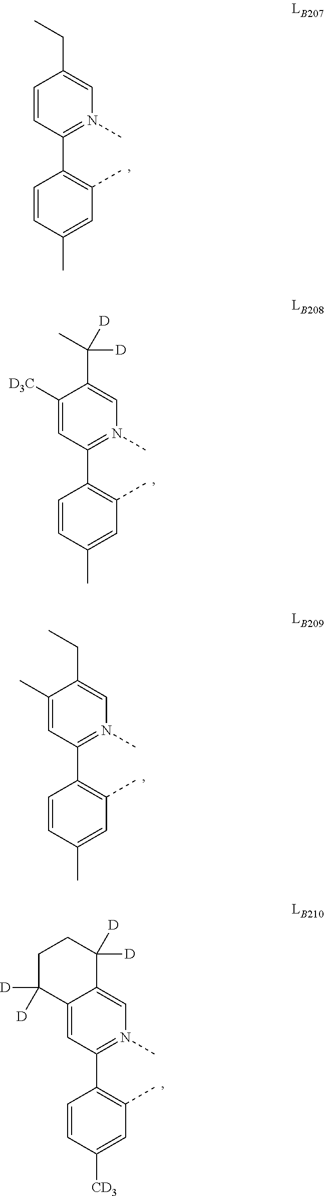

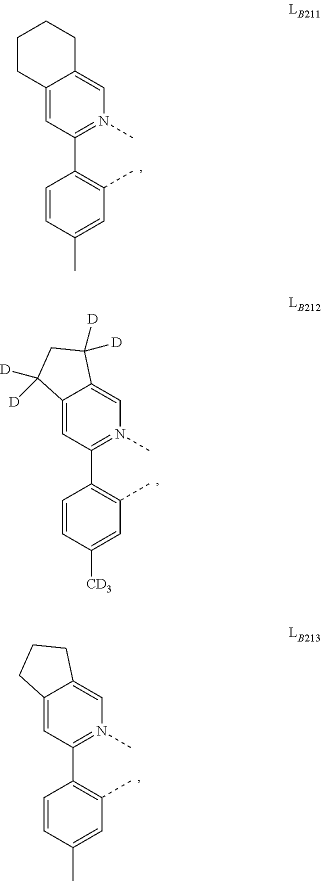

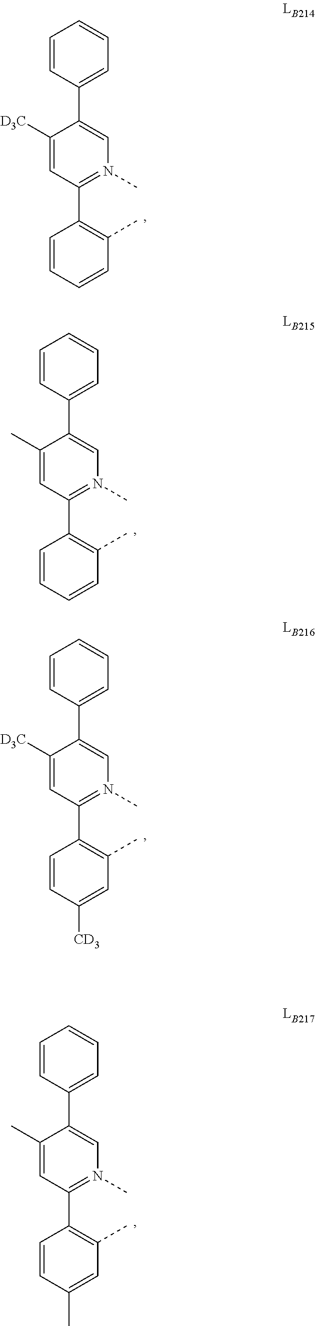

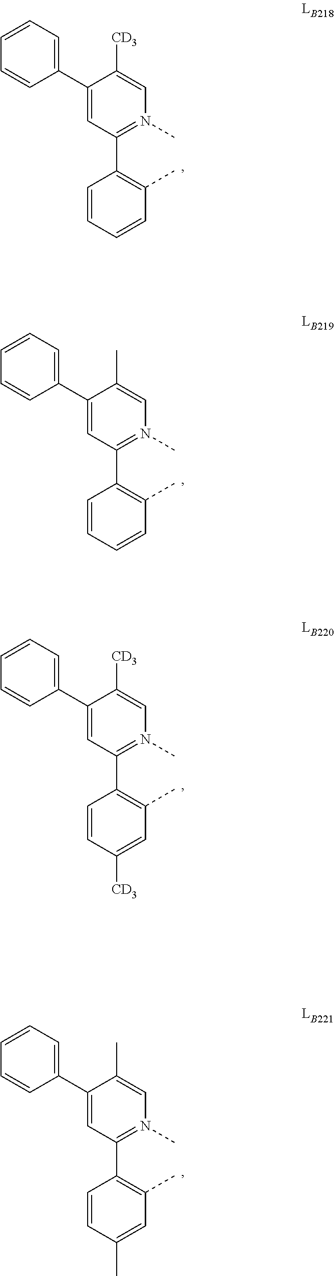

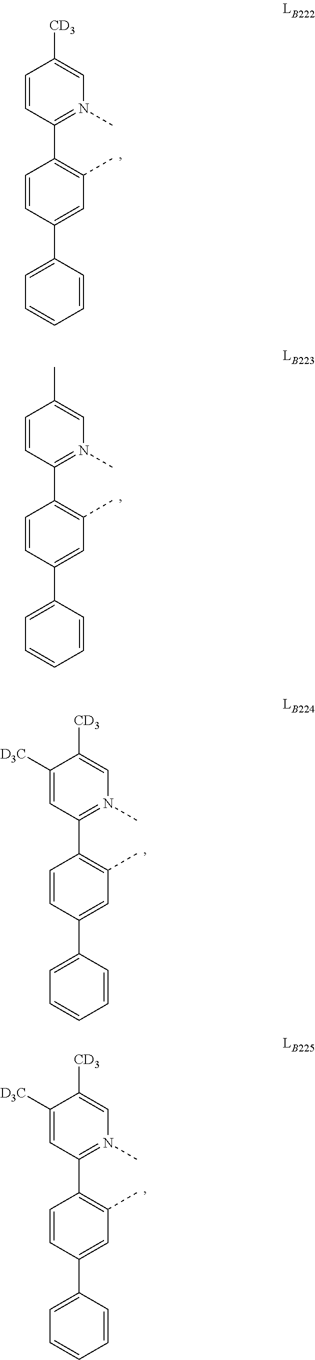

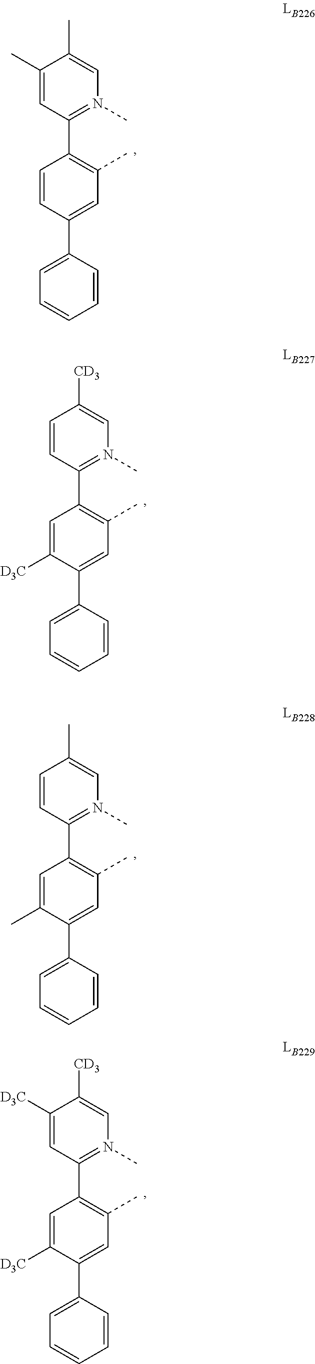

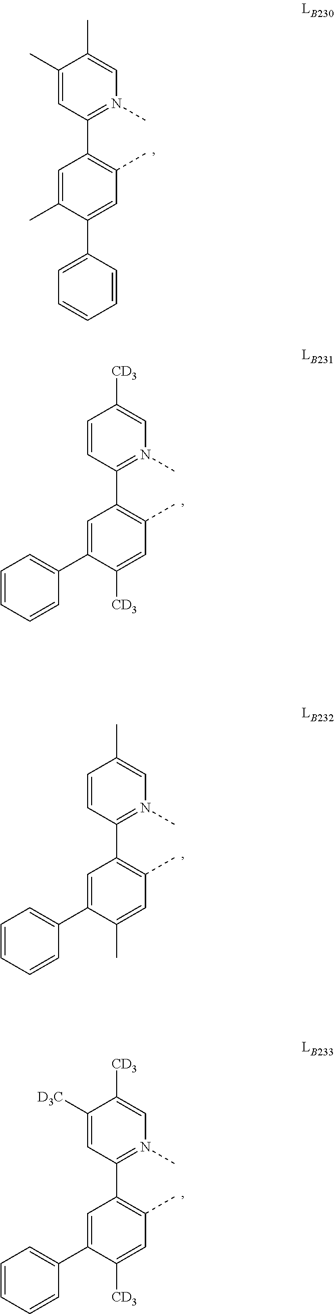

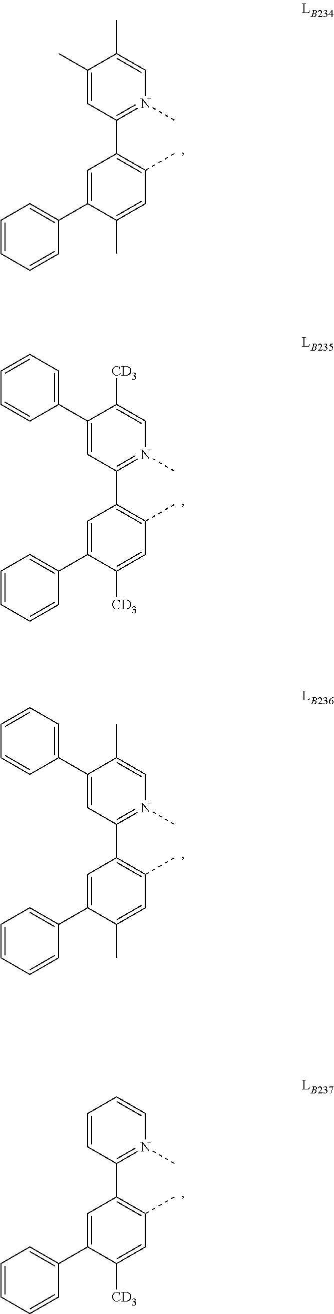

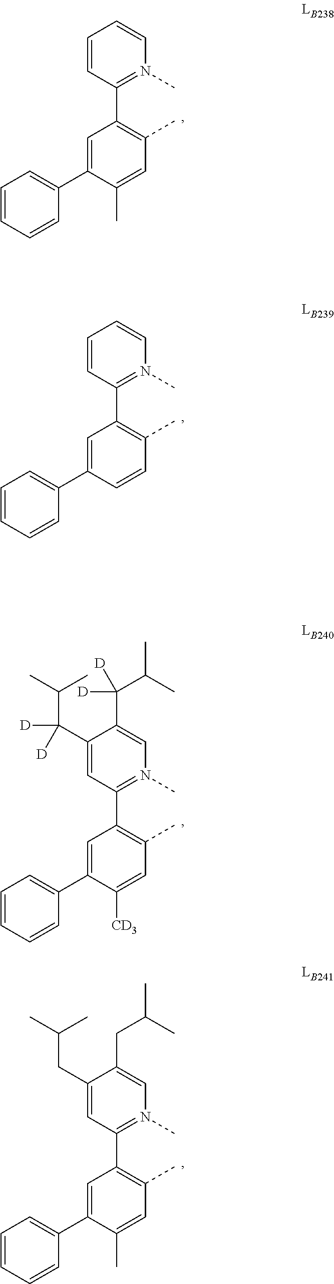

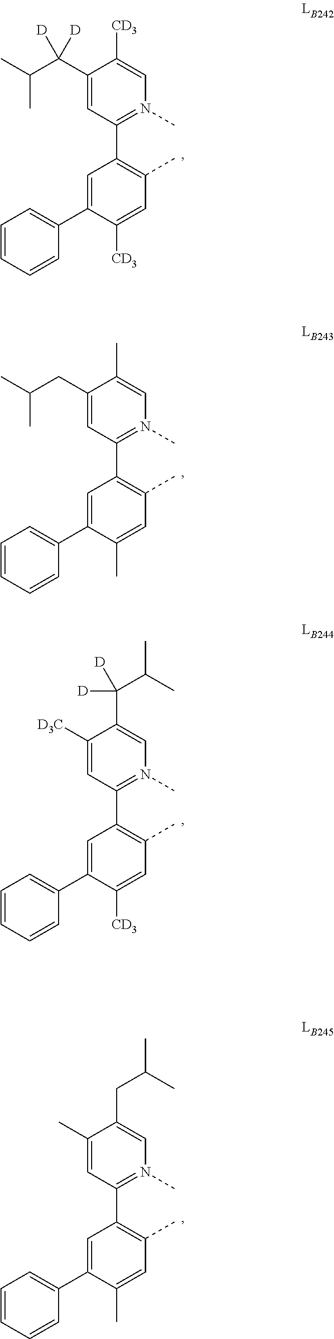

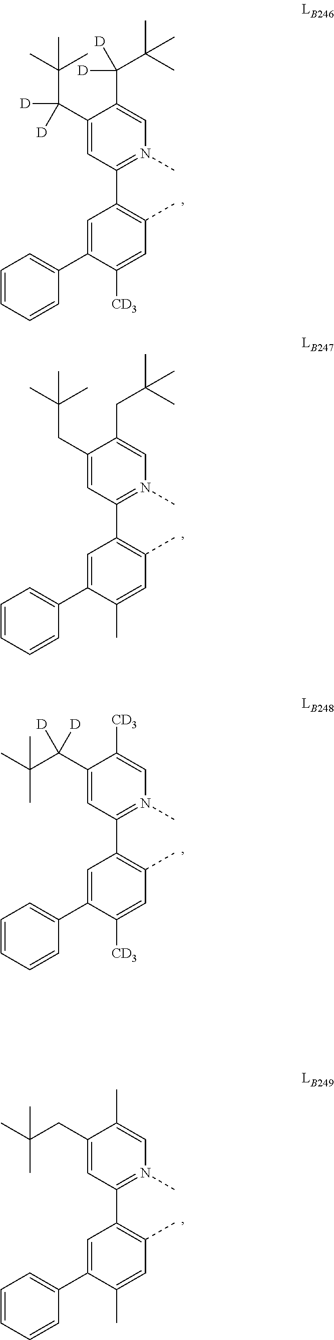

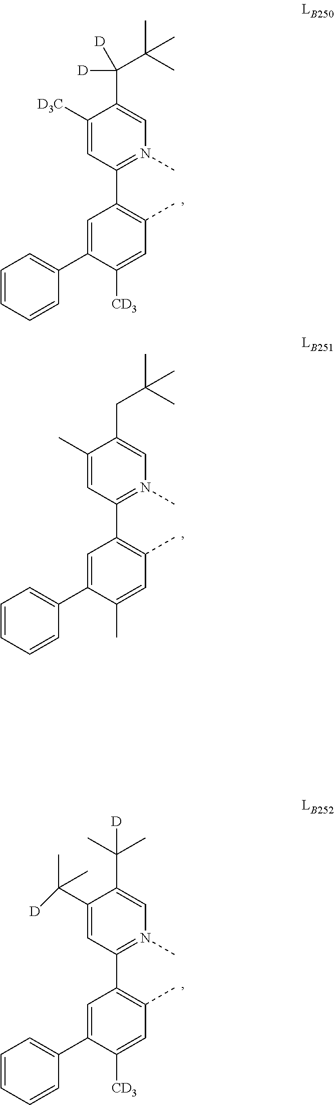

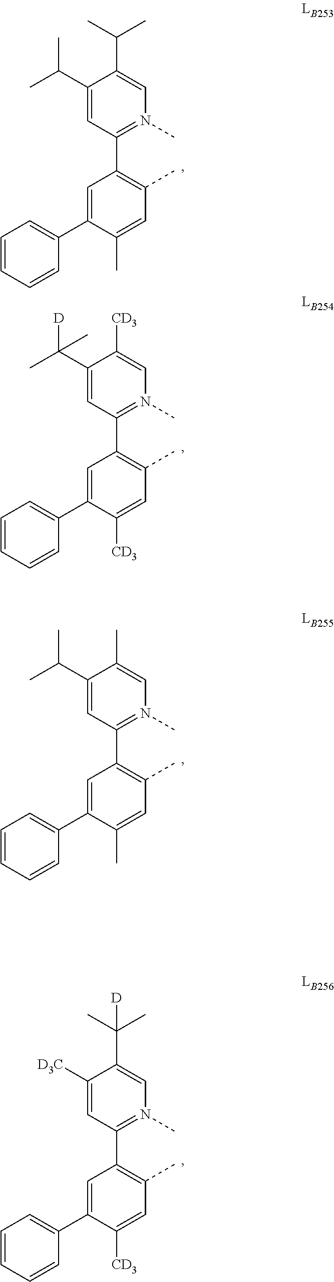

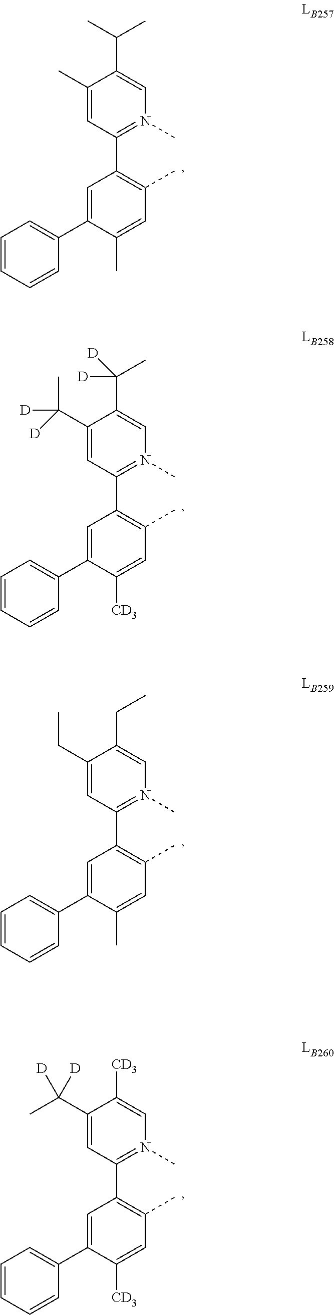

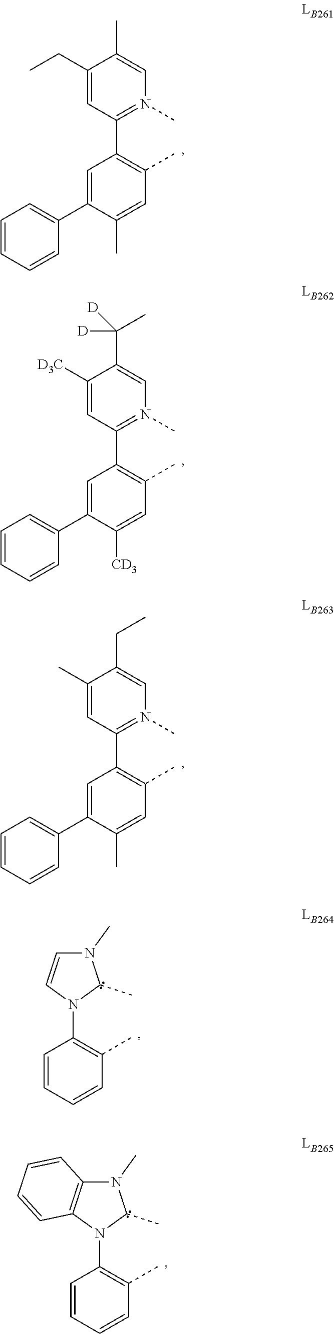

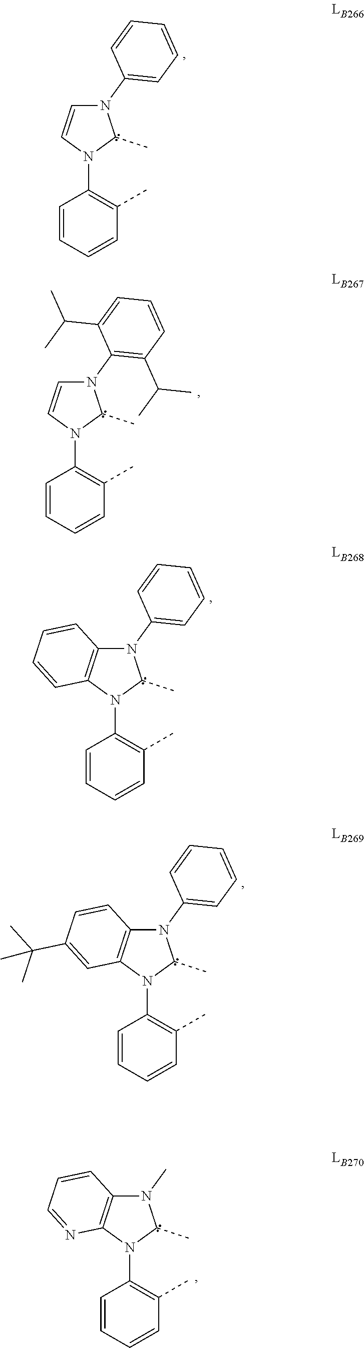

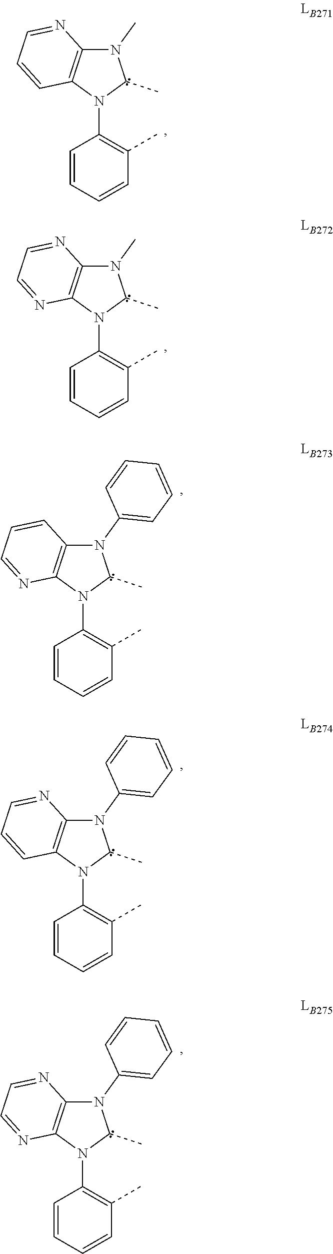

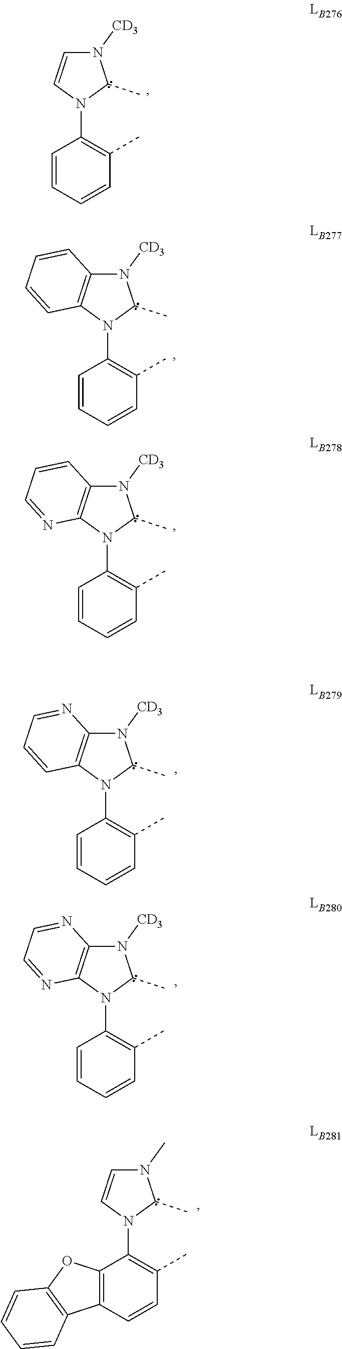

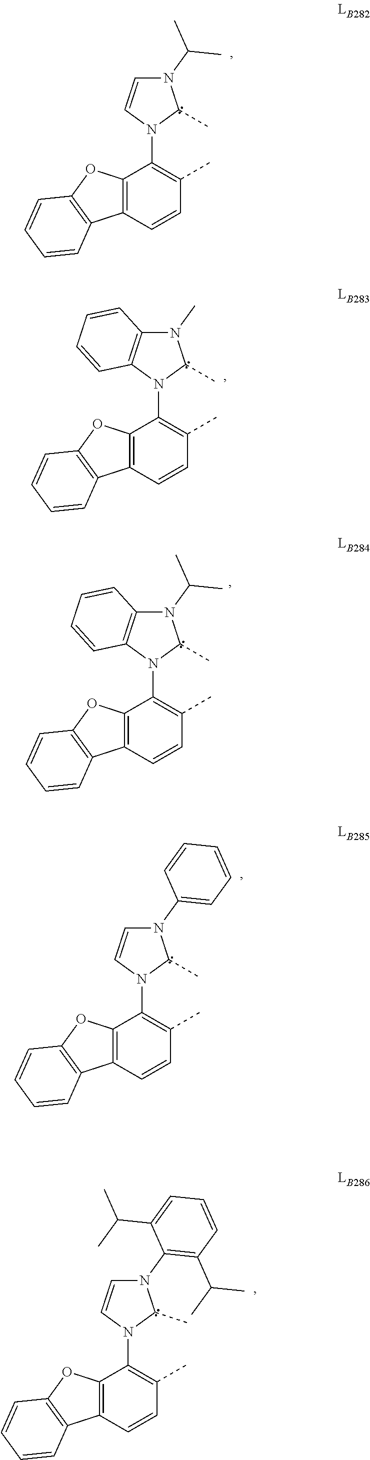

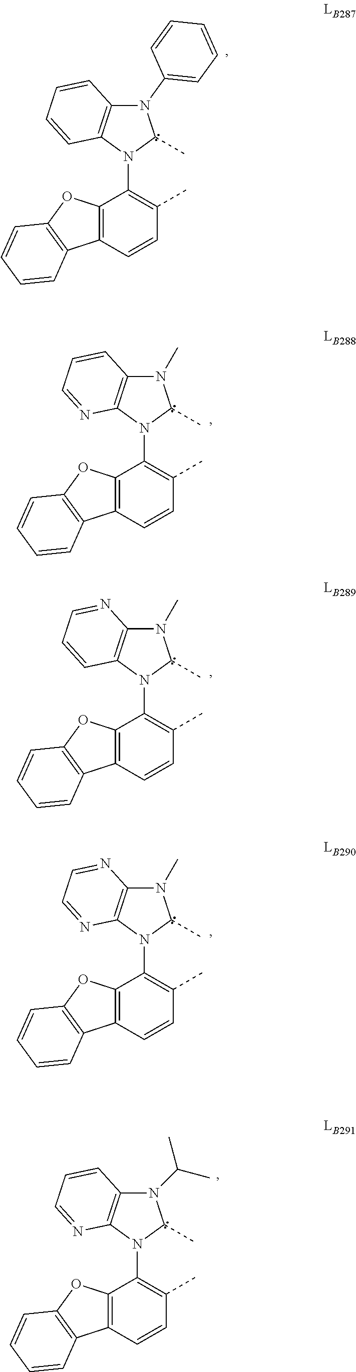

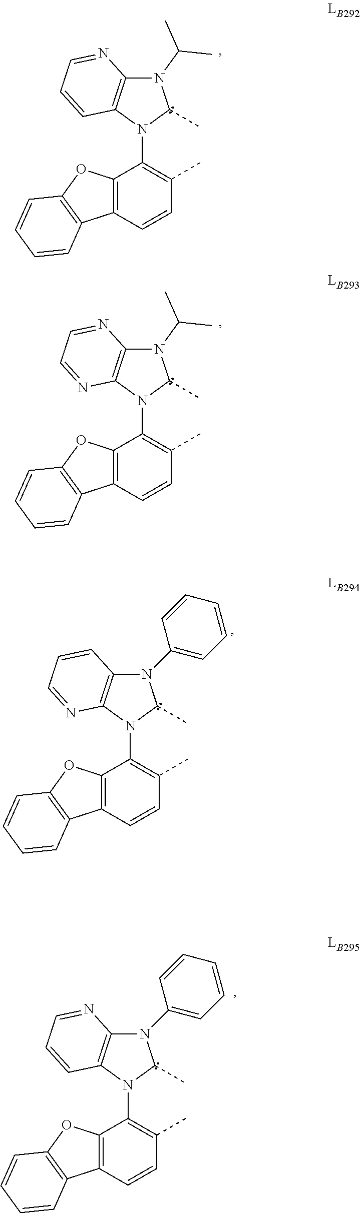

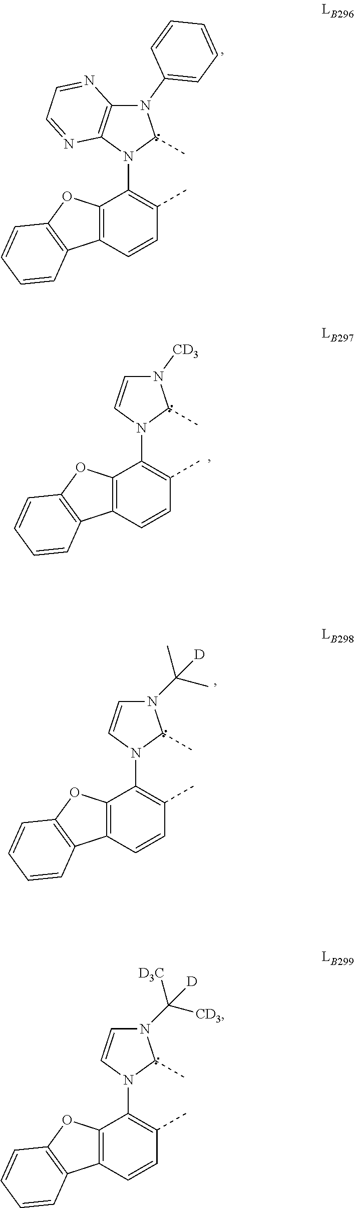

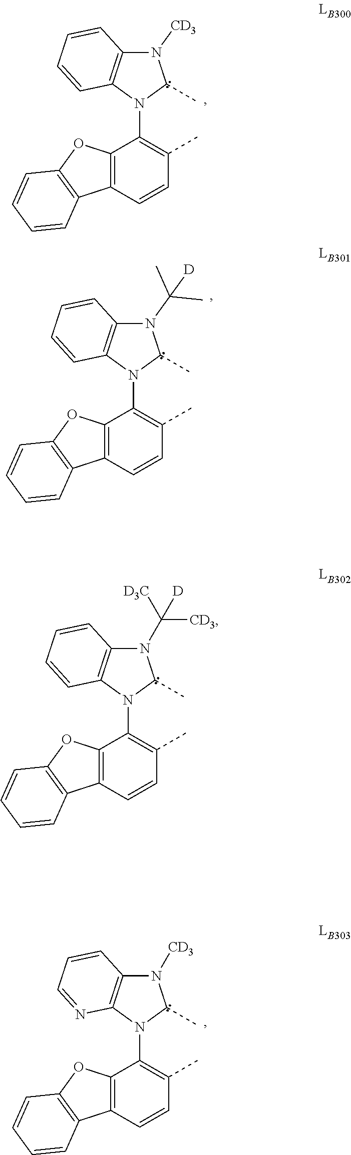

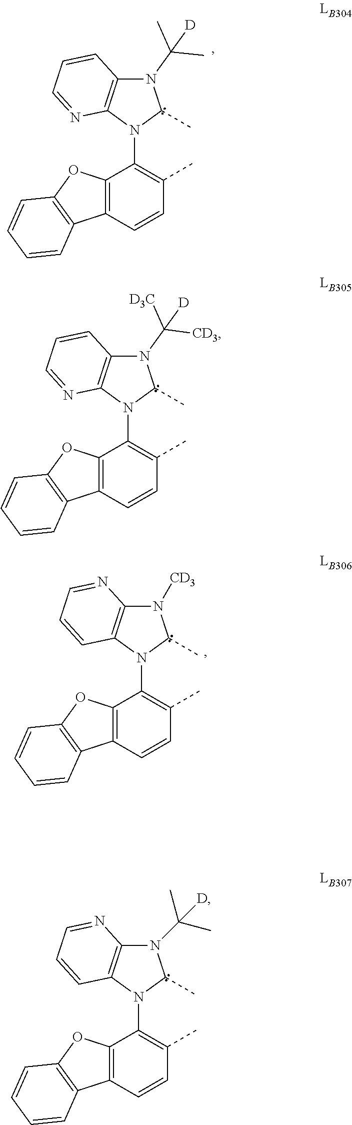

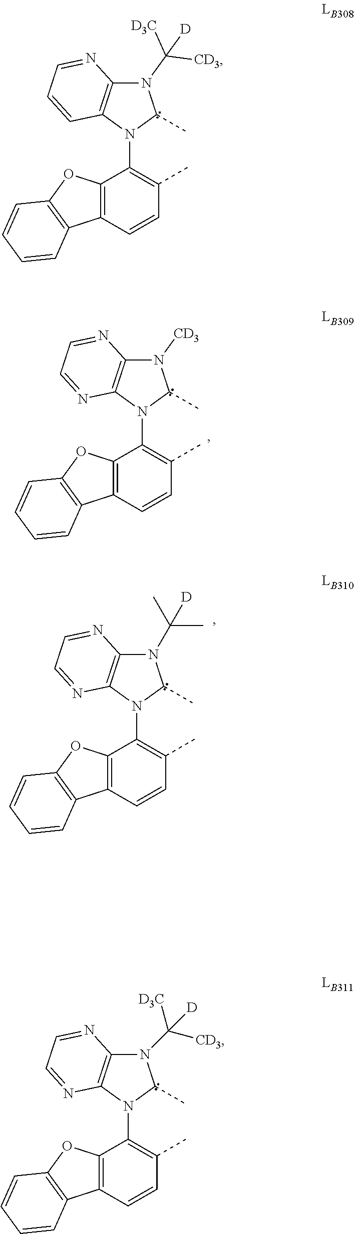

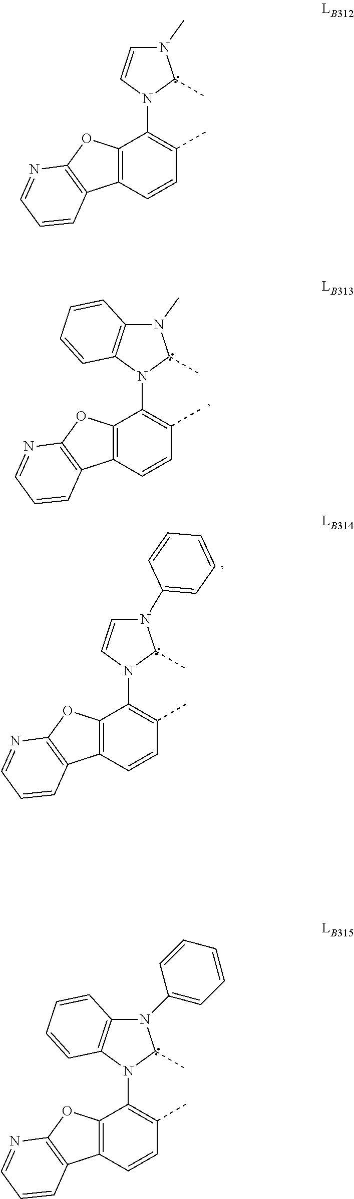

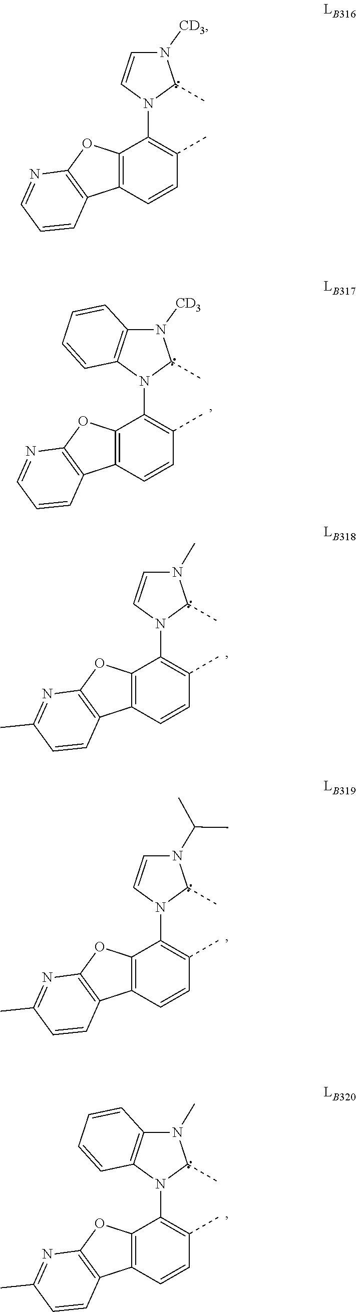

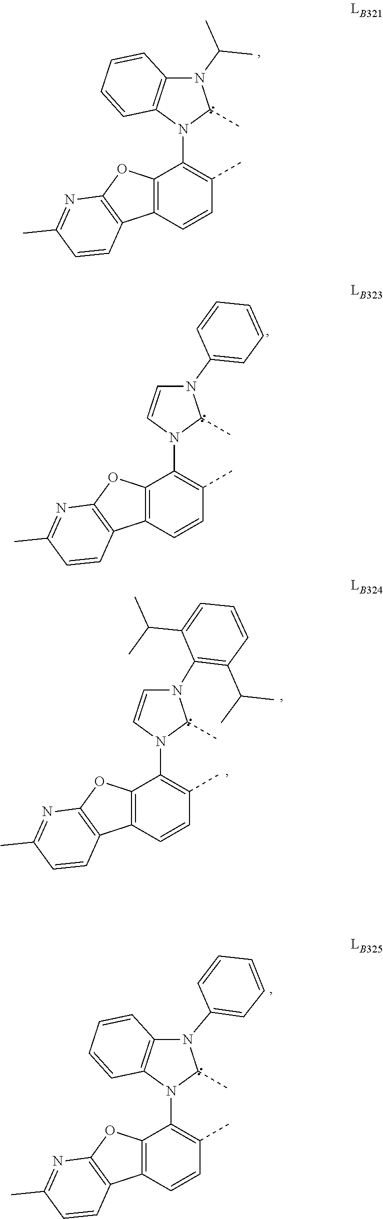

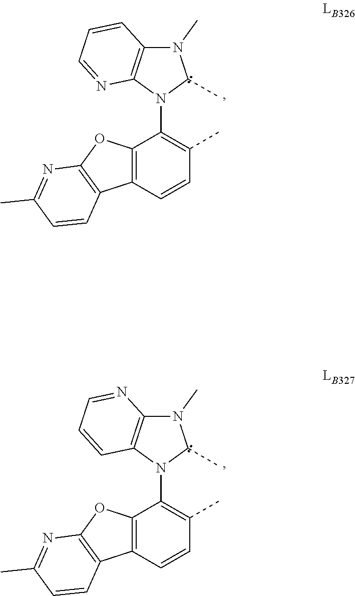

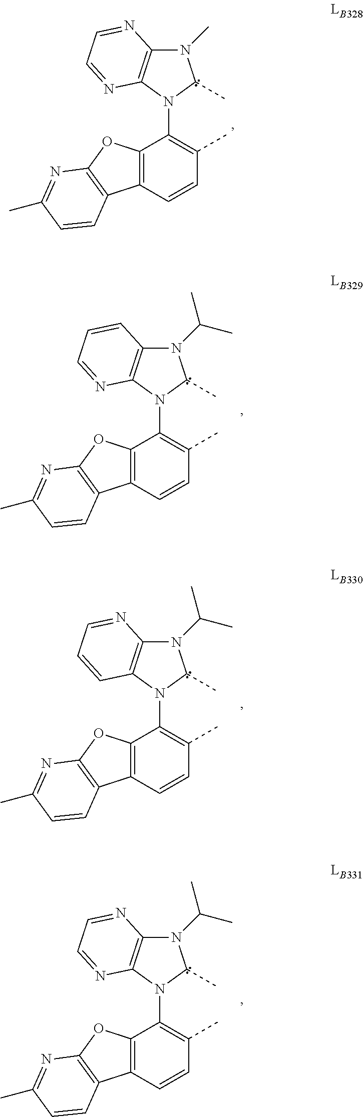

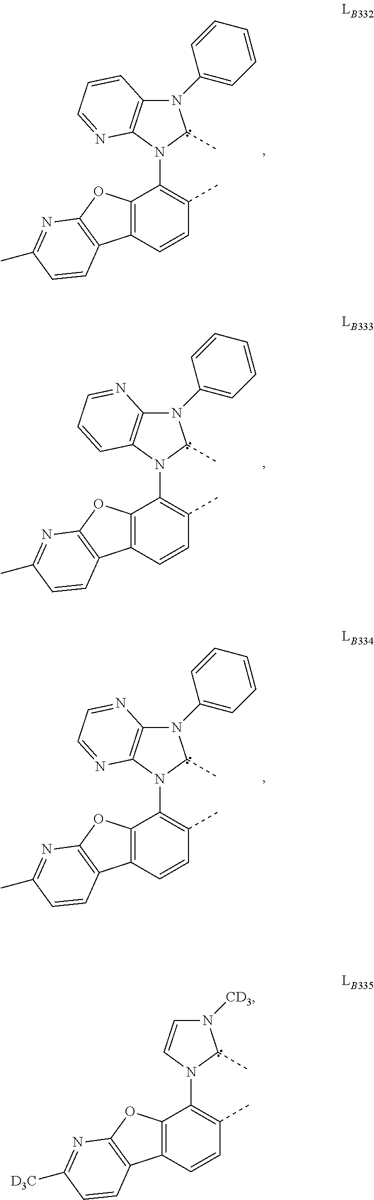

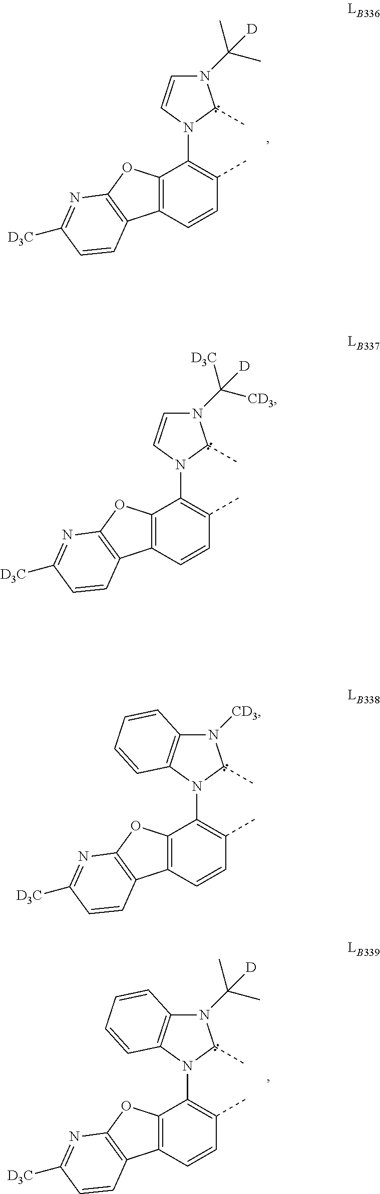

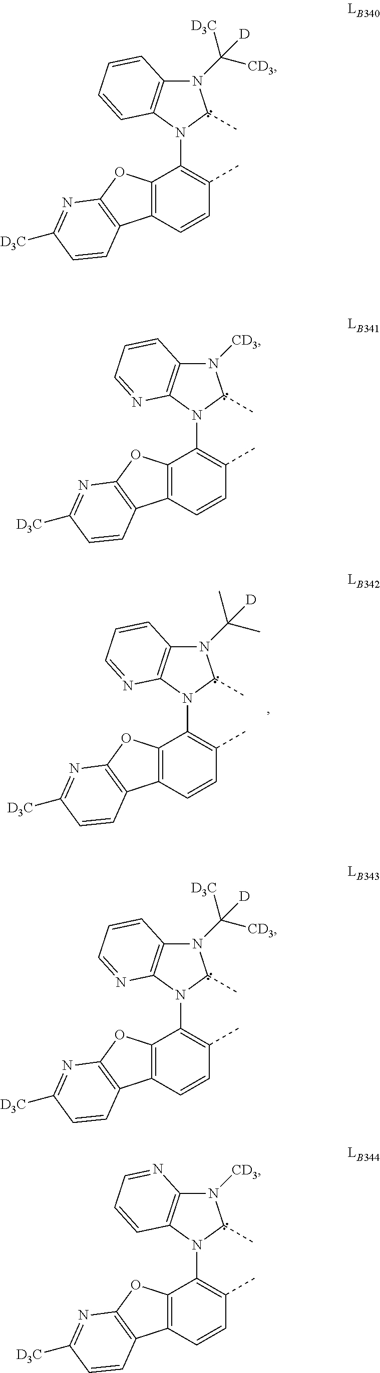

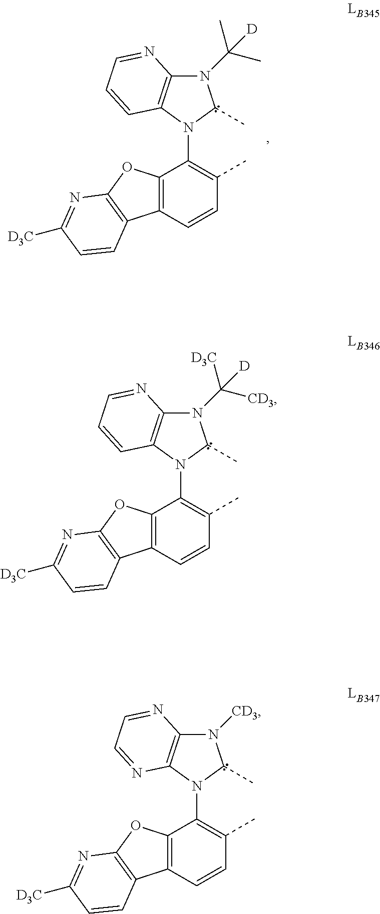

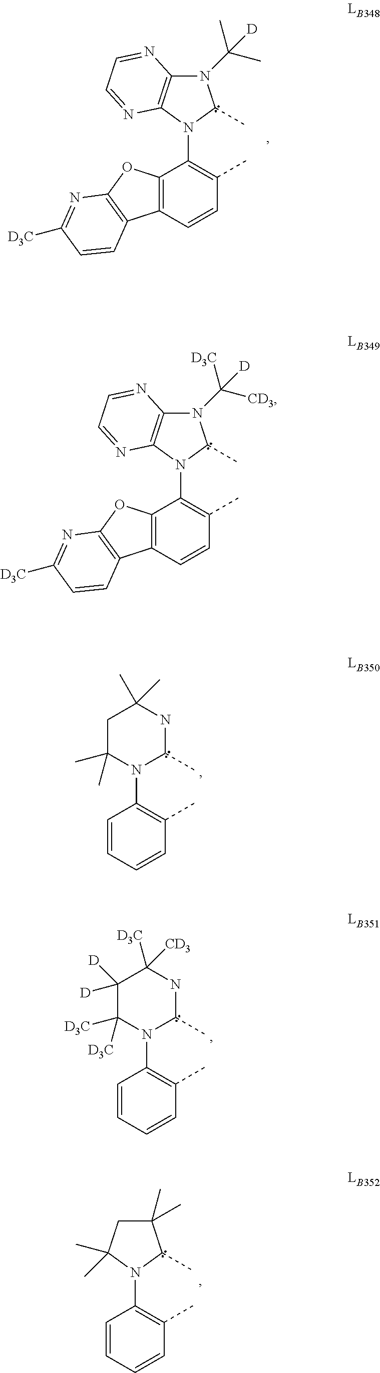

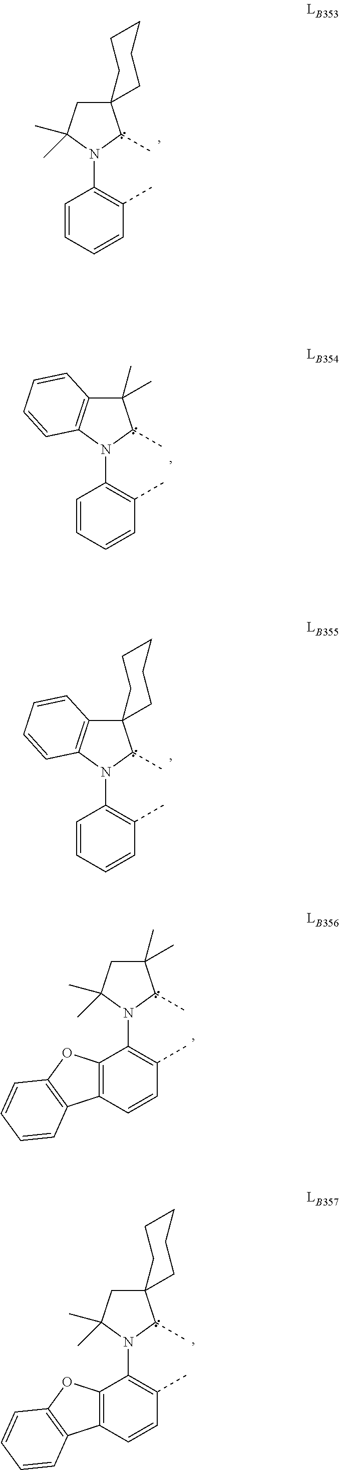

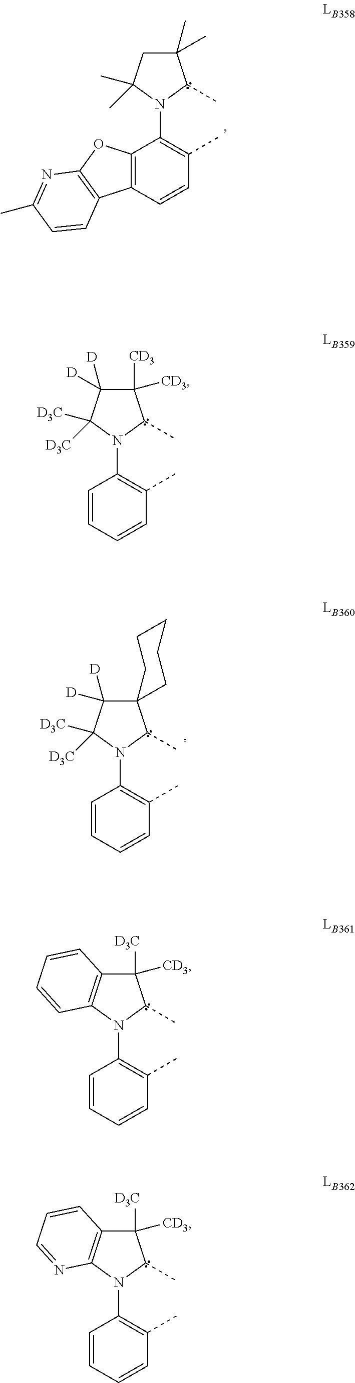

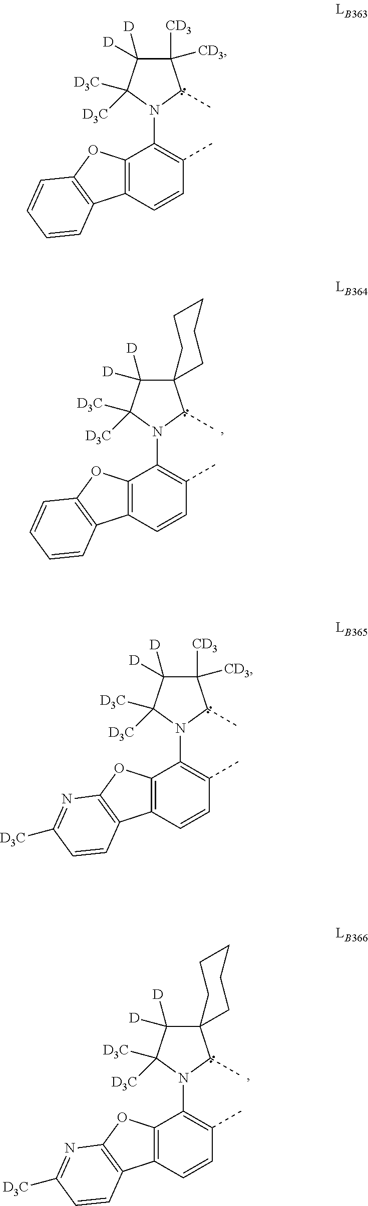

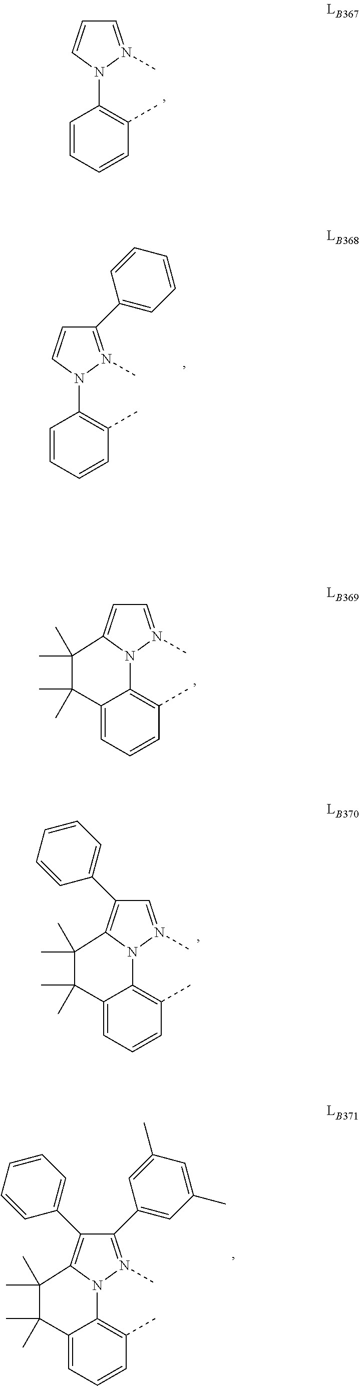

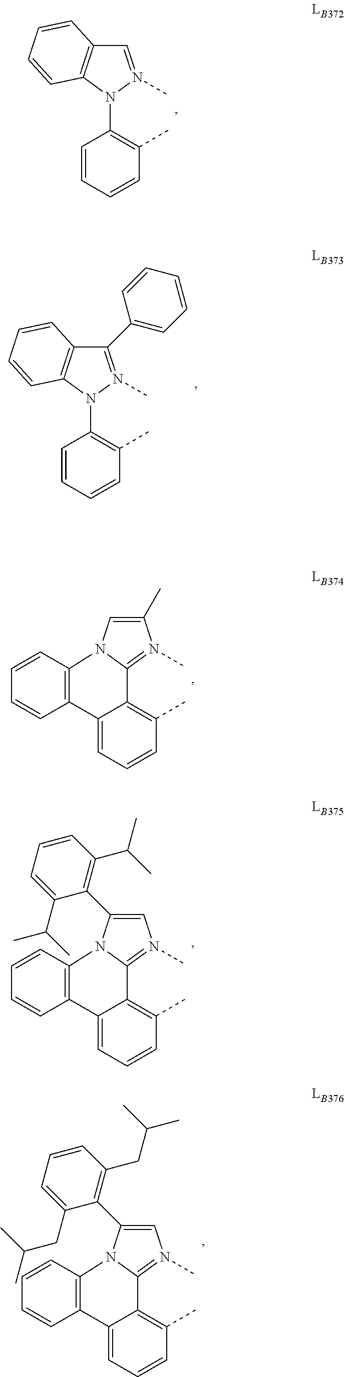

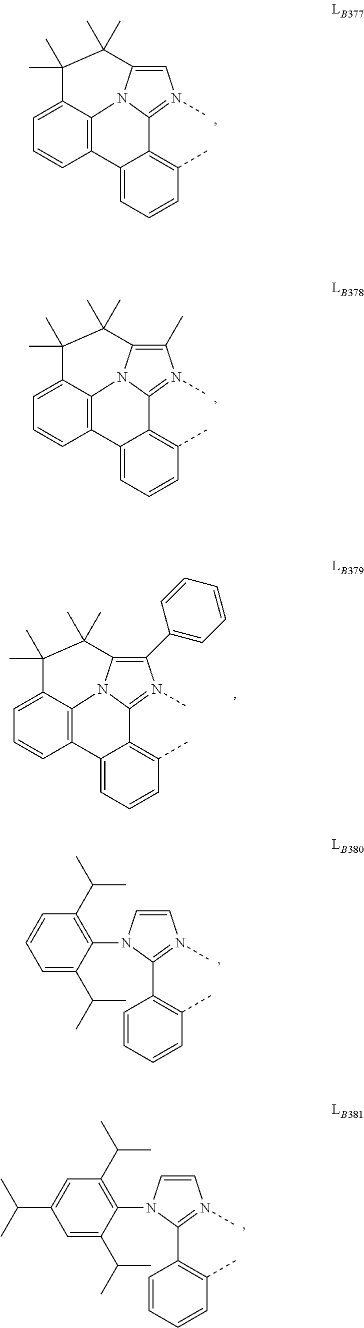

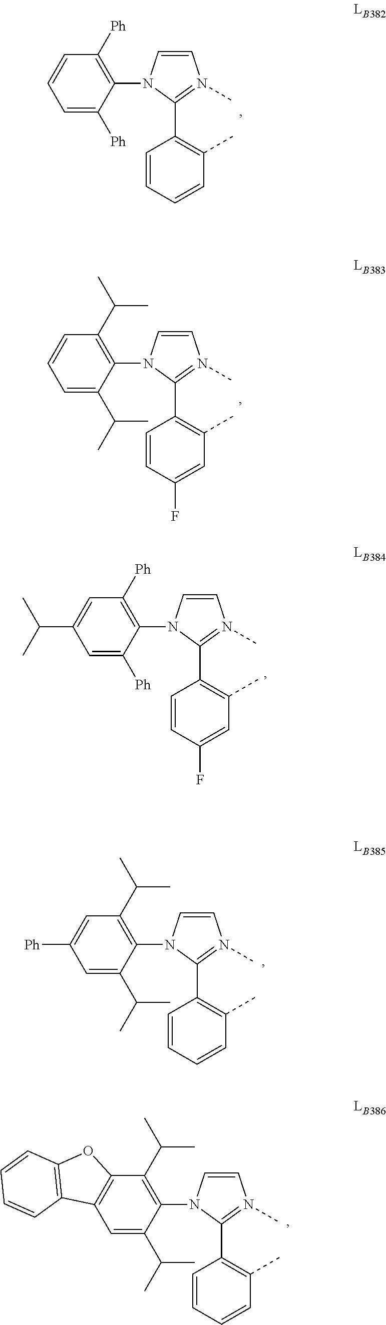

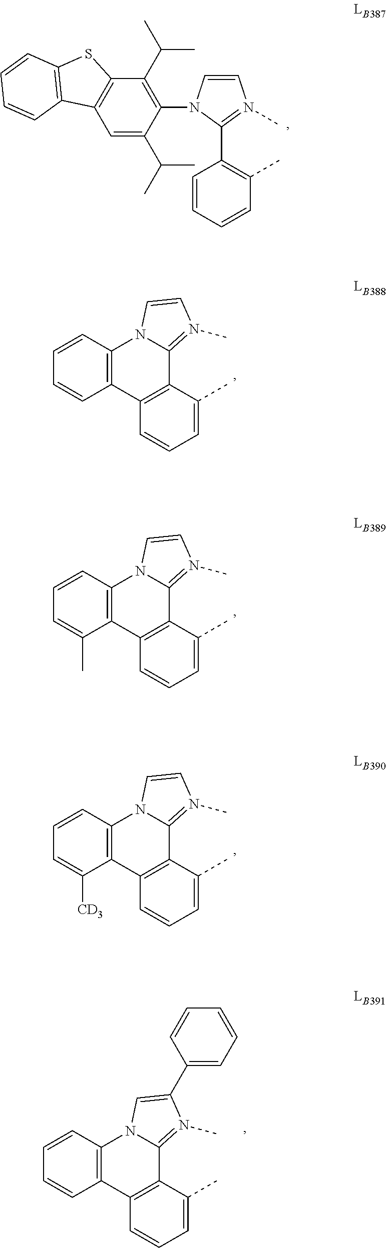

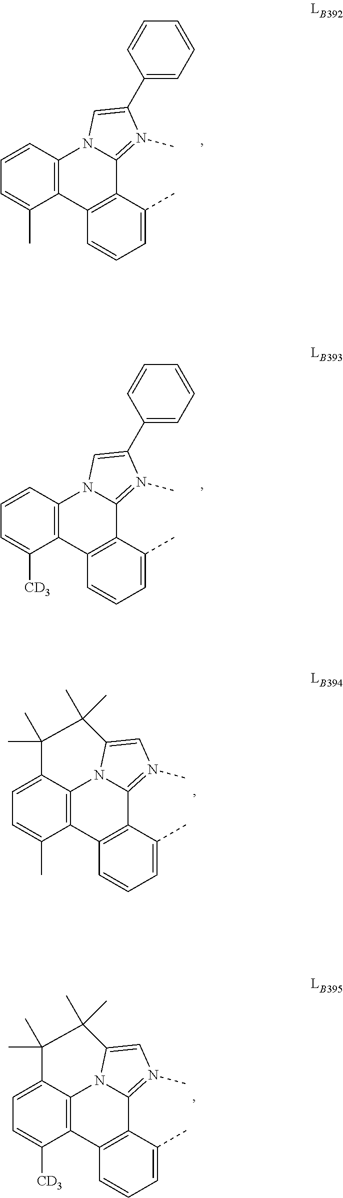

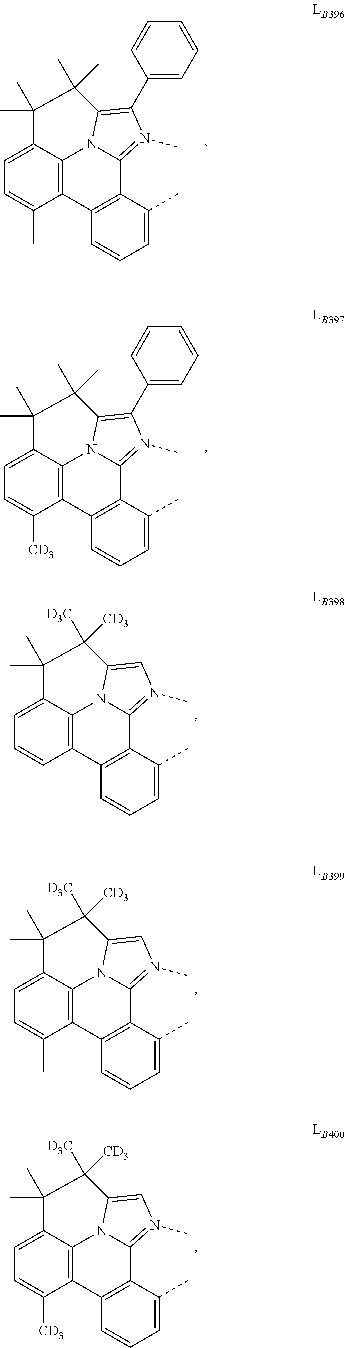

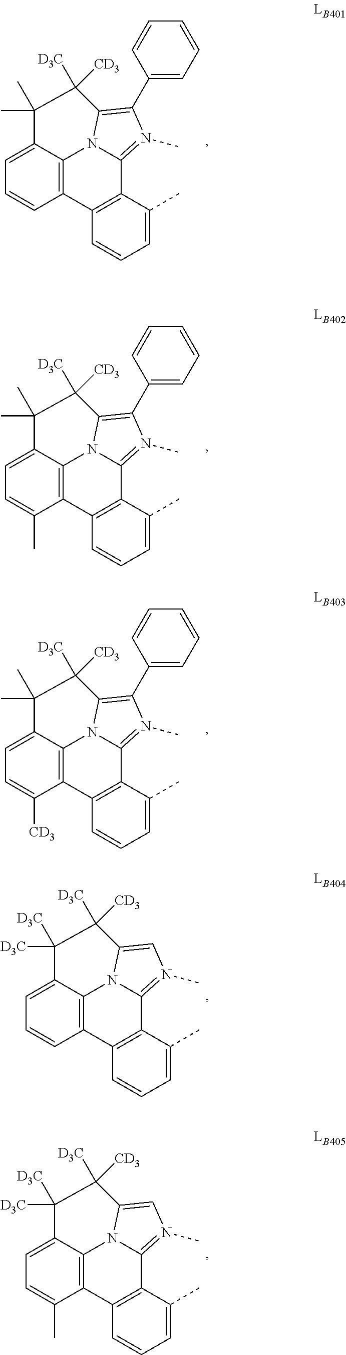

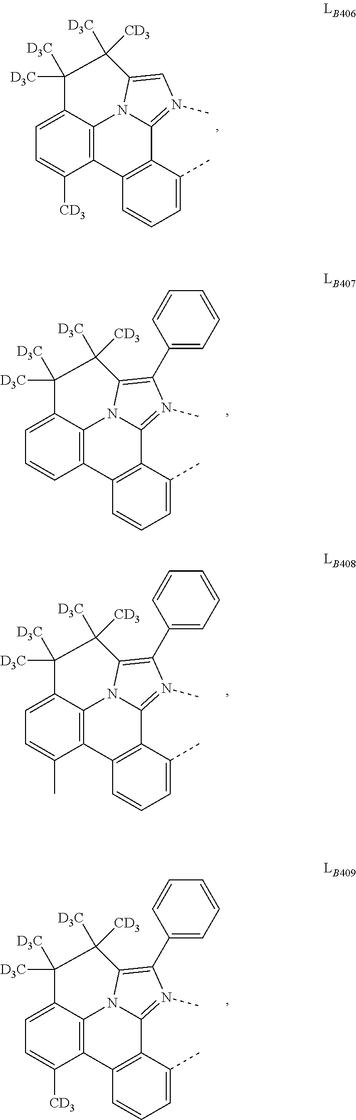

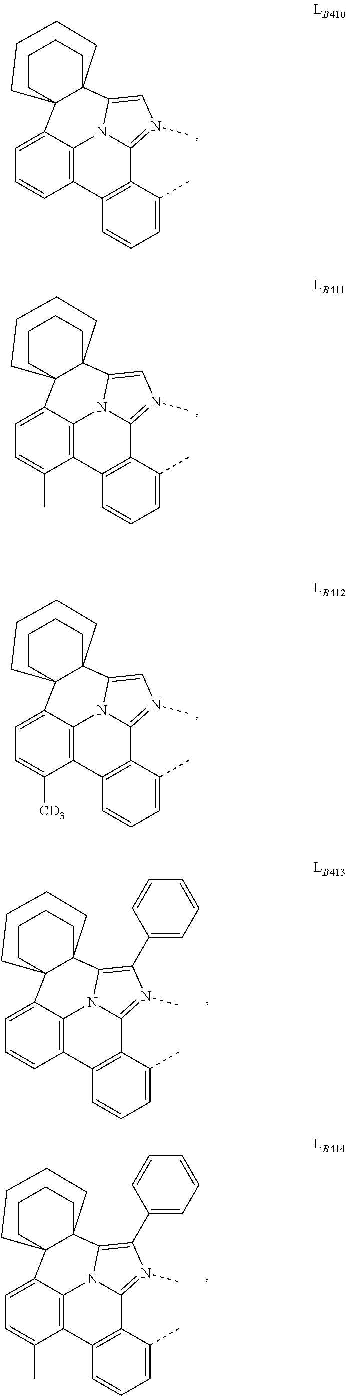

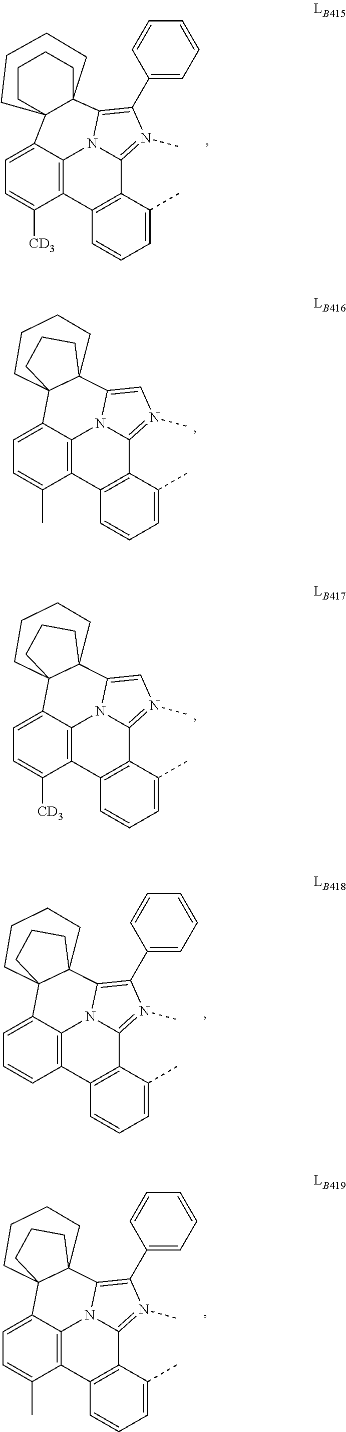

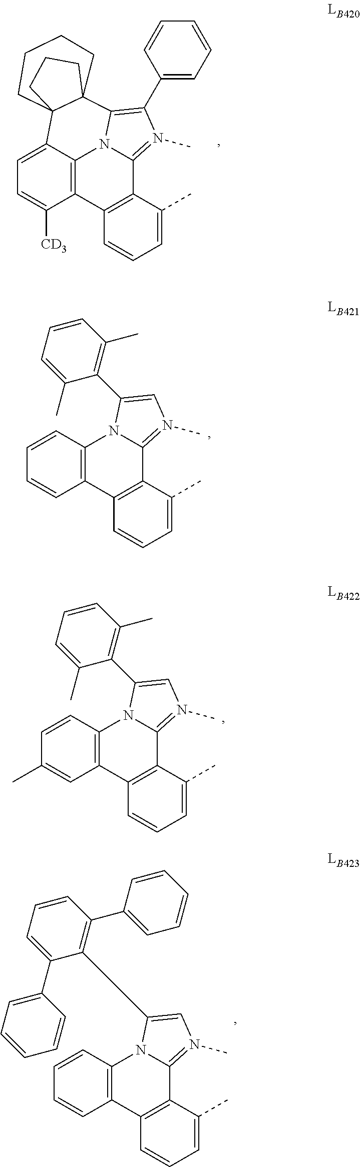

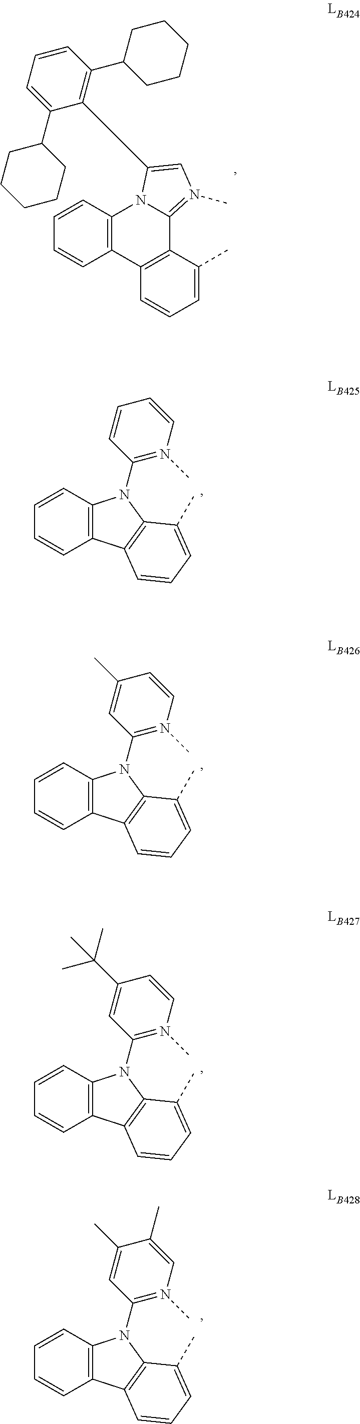

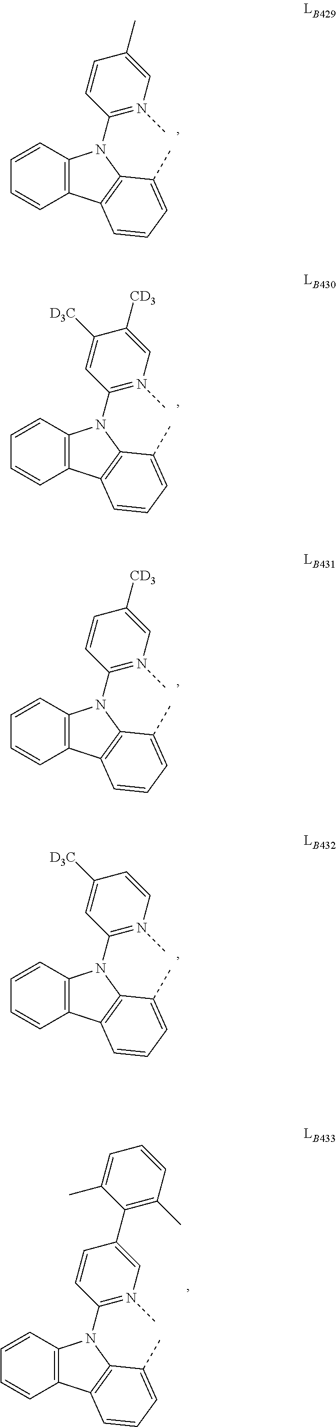

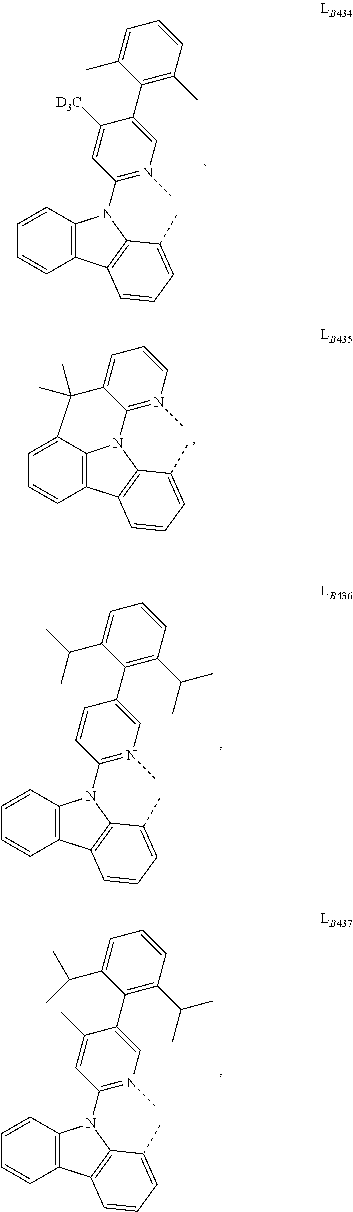

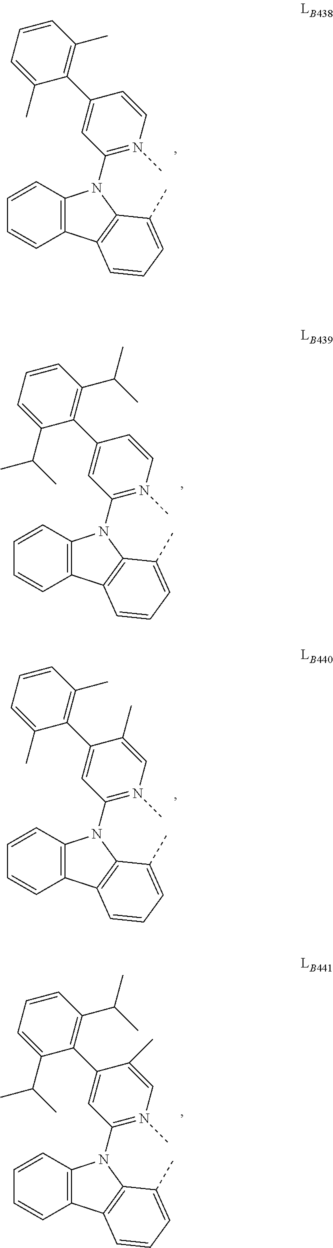

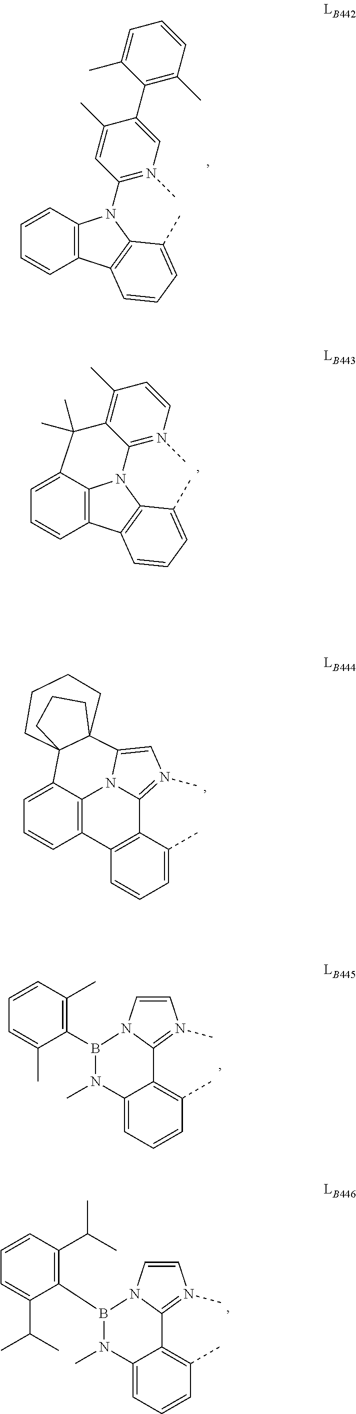

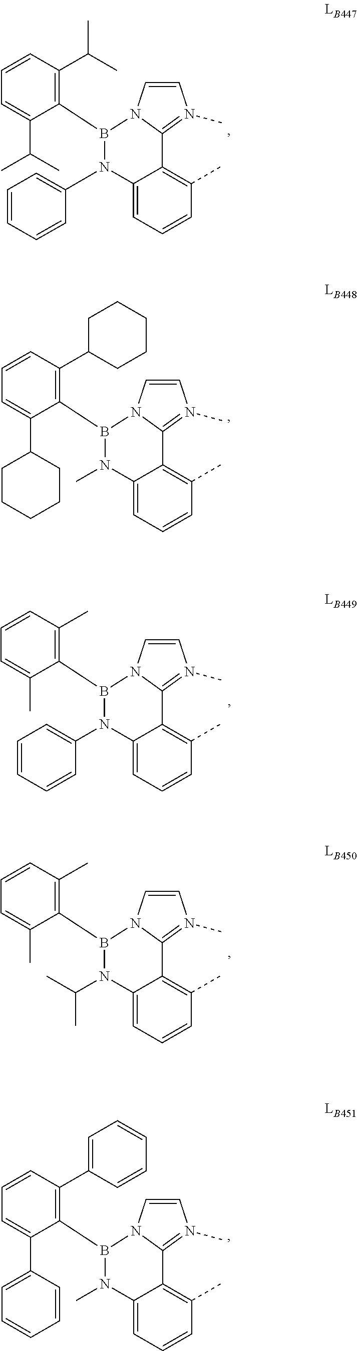

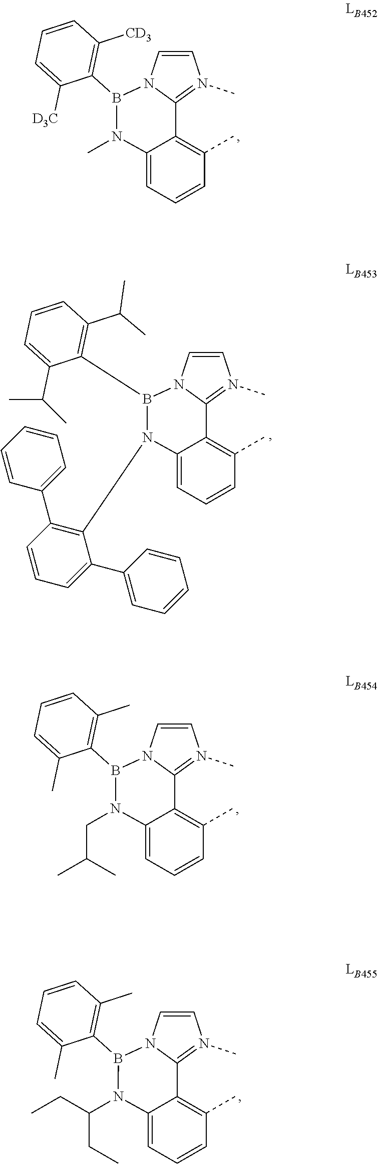

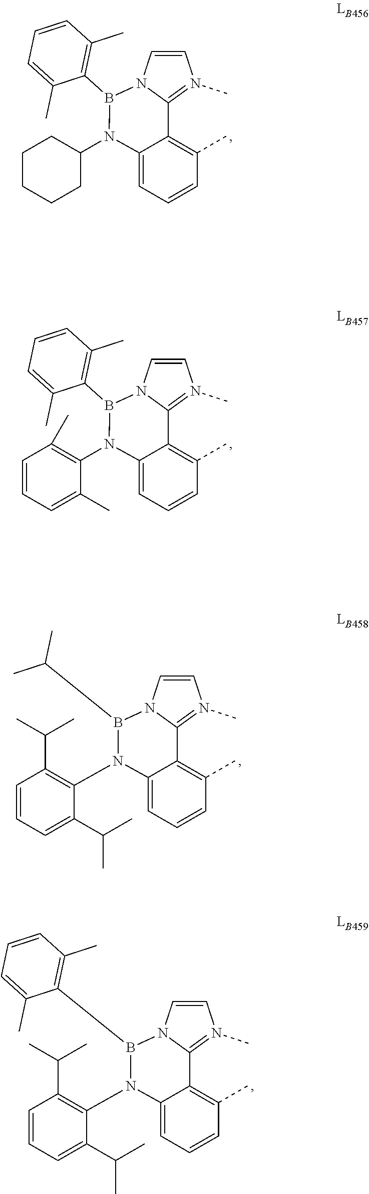

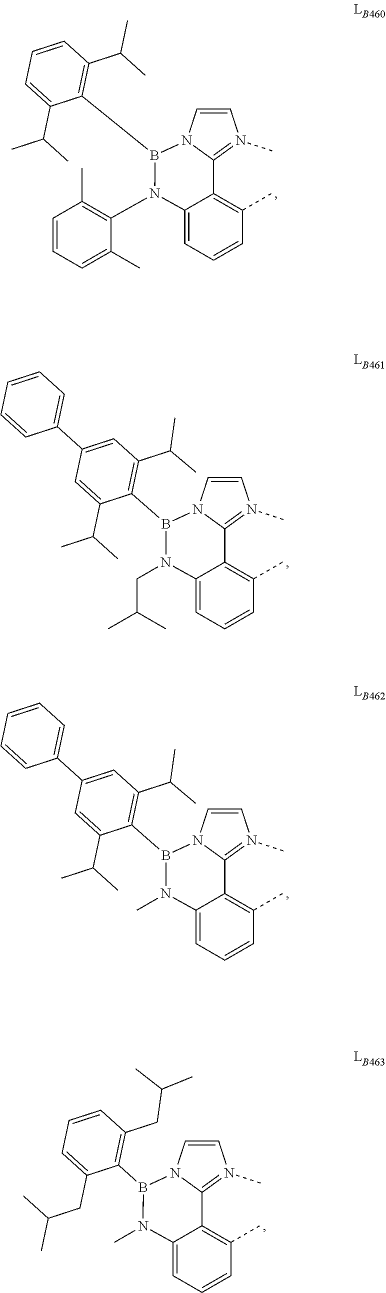

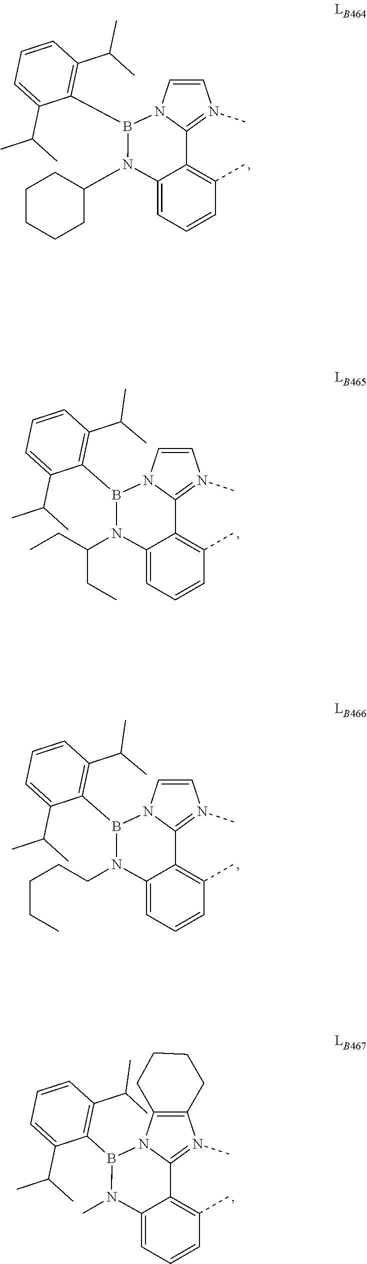

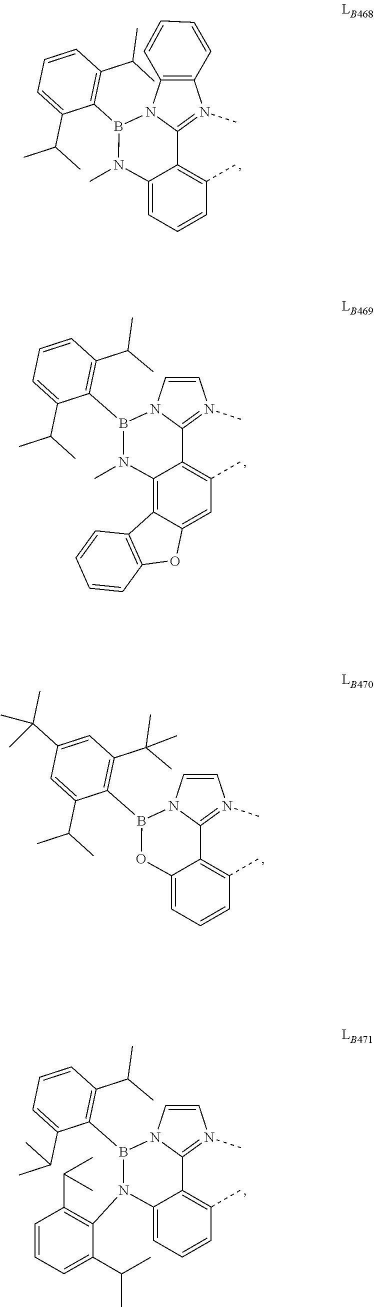

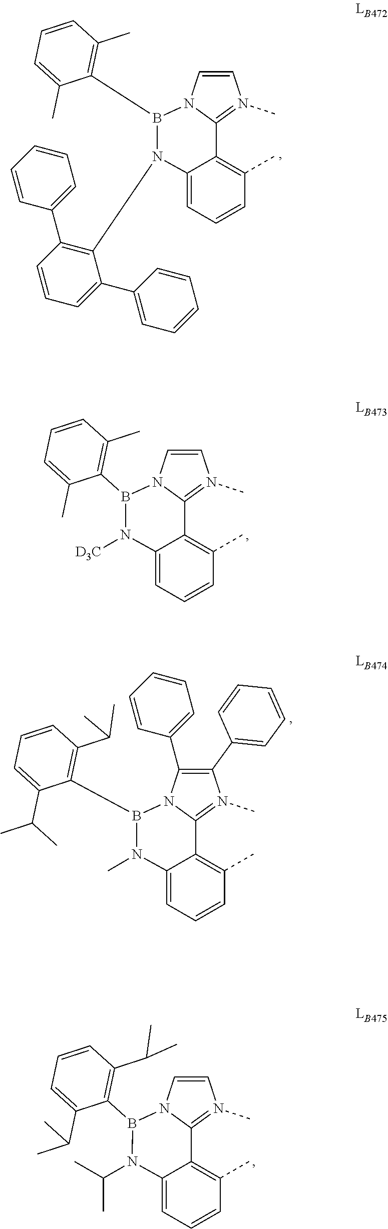

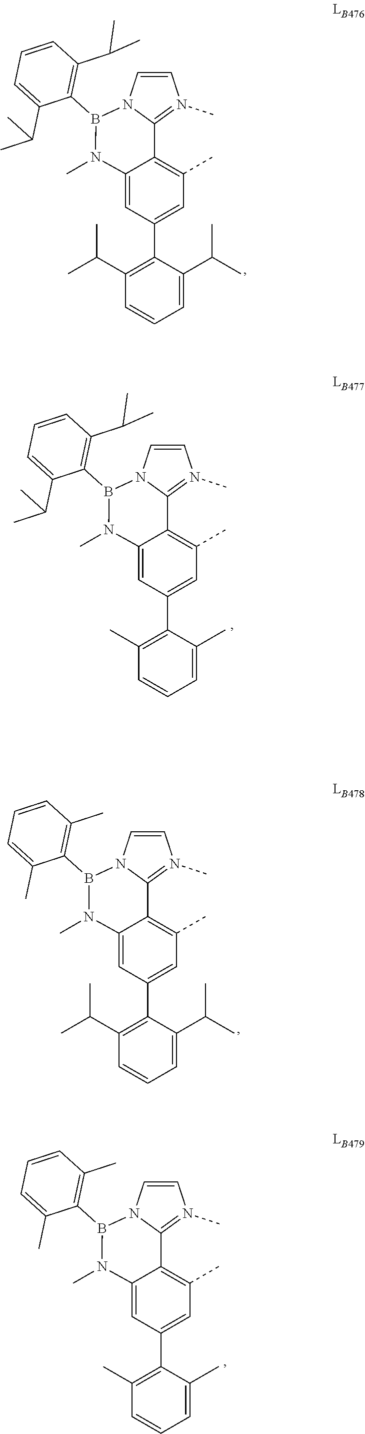

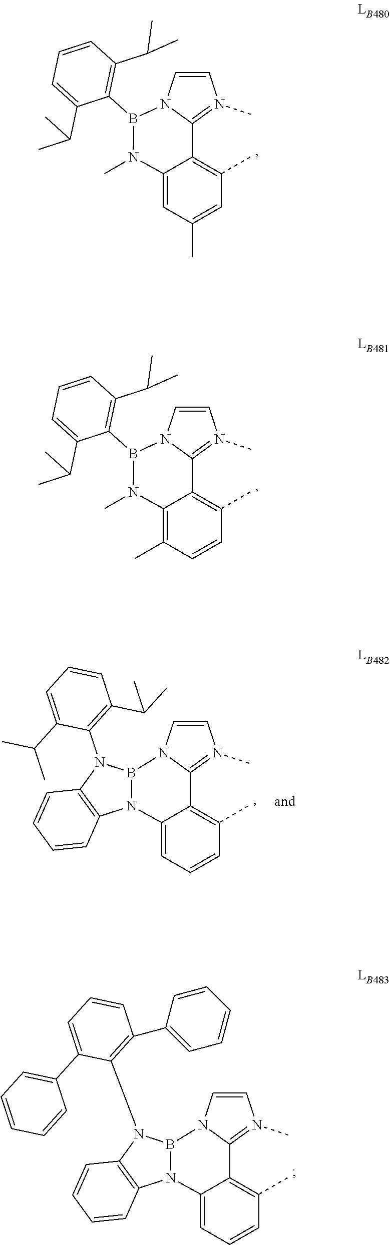

and

L_{C} can be selected from the group consisting of:
L_{Cj-I} having the structures based on

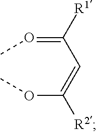

and
L_{Cj-II} having the structures based on

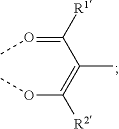

wherein j is an integer from 1 to 768, wherein for each L_{Cj} in L_{Cj-I} and L_{Cj-II}, R^{1′} and R^{2′} are defined as provided below:

| L_{Cj} | R^{1′} | R^{2′} |
|---|---|---|
| L_{C1} | R^{D1} | R^{D1} |
| L_{C2} | R^{D2} | R^{D2} |
| L_{C3} | R^{D3} | R^{D3} |
| L_{C4} | R^{D4} | R^{D4} |
| L_{C5} | R^{D5} | R^{D5} |
| L_{C6} | R^{D6} | R^{D6} |
| L_{C7} | R^{D7} | R^{D7} |
| L_{C8} | R^{D8} | R^{D8} |
| L_{C9} | R^{D9} | R^{D9} |
| L_{C10} | R^{D10} | R^{D10} |
| L_{C11} | R^{D11} | R^{D11} |
| L_{C12} | R^{D12} | R^{D12} |
| L_{C13} | R^{D13} | R^{D13} |
| L_{C14} | R^{D14} | R^{D14} |
| L_{C15} | R^{D15} | R^{D15} |
| L_{C16} | R^{D16} | R^{D16} |
| L_{C17} | R^{D17} | R^{D17} |
| L_{C18} | R^{D18} | R^{D18} |
| L_{C19} | R^{D19} | R^{D19} |
| L_{C20} | R^{D2} | R^{D2} |
| L_{C21} | R^{D21} | R^{D21} |
| L_{C22} | R^{D22} | R^{D22} |
| L_{C23} | R^{D23} | R^{D23} |
| L_{C24} | R^{D24} | R^{D24} |
| L_{C25} | R^{D25} | R^{D25} |
| L_{C26} | R^{D26} | R^{D26} |
| L_{C27} | R^{D27} | R^{D27} |
| L_{C28} | R^{D28} | R^{D28} |
| L_{C29} | R^{D29} | R^{D29} |
| L_{C30} | R^{D30} | R^{D30} |
| L_{C31} | R^{D31} | R^{D31} |
| L_{C32} | R^{D32} | R^{D32} |
| L_{C33} | R^{D33} | R^{D33} |
| L_{C34} | R^{D34} | R^{D34} |
| L_{C35} | R^{D35} | R^{D35} |
| L_{C36} | R^{D36} | R^{D36} |
| L_{C37} | R^{D37} | R^{D37} |
| L_{C38} | R^{D38} | R^{D38} |
| L_{C39} | R^{D39} | R^{D39} |
| L_{C40} | R^{D40} | R^{D40} |
| L_{C41} | R^{D41} | R^{D41} |
| L_{C42} | R^{D42} | R^{D42} |
| L_{C43} | R^{D43} | R^{D43} |
| L_{C44} | R^{D44} | R^{D44} |
| L_{C45} | R^{D45} | R^{D45} |
| L_{C46} | R^{D46} | R^{D46} |
| L_{C47} | R^{D47} | R^{D47} |
| L_{C48} | R^{D48} | R^{D48} |
| L_{C49} | R^{D49} | R^{D49} |
| L_{C50} | R^{D50} | R^{D50} |
| L_{C51} | R^{D51} | R^{D51} |
| L_{C52} | R^{D52} | R^{D52} |
| L_{C53} | R^{D53} | R^{D53} |
| L_{C54} | R^{D54} | R^{D54} |
| L_{C55} | R^{D55} | R^{D55} |
| L_{C56} | R^{D56} | R^{D56} |
| L_{C57} | R^{D57} | R^{D57} |
| L_{C58} | R^{D58} | R^{D58} |
| L_{C59} | R^{D59} | R^{D59} |
| L_{C60} | R^{D60} | R^{D60} |
| L_{C61} | R^{D61} | R^{D61} |
| L_{C62} | R^{D62} | R^{D62} |
| L_{C63} | R^{D63} | R^{D63} |
| L_{C64} | R^{D64} | R^{D64} |
| L_{C65} | R^{D65} | R^{D65} |
| L_{C66} | R^{D66} | R^{D66} |
| L_{C67} | R^{D67} | R^{D67} |
| L_{C68} | R^{D68} | R^{D68} |
| L_{C69} | R^{D69} | R^{D69} |
| L_{C70} | R^{D70} | R^{D70} |
| L_{C71} | R^{D71} | R^{D71} |
| L_{C72} | R^{D72} | R^{D72} |
| L_{C73} | R^{D73} | R^{D73} |
| L_{C74} | R^{D74} | R^{D74} |
| L_{C75} | R^{D75} | R^{D75} |
| L_{C76} | R^{D76} | R^{D76} |
| L_{C77} | R^{D77} | R^{D77} |
| L_{C78} | R^{D78} | R^{D78} |
| L_{C79} | R^{D79} | R^{D79} |
| L_{C80} | R^{D80} | R^{D80} |
| L_{C81} | R^{D81} | R^{D81} |
| L_{C82} | R^{D82} | R^{D82} |
| L_{C83} | R^{D83} | R^{D83} |
| L_{C84} | R^{D84} | R^{D84} |
| L_{C85} | R^{D85} | R^{D85} |
| L_{C86} | R^{D86} | R^{D86} |
| L_{C87} | R^{D87} | R^{D87} |
| L_{C88} | R^{D88} | R^{D88} |
| L_{C89} | R^{D89} | R^{D89} |
| L_{C90} | R^{D90} | R^{D90} |
| L_{C91} | R^{D91} | R^{D91} |
| L_{C92} | R^{D92} | R^{D92} |
| L_{C93} | R^{D93} | R^{D93} |
| L_{C94} | R^{D94} | R^{D94} |
| L_{C95} | R^{D95} | R^{D95} |
| L_{C96} | R^{D96} | R^{D96} |
| L_{C97} | R^{D97} | R^{D97} |
| L_{C98} | R^{D98} | R^{D98} |
| L_{C99} | R^{D99} | R^{D99} |
| L_{C100} | R^{D100} | R^{D100} |
| L_{C101} | R^{D101} | R^{D101} |
| L_{C102} | R^{D102} | R^{D102} |
| L_{C103} | R^{D103} | R^{D103} |
| L_{C104} | R^{D104} | R^{D104} |
| L_{C105} | R^{D105} | R^{D105} |
| L_{C106} | R^{D106} | R^{D106} |
| L_{C107} | R^{D107} | R^{D107} |
| L_{C108} | R^{D108} | R^{D108} |
| L_{C109} | R^{D109} | R^{D109} |
| L_{C110} | R^{D110} | R^{D110} |
| L_{C111} | R^{D111} | R^{D111} |
| L_{C112} | R^{D112} | R^{D112} |
| L_{C113} | R^{D113} | R^{D113} |
| L_{C114} | R^{D114} | R^{D114} |
| L_{C115} | R^{D115} | R^{D115} |
| L_{C116} | R^{D116} | R^{D116} |
| L_{C117} | R^{D117} | R^{D117} |
| L_{C118} | R^{D118} | R^{D118} |
| L_{C119} | R^{D119} | R^{D119} |
| L_{C120} | R^{D120} | R^{D120} |
| L_{C121} | R^{D121} | R^{D121} |
| L_{C122} | R^{D122} | R^{D122} |
| L_{C123} | R^{D123} | R^{D123} |
| L_{C124} | R^{D124} | R^{D124} |
| L_{C125} | R^{D125} | R^{D125} |
| L_{C126} | R^{D126} | R^{D126} |
| L_{C127} | R^{D127} | R^{D127} |
| L_{C128} | R^{D128} | R^{D128} |
| L_{C129} | R^{D129} | R^{D129} |
| L_{C130} | R^{D130} | R^{D130} |
| L_{C131} | R^{D131} | R^{D131} |
| L_{C132} | R^{D132} | R^{D132} |
| L_{C133} | R^{D133} | R^{D133} |
| L_{C134} | R^{D134} | R^{D134} |
| L_{C135} | R^{D135} | R^{D135} |
| L_{C136} | R^{D136} | R^{D136} |
| L_{C137} | R^{D137} | R^{D137} |
| L_{C138} | R^{D138} | R^{D138} |
| L_{C139} | R^{D139} | R^{D139} |
| L_{C140} | R^{D140} | R^{D140} |
| L_{C141} | R^{D141} | R^{D141} |
| L_{C142} | R^{D142} | R^{D142} |
| L_{C143} | R^{D143} | R^{D143} |
| L_{C144} | R^{D144} | R^{D144} |
| L_{C145} | R^{D145} | R^{D145} |
| L_{C146} | R^{D146} | R^{D146} |
| L_{C147} | R^{D147} | R^{D147} |
| L_{C148} | R^{D148} | R^{D148} |
| L_{C149} | R^{D149} | R^{D149} |
| L_{C150} | R^{D150} | R^{D150} |
| L_{C151} | R^{D151} | R^{D151} |
| L_{C152} | R^{D152} | R^{D152} |
| L_{C153} | R^{D153} | R^{D153} |
| L_{C154} | R^{D154} | R^{D154} |
| L_{C155} | R^{D155} | R^{D155} |
| L_{C156} | R^{D156} | R^{D156} |
| L_{C157} | R^{D157} | R^{D157} |
| L_{C158} | R^{D158} | R^{D158} |
| L_{C159} | R^{D159} | R^{D159} |
| L_{C160} | R^{D160} | R^{D160} |
| L_{C161} | R^{D161} | R^{D161} |
| L_{C162} | R^{D162} | R^{D162} |
| L_{C163} | R^{D163} | R^{D163} |
| L_{C164} | R^{D164} | R^{D164} |
| L_{C165} | R^{D165} | R^{D165} |
| L_{C166} | R^{D166} | R^{D166} |
| L_{C167} | R^{D167} | R^{D167} |
| L_{C168} | R^{D168} | R^{D168} |
| L_{C169} | R^{D169} | R^{D169} |
| L_{C170} | R^{D170} | R^{D170} |
| L_{C171} | R^{D171} | R^{D171} |
| L_{C172} | R^{D172} | R^{D172} |
| L_{C173} | R^{D173} | R^{D173} |
| L_{C174} | R^{D174} | R^{D174} |
| L_{C175} | R^{D175} | R^{D175} |
| L_{C176} | R^{D176} | R^{D176} |
| L_{C177} | R^{D177} | R^{D177} |
| L_{C178} | R^{D178} | R^{D178} |
| L_{C179} | R^{D179} | R^{D179} |
| L_{C180} | R^{D180} | R^{D180} |
| L_{C181} | R^{D181} | R^{D181} |
| L_{C182} | R^{D182} | R^{D182} |
| L_{C183} | R^{D183} | R^{D183} |
| L_{C184} | R^{D184} | R^{D184} |
| L_{C185} | R^{D185} | R^{D185} |
| L_{C186} | R^{D186} | R^{D186} |
| L_{C187} | R^{D187} | R^{D187} |
| L_{C188} | R^{D188} | R^{D188} |
| L_{C189} | R^{D189} | R^{D189} |
| L_{C190} | R^{D190} | R^{D190} |
| L_{C191} | R^{D191} | R^{D191} |
| L_{C192} | R^{D192} | R^{D192} |
| L_{C193} | R^{D1} | R^{D3} |
| L_{C194} | R^{D1} | R^{D4} |
| L_{C195} | R^{D1} | R^{D5} |
| L_{C196} | R^{D1} | R^{D9} |
| L_{C197} | R^{D1} | R^{D10} |
| L_{C198} | R^{D1} | R^{D17} |
| L_{C199} | R^{D1} | R^{D18} |
| L_{C200} | R^{D1} | R^{D20} |
| L_{C201} | R^{D1} | R^{D22} |
| L_{C202} | R^{D1} | R^{D37} |
| L_{C203} | R^{D1} | R^{D40} |
| L_{C204} | R^{D1} | R^{D41} |
| L_{C205} | R^{D1} | R^{D42} |
| L_{C206} | R^{D1} | R^{D43} |
| L_{C207} | R^{D1} | R^{D48} |
| L_{C208} | R^{D1} | R^{D49} |
| L_{C209} | R^{D1} | R^{D50} |
| L_{C210} | R^{D1} | R^{D54} |
| L_{C211} | R^{D1} | R^{D55} |
| L_{C212} | R^{D1} | R^{D58} |
| L_{C213} | R^{D1} | R^{D59} |
| L_{C214} | R^{D1} | R^{D78} |
| L_{C215} | R^{D1} | R^{D79} |
| L_{C216} | R^{D1} | R^{D81} |
| L_{C217} | R^{D1} | R^{D87} |
| L_{C218} | R^{D1} | R^{D88} |
| L_{C219} | R^{D1} | R^{D89} |
| L_{C220} | R^{D1} | R^{D93} |
| L_{C221} | R^{D1} | R^{D116} |
| L_{C222} | R^{D1} | R^{D117} |
| L_{C223} | R^{D1} | R^{D118} |
| L_{C224} | R^{D1} | R^{D119} |
| L_{C225} | R^{D1} | R^{D120} |
| L_{C226} | R^{D1} | R^{D133} |
| L_{C227} | R^{D1} | R^{D134} |
| L_{C228} | R^{D1} | R^{D135} |
| L_{C229} | R^{D1} | R^{D136} |
| L_{C230} | R^{D1} | R^{D143} |
| L_{C231} | R^{D1} | R^{D144} |
| L_{C232} | R^{D1} | R^{D145} |
| L_{C233} | R^{D1} | R^{D146} |
| L_{C234} | R^{D1} | R^{D147} |
| L_{C235} | R^{D1} | R^{D149} |
| L_{C236} | R^{D1} | R^{D151} |
| L_{C237} | R^{D1} | R^{D154} |
| L_{C238} | R^{D1} | R^{D155} |
| L_{C239} | R^{D1} | R^{D161} |
| L_{C240} | R^{D1} | R^{D175} |
| L_{C241} | R^{D4} | R^{D3} |
| L_{C242} | R^{D4} | R^{D5} |
| L_{C243} | R^{D4} | R^{D9} |
| L_{C244} | R^{D4} | R^{D10} |
| L_{C245} | R^{D4} | R^{D17} |
| L_{C246} | R^{D4} | R^{D18} |
| L_{C247} | R^{D4} | R^{D20} |
| L_{C248} | R^{D4} | R^{D22} |
| L_{C249} | R^{D4} | R^{D37} |
| L_{C250} | R^{D4} | R^{D40} |
| L_{C251} | R^{D4} | R^{D41} |
| L_{C252} | R^{D4} | R^{D42} |
| L_{C253} | R^{D4} | R^{D43} |
| L_{C254} | R^{D4} | R^{D48} |
| L_{C255} | R^{D4} | R^{D49} |
| L_{C256} | R^{D4} | R^{D50} |
| L_{C257} | R^{D4} | R^{D54} |
| L_{C258} | R^{D4} | R^{D55} |
| L_{C259} | R^{D4} | R^{D58} |
| L_{C260} | R^{D4} | R^{D59} |
| L_{C261} | R^{D4} | R^{D78} |
| L_{C262} | R^{D4} | R^{D79} |
| L_{C263} | R^{D4} | R^{D81} |
| L_{C264} | R^{D4} | R^{D87} |
| L_{C265} | R^{D4} | R^{D88} |
| L_{C266} | R^{D4} | R^{D89} |
| L_{C267} | R^{D4} | R^{D93} |
| L_{C268} | R^{D4} | R^{D116} |
| L_{C269} | R^{D4} | R^{D117} |
| L_{C270} | R^{D4} | R^{D118} |
| L_{C271} | R^{D4} | R^{D119} |
| L_{C272} | R^{D4} | R^{D120} |
| L_{C273} | R^{D4} | R^{D133} |
| L_{C274} | R^{D4} | R^{D134} |
| L_{C275} | R^{D4} | R^{D135} |
| L_{C276} | R^{D4} | R^{D136} |
| L_{C277} | R^{D4} | R^{D143} |
| L_{C278} | R^{D4} | R^{D144} |
| L_{C279} | R^{D4} | R^{D145} |
| L_{C280} | R^{D4} | R^{D146} |
| L_{C281} | R^{D4} | R^{D147} |
| L_{C282} | R^{D4} | R^{D149} |
| L_{C283} | R^{D4} | R^{D151} |
| L_{C284} | R^{D4} | R^{D154} |
| L_{C285} | R^{D4} | R^{D155} |
| L_{C286} | R^{D4} | R^{D161} |
| L_{C287} | R^{D4} | R^{D175} |
| L_{C288} | R^{D9} | R^{D3} |
| L_{C289} | R^{D9} | R^{D5} |
| L_{C290} | R^{D9} | R^{D10} |
| L_{C291} | R^{D9} | R^{D17} |
| L_{C292} | R^{D9} | R^{D18} |
| L_{C293} | R^{D9} | R^{D20} |
| L_{C294} | R^{D9} | R^{D22} |
| L_{C295} | R^{D9} | R^{D37} |
| L_{C296} | R^{D9} | R^{D40} |
| L_{C297} | R^{D9} | R^{D41} |
| L_{C298} | R^{D9} | R^{D42} |
| L_{C299} | R^{D9} | R^{D43} |
| L_{C300} | R^{D9} | R^{D48} |
| L_{C301} | R^{D9} | R^{D49} |
| L_{C302} | R^{D9} | R^{D50} |
| L_{C303} | R^{D9} | R^{D54} |
| L_{C304} | R^{D9} | R^{D55} |
| L_{C305} | R^{D9} | R^{D58} |
| L_{C306} | R^{D9} | R^{D59} |
| L_{C307} | R^{D9} | R^{D78} |
| L_{C308} | R^{D9} | R^{D79} |
| L_{C309} | R^{D9} | R^{D81} |
| L_{C310} | R^{D9} | R^{D87} |
| L_{C311} | R^{D9} | R^{D88} |
| L_{C312} | R^{D9} | R^{D89} |
| L_{C313} | R^{D9} | R^{D93} |
| L_{C314} | R^{D9} | R^{D116} |
| L_{C315} | R^{D9} | R^{D117} |
| L_{C316} | R^{D9} | R^{D118} |
| L_{C317} | R^{D9} | R^{D119} |
| L_{C318} | R^{D9} | R^{D120} |
| L_{C319} | R^{D9} | R^{D133} |
| L_{C320} | R^{D9} | R^{D134} |
| L_{C321} | R^{D9} | R^{D135} |
| L_{C322} | R^{D9} | R^{D136} |
| L_{C323} | R^{D9} | R^{D143} |
| L_{C324} | R^{D9} | R^{D144} |
| L_{C325} | R^{D9} | R^{D145} |
| L_{C326} | R^{D9} | R^{D146} |
| L_{C327} | R^{D9} | R^{D147} |
| L_{C328} | R^{D9} | R^{D149} |
| L_{C329} | R^{D9} | R^{D151} |
| L_{C330} | R^{D9} | R^{D154} |
| L_{C331} | R^{D9} | R^{D155} |
| L_{C332} | R^{D9} | R^{D161} |
| L_{C333} | R^{D9} | R^{D175} |
| L_{C334} | R^{D10} | R^{D3} |
| L_{C335} | R^{D10} | R^{D5} |
| L_{C336} | R^{D10} | R^{D17} |
| L_{C337} | R^{D10} | R^{D18} |
| L_{C338} | R^{D10} | R^{D20} |
| L_{C339} | R^{D10} | R^{D22} |
| L_{C340} | R^{D10} | R^{D37} |
| L_{C341} | R^{D10} | R^{D40} |
| L_{C342} | R^{D10} | R^{D41} |
| L_{C343} | R^{D10} | R^{D42} |
| L_{C344} | R^{D10} | R^{D43} |
| L_{C345} | R^{D10} | R^{D48} |
| L_{C346} | R^{D10} | R^{D49} |
| L_{C347} | R^{D10} | R^{D50} |
| L_{C348} | R^{D10} | R^{D54} |
| L_{C349} | R^{D10} | R^{D55} |
| L_{C350} | R^{D10} | R^{D58} |
| L_{C351} | R^{D10} | R^{D59} |
| L_{C352} | R^{D10} | R^{D78} |
| L_{C353} | R^{D10} | R^{D79} |
| L_{C354} | R^{D10} | R^{D81} |
| L_{C355} | R^{D10} | R^{D87} |
| L_{C356} | R^{D10} | R^{D88} |
| L_{C357} | R^{D10} | R^{D89} |
| L_{C358} | R^{D10} | R^{D93} |
| L_{C359} | R^{D10} | R^{D116} |
| L_{C360} | R^{D10} | R^{D117} |
| L_{C361} | R^{D10} | R^{D118} |
| L_{C362} | R^{D10} | R^{D119} |
| L_{C363} | R^{D10} | R^{D120} |
| L_{C364} | R^{D10} | R^{D133} |
| L_{C365} | R^{D10} | R^{D134} |
| L_{C366} | R^{D10} | R^{D135} |
| L_{C367} | R^{D10} | R^{D136} |
| L_{C368} | R^{D10} | R^{D143} |
| L_{C369} | R^{D10} | R^{D144} |
| L_{C370} | R^{D10} | R^{D145} |
| L_{C371} | R^{D10} | R^{D146} |
| L_{C372} | R^{D10} | R^{D147} |
| L_{C373} | R^{D10} | R^{D149} |
| L_{C374} | R^{D10} | R^{D151} |
| L_{C375} | R^{D10} | R^{D154} |
| L_{C376} | R^{D10} | R^{D155} |
| L_{C377} | R^{D10} | R^{D161} |
| L_{C378} | R^{D10} | R^{D175} |
| L_{C379} | R^{D10} | R^{D3} |
| L_{C380} | R^{D10} | R^{D5} |
| L_{C381} | R^{D10} | R^{D18} |
| L_{C382} | R^{D10} | R^{D20} |
| L_{C383} | R^{D10} | R^{D22} |
| L_{C384} | R^{D10} | R^{D37} |
| L_{C385} | R^{D17} | R^{D40} |
| L_{C386} | R^{D17} | R^{D41} |
| L_{C387} | R^{D17} | R^{D42} |
| L_{C388} | R^{D17} | R^{D43} |
| L_{C389} | R^{D17} | R^{D48} |
| L_{C390} | R^{D17} | R^{D49} |
| L_{C391} | R^{D17} | R^{D50} |
| L_{C392} | R^{D17} | R^{D54} |
| L_{C393} | R^{D17} | R^{D55} |
| L_{C394} | R^{D17} | R^{D58} |
| L_{C395} | R^{D17} | R^{D59} |
| L_{C396} | R^{D17} | R^{D78} |
| L_{C397} | R^{D17} | R^{D79} |
| L_{C398} | R^{D17} | R^{D81} |
| L_{C399} | R^{D17} | R^{D87} |
| L_{C400} | R^{D17} | R^{D88} |
| L_{C401} | R^{D17} | R^{D89} |
| L_{C402} | R^{D17} | R^{D93} |
| L_{C403} | R^{D17} | R^{D116} |
| L_{C404} | R^{D17} | R^{D117} |
| L_{C405} | R^{D17} | R^{D118} |
| L_{C406} | R^{D17} | R^{D119} |
| L_{C407} | R^{D17} | R^{D120} |
| L_{C408} | R^{D17} | R^{D133} |
| L_{C409} | R^{D17} | R^{D134} |
| L_{C410} | R^{D17} | R^{D135} |
| L_{C411} | R^{D17} | R^{D136} |
| L_{C412} | R^{D17} | R^{D143} |
| L_{C413} | R^{D17} | R^{D144} |
| L_{C414} | R^{D17} | R^{D145} |
| L_{C415} | R^{D17} | R^{D146} |
| L_{C416} | R^{D17} | R^{D147} |
| L_{C417} | R^{D17} | R^{D149} |
| L_{C418} | R^{D17} | R^{D151} |
| L_{C419} | R^{D17} | R^{D154} |
| L_{C420} | R^{D17} | R^{D155} |
| L_{C421} | R^{D17} | R^{D161} |
| L_{C422} | R^{D17} | R^{D175} |
| L_{C423} | R^{D50} | R^{D3} |
| L_{C424} | R^{D50} | R^{D5} |
| L_{C425} | R^{D50} | R^{D18} |
| L_{C426} | R^{D50} | R^{D20} |
| L_{C427} | R^{D50} | R^{D22} |
| L_{C428} | R^{D50} | R^{D37} |
| L_{C429} | R^{D50} | R^{D40} |
| L_{C430} | R^{D50} | R^{D41} |
| L_{C431} | R^{D50} | R^{D42} |
| L_{C432} | R^{D50} | R^{D43} |
| L_{C433} | R^{D50} | R^{D48} |
| L_{C434} | R^{D50} | R^{D49} |
| L_{C435} | R^{D50} | R^{D54} |
| L_{C436} | R^{D50} | R^{D55} |
| L_{C437} | R^{D50} | R^{D58} |
| L_{C438} | R^{D50} | R^{D59} |
| L_{C439} | R^{D50} | R^{D78} |
| L_{C440} | R^{D50} | R^{D79} |
| L_{C441} | R^{D50} | R^{D81} |
| L_{C442} | R^{D50} | R^{D87} |
| L_{C443} | R^{D50} | R^{D88} |
| L_{C444} | R^{D50} | R^{D89} |
| L_{C445} | R^{D50} | R^{D93} |
| L_{C446} | R^{D50} | R^{D116} |
| L_{C447} | R^{D50} | R^{D117} |
| L_{C448} | R^{D50} | R^{D118} |
| L_{C449} | R^{D50} | R^{D119} |
| L_{C450} | R^{D50} | R^{D120} |
| L_{C451} | R^{D50} | R^{D133} |
| L_{C452} | R^{D50} | R^{D134} |
| L_{C453} | R^{D50} | R^{D135} |
| L_{C454} | R^{D50} | R^{D136} |
| L_{C455} | R^{D50} | R^{D143} |
| L_{C456} | R^{D50} | R^{D144} |
| L_{C457} | R^{D50} | R^{D145} |
| L_{C458} | R^{D50} | R^{D146} |
| L_{C459} | R^{D50} | R^{D147} |
| L_{C460} | R^{D50} | R^{D149} |
| L_{C461} | R^{D50} | R^{D151} |
| L_{C462} | R^{D50} | R^{D154} |
| L_{C463} | R^{D50} | R^{D155} |
| L_{C464} | R^{D50} | R^{D161} |
| L_{C465} | R^{D50} | R^{D175} |
| L_{C466} | R^{D55} | R^{D3} |
| L_{C467} | R^{D55} | R^{D5} |
| L_{C468} | R^{D55} | R^{D18} |
| L_{C469} | R^{D55} | R^{D20} |
| L_{C470} | R^{D55} | R^{D22} |
| L_{C471} | R^{D55} | R^{D37} |
| L_{C472} | R^{D55} | R^{D40} |
| L_{C473} | R^{D55} | R^{D41} |
| L_{C474} | R^{D55} | R^{D42} |
| L_{C475} | R^{D55} | R^{D43} |
| L_{C476} | R^{D55} | R^{D48} |
| L_{C477} | R^{D55} | R^{D49} |
| L_{C478} | R^{D55} | R^{D54} |
| L_{C479} | R^{D55} | R^{D58} |
| L_{C480} | R^{D55} | R^{D59} |
| L_{C481} | R^{D55} | R^{D78} |
| L_{C482} | R^{D55} | R^{D79} |
| L_{C483} | R^{D55} | R^{D81} |
| L_{C484} | R^{D55} | R^{D87} |
| L_{C485} | R^{D55} | R^{D88} |
| L_{C486} | R^{D55} | R^{D89} |
| L_{C487} | R^{D55} | R^{D93} |
| L_{C488} | R^{D55} | R^{D116} |
| L_{C489} | R^{D55} | R^{D117} |
| L_{C490} | R^{D55} | R^{D118} |
| L_{C491} | R^{D55} | R^{D119} |
| L_{C492} | R^{D55} | R^{D120} |
| L_{C493} | R^{D55} | R^{D133} |
| L_{C494} | R^{D55} | R^{D134} |
| L_{C495} | R^{D55} | R^{D135} |
| L_{C496} | R^{D55} | R^{D136} |
| L_{C497} | R^{D55} | R^{D143} |
| L_{C498} | R^{D55} | R^{D144} |
| L_{C499} | R^{D55} | R^{D145} |
| L_{C500} | R^{D55} | R^{D146} |
| L_{C501} | R^{D55} | R^{D147} |
| L_{C502} | R^{D55} | R^{D149} |
| L_{C503} | R^{D55} | R^{D151} |
| L_{C504} | R^{D55} | R^{D154} |
| L_{C505} | R^{D55} | R^{D155} |
| L_{C506} | R^{D55} | R^{D161} |
| L_{C507} | R^{D55} | R^{D175} |
| L_{C508} | R^{D116} | R^{D3} |
| L_{C509} | R^{D116} | R^{D5} |
| L_{C510} | R^{D116} | R^{D17} |
| L_{C511} | R^{D116} | R^{D18} |
| L_{C512} | R^{D116} | R^{D20} |
| L_{C513} | R^{D116} | R^{D22} |
| L_{C514} | R^{D116} | R^{D37} |
| L_{C515} | R^{D116} | R^{D40} |
| L_{C516} | R^{D116} | R^{D41} |
| L_{C517} | R^{D116} | R^{D42} |
| L_{C518} | R^{D116} | R^{D43} |
| L_{C519} | R^{D116} | R^{D48} |
| L_{C520} | R^{D116} | R^{D49} |
| L_{C521} | R^{D116} | R^{D54} |
| L_{C522} | R^{D116} | R^{D58} |
| L_{C523} | R^{D116} | R^{D59} |
| L_{C524} | R^{D116} | R^{D78} |
| L_{C525} | R^{D116} | R^{D79} |
| L_{C526} | R^{D116} | R^{D81} |
| L_{C527} | R^{D116} | R^{D87} |
| L_{C528} | R^{D116} | R^{D88} |
| L_{C529} | R^{D116} | R^{D89} |
| L_{C530} | R^{D116} | R^{D93} |
| L_{C531} | R^{D116} | R^{D117} |
| L_{C532} | R^{D116} | R^{D118} |
| L_{C533} | R^{D116} | R^{D119} |
| L_{C534} | R^{D116} | R^{D120} |
| L_{C535} | R^{D116} | R^{D133} |
| L_{C536} | R^{D116} | R^{D134} |
| L_{C537} | R^{D116} | R^{D135} |
| L_{C538} | R^{D116} | R^{D136} |
| L_{C539} | R^{D116} | R^{D143} |
| L_{C540} | R^{D116} | R^{D144} |
| L_{C541} | R^{D116} | R^{D145} |
| L_{C542} | R^{D116} | R^{D146} |
| L_{C543} | R^{D116} | R^{D147} |
| L_{C544} | R^{D116} | R^{D149} |
| L_{C545} | R^{D116} | R^{D151} |
| L_{C546} | R^{D116} | R^{D154} |
| L_{C547} | R^{D116} | R^{D155} |
| L_{C548} | R^{D116} | R^{D161} |
| L_{C549} | R^{D116} | R^{D175} |
| L_{C550} | R^{D143} | R^{D3} |
| L_{C551} | R^{D143} | R^{D5} |
| L_{C552} | R^{D143} | R^{D17} |
| L_{C553} | R^{D143} | R^{D18} |
| L_{C554} | R^{D143} | R^{D20} |
| L_{C555} | R^{D143} | R^{D22} |
| L_{C556} | R^{D143} | R^{D37} |
| L_{C557} | R^{D143} | R^{D40} |
| L_{C558} | R^{D143} | R^{D41} |
| L_{C559} | R^{D143} | R^{D42} |
| L_{C560} | R^{D143} | R^{D43} |
| L_{C561} | R^{D143} | R^{D48} |
| L_{C562} | R^{D143} | R^{D49} |
| L_{C563} | R^{D143} | R^{D54} |
| L_{C564} | R^{D143} | R^{D58} |
| L_{C565} | R^{D143} | R^{D59} |
| L_{C566} | R^{D143} | R^{D78} |
| L_{C567} | R^{D143} | R^{D79} |
| L_{C568} | R^{D143} | R^{D81} |
| L_{C569} | R^{D143} | R^{D87} |
| L_{C570} | R^{D143} | R^{D88} |
| L_{C571} | R^{D143} | R^{D89} |
| L_{C572} | R^{D143} | R^{D93} |
| L_{C573} | R^{D143} | R^{D116} |
| L_{C574} | R^{D143} | R^{D117} |
| L_{C575} | R^{D143} | R^{D118} |
| L_{C576} | R^{D143} | R^{D119} |
| L_{C577} | R^{D143} | R^{D120} |
| L_{C578} | R^{D143} | R^{D133} |
| L_{C579} | R^{D143} | R^{D134} |
| L_{C580} | R^{D143} | R^{D135} |
| L_{C581} | R^{D143} | R^{D136} |
| L_{C582} | R^{D143} | R^{D144} |
| L_{C583} | R^{D143} | R^{D145} |
| L_{C584} | R^{D143} | R^{D146} |
| L_{C585} | R^{D143} | R^{D147} |
| L_{C586} | R^{D143} | R^{D149} |
| L_{C587} | R^{D143} | R^{D151} |
| L_{C588} | R^{D143} | R^{D154} |
| L_{C589} | R^{D143} | R^{D155} |
| L_{C590} | R^{D143} | R^{D161} |
| L_{C591} | R^{D143} | R^{D175} |
| L_{C592} | R^{D144} | R^{D3} |
| L_{C593} | R^{D144} | R^{D5} |
| L_{C594} | R^{D144} | R^{D17} |
| L_{C595} | R^{D144} | R^{D18} |
| L_{C596} | R^{D144} | R^{D20} |
| L_{C597} | R^{D144} | R^{D22} |
| L_{C598} | R^{D144} | R^{D37} |
| L_{C599} | R^{D144} | R^{D40} |
| L_{C600} | R^{D144} | R^{D41} |
| L_{C601} | R^{D144} | R^{D42} |
| L_{C602} | R^{D144} | R^{D43} |
| L_{C603} | R^{D144} | R^{D48} |
| L_{C604} | R^{D144} | R^{D49} |
| L_{C605} | R^{D144} | R^{D54} |
| L_{C606} | R^{D144} | R^{D58} |
| L_{C607} | R^{D144} | R^{D59} |
| L_{C608} | R^{D144} | R^{D78} |
| L_{C609} | R^{D144} | R^{D79} |
| L_{C610} | R^{D144} | R^{D81} |
| L_{C611} | R^{D144} | R^{D87} |
| L_{C612} | R^{D144} | R^{D88} |
| L_{C613} | R^{D144} | R^{D89} |
| L_{C614} | R^{D144} | R^{D93} |
| L_{C615} | R^{D144} | R^{D116} |
| L_{C616} | R^{D144} | R^{D117} |
| L_{C617} | R^{D144} | R^{D118} |
| L_{C618} | R^{D144} | R^{D119} |
| L_{C619} | R^{D144} | R^{D120} |
| L_{C620} | R^{D144} | R^{D133} |
| L_{C621} | R^{D144} | R^{D134} |
| L_{C622} | R^{D144} | R^{D135} |
| L_{C623} | R^{D144} | R^{D136} |
| L_{C624} | R^{D144} | R^{D145} |
| L_{C625} | R^{D144} | R^{D146} |
| L_{C626} | R^{D144} | R^{D147} |
| L_{C627} | R^{D144} | R^{D149} |
| L_{C628} | R^{D144} | R^{D151} |
| L_{C629} | R^{D144} | R^{D154} |
| L_{C630} | R^{D144} | R^{D155} |
| L_{C631} | R^{D144} | R^{D161} |
| L_{C632} | R^{D144} | R^{D175} |
| L_{C633} | R^{D145} | R^{D3} |
| L_{C634} | R^{D145} | R^{D5} |
| L_{C635} | R^{D145} | R^{D17} |
| L_{C636} | R^{D145} | R^{D18} |
| L_{C637} | R^{D145} | R^{D20} |
| L_{C638} | R^{D145} | R^{D22} |
| L_{C639} | R^{D145} | R^{D37} |
| L_{C640} | R^{D145} | R^{D40} |
| L_{C641} | R^{D145} | R^{D41} |
| L_{C642} | R^{D145} | R^{D42} |
| L_{C643} | R^{D145} | R^{D43} |
| L_{C644} | R^{D145} | R^{D48} |
| L_{C645} | R^{D145} | R^{D49} |
| L_{C646} | R^{D145} | R^{D54} |
| L_{C647} | R^{D145} | R^{D58} |
| L_{C648} | R^{D145} | R^{D59} |
| L_{C649} | R^{D145} | R^{D78} |
| L_{C650} | R^{D145} | R^{D79} |
| L_{C651} | R^{D145} | R^{D81} |
| L_{C652} | R^{D145} | R^{D87} |
| L_{C653} | R^{D145} | R^{D88} |
| L_{C654} | R^{D145} | R^{D89} |
| L_{C655} | R^{D145} | R^{D93} |
| L_{C656} | R^{D145} | R^{D116} |
| L_{C657} | R^{D145} | R^{D117} |
| L_{C658} | R^{D145} | R^{D118} |
| L_{C659} | R^{D145} | R^{D119} |
| L_{C660} | R^{D145} | R^{D120} |
| L_{C661} | R^{D145} | R^{D133} |
| L_{C662} | R^{D145} | R^{D134} |
| L_{C663} | R^{D145} | R^{D135} |
| L_{C664} | R^{D145} | R^{D136} |
| L_{C665} | R^{D145} | R^{D146} |
| L_{C666} | R^{D145} | R^{D147} |
| L_{C667} | R^{D145} | R^{D149} |
| L_{C668} | R^{D145} | R^{D151} |
| L_{C669} | R^{D145} | R^{D154} |
| L_{C670} | R^{D145} | R^{D155} |
| L_{C671} | R^{D145} | R^{D161} |
| L_{C672} | R^{D145} | R^{D175} |
| L_{C673} | R^{D146} | R^{D3} |
| L_{C674} | R^{D146} | R^{D5} |
| L_{C675} | R^{D146} | R^{D17} |
| L_{C676} | R^{D146} | R^{D18} |
| L_{C677} | R^{D146} | R^{D20} |
| L_{C678} | R^{D146} | R^{D22} |
| L_{C679} | R^{D146} | R^{D37} |
| L_{C680} | R^{D146} | R^{D40} |
| L_{C681} | R^{D146} | R^{D41} |
| L_{C682} | R^{D146} | R^{D42} |
| L_{C683} | R^{D146} | R^{D43} |
| L_{C684} | R^{D146} | R^{D48} |
| L_{C385} | R^{D146} | R^{D49} |
| L_{C386} | R^{D146} | R^{D54} |
| L_{C387} | R^{D146} | R^{D58} |
| L_{C388} | R^{D146} | R^{D59} |
| L_{C389} | R^{D146} | R^{D78} |
| L_{C390} | R^{D146} | R^{D79} |
| L_{C391} | R^{D146} | R^{D81} |
| L_{C392} | R^{D146} | R^{D87} |
| L_{C393} | R^{D146} | R^{D88} |
| L_{C394} | R^{D146} | R^{D89} |
| L_{C395} | R^{D146} | R^{D93} |
| L_{C396} | R^{D146} | R^{D117} |
| L_{C397} | R^{D146} | R^{D118} |
| L_{C398} | R^{D146} | R^{D119} |
| L_{C399} | R^{D146} | R^{D120} |
| L_{C700} | R^{D146} | R^{D133} |
| L_{C701} | R^{D146} | R^{D134} |
| L_{C702} | R^{D146} | R^{D135} |
| L_{C703} | R^{D146} | R^{D136} |
| L_{C704} | R^{D146} | R^{D146} |
| L_{C705} | R^{D146} | R^{D147} |
| L_{C706} | R^{D146} | R^{D149} |
| L_{C707} | R^{D146} | R^{D151} |
| L_{C708} | R^{D146} | R^{D154} |
| L_{C709} | R^{D146} | R^{D155} |
| L_{C710} | R^{D146} | R^{D161} |
| L_{C711} | R^{D146} | R^{D175} |
| L_{C712} | R^{D133} | R^{D3} |
| L_{C713} | R^{D133} | R^{D5} |
| L_{C714} | R^{D133} | R^{D3} |
| L_{C715} | R^{D133} | R^{D18} |
| L_{C716} | R^{D133} | R^{D20} |
| L_{C717} | R^{D133} | R^{D22} |
| L_{C718} | R^{D133} | R^{D37} |
| L_{C719} | R^{D133} | R^{D40} |
| L_{C720} | R^{D133} | R^{D41} |
| L_{C721} | R^{D133} | R^{D42} |
| L_{C722} | R^{D133} | R^{D43} |
| L_{C723} | R^{D133} | R^{D48} |
| L_{C724} | R^{D133} | R^{D49} |
| L_{C725} | R^{D133} | R^{D54} |
| L_{C726} | R^{D133} | R^{D58} |
| L_{C727} | R^{D133} | R^{D59} |
| L_{C728} | R^{D133} | R^{D78} |
| L_{C729} | R^{D133} | R^{D79} |
| L_{C730} | R^{D133} | R^{D81} |
| L_{C731} | R^{D133} | R^{D87} |
| L_{C732} | R^{D133} | R^{D88} |
| L_{C733} | R^{D133} | R^{D89} |
| L_{C734} | R^{D133} | R^{D93} |
| L_{C735} | R^{D133} | R^{D117} |
| L_{C736} | R^{D133} | R^{D118} |
| L_{C737} | R^{D133} | R^{D119} |
| L_{C738} | R^{D133} | R^{D120} |
| L_{C739} | R^{D133} | R^{D133} |
| L_{C740} | R^{D133} | R^{D134} |
| L_{C741} | R^{D133} | R^{D135} |
| L_{C742} | R^{D133} | R^{D136} |
| L_{C743} | R^{D133} | R^{D146} |
| L_{C744} | R^{D133} | R^{D147} |
| L_{C745} | R^{D133} | R^{D149} |
| L_{C746} | R^{D133} | R^{D151} |
| L_{C747} | R^{D133} | R^{D154} |
| L_{C748} | R^{D133} | R^{D155} |
| L_{C749} | R^{D133} | R^{D161} |
| L_{C750} | R^{D133} | R^{D175} |
| L_{C751} | R^{D175} | R^{D3} |
| L_{C752} | R^{D175} | R^{D5} |
| L_{C753} | R^{D175} | R^{D18} |
| L_{C754} | R^{D175} | R^{D20} |
| L_{C755} | R^{D175} | R^{D22} |
| L_{C756} | R^{D175} | R^{D37} |
| L_{C757} | R^{D175} | R^{D40} |
| L_{C758} | R^{D175} | R^{D41} |
| L_{C759} | R^{D175} | R^{D42} |
| L_{C760} | R^{D175} | R^{D43} |
| L_{C761} | R^{D175} | R^{D48} |
| L_{C762} | R^{D175} | R^{D49} |
| L_{C763} | R^{D175} | R^{D54} |
| L_{C764} | R^{D175} | R^{D58} |
| L_{C765} | R^{D175} | R^{D59} |
| L_{C766} | R^{D175} | R^{D78} |
| L_{C767} | R^{D175} | R^{D79} |
| L_{C768} | R^{D175} | R^{D81} |

wherein R^{D1} to R^{D192} have the following structures:

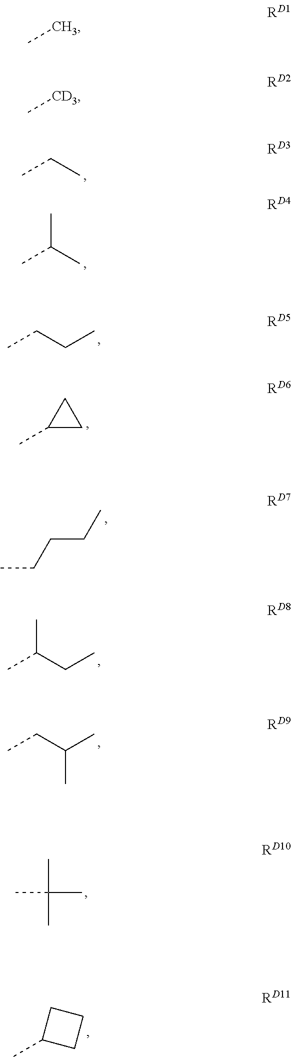

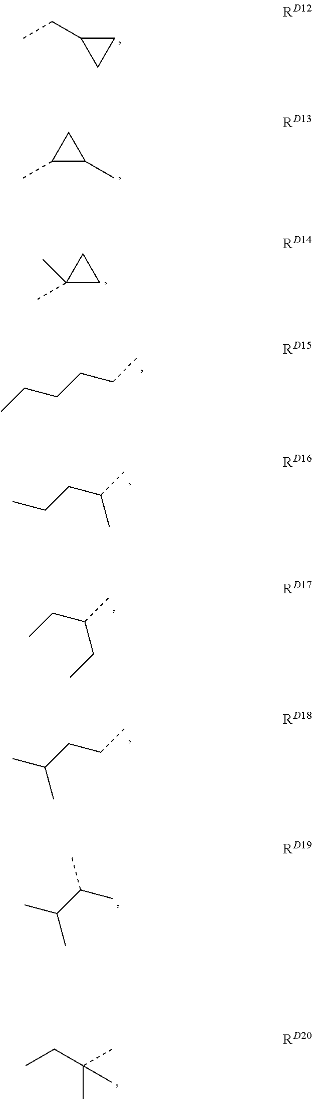

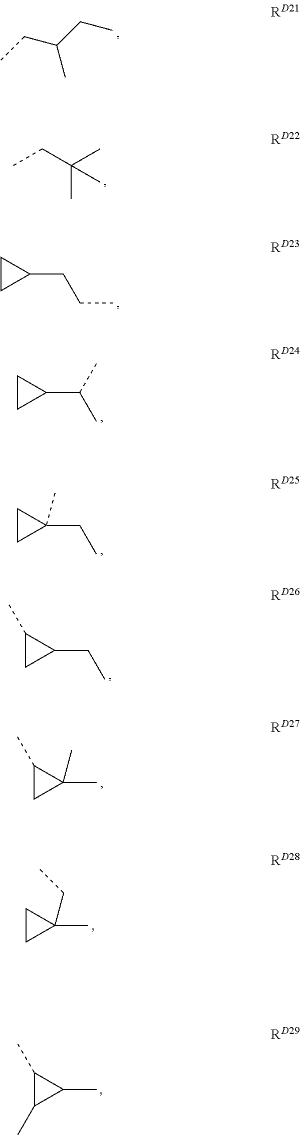

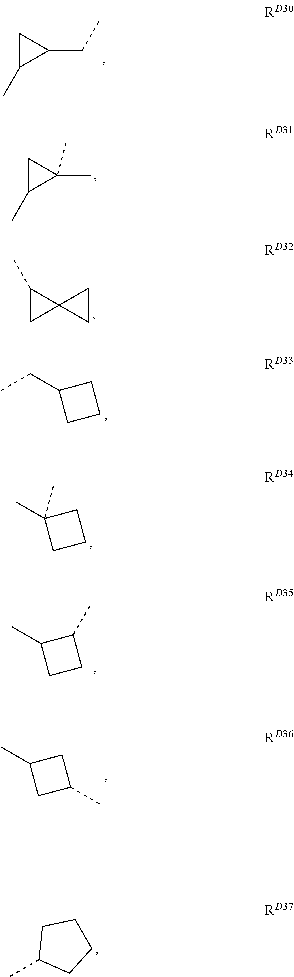

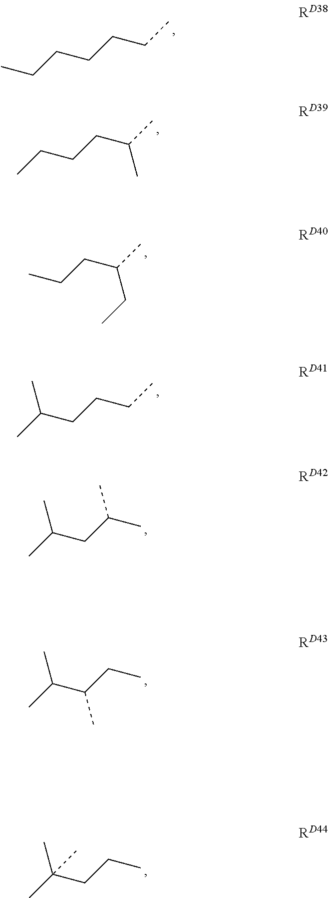

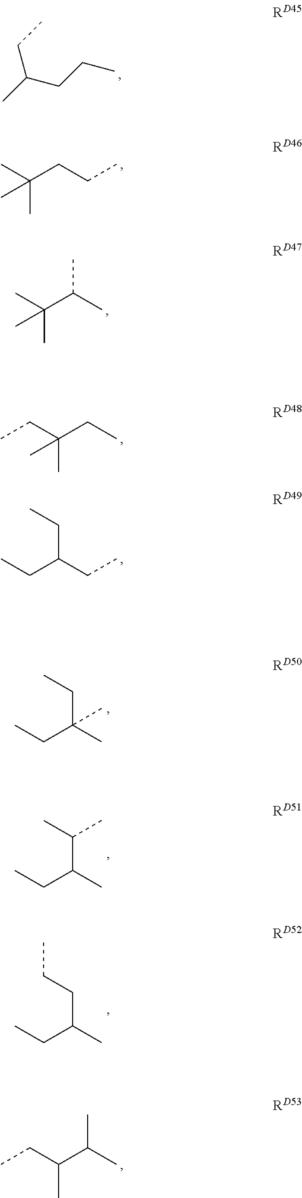

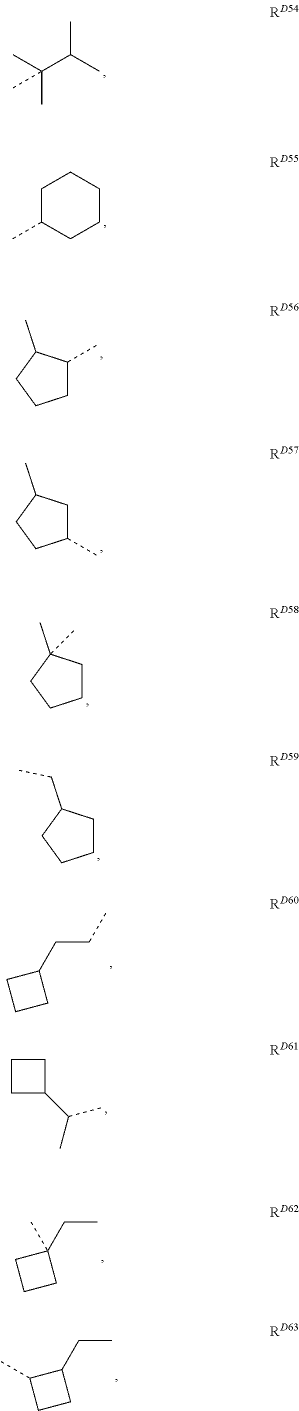

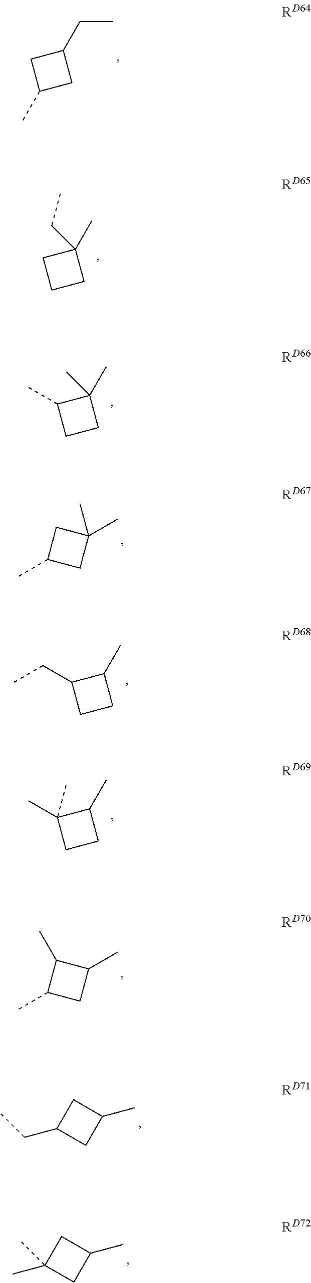

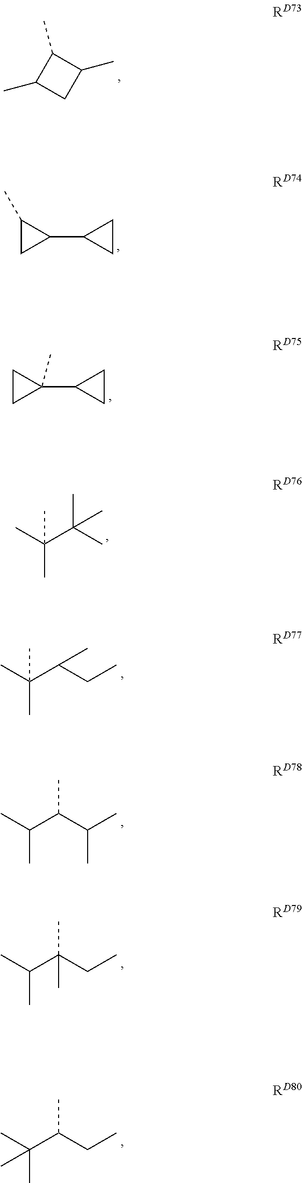

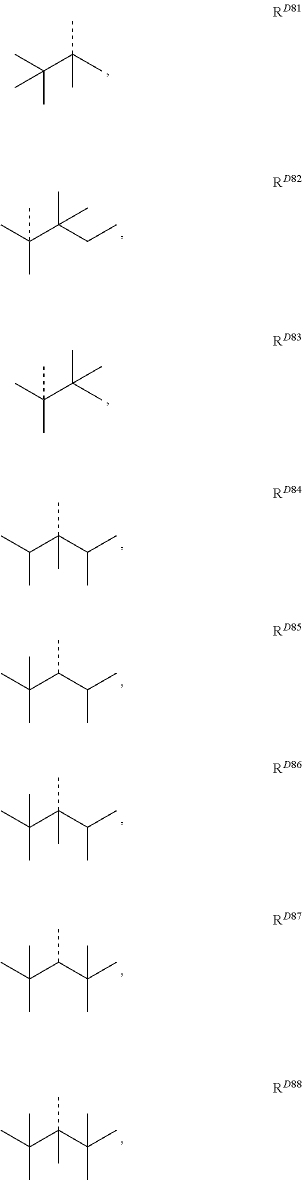

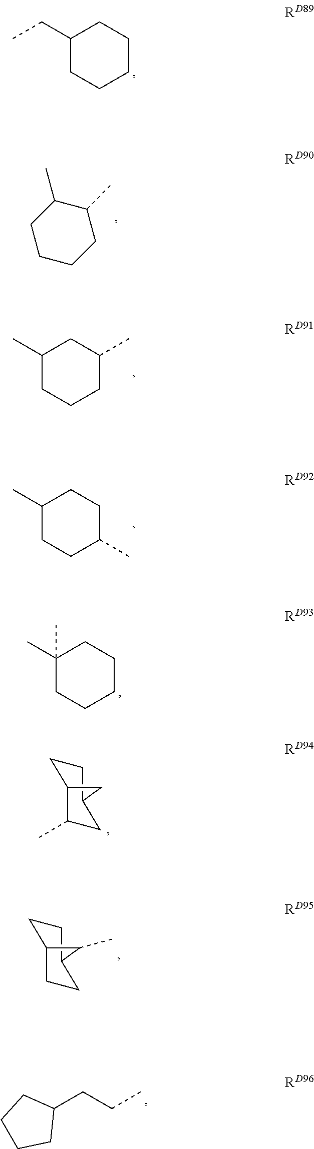

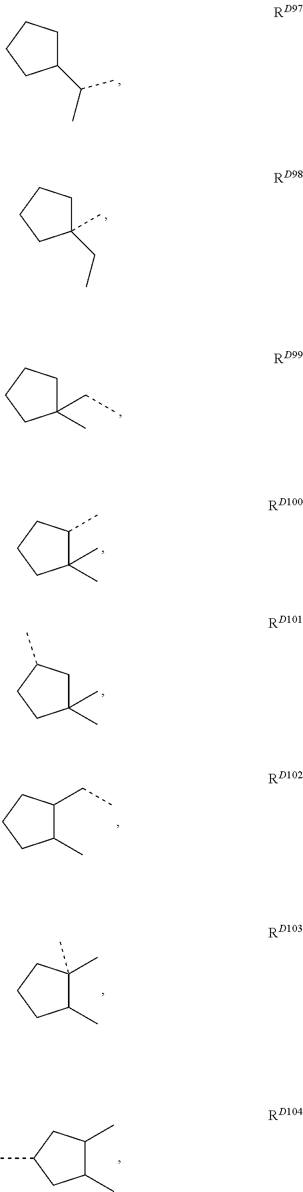

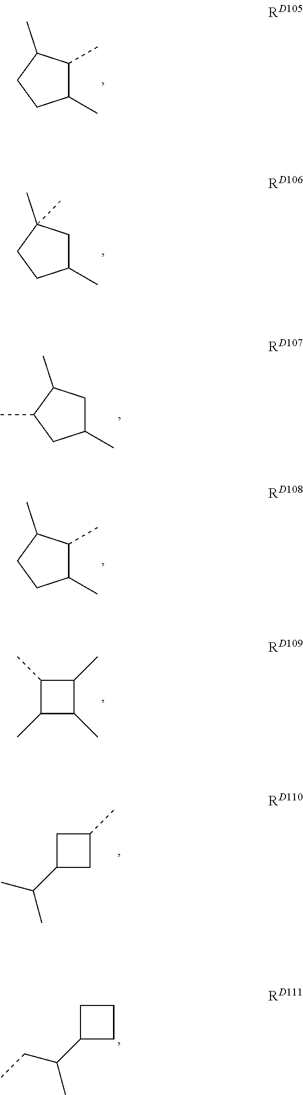

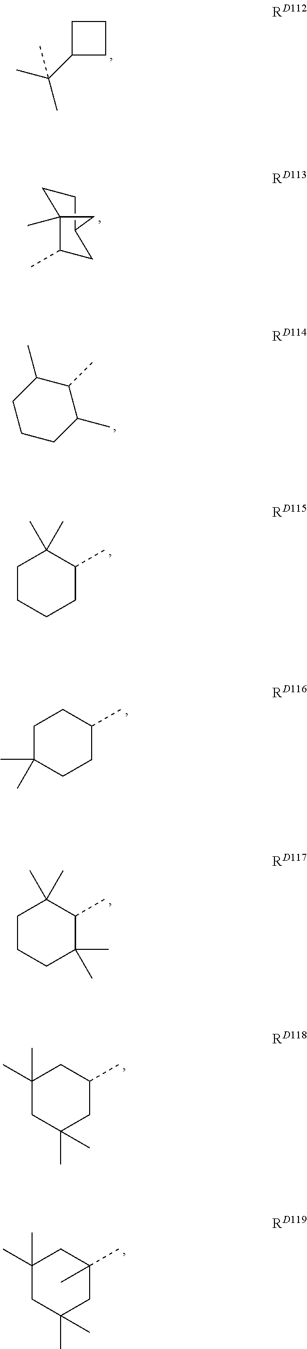

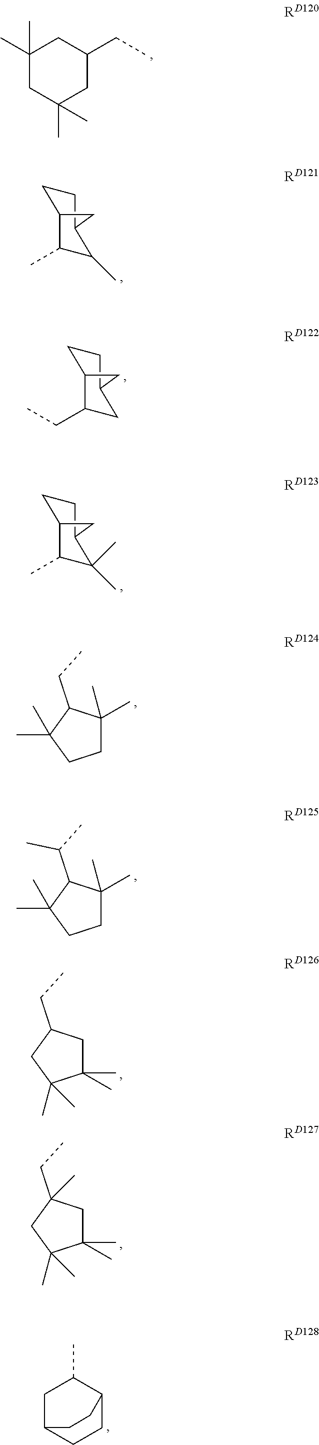

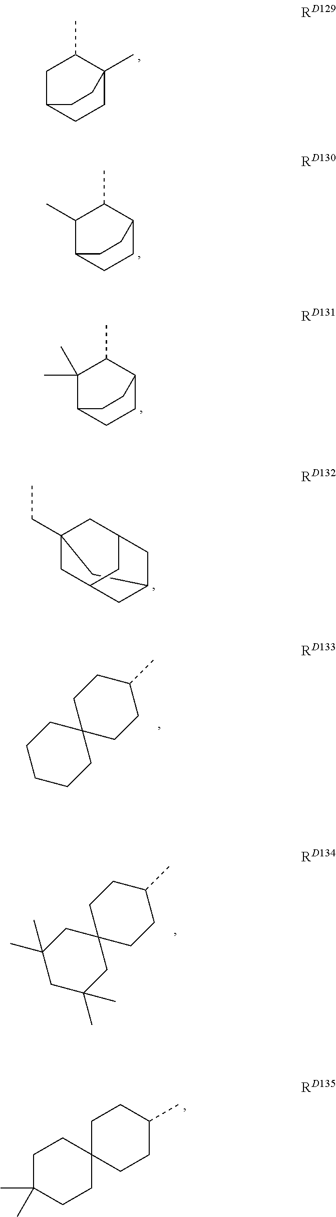

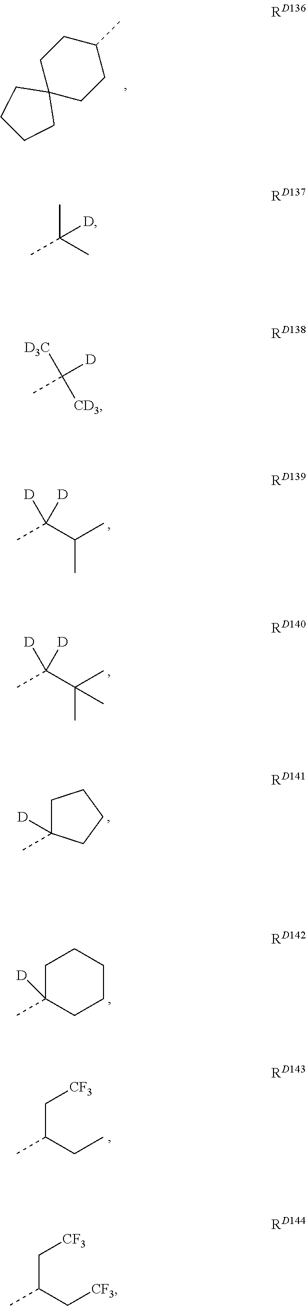

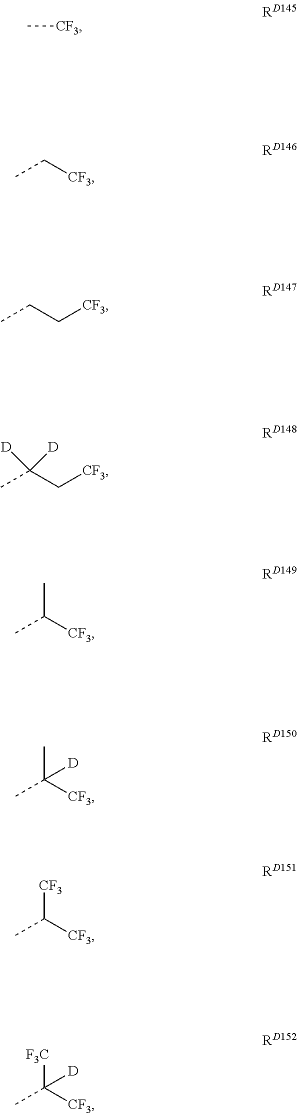

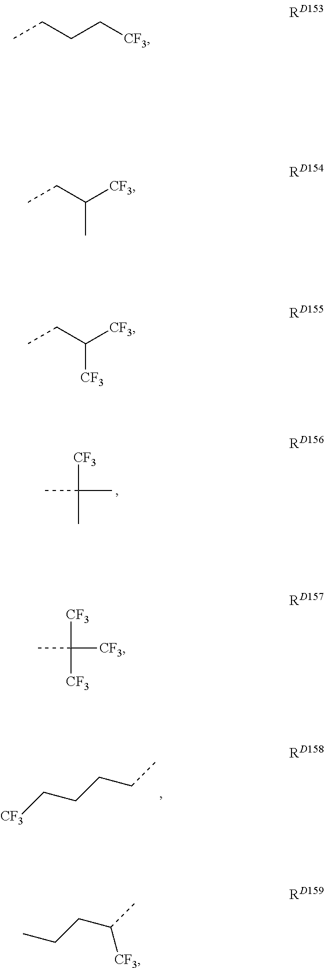

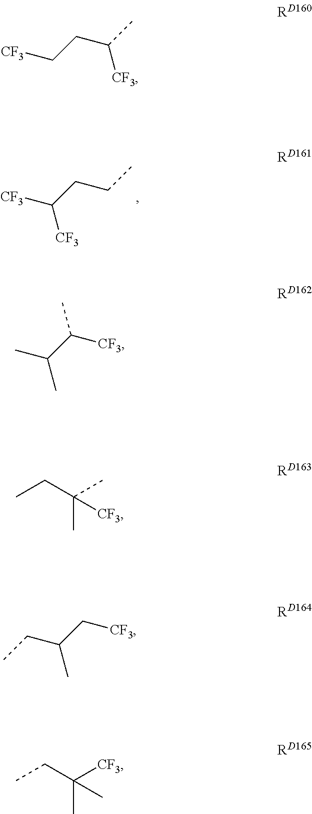

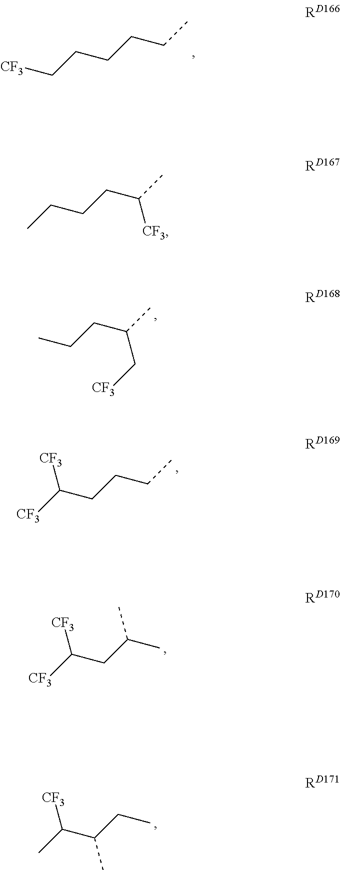

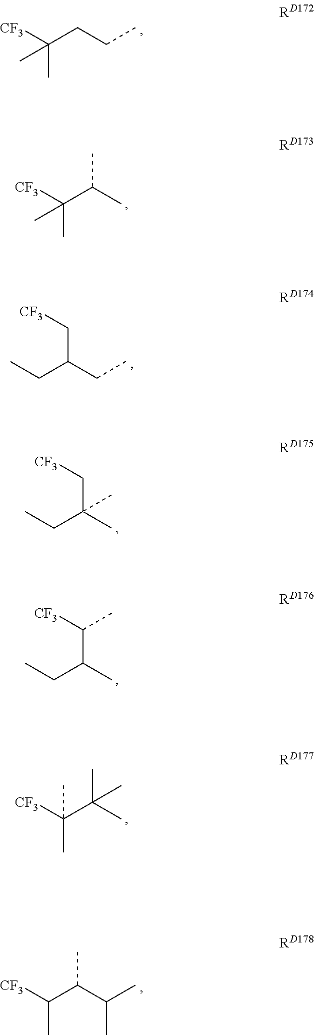

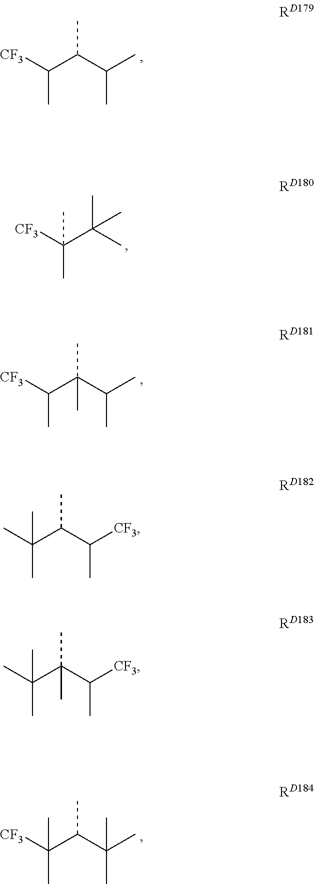

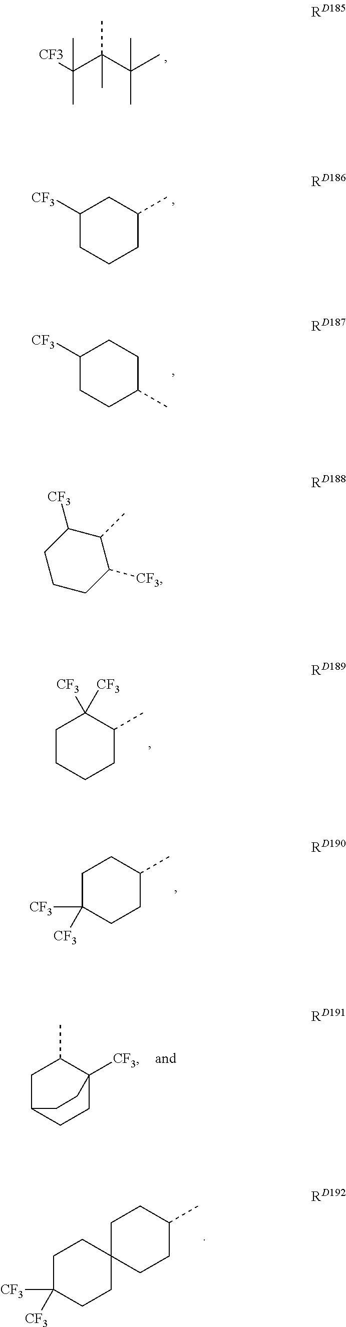

In some embodiments where the compound is Compound A, Compound B, or Compound C, where L_{A} can be any of the structures for L_{A} defined above, L_{B} is selected from the group consisting of: L_{B1}, L_{B2}, L_{B18}, L_{B28}, L_{B38}, L_{B108}, L_{B118}, L_{B122}, L_{B124}, L_{B126}, L_{B128}, L_{B130}, L_{B32}, L_{B134}, L_{B136}, L_{B138}, L_{B140}, L_{B142}, L_{B144}, L_{B156}, L_{B58}, L_{B160}, L_{B162}, L_{B164}, L_{B168}, L_{B172}, L_{B175}, L_{B204}, L_{B206}, L_{B214}, L_{B216}, L_{B218}, L_{B220}, L_{B222}, L_{B231}, L_{B233}, L_{B235}, L_{B237}, L_{B240}, L_{B242}, L_{B244}, L_{B246}, L_{B248}, L_{B250}, L_{B252}, L_{B254}, L_{B256}, L_{B258}, L_{B260}, L_{B262}, L_{B263}, L_{B264}, L_{B265}, L_{B266}, L_{B267}, L_{B268}, L_{B269}, L_{B270}, L_{B271}, L_{B272}, L_{B273}, L_{B274}, L_{B275}, L_{B276}, L_{B277}, L_{B278}, L_{B279}, L_{B280}, L_{B281}, L_{B283}, L_{B285}, L_{B287}, L_{B297}, L_{B300}, L_{B335}, L_{B338}, L_{B352}, L_{B354}, L_{B368}, L_{B369}, L_{B370}, L_{B375}, L_{B376}, L_{B377}, L_{B379}, L_{B380}, L_{B382}, L_{B385}, L_{B386}, L_{B394}, L_{B395}, L_{B396}, L_{B397}, L_{B398}, L_{B399}, L_{B400}, L_{B401}, L_{B402}, L_{B403}, L_{B410}, L_{B411}, L_{B412}, L_{B417}, L_{B425}, L_{B427}, L_{B430}, L_{B431}, L_{B432}, L_{B434}, L_{B440}, L_{B444}, L_{B445}, L_{B446}, L_{B447}, L_{B449}, L_{B450}, L_{B451}, L_{B452}, L_{B454}, L_{B455}, L_{B457}, L_{B460}, L_{B462}, L_{B463}, L_{B469}, and L_{B471}.

In some embodiments, L_{B} is selected from the group consisting of: L_{B1}, L_{B2}, L_{B18}, L_{B28}, L_{B38}, L_{B108}, L_{B118}, L_{B122}, L_{B124}, L_{B126}, L_{B128}, L_{B132}, L_{B136}, L_{B138}, L_{B142}, L_{B156}, L_{B162}, L_{B204}, L_{B206}, L_{B214}, L_{B216}, L_{B218}, L_{B220}, L_{B231}, L_{B233}, L_{B237}, L_{B266}, L_{B268}, L_{B275}, L_{B276}, L_{B277}, L_{B285}, L_{B287}, L_{B297}, L_{B300}, L_{B335}, L_{B338}, L_{B376}, L_{B379}, L_{B380}, L_{B385}, L_{B386}, L_{B398}, L_{B400}, L_{B401}, L_{B403}, L_{B412}, L_{B417}, L_{B427}, L_{B430}, L_{B444}, L_{B445}, L_{B446}, L_{B447}, L_{B452}, L_{B460}, L_{B462}, and L_{B463}.

In some embodiments, L_{C} is selected from the group consisting of only those L_{Cj-I} and L_{Cj-II} whose corresponding R¹ and R² are defined to be selected from the following structures: R^{D1}, R^{D3}, R^{D4}, R^{D5}, R^{D9}, R^{D10}, R^{D17}, R^{D18}, R^{D20}, R^{D22}, R^{D37}, R^{D40}, R^{D41}, R^{D42}, R^{D43}, R^{D48}, R^{D49}, R^{D50}, R^{D54}, R^{D55}, R^{D58}, R^{D59}, R^{D78}, R^{D79}, R^{D81}, R^{D87}, R^{D88}, R^{D89}, R^{D93}, R^{D116}, R^{D117}, R^{D118}, R^{D119}, R^{D120}, R^{D133}, R^{D134}, R^{D135}, R^{D136}, R^{D143}, R^{D144}, R^{D145}, R^{D146}, R^{D147}, R^{D149}, R^{D151}, R^{D154}, R^{D155}, R^{D161}, R^{D175}, and R^{D190}.

In some embodiments, L_{C} is selected from the group consisting of only those L_{Cj-I} and L_{Cj-II} whose corresponding R¹ and R² are defined to be selected from the following structures: R^{D1}, R^{D3}, R^{D4}, R^{D5}, R^{D9}, R^{D17}, R^{D22}, R^{D43}, R^{D50}, R^{D78}, R^{D116}, R^{D118}, R^{D133}, R^{D134}, R^{D135}, R^{D136}, R^{D143}, R^{D144}, R^{D145}, R^{D146}, R^{D149}, R^{D151}, R^{D154}, R^{D155}, and R^{D190}.

In some embodiments, L_{C} is selected from the group consisting of:

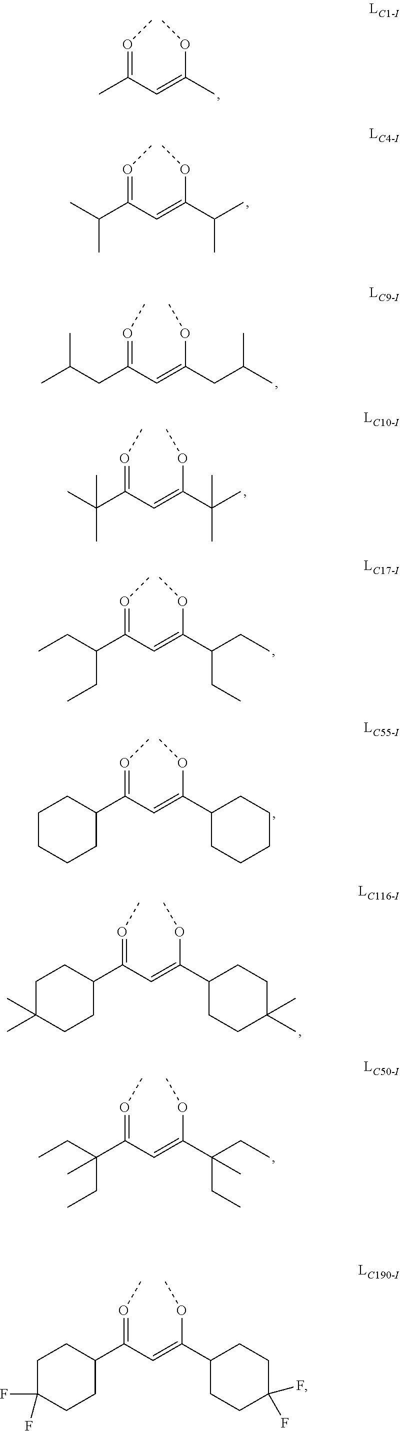

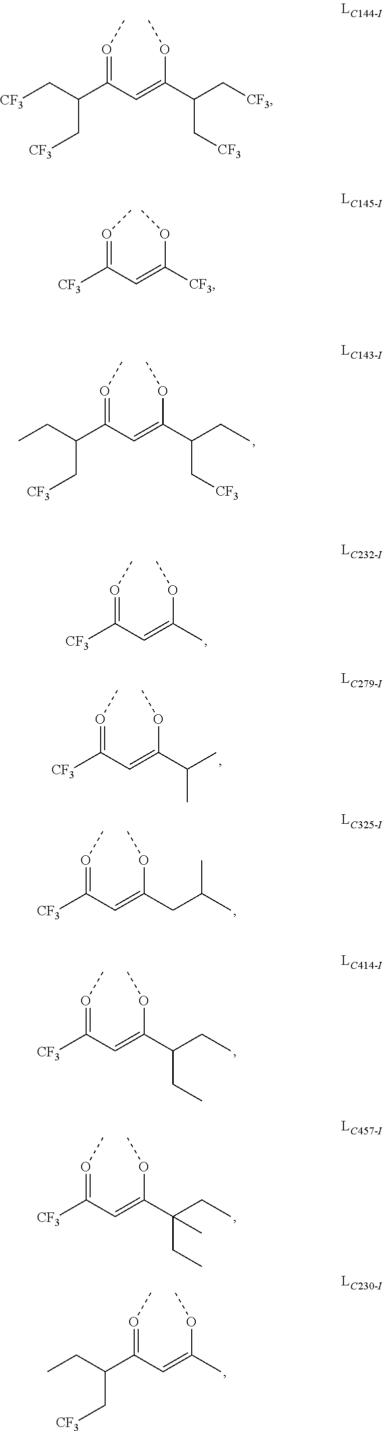

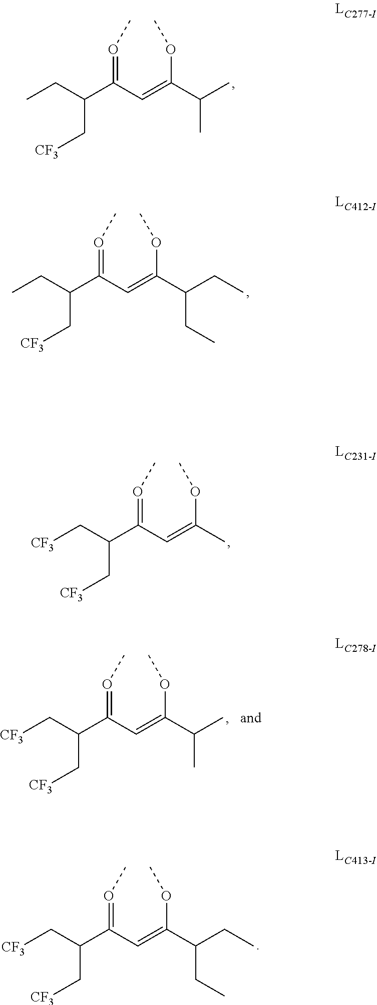

In some embodiments, the compound is selected from the group consisting of the compounds in LIST5 below:

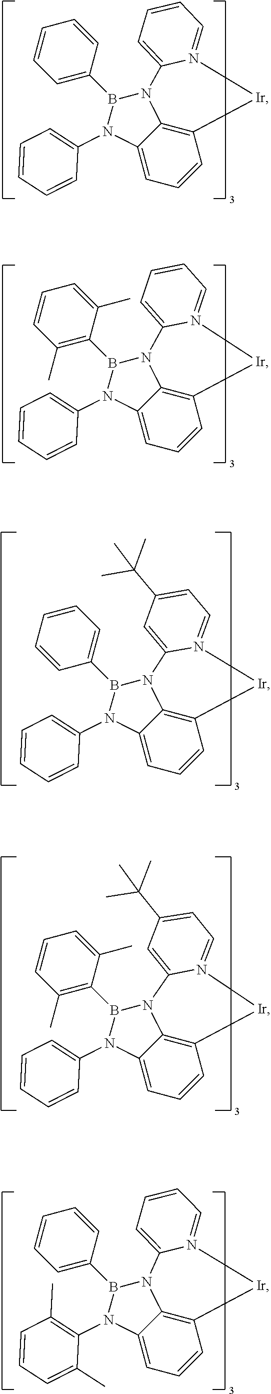

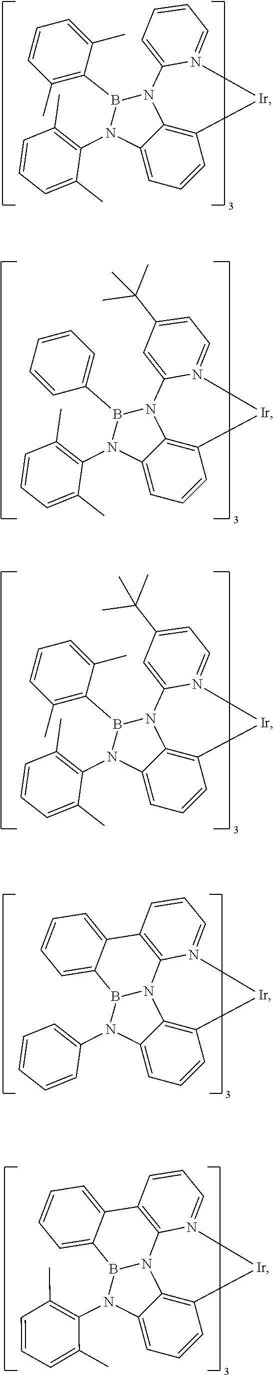

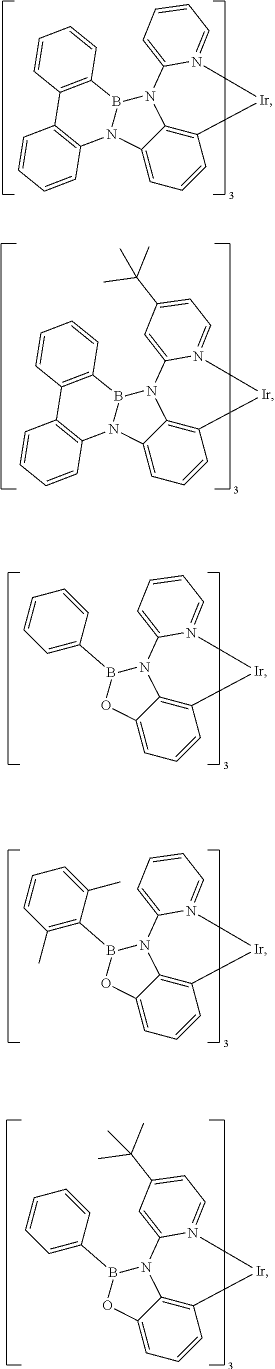

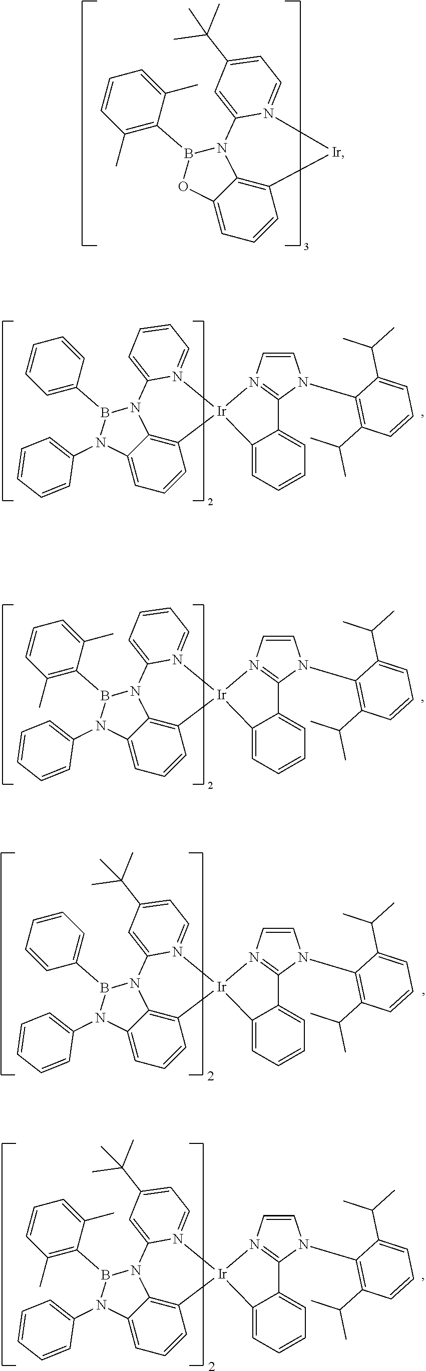

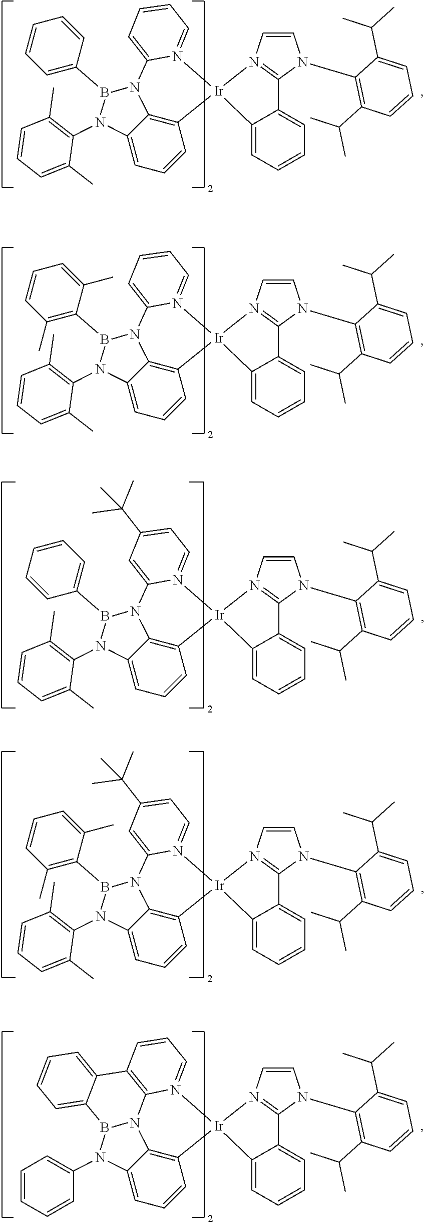

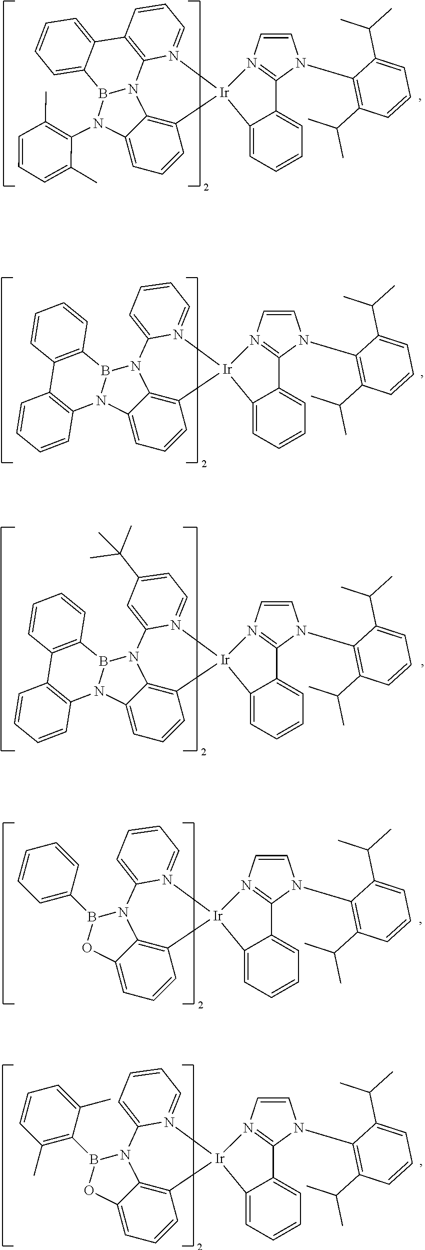

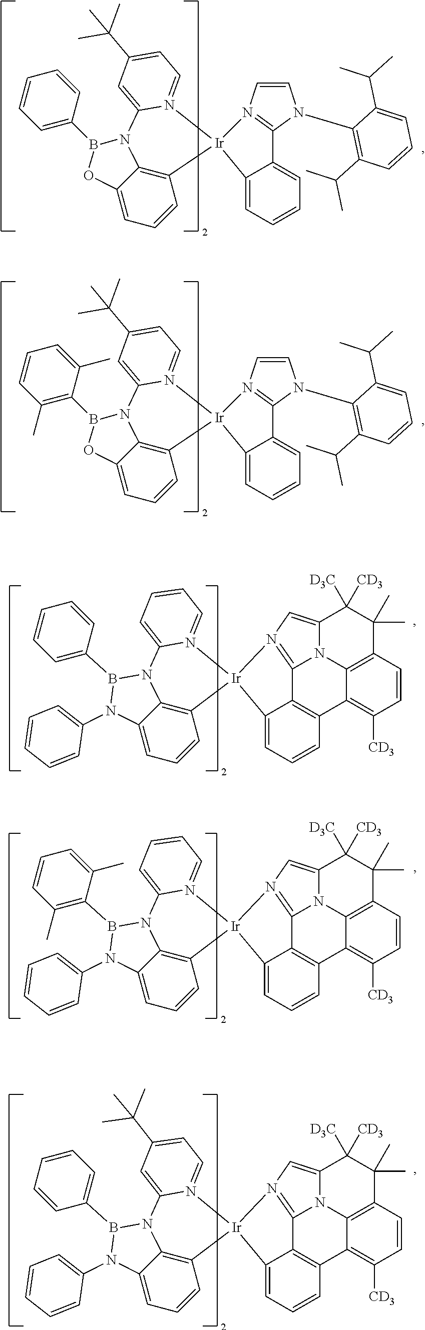

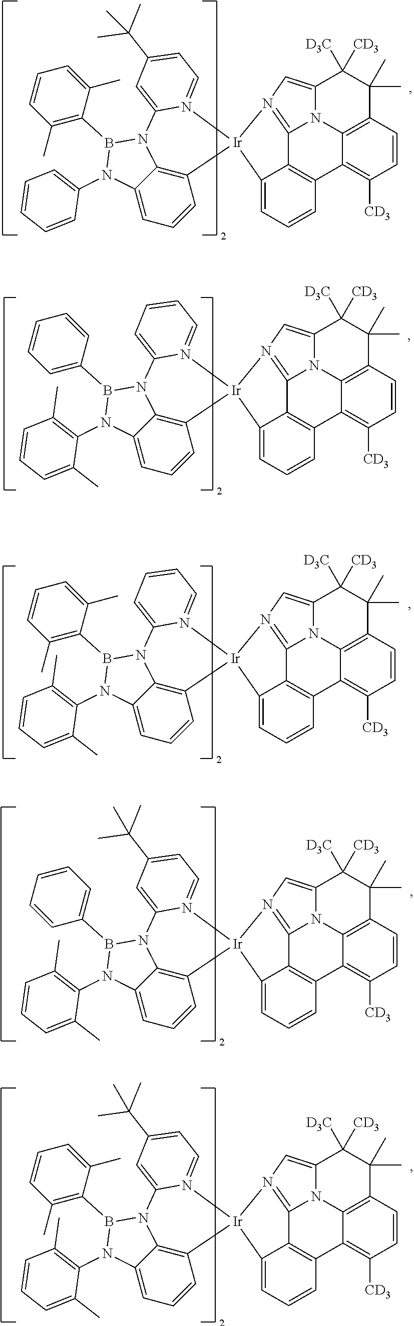

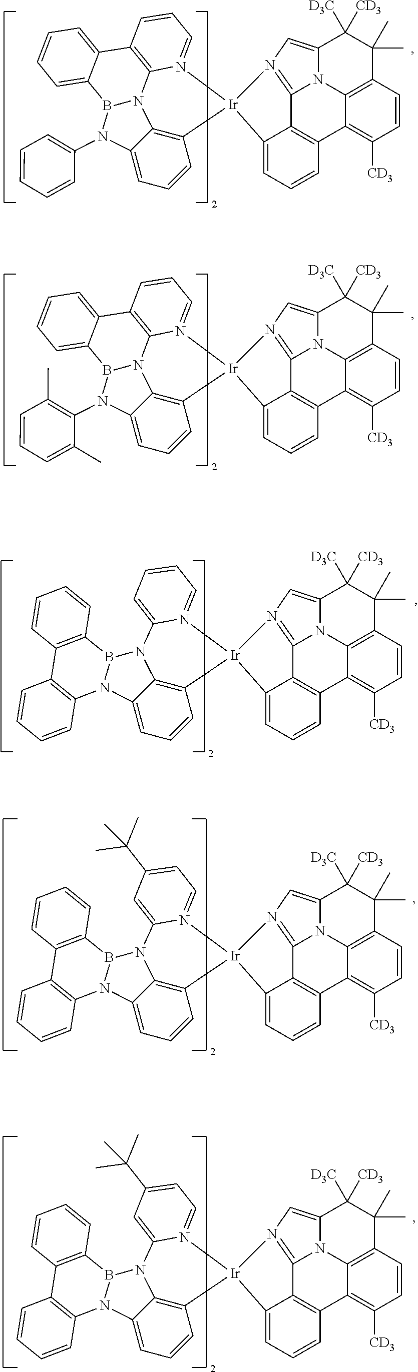

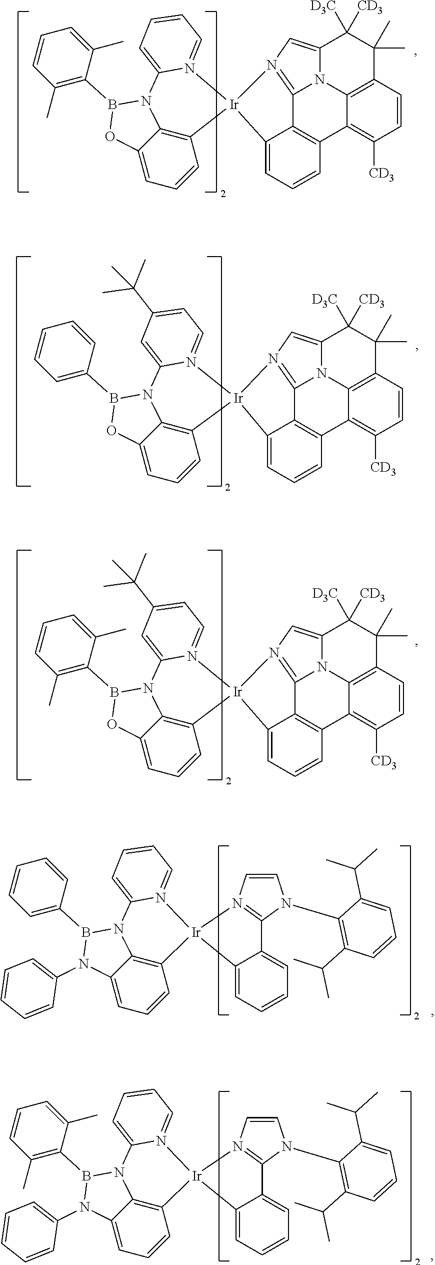

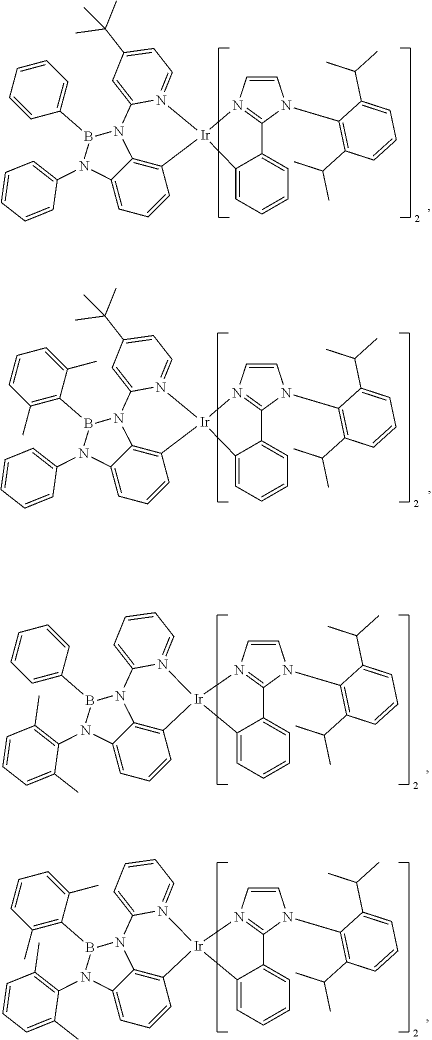

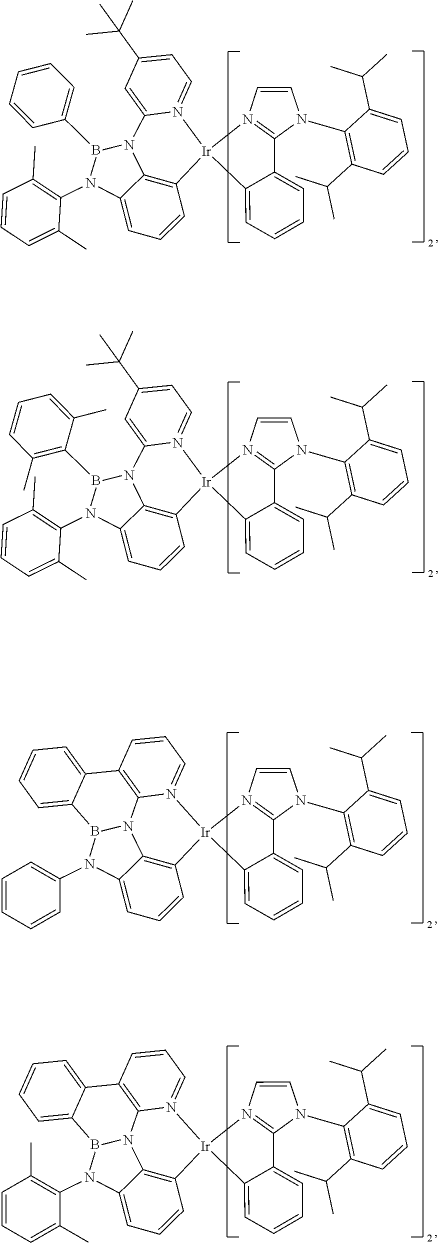

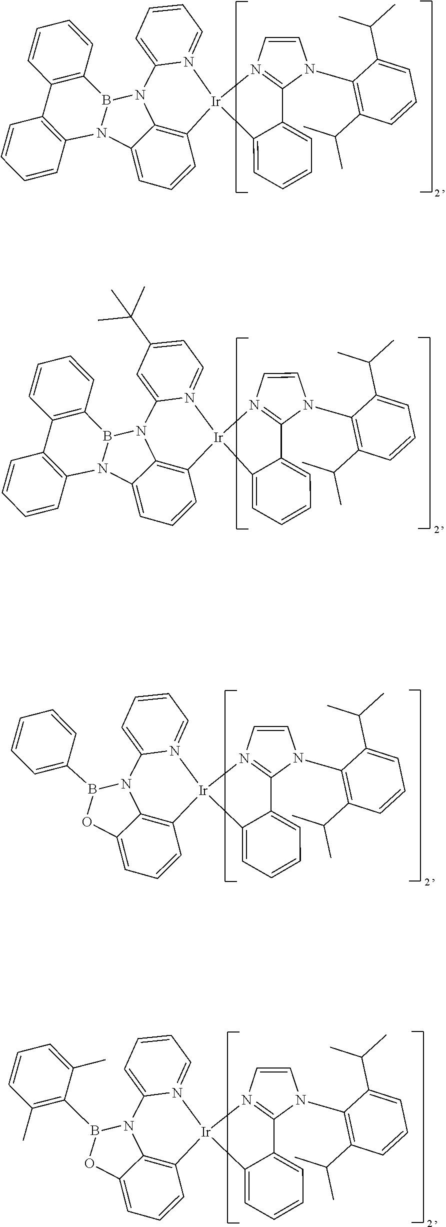

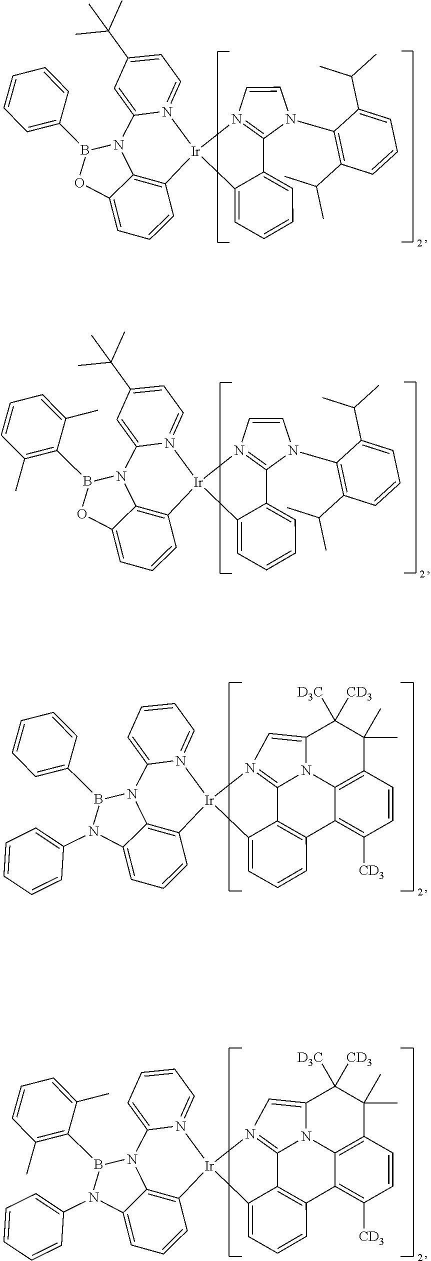

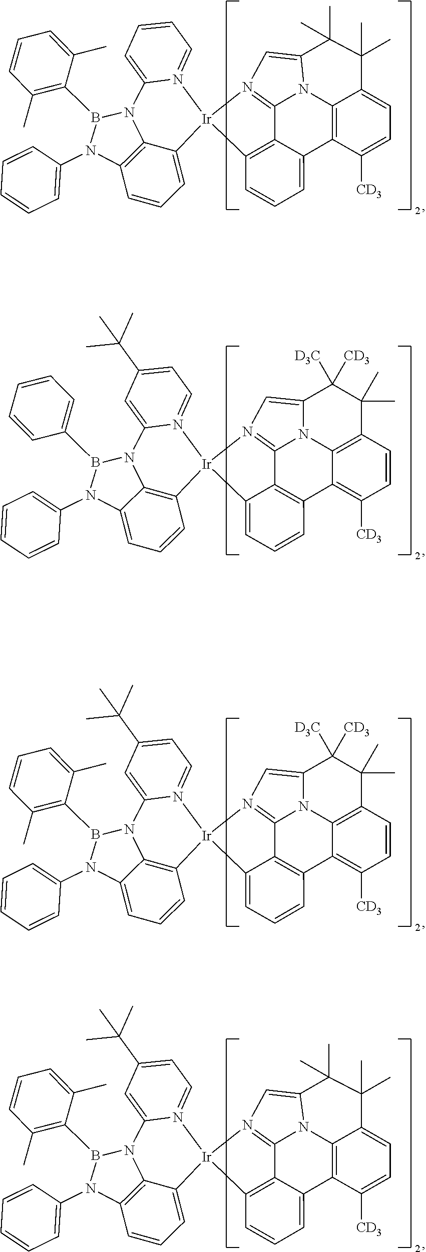

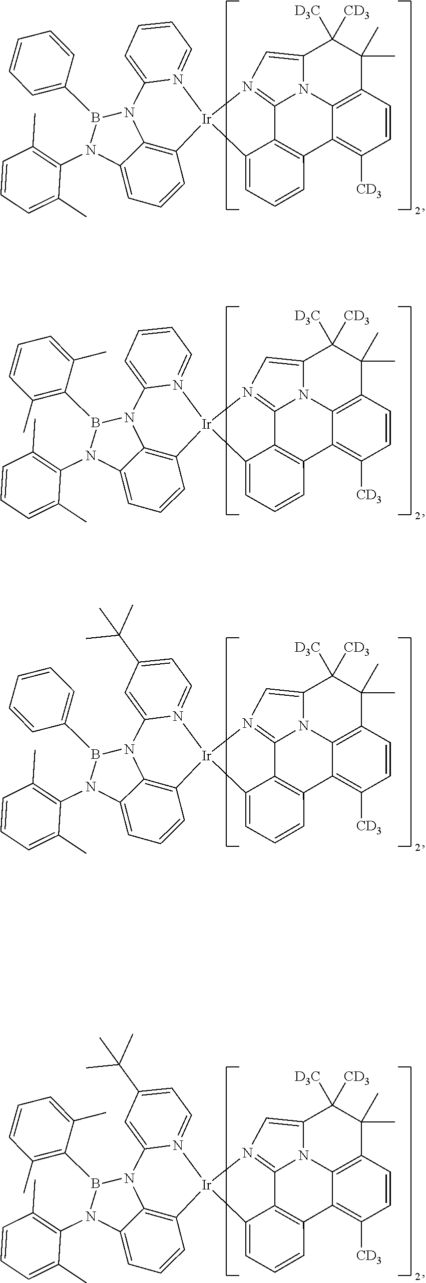

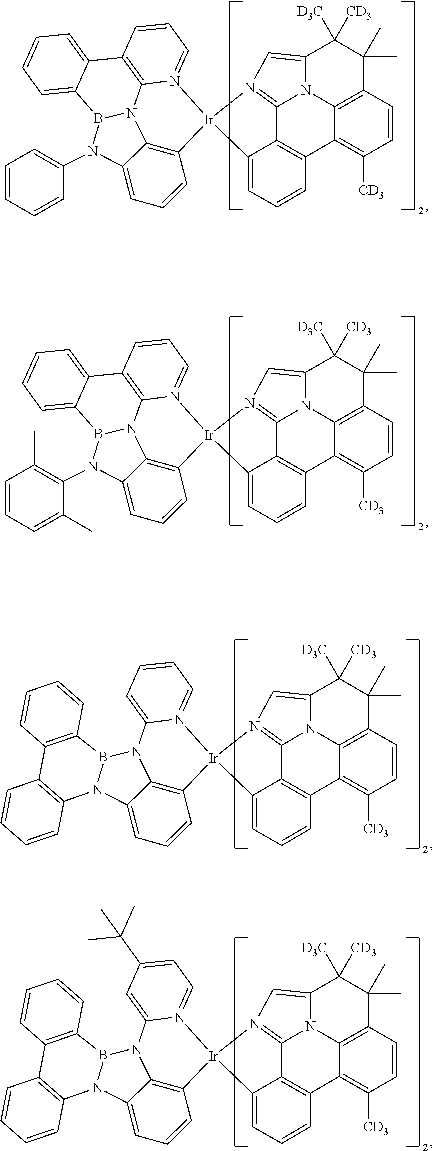

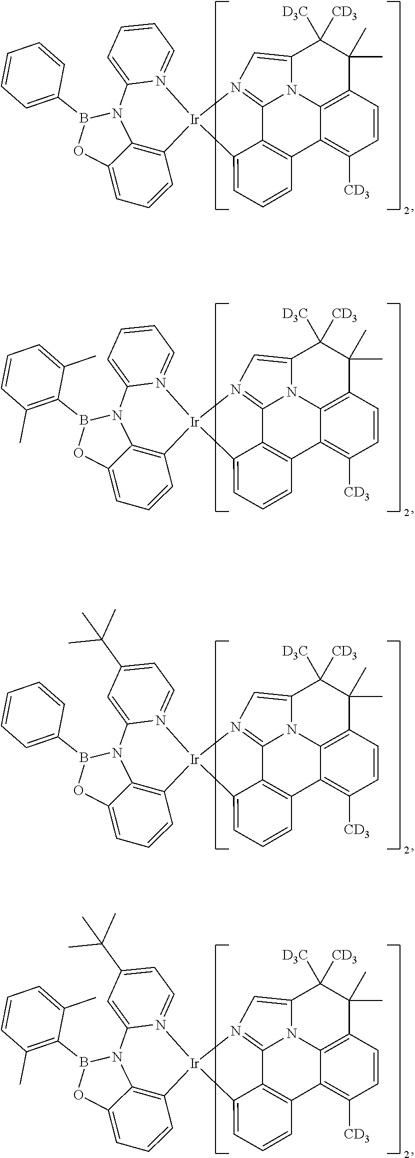

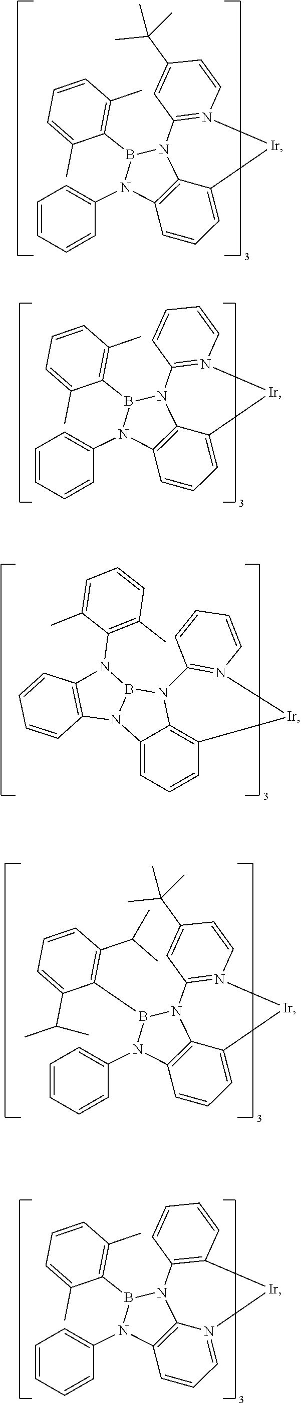

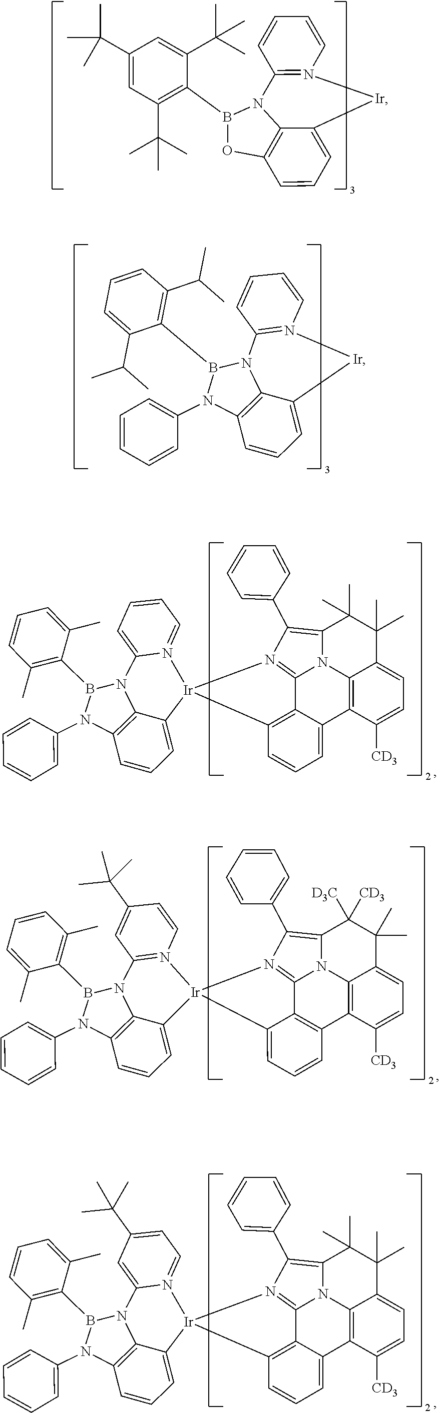

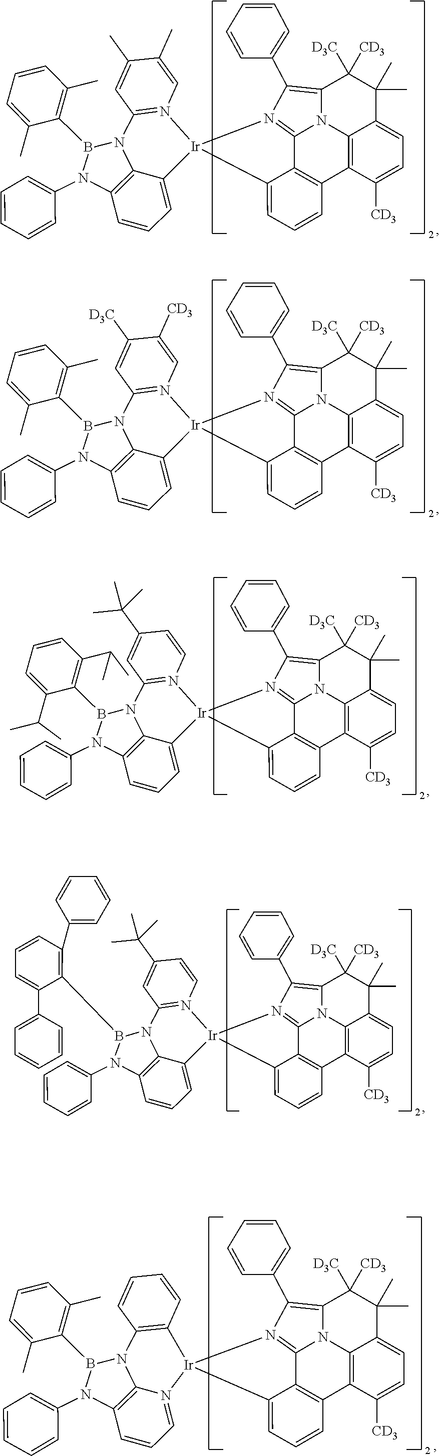

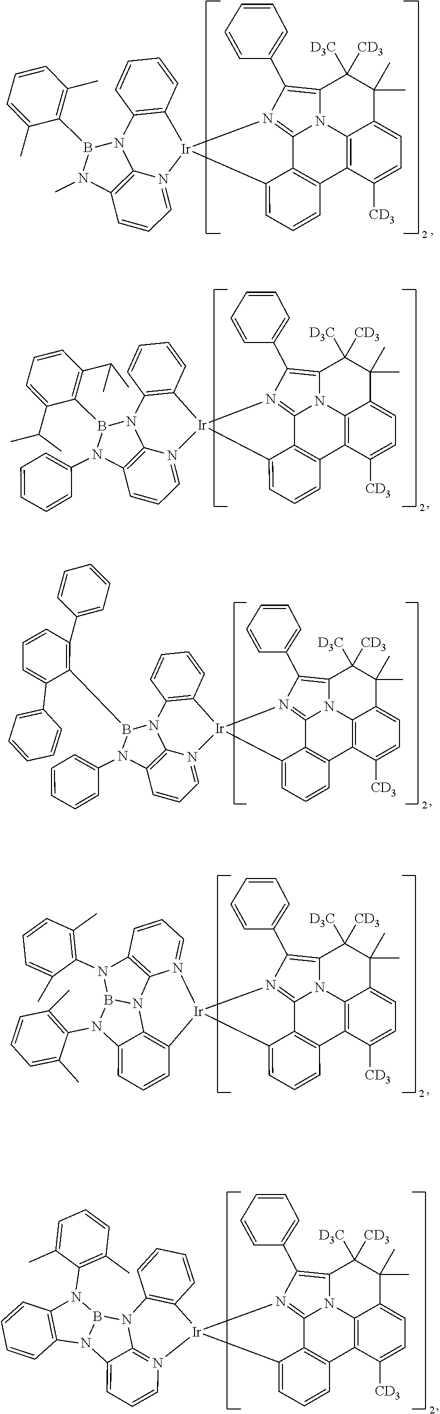

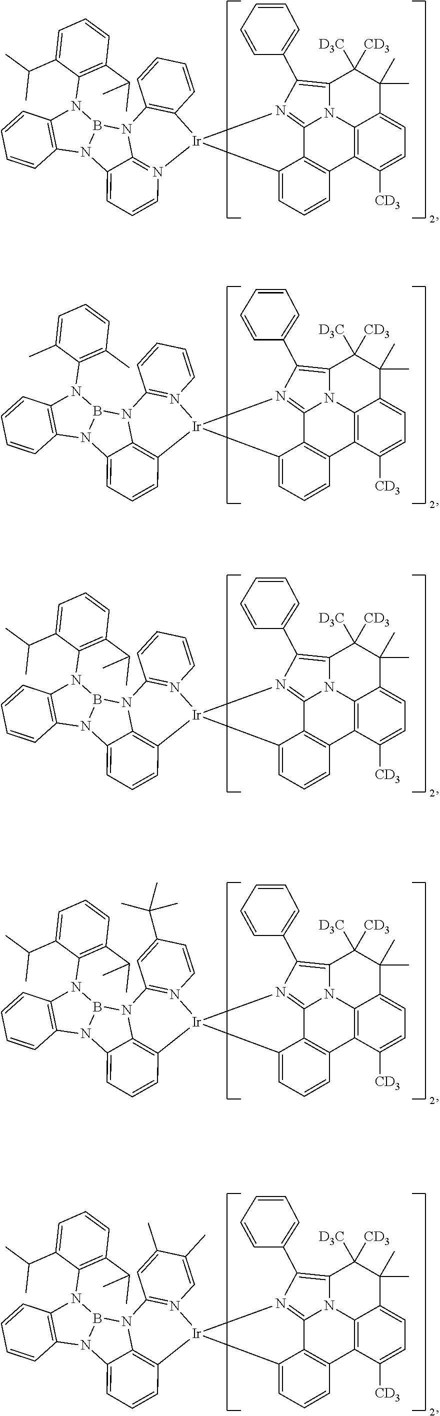

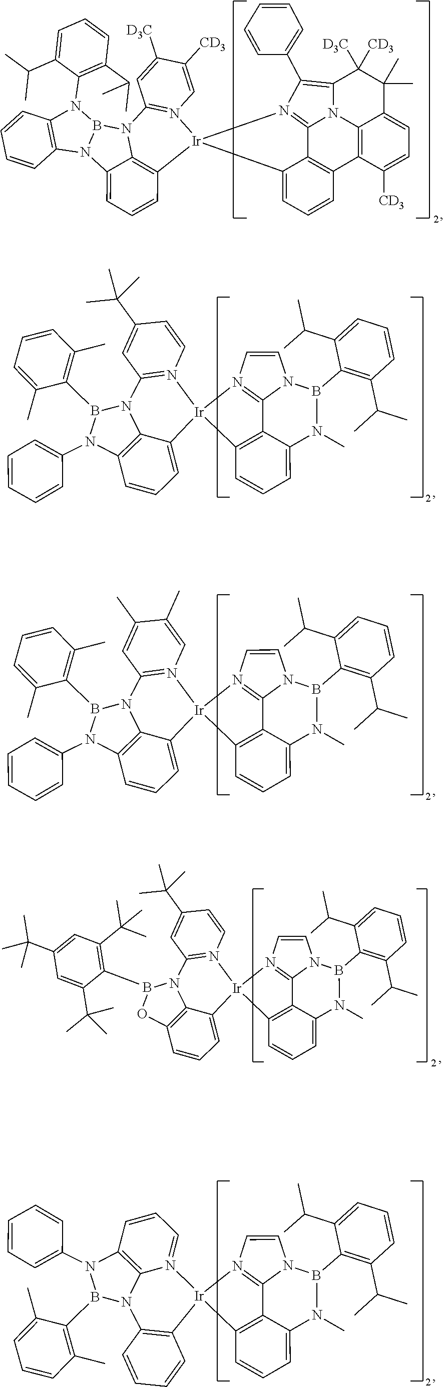

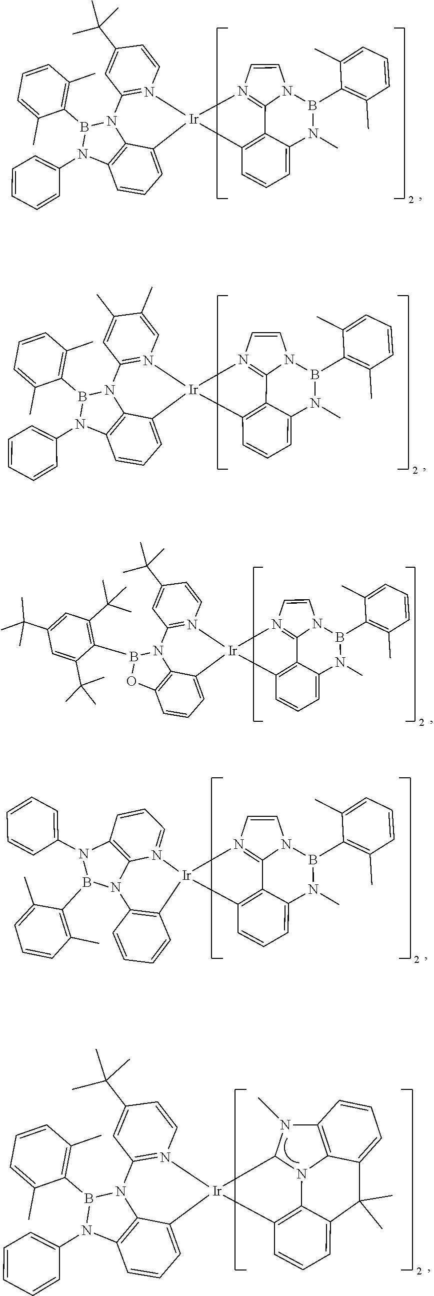

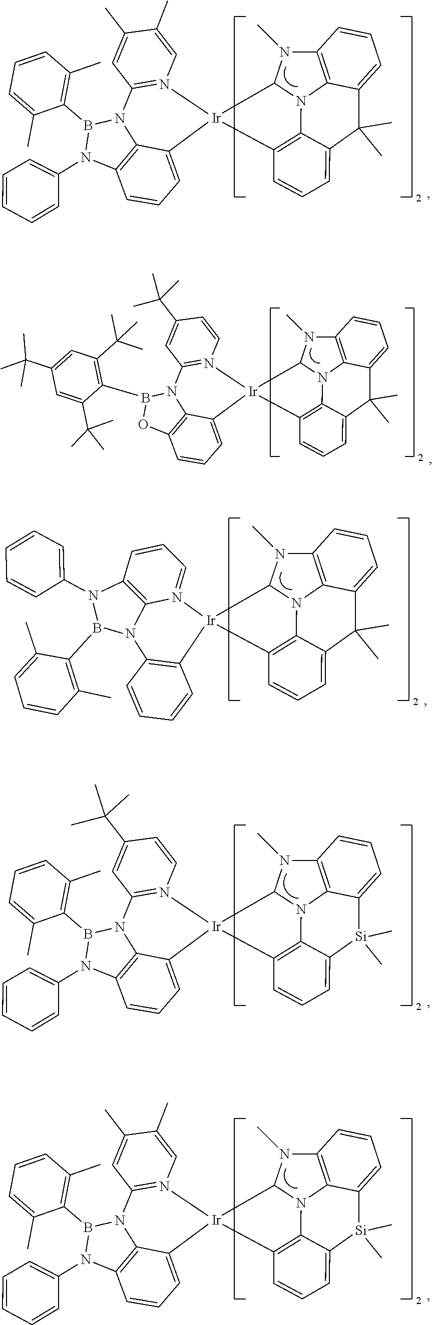

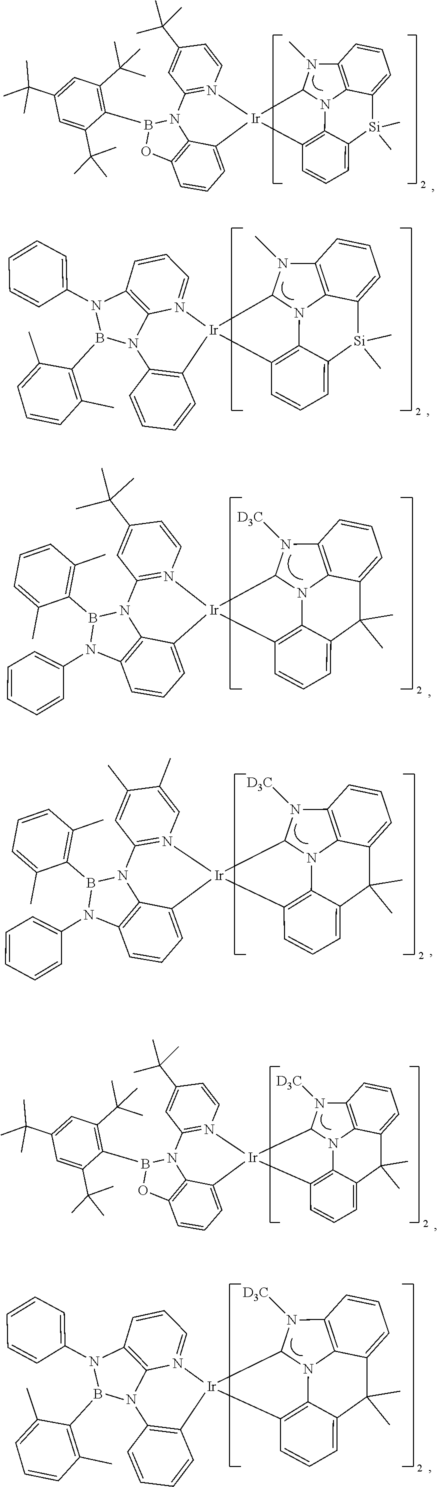

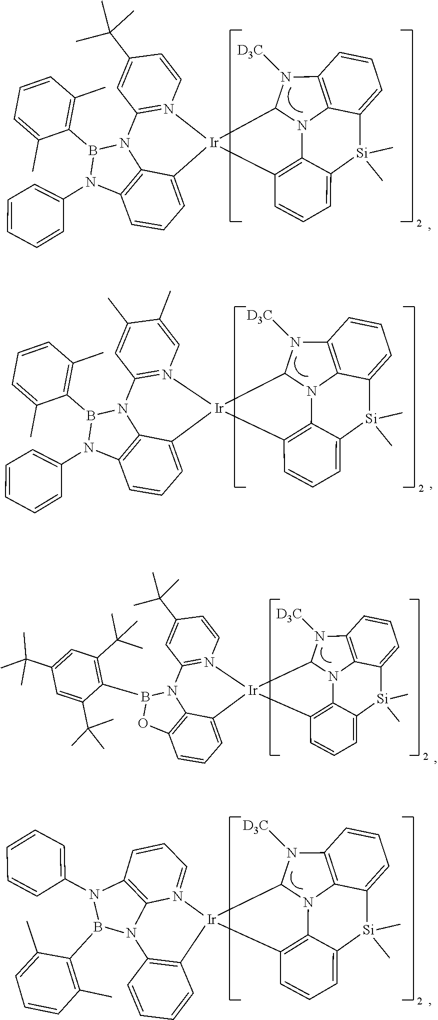

In some embodiments, the compound has Formula II

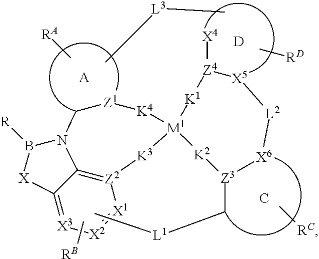

wherein: M¹ is Pd or Pt; rings C and D are each independently a 5-membered or 6-membered carbocyclic or heterocyclic ring; Z³ and Z⁴ are each independently C or N; K¹, K², K³, and K⁴ are each independently selected from the group consisting of a direct bond, O, and S, with at least two of them being direct bonds; L¹, L², and L³ are each independently selected from the group consisting of a single bond, absent a bond, O, S, CR′R″, SiR′R″, BR′, and NR′, at least one of L¹ and L² is not absent a bond; X⁴-X⁶ are each independently C or N; R^{C} and R^{D} each independently represent zero, mono, or up to the maximum number of allowed substitutions to its associated ring; each R′, R″, R^{C}, and R^{D} is independently a hydrogen or a substituent selected from the group consisting of the general substituents defined herein; two adjacent substituents can be joined or fused together to form a ring wherever chemically feasible; and X¹-X³, R, R^{A}, R^{B}, X, Z¹, Z², and ring A are all as defined above for Formula I.

In some embodiments where the compound has Formula II, ring C can be a 6-membered aromatic ring.

In some embodiments, L¹ can be O, CR′R″, or NR′.

In some embodiments, L² is a direct bond.

In some embodiments, L² is NR′.

In some embodiments, K¹, K², K³, and K⁴ are each direct bonds. In some embodiments, one of K¹, K², K³, and K⁴ can be O. In some embodiments, one of K³ and K⁴ can be O.

In some embodiments, X⁴-X⁵ are both N, and X⁶ is C.

In some embodiments, L³ is absent a bond. In some embodiments, L¹ is absent a bond.

In some embodiments, the compound is selected from the group consisting of compounds having the formula of Pt(L_{A}′)(Ly), Pt(L_{A}″)(Ly), Pt(L_{A}″′)(Ly), Pt(L_{A}″″)(Ly), Pt(L_{A}″″′)(Ly), or Pt(L_{A}″″″)(Ly) having the following structures:

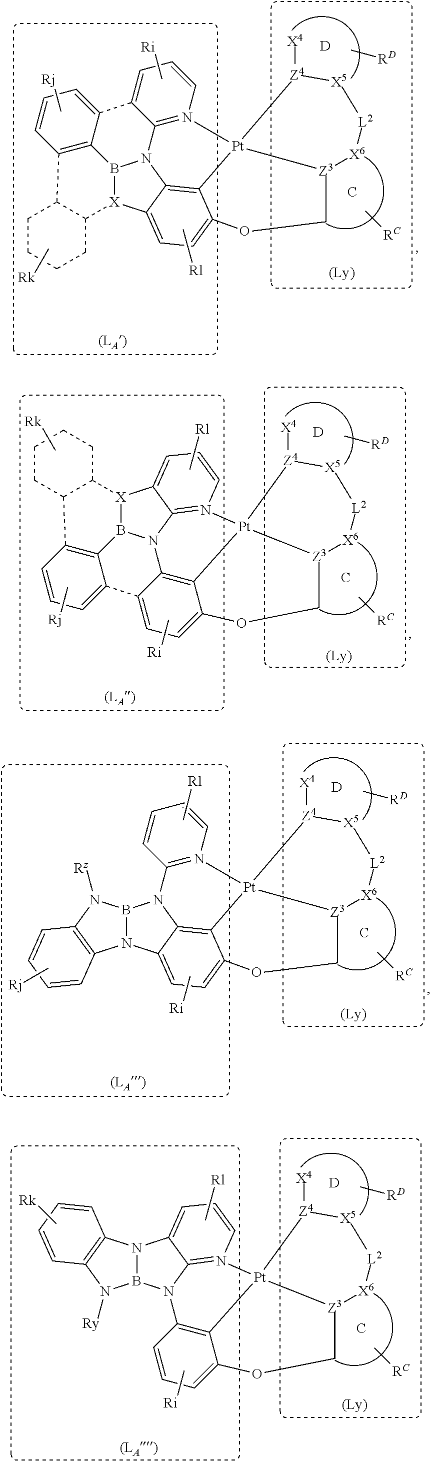

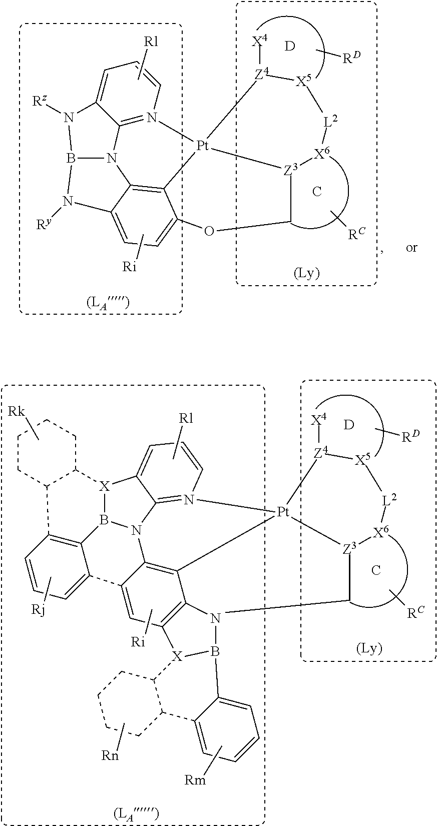

wherein L_{A}′ is selected from the group consisting of L_{A}′1-G to L_{A}′8-G whose structures are defined in LIST7A below, L_{A}″ is selected from the group consisting of L_{A}″9-G to L_{A}″ 16-G whose structures are defined in LIST7A below, L_{A}′″ is selected from the group consisting of L_{A}″16-G whose structures are defined in LIST7A below, L_{A}″″ is selected from the group consisting of L_{A}″″17-G whose structures are defined in LIST7A below, and L_{A}″″′ is selected from the group consisting of L_{A}″″″18-G whose ″″″′19-G to structures are defined in LIST7A below, and L_{A}″″″″ is selected from the group consisting of L_{A}″″″19-G to L_{A}″″″21-G whose structures are defined in LIST7A below:

LIST7A
Ligand naming convention and structure

| | | |
|---|---|---|
| L_{A}′1-G having the structure | L_{A}′8-G having the structure | L_{A}″15-G having the structure |
| 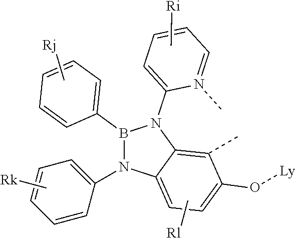 | 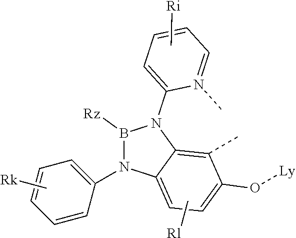 | 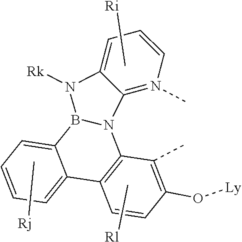 |
| L_{A}′2-G having the structure | L_{A}″9-G having the structure | L_{A}″16-G having the structure |
| 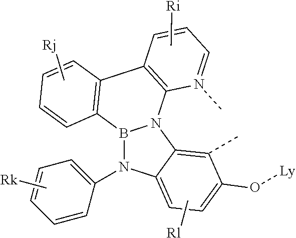 | 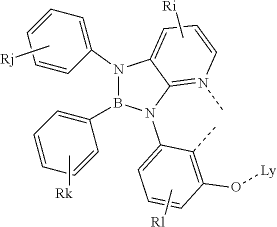 | 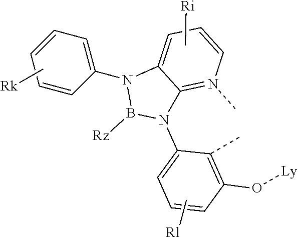 |
| L_{A}′3-G having the structure | L_{A}″10-G having the structure | L_{A}′′′16-G having the structure |
| 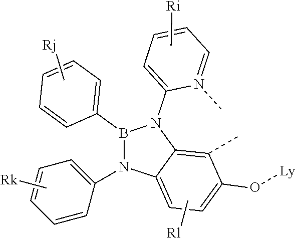 | 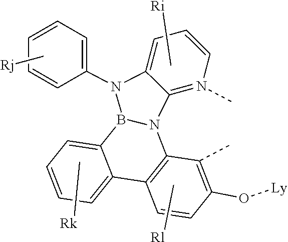 | 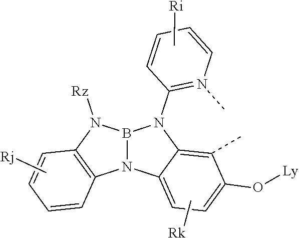 |
| L_{A}′4-G having the structure | L_{A}″11-G having the structure | L_{A}′′′′17-G having the structure |
| 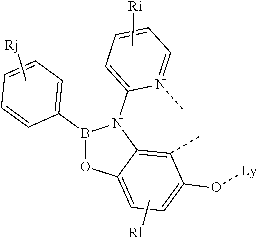 | 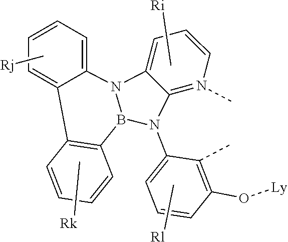 | 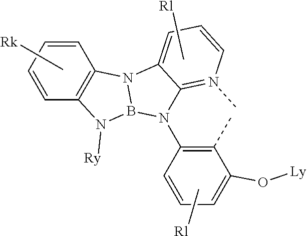 |
| L_{A}′5-G having the structure | L_{A}″12-G having the structure | L_{A}′′′′′18-G having the structure |
| 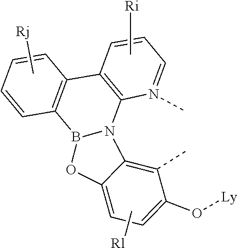 | 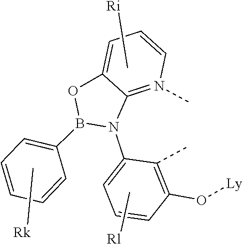 | 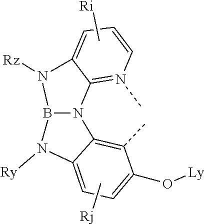 |
| L_{A}′6-G having the structure | L_{A}″13-G having the structure | L_{A}′′′′′′19-G having the structure |
| 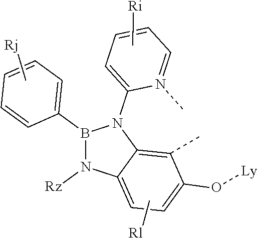 | 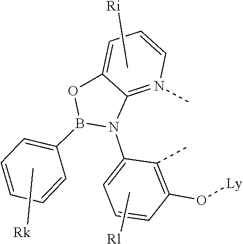 | 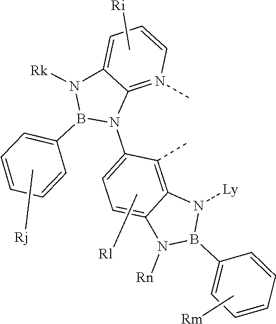 |
| L_{A}′7-G having the structure | L_{A}″14-G having the structure | L_{A}′′′′′′20-G having the structure |
| 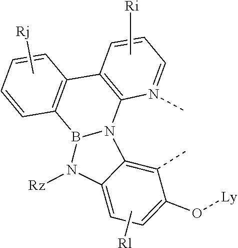 | 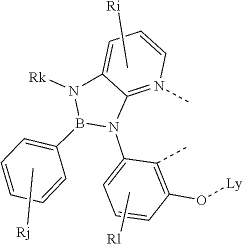 | 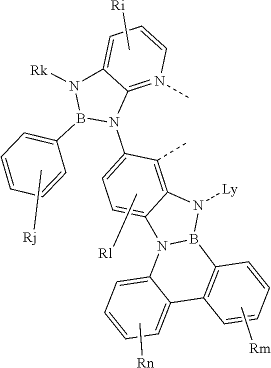 |
| | | L_{A}′′′′′′21-G having the structure |
| | | 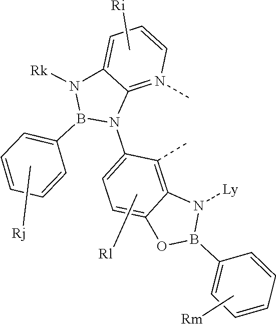 |

wherein i, j, k, l, z, and y are independently an integer from 1 to 55, Ri=Bi, Rj=Bj, Rk=Bk, Rl=Bl, and Rz=Bz, and
B1 to B55 have the structures as defined above in connection with LIST1, wherein L_{y} is selected from the group consisting of the structures shown in LIST7B below

LIST7B
L_{y}

| | | |
|---|---|---|
| L_{y}1-G having the structure | L_{y}14-G, having the structure | L_{y}27-G having the structure |
| 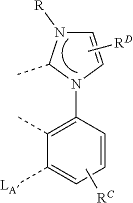 | 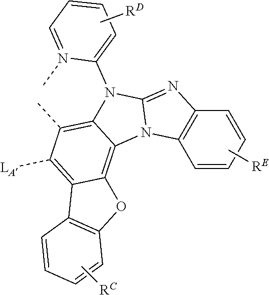 | 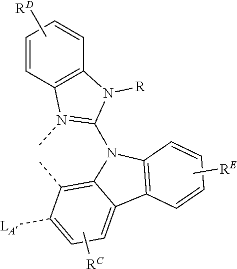 |
| L_{y}2-G having the structure | L_{y}15-G having the structure | L_{y}28-G having the structure |
| 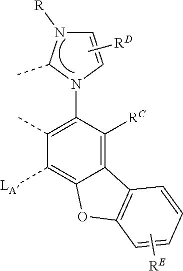 | 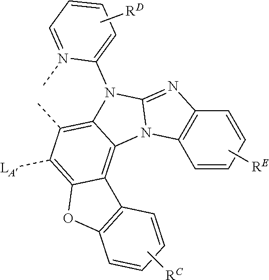 | 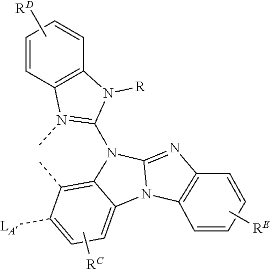 |
| L_{y}3-G having the structure | L_{y}16-G having the structure | L_{y}29-G having the structure |
| 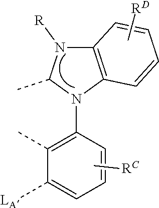 | 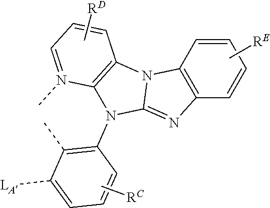 | 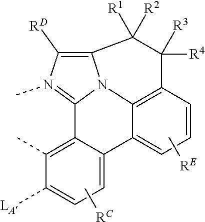 |
| L_{y}4-G having the structure | L_{y}17-G having the structure | L_{y}30-G having the structure |
| 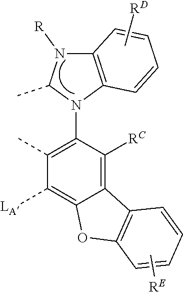 | 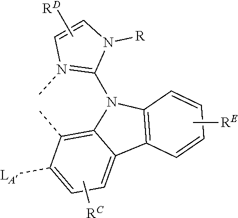 | 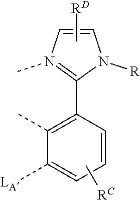 |
| L_{y}5-G having the structure | L_{y}18-G having the structure | L_{y}31-G having the structure |
| 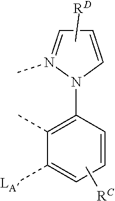 | 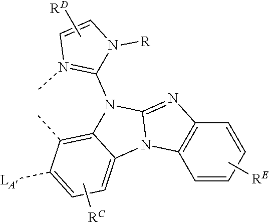 | 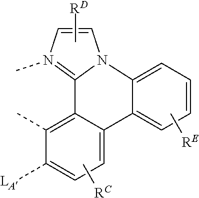 |
| L_{y}6-G having the structure | L_{y}19-G having the structure | L_{y}32-G having the structure |
| 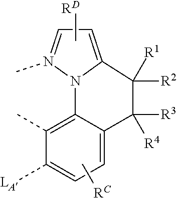 | 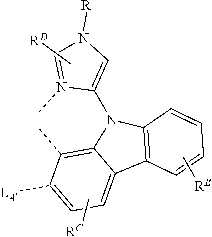 | 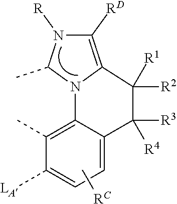 |
| L_{y}7-G having the structure | L_{y}20-G having the structure | L_{y}33-G having the structure |
| 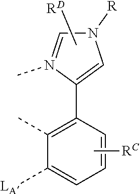 | 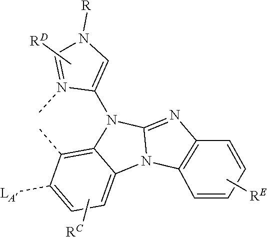 | 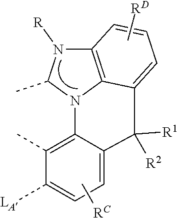 |
| L_{y}8-G having the structure | L_{y}21-G having the structure | L_{y}34-G having the structure |
| 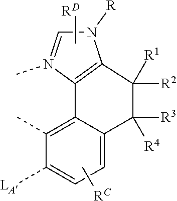 | 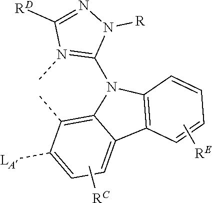 | 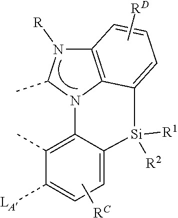 |
| L_{y}9-G having the structure | L_{y}22-G having the structure | L_{y}35-G having the structure |
| 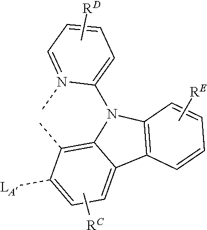 | 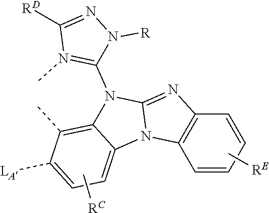 | 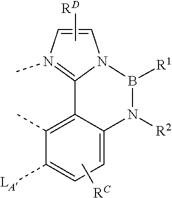 |
| L_{y}10-G having the structure | L_{y}23-G having the structure | L_{y}36-G having the structure |
| 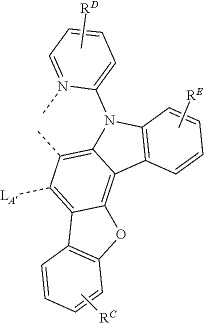 | 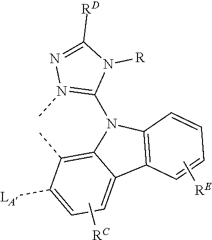 | 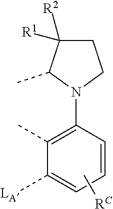 |
| L_{y}11-G having the structure | L_{y}24-G having the structure | L_{y}37-G having the structure |
| 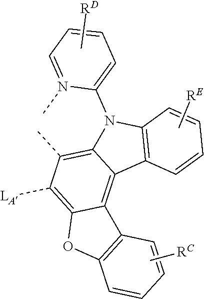 | 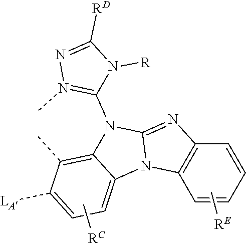 | 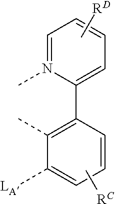 |
| L_{y}12-G having the structure | L_{y}25-G having the structure | L_{y}38-G having the structure |
| 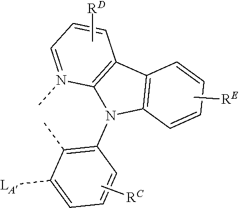 | 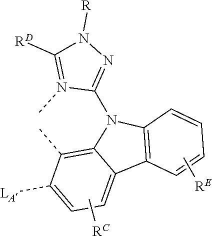 | 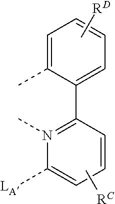 |
| L_{y}13-G having the structure | L_{y}26-G having the structure | L_{y}39-G having the structure |
| 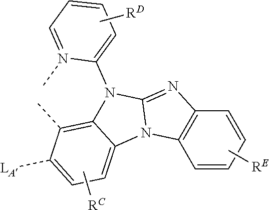 | 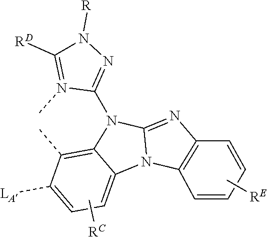 | 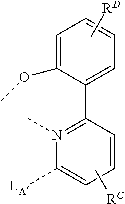 |

wherein R, R^{C}, R^{D}, and R^{E} each represents zero, mono, or up to the maximum number of allowed substitutions to its associated ring; each R¹, R², R³, R⁴, R, R′, R^{A}, and R^{B} are independently a hydrogen or a substituent selected from the group consisting of the general substituents defined herein; and two adjacent groups can be joined or fused to form a ring wherever chemically feasible.

In some embodiments of the compound selected from the group consisting of compounds having the formula of Pt(L_{A}′)(L_{y}), Pt(L_{A}″)(Ly), Pt(L_{A}′″)(Ly), Pt(L_{A}″″)(Ly), Pt(L_{A}″″′)(Ly), or Pt(L_{A}″″″)(Ly) defined above, wherein L_{A}′ is selected from the group consisting of L_{A}′1-(j)(k)(p)(z) to L_{A}′5-(j)(k) and L_{A}′18-(j)(k)(p)(z) to L_{A}′22-(j)(k) whose structures are defined in LIST8 below, L_{A}″ is selected from the group consisting of L_{A}″6-(j)(k)(p)(z) to L_{A}″10-(j) and L_{A}″23-(j)(k)(p)(z) to L_{A}″27-(j) whose structures are defined in LIST8 below, L_{A}′″ is selected from the group consisting of L_{A}′″11-(j)(k)(z) and L_{A}′″28-(j)(k)(z) whose structures are defined in LIST8 below, L_{A}″″ is selected from the group consisting of L_{A}″″12-(j)(k)(z) and L_{A}″″29-(j)(k)(z) whose structures are defined in LIST8 below, L_{A}″″′ is selected from the group consisting of L_{A}″″″ 13-(j)(k)(p)(z) and L_{A}″″′ 30-(j)(k)(p)(z) whose structures are defined in LIST8 below, and L_{A}″″″ is selected from the group consisting of L_{A}″″″ 14-(j)(k)(p)(z) to L_{A}″″″17-(i)(k)(p)(z) whose structures are defined in LIST8 below:

| Ligand naming convention | Structure |
|---|---|
| L_{A}′1-(j)(k)(p)(z), wherein each of j, k, p, and z is independently an integer from 1 to 55, wherein L_{A}′1-(1)(1)(1)(1) to L_{A}'1-(55)(55)(55)(55) having the structure | 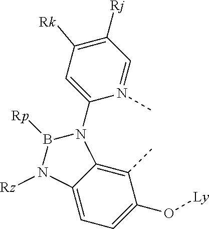 |
| L_{A}′2-(j)(k)(p), wherein each of j, k, and p is independently an integer from 1 to 55, wherein L_{A}′2-(1)(1)(1) to L_{A}′2- (55)(55)(55) having the structure | 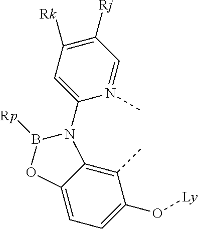 |
| L_{A}′3-(j)(z), wherein each of j, and z is independently an integer from 1 to 55, wherein L_{A}′3-(1)(1) to L_{A}′3-(55)(55) having the structure | 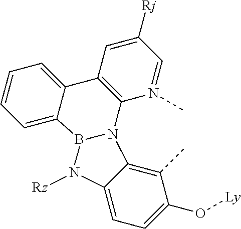 |
| L_{A}′4-(j), wherein j is an integer from 1 to 55, wherein L_{A}′4-(1) to L_{A}′4-(55) having the structure | 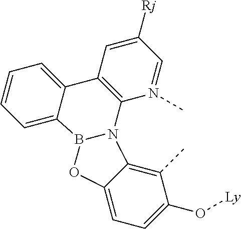 |
| L_{A}′5-(j)(k), wherein each of j, and k is independently an integer from 1 to 55, wherein L_{A}'5-(1)(1) to L_{A}'5-(55)(55) having the structure | 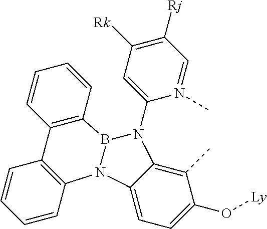 |
| L_{A}″6-(j)(k)(p)(z), wherein each of j, k, p, and z is independently an integer from 1 to 55, wherein L_{A}″6- (1)(1)(1)(1) to L_{A′}″6-(55)(55)(55)(55) having the structure | 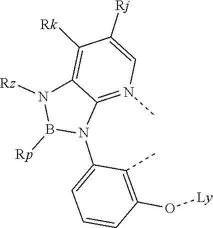 |
| L_{A}″7-(j)(k)(p), wherein each of j, k, and p is independently an integer from 1 to 55, wherein L_{A}″7-(1)(1)(1) to L_{A}″7-(55)(55)(55) having the structure | 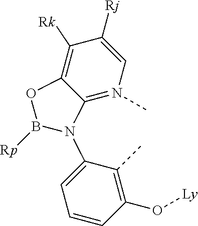 |
| L_{A}″8-(j)(k)(z), wherein each of j, k, and z is independently an integer from 1 to 55, wherein L_{A}″8-(1)(1)(1) to L_{A}″8- (55)(55)(55) having the structure | 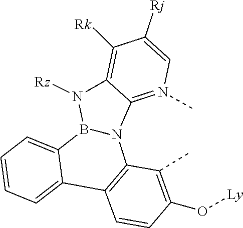 |
| L_{A}″9-(j)(k), wherein each of j, and k is independently an integer from 1 to 55, wherein L_{A}″9-(1)(1) to L_{A}″9-(55)(55) having the structure | 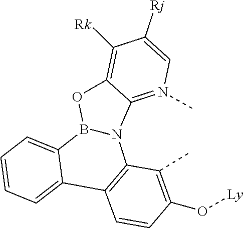 |
| L_{A}″10-(j), wherein j is an integer from 1 to 55, wherein L_{A}″10-(1) to L_{A}″10- (55) having the structure | 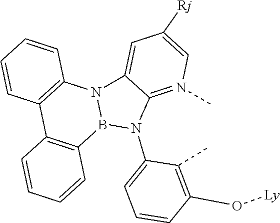 |
| L_{A}′′′11-(j)(k)(z), wherein each of j, k, and z is independently an integer from 1 to 55, wherein L_{A}′′′11-(1)(1)(1) to L_{A}′′′11-(55)(55)(55) having the structure | 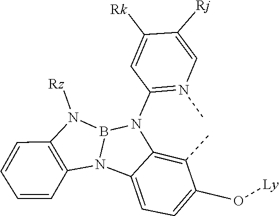 |
| L_{A}′′′′12-(j)(k)(z), wherein each of j, k, and z is independently an integer from 1 to 55, wherein L_{A}′′′′12-(1)(1)(1) to L_{A}′′′′12-(55)(55)(55) having the structure | 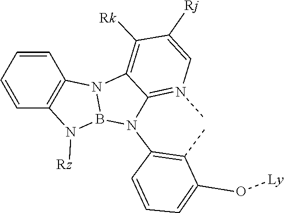 |
| L_{A}′′′′′13-(j)(k)(p)(z), wherein each of j, k, p, and z is independently an integer from 1 to 55, wherein L_{A}′′′′′13- (1)(1)(1)(1) to L_{A}′′′′′13- (55)(55)(55)(55) having the structure | 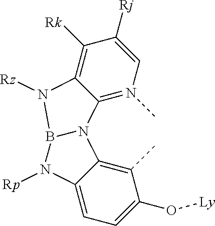 |
| L_{A}′′′′′′14-(j)(k)(p)(z), wherein each of j, k, p, and z is independently an integer from 1 to 55, wherein L_{A}′′′′′′14- (1)(1)(1)(1) to L_{A}′′′′′′14- (55)(55)(55)(55) having the structure | 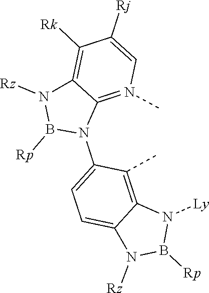 |
| L_{A}′′′′′′15-(j)(k)(p)(z), wherein each of j, k, p, and z is independently an integer from 1 to 55, wherein L_{A}′′′′′′15- (1)(1)(1)(1) to L_{A}′′′′′′15- (55)(55)(55)(55) having the structure | 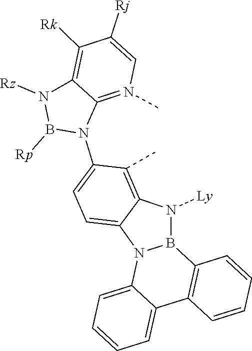 |
| L_{A}′′′′′′16-(j), wherein j is an integer from 1 to 55, wherein L_{A}′′′′′′16-(1) to L_{A}′′′′′′16-(55) having the structure | 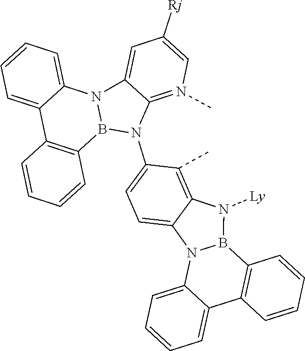 |
| L_{A}′′′′′′17-(j)(k)(p)(z), wherein each of j, k, p, and z is independently an integer from 1 to 55, wherein L_{A}′′′′′′17- (1)(1)(1)(1) to L_{A}′′′′′′17- (55)(55)(55)(55) having the structure | 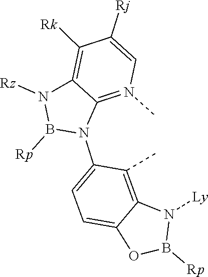 |
| L_{A}′18-(j)(k)(p)(z), wherein each of j, k, p, and z is independently an integer from 1 to 55, wherein L_{A}′18-(1)(1)(1)(1) to L_{A}'18-(55)(55)(55)(55) having the structure | 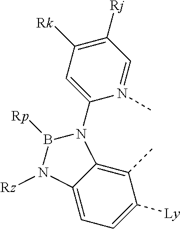 |
| L_{A}′19-(j)(k)(p), wherein each of j, k, and p is independently an integer from 1 to 55, wherein L_{A}′19-(1)(1)(1) to L_{A}′19-(55)(55)(55) having the structure | 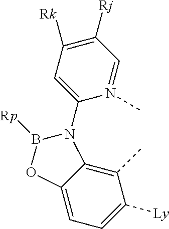 |
| L_{A}′20-(j)(z), wherein each of j, and z is independently an integer from 1 to 55, wherein L_{A}′20-(1)(1) to L_{A}′20-(55)(55) having the structure | 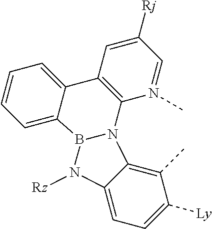 |
| L_{A}′21-(j), wherein j is an integer from 1 to 55, wherein L_{A}′21-(1) to L_{A}′21- (55) having the structure | 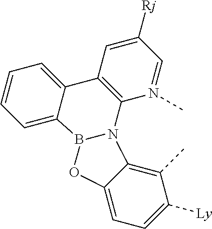 |
| L_{A}′22(j)(k), wherein each of j, and k is independently an integer from 1 to 55, wherein L_{A}′22-(1)(1) to L_{A}′22-(55)(55) having the structure | 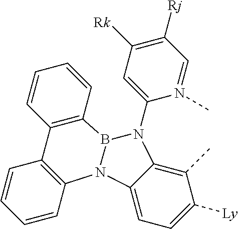 |
| L_{A}″23-(j)(k)(p)(z), wherein each of j, k, p, and z is independently an integer from 1 to 55, wherein L_{A}″23- (1)(1)(1)(1) to L_{A′}″23-(55)(55)(55)(55) having the structure | 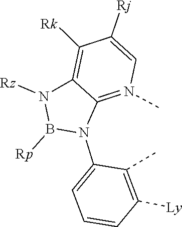 |
| L_{A}″24-(j)(k)(p), wherein each of j, k, and p is independently an integer from 1 to 55, wherein L_{A}″24-(1)(1)(1) to L_{A}″24-(55)(55)(55) having the structure | 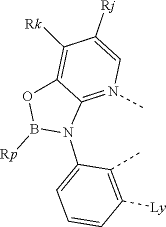 |
| L_{A}″25-(j)(k)(z), wherein each of j, k, and z is independently an integer from 1 to 55, wherein L_{A}″25-(1)(1)(1) to L_{A}″25-(55)(55)(55) having the structure | 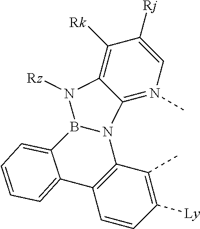 |
| L_{A}″26-(j)(k), wherein each of j, and k is independently an integer from 1 to 55, wherein L_{A}″26-(1)(1) to L_{A}″26- (55)(55) having the structure | 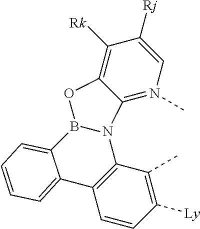 |
| L_{A}″27-(j), wherein j is an integer from 1 to 55, wherein L_{A}″27-(1) to L_{A}″27- (55) having the structure | 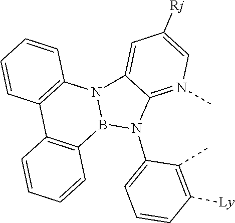 |
| L_{A}′′′28-(j)(k)(z), wherein each of j, k, and z is independently an integer from 1 to 55, wherein L_{A}′′′28-(1)(1)(1) to L_{A}′′′28-(55)(55)(55) having the structure | 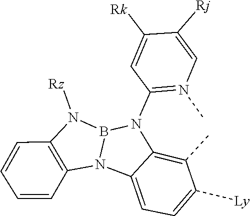 |
| L_{A}′′′′29-(j)(k)(z), wherein each of j, k, and z is independently an integer from 1 to 55, wherein L_{A}′′′′29(1)(1)(1) to L_{A}′′′′29-(55)(55)(55) having the structure | 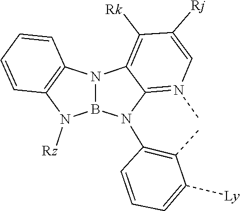 |
| L_{A}′′′′′30-(j)(k)(p)(z), wherein each of j, k, p, and z is independently an integer from 1 to 55, wherein L_{A}′′′′′30- (1)(1)(1)(1) to L_{A}′′′′′30- (55)(55)(55)(55) having the structure | 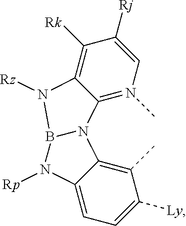 |

wherein Rj=Bj, Rk=Bk, Rp=Bp, and Rz=Bz, and
B1 to B55 have the structures as defined above in connection with LIST1, and when L_{A} is L_{A}′18, L_{A}′19, L_{A} ′20, L_{A}′21, L_{A}′22, L_{A}″23, L_{A}″24, L_{A}″25, L_{A}″26, L_{A}″27, L_{A}″′28, L_{A}″″29, or L_{A}″″′30, Ly=Ly44 to Ly50,
wherein L_{y} is selected from the group consisting of the structures shown in LIST9 below:

| L_{y} | Structure of L_{y} | R^{B1}-R^{B17} |
|---|---|---|
| L_{y}1-(i)(j)(k)(o), wherein i, j, k, and o are each independently an integer from 1 to 330, wherein L_{y}1- (1)(1)(1)(1) to L_{y}1- (330)(330)(330)(330), having the structure | 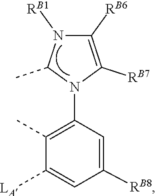 | wherein R^{B1} = Ri, R^{B6} = Rj, R^{B7} = Rk, and R^{B8} = Ro, |
| L_{y}2-(i)(j)(k), wherein i, j, and k are each independently an integer from 1 to 330, wherein L_{y}2-(1)(1)(1) to L_{y}2-(330)(330)(330), having the structure | 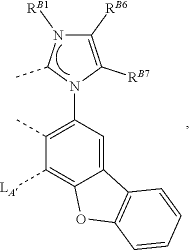 | wherein R^{B1} = Ri, R^{B6} = Rj, and R^{B7} = Rk, |
| L_{y}3-(i)(j)(k)(o), wherein i, j, k, and o are each an integer from 1 to 330, wherein L_{y}3-(1)(1)(1)(1) to L_{y}3- (330)(330)(330)(330), having the structure | 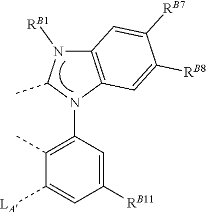 | wherein R^{B1} = Ri, R^{B7} = Rj, R^{B8} = Rk, and R^{B11} = Ro, |
| L_{y}4-(i)(j)(k), wherein i, j, and k are each an integer from 1 to 330, wherein L_{y}4-(1)(1)(1) to L_{y}4- (330)(330)(330), having the structure | 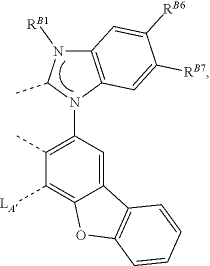 | wherein R^{B1} = Ri, R^{B6} = Rj, and R^{B7} = Rk, |
| L_{y}5-(i)(j)(k), wherein i, j, and k are each an integer from 1 to 330, wherein L_{y}5-(1)(1)(1) to L_{y}5- (330)(330)(330), having the structure | 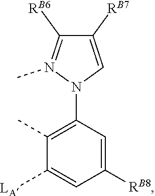 | wherein R^{B6} = Ri, R^{B7} = Rj, and R^{B8} = Rk, |
| L_{y}6-(i)(j), wherein i and j are each an integer from 1 to 330, wherein L_{y}6-(1)(1) to L_{y}6-(330)(330), having the structure | 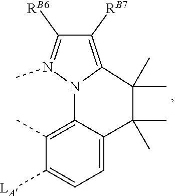 | wherein R^{B6} = Ri and R^{B7} = Rj, |
| L_{y}7-(i)(j)(k), wherein i, j, and k are each an integer from 1 to 330, wherein L_{y}7-(1)(1)(1) to L_{y}7- (330)(330)(330), having the structure | 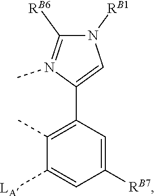 | wherein R^{B1} = Ri, R^{B6} = Rj, and R^{B7} = Rk, |
| L_{y}8-(i)(j), wherein i and j are each an integer from 1 to 330, wherein L_{y}8-(1)(1) to L_{y}8-(330)(330), having the structure | 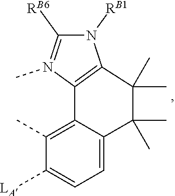 | wherein R^{B1} = Ri and R^{B6} = Rj, |
| L_{y}9-(i)(j)(k)(o), wherein i, j, k, and o are each an integer from 1 to 330, wherein L_{y}9-(1)(1)(1)(1) to L_{y}9- (330)(330)(330)(330), having the structure | 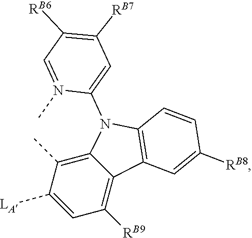 | wherein R^{B6} = Ri, R^{B7} = Rj, R^{B8} = Rk, and R^{B9} = Ro, |
| L_{y}10-(i)(j)(k), wherein i, j, and k are each an integer from 1 to 330, wherein L_{y}10-(1)(1)(1) to L_{y}10- (330)(330)(330), having the structure | 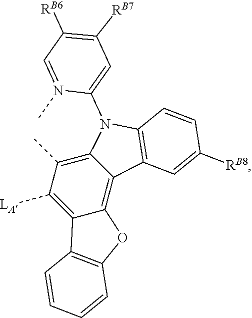 | wherein R^{B6} = Ri, R^{B7} = Rj, and R^{B8} = Rk, |
| L_{y}11-(i)(j)(k), wherein i, j, and k are each an integer from 1 to 330, wherein L_{y}11-(1)(1)(1) to L_{y}11- (330)(330)(330), having the structure | 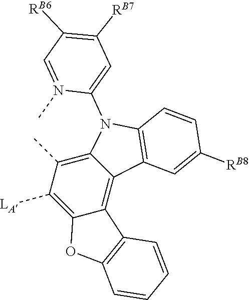 | wherein R^{B6} = Ri, R^{B7} = Rj, and R^{B8} = Rk, |
| L_{y}12-(i)(j)(k)(o), wherein i, j, k, and o are each an integer from 1 to 330, wherein L_{y}12-(1)(1)(1)(1) to L_{y}12- (330)(330)(330)(330), having the structure | 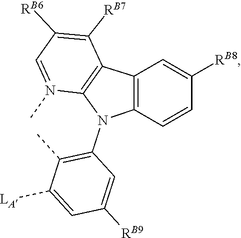 | wherein R^{B6} = Ri, R^{B7} = Rj, R^{B8} = Rk, and R^{B9} = Ro, |
| L_{y}13-(i)(j)(k), wherein i, j, and k are each an integer from 1 to 330, wherein L_{y}13-(1)(1)(1) to L_{y}13- (330)(330)(330), having the structure | 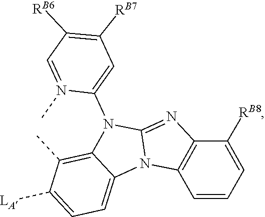 | wherein R^{B6} = Ri, R^{B7} = Rj, and R^{B8} = Rk, |
| L_{y}14-(i)(j)(k), wherein i, j, and k are each an integer from 1 to 330, wherein L_{y}14-(1)(1)(1) to L_{y}14- (330)(330)(330), having the structure | 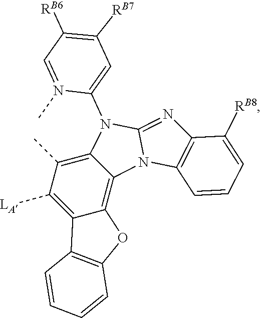 | wherein R^{B6} = Ri, R^{B7} = Rj, and R^{B8} = Rk, |
| L_{y}15-(i)(j)(k), wherein i, j, and k are each an integer from 1 to 330, wherein L_{y}15-(1)(1)(1) to L_{y}15- (330)(330)(330), having the structure | 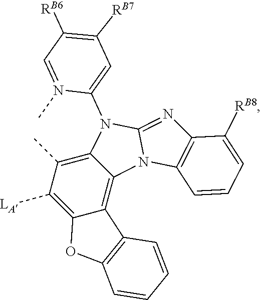 | wherein R^{B6} = Ri, R^{B7} = Rj, and R^{B8} = Rk, |
| L_{y}16-(i)(j)(k)(o), wherein i, j, k, and o are each an integer from 1 to 330, wherein L_{y}16-(1)(1)(1)(1) to L_{y}16- (330)(330)(330)(330), having the structure | 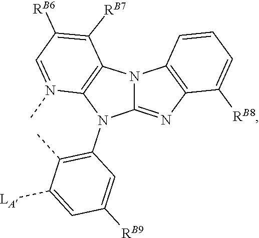 | wherein R^{B6} = Ri, R^{B7} = Rj, R^{B8} = Rk, and R^{B9} = Ro, |
| L_{y}17-(i)(j)(k), wherein i, j, and k are each an integer from 1 to 330, wherein L_{y}17-(1)(1)(1) to L_{y}17- (330)(330)(330), having the structure | 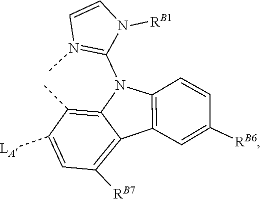 | wherein R^{B1} = Ri, R^{B6} = Rj, and R^{B7} = Rk, |
| L_{y}18-(i)(j), wherein i and j are each an integer from 1 to 330, wherein L_{y}18-(1)(1) to L_{y}18-(330)(330), having the structure | 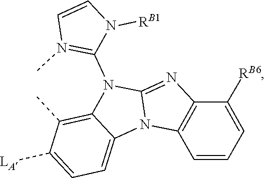 | wherein R^{B1} = Ri and R^{B6} = Rj, |
| L_{y}19-(i)(j)(k), wherein i, j, and k are each an integer from 1 to 330, wherein L_{y}19-(1)(1)(1) to L_{y}19- (330)(330)(330), having the structure | 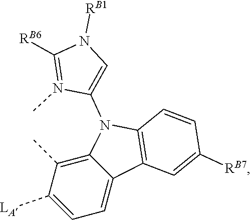 | wherein R^{B1} = Ri, R^{B6} = Rj, and R^{B7} = Rk, |
| L_{y}20-(i)(j)(k), wherein i, j, and k are each an integer from 1 to 330, wherein L_{y}20-(1)(1)(1) to L_{y}20- (330)(330)(330), having the structure | 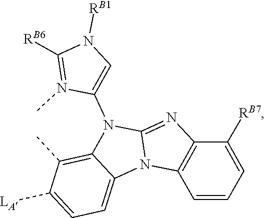 | wherein R^{B1} = Ri, R^{B6} = Rj, and R^{B7} = Rk, |
| L_{y}21-(i)(j)(k), wherein i, j, and k are each an integer from 1 to 330, wherein L_{y}21-(1)(1)(1) to L_{y}21- (330)(330)(330), having the structure | 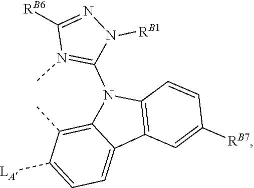 | wherein R^{B1} = Ri, R^{B6} = Rj, and R^{B7} = Rk, |
| L_{y}22-(i)(j)(k), wherein i, j, and k are each an integer from 1 to 330, wherein L_{y}22-(1)(1)(1) to L_{y}22- (330)(330)(330), having the structure | 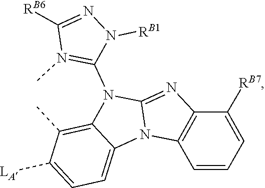 | wherein R^{B1} = Ri, R^{B6} = Rj, and R^{B7} = Rk, |
| L_{y}23-(i)(j)(k), wherein i, j, and k are each an integer from 1 to 330, wherein L_{y}23-(1)(1)(1) to L_{y}23- (330)(330)(330), having the structure | 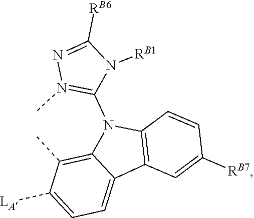 | wherein R^{B1} = Ri, R^{B6} = Rj, and R^{B7} = Rk, |
| L_{y}24-(i)(j)(k), wherein i, j, and k are each an integer from 1 to 330, wherein L_{y}24-(1)(1)(1) to L_{y}24- (330)(330)(330), having the structure | 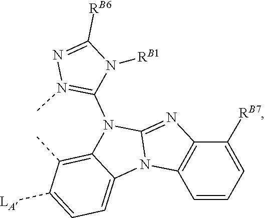 | wherein R^{B1} = Ri, R^{B6} = Rj, and R^{B7} = Rk, |
| L_{y}25-(i)(j)(k), wherein i, j, and k are each an integer from 1 to 330, wherein L_{y}25-(1)(1)(1) to L_{y}25- (330)(330)(330), having the structure | 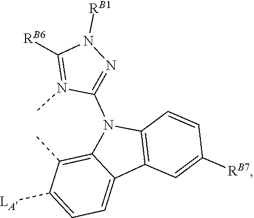 | wherein R^{B1} = Ri, R^{B6} = Rj, and R^{B7} = Rk, |
| L_{y}26-(i)(j)(k), wherein i, j, and k are each an integer from 1 to 330, wherein L_{y}26-(1)(1)(1) to L_{y}26- (330)(330)(330), having the structure | 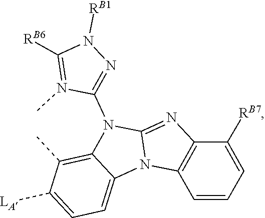 | wherein R^{B1} = Ri, R^{B6} = Rj, and R^{B7} = Rk, |
| L_{y}27-(i)(j)(k)(o), wherein i, j, k, and o are each an integer from 1 to 330, wherein L_{y}27-(1)(1)(1)(1) to L_{y}27- (330)(330)(330)(330), having the structure | 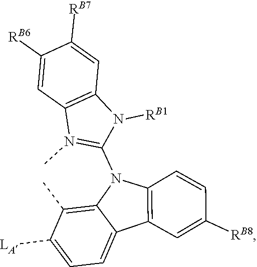 | wherein R^{B1} = Ri, R^{B6} = Rj, R^{B7} = Rk, and R^{B8} = Ro, |
| L_{y}28-(i)(j)(k)(o), wherein i, j, k, and o are each an integer from 1 to 330, wherein L_{y}28-(1)(1)(1)(1) to L_{y}28- (330)(330)(330)(330), having the structure | 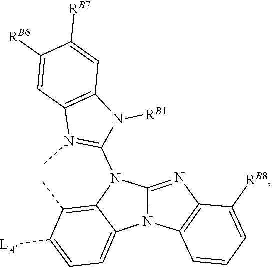 | wherein R^{B1} = Ri, R^{B6} = Rj, R^{B7} = Rk, and R^{B8} = Ro, |
| L_{y}29-(i)(j)(k), wherein i, j, and k are each an integer from 1 to 330, wherein L_{y}29-(1)(1)(1) to L_{y}29- (330)(330)(330), having the structure | 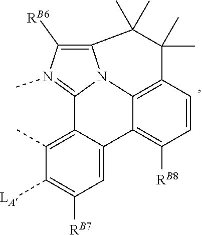 | wherein R^{B6} = Ri, R^{B7} = Rj, and R^{B8} = Rk, |
| L_{y}30-(i)(j)(k)(o), wherein i, j, k, and o are each an integer from 1 to 330, wherein L_{y}30-(1)(1)(1)(1) to L_{y}30- (330)(330)(330)(330), having the structure | 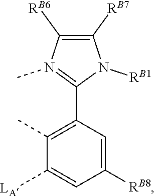 | wherein R^{B1} = Ri, R^{B6} = Rj, R^{B7} = Rk, and R^{B8} = Ro, |
| L_{y}31-(i)(j)(k), wherein i, j, and k are each an integer from 1 to 330, wherein L_{y}31-(1)(1)(1) to L_{y}31- (330)(330)(330), having the structure | 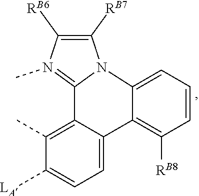 | wherein R^{B6} = Ri, R^{B7} = Rj, and R^{B8} = Rk, |
| L_{y}32-(i)(j)(k), wherein i, j, and k are each an integer from 1 to 330, wherein L_{y}32-(1)(1)(1) to L_{y}32- (330)(330)(330), having the structure | 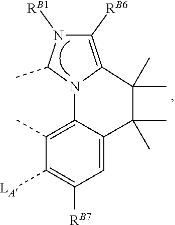 | wherein R^{B1} = Ri, R^{B6} = Rj, and R^{B7} = Rk, |
| L_{y}33-(i)(j), wherein i and j are each an integer from 1 to 330, wherein L_{y}33-(1)(1) to L_{y}33-(330)(330), having the structure | 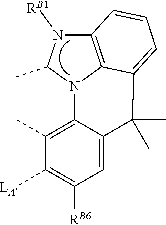 | wherein R^{B1} = Ri and R^{B6} = Rj, |
| L_{y}34-(i)(j), wherein i and j are each an integer from 1 to 330, wherein L_{y}34-(1)(1) to L_{y}34-(330)(330), having the structure | 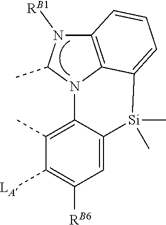 | wherein R^{B1} = Ri and R^{B6} = Rj, |
| L_{y}35-(i)(j)(k)(o), wherein i, j, k, and o are each an integer from 1 to 330, wherein L_{y}35-(1)(1)(1)(1) to L_{y}35- (330)(330)(330)(330), having the structure | 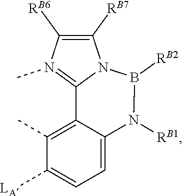 | wherein R^{B1} = Ri, R^{B2} = Rj, R^{B6} = Rk, and R^{B7} = Ro, |
| L_{y}36-(i)(j), wherein i and j are each an integer from 1 to 330, wherein L_{y}36-(1)(1) to L_{y}36-(330)(330), having the structure | 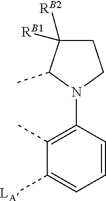 | wherein R^{B1} = Ri and R^{B2} = Rj, |
| L_{y}37-(i)(j)(k), whereinach of i, j, and k is independently an integer from 1 to 330, wherein L_{y}37- (1)(1)(1) to L_{y}37-(330)(330)(330) having the structure | 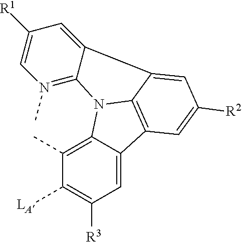 | wherein R¹ = Ri, R² = Rj, and R³ = Rk, and |
| L_{y}38-(i)(j) wherein each of i and j is independently an integer from 1 to 330, wherein L_{y}38-(1)(1) to L_{y}38- (330)(330) having the structure | 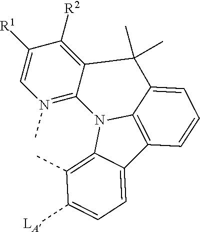 | wherein R¹ = Ri and R² = Rj, and |
| L_{y}39-(i)(j) wherein each of i and j is independently an integer from 1 to 330, wherein L_{y}39-(1)(1) to L_{y}39- (330)(330) having the structure | 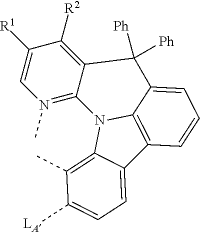 | wherein R¹ = Ri and R² = Rj, and |
| L_{y}40-(i)(j) wherein each of i and j is independently an integer from 1 to 330, wherein L_{y}40-(1)(1) to L_{y}40- (330)(330) having the structure | 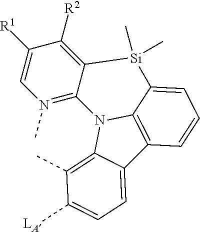 | wherein R¹ = Ri and R² = Rj, and |
| L_{y}41-(i)(j) wherein each of i and j is independently an integer from 1 to 330, wherein L_{y}41-(1)(1) to L_{y}41- (330)(330) having the structure | 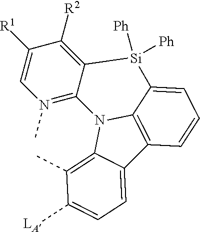 | wherein R¹ = Ri and R² = Rj, and |
| L_{y}42-(i)(j)(k)(l) wherein each of i, j, k, and l is independently an integer from 1 to 330, L_{y}42-(1)(1)(1)(1) to L_{y}42-(330)(330)(330)(330) having the structure | 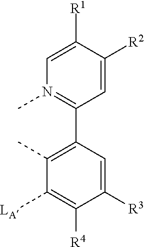 | wherein R¹ = Ri, R² = Rj, R³ = Rk, and R⁴ = Rl, and |
| L_{y}43-(i)(j)(k)(l) wherein each of i, j, k, and l is independently an integer from 1 to 330, wherein L_{y}43- (1)(1)(1)(1) to L_{y}43- (330)(330)(330)(330) having the structure | 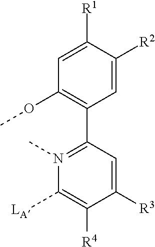 | wherein R¹ = Ri, R² = Rj, R³ = Rk, and R⁴ = Rl. |
| L_{y}44-(i)(j)(k)(l)(m), wherein i, j, k, l, and m are each independently an integer from 1 to 330, wherein L_{y}44- (1)(1)(1)(1)(1) to L_{y}44- (330)(330)(330)(330)(330), having the structure | 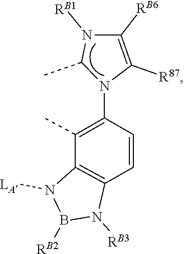 | wherein R^{B1} = Ri, R^{B2} = Rj, R^{B3} = Rk, R^{B6} = Rl, and R^{B7} = Rm, |
| L_{y}45-(i)(j)(k)(l)(m), wherein i, j, k, l, and m are each independently an integer from 1 to 330, wherein L_{y}45- (1)(1)(1)(1)(1) to L_{y}45- (330)(330)(330)(330)(330), having the structure | 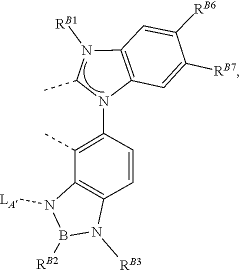 | wherein R^{B1} = Ri, R^{B2} = Rj, R^{B3} = Rk, R^{B6} = Rl, and R^{B7} = Rm, |
| L_{y}46-(i)(j)(k)(l)(m), wherein i, j, k, l, and m are each independently an integer from 1 to 330, wherein L_{y}46- (1)(1)(1)(1)(1) to L_{y}46- (330)(330)(330)(330)(330), having the structure | 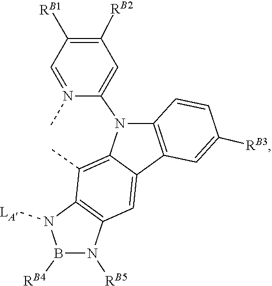 | wherein R^{B1} = Ri, R^{B2} = Rj, R^{B3} = Rk, R^{B4} = Rl, and R^{B5} = Rm, |
| L_{y}47-(i)(j)(k)(l)(m), wherein i, j, k, l, and m are each independently an integer from 1 to 330, wherein L_{y}47- (1)(1)(1)(1)(1) to L_{y}47- (330)(330)(330)(330)(330), having the structure | 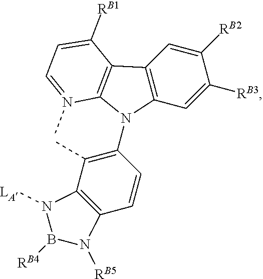 | wherein R^{B1} = Ri, R^{B2} = Rj, R^{B3} = Rk, R^{B4} = Rl, and R^{B5} = Rm, |
| L_{y}48-(i)(j)(k)(l) wherein i, j, k, and l are each independently an integer from 1 to 330, wherein L_{y}48- (1)(1)(1)(1) to L_{y}48- (330)(330)(330)(330), having the structure | 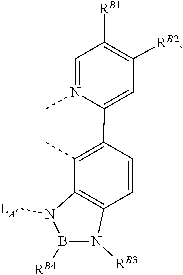 | wherein R^{B1} = Ri, R^{B2} = Rj, R^{B3} = Rk, and R^{B4} = Rl, |
| L_{y}49-(i)(j)(k)(l) wherein i, j, k, and l are each independently an integer from 1 to 330, wherein L_{y}49- (1)(1)(1)(1) to L_{y}49- (330)(330)(330)(330), having the structure | 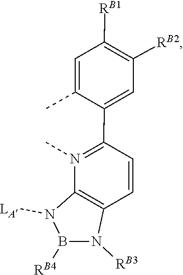 | wherein R^{B1} = Ri, R^{B2} = Rj, R^{B3} = Rk, and R^{B4} = Rl, |
| L_{y}50-(i)(j)(k)(l) wherein i, j, k, and l are each independently an integer from 1 to 330, wherein L_{y}50- (1)(1)(1)(1) to L_{y}50- (330)(330)(330)(330), having the structure | 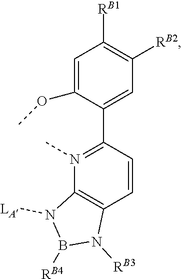 | wherein R^{B1} = Ri, R^{B2} = Rj, R^{B3} = Rk, and R^{B4} = Rl, |

wherein R1 to R330 have the following structures:

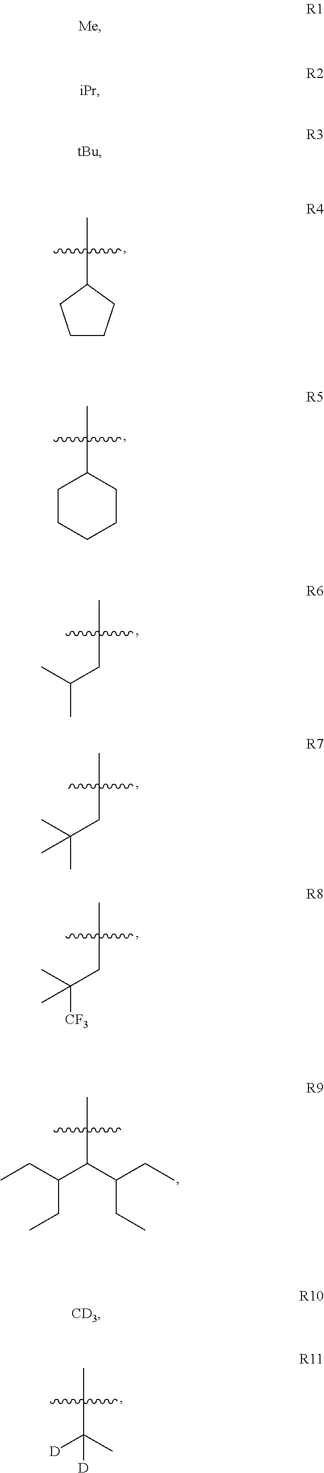

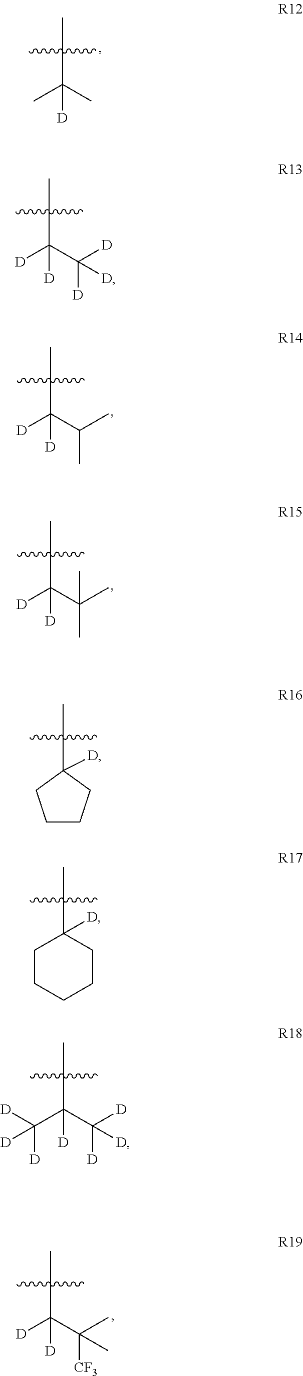

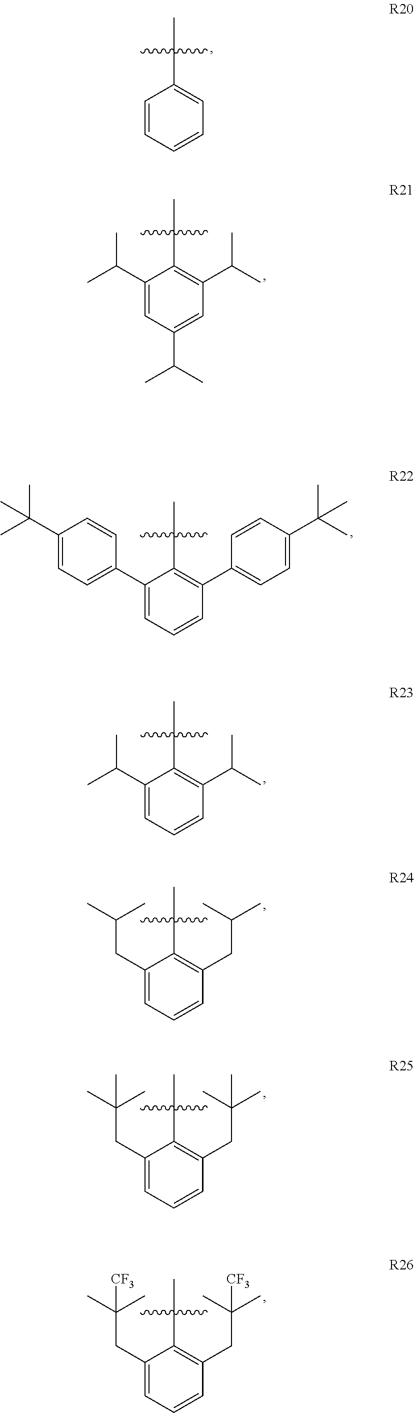

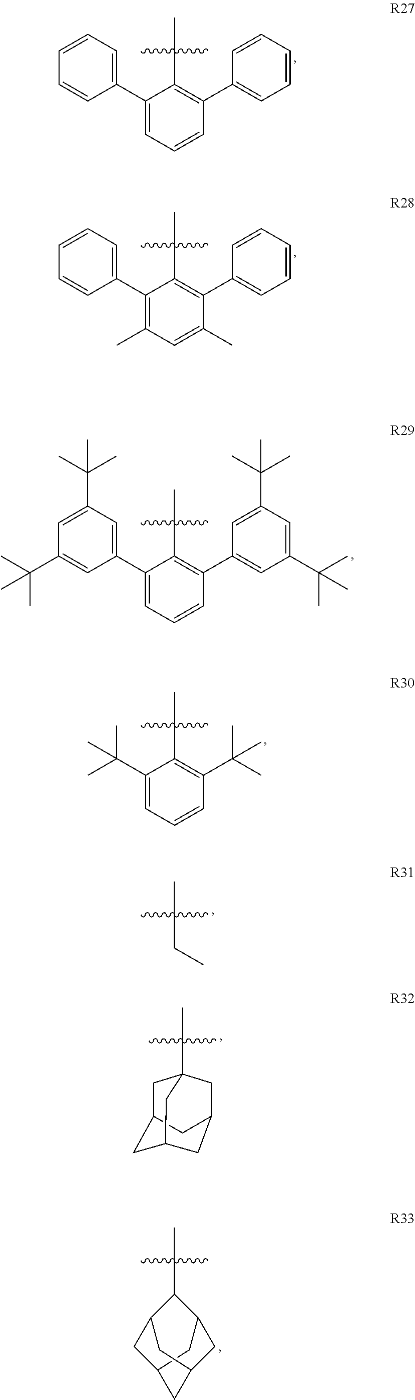

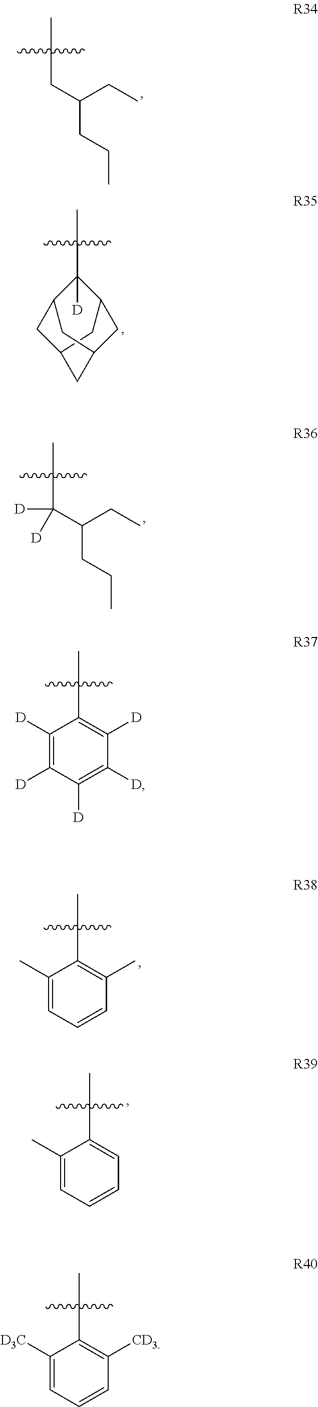

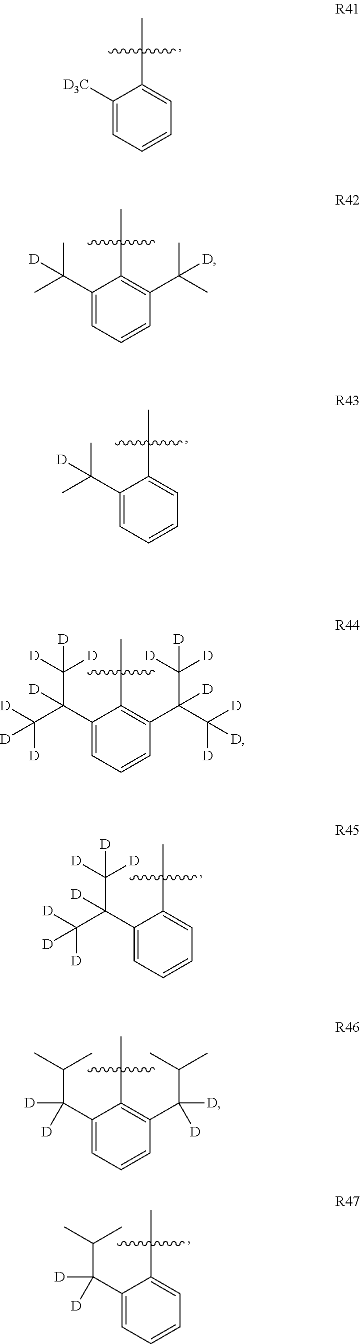

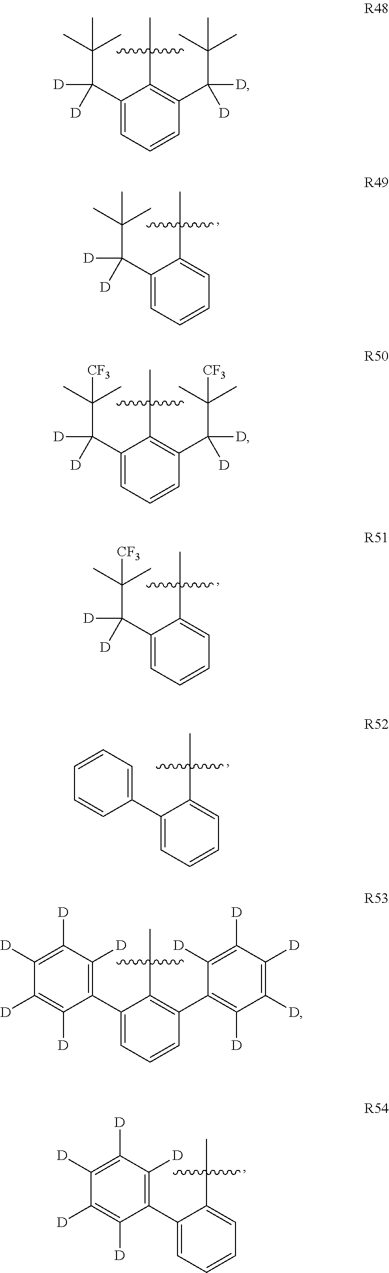

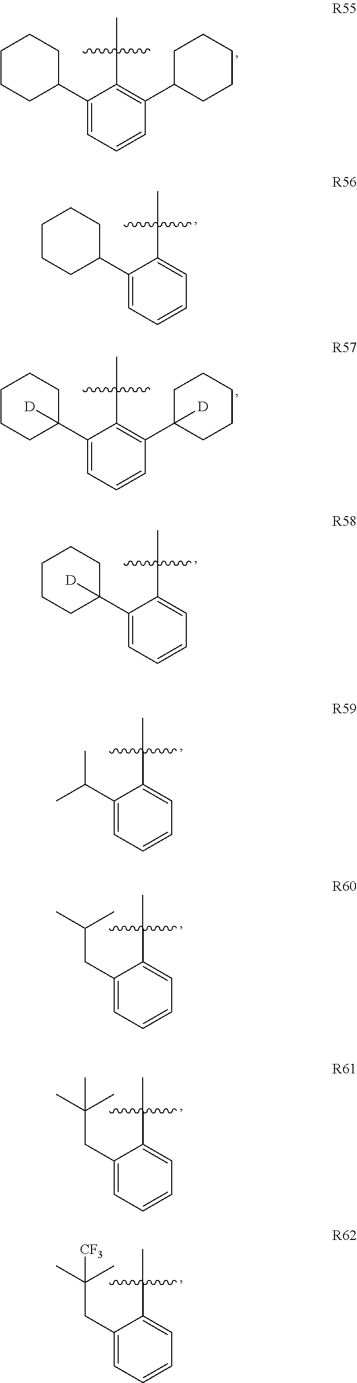

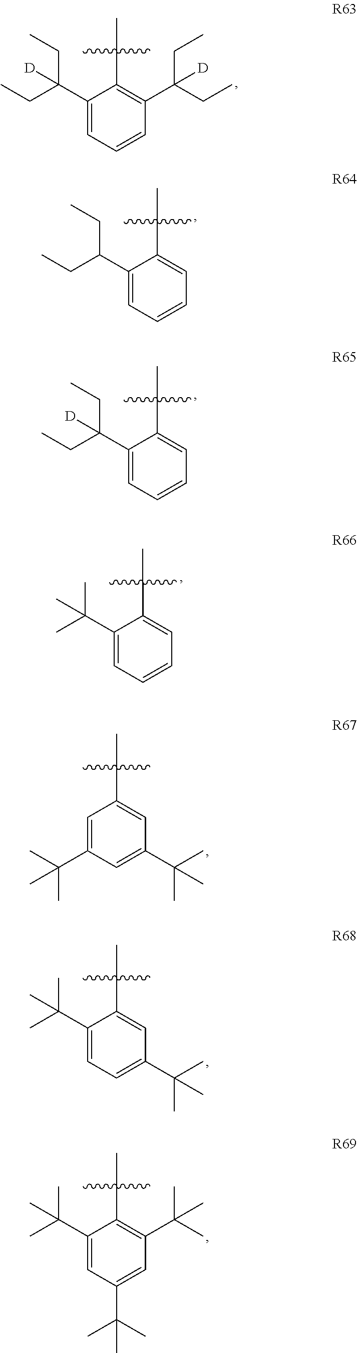

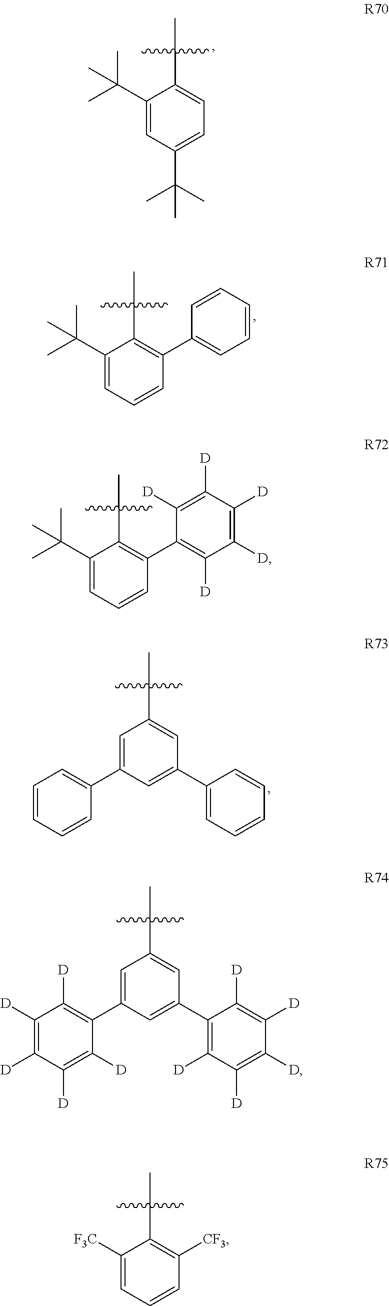

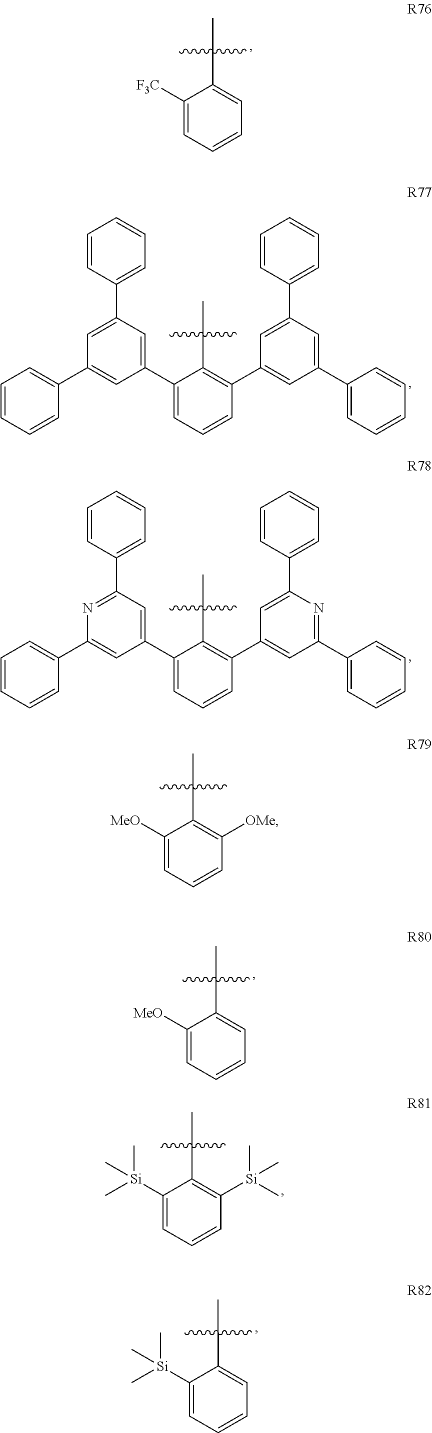

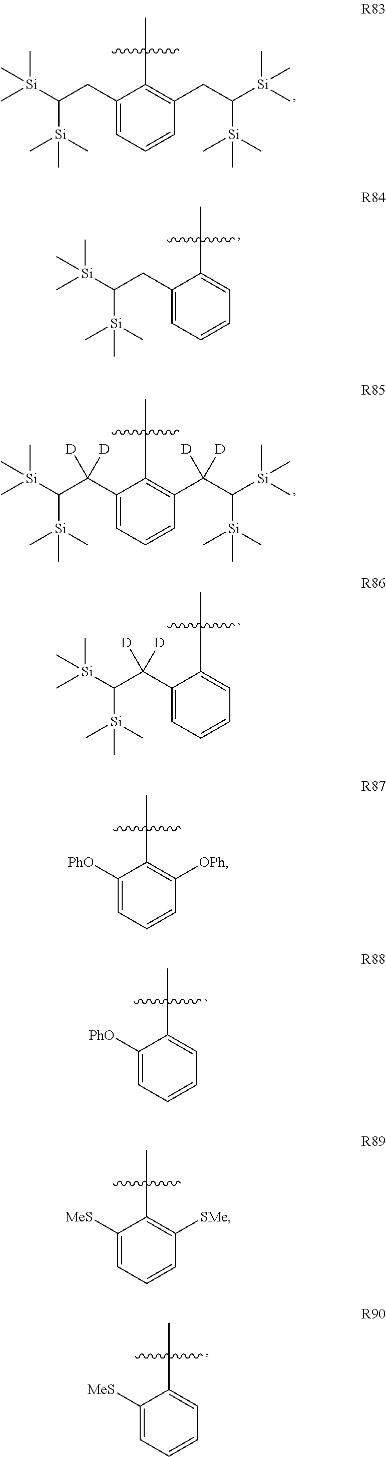

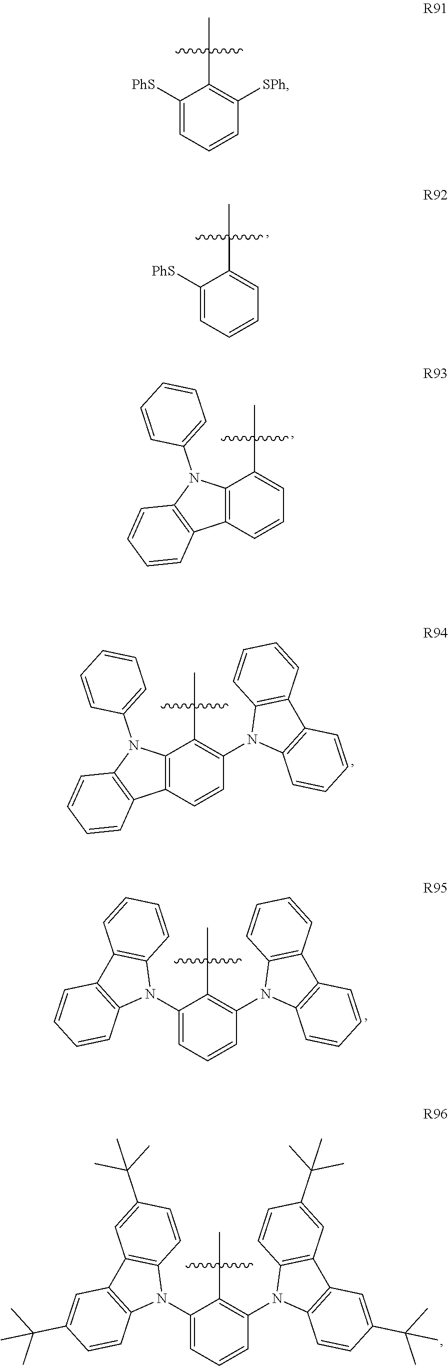

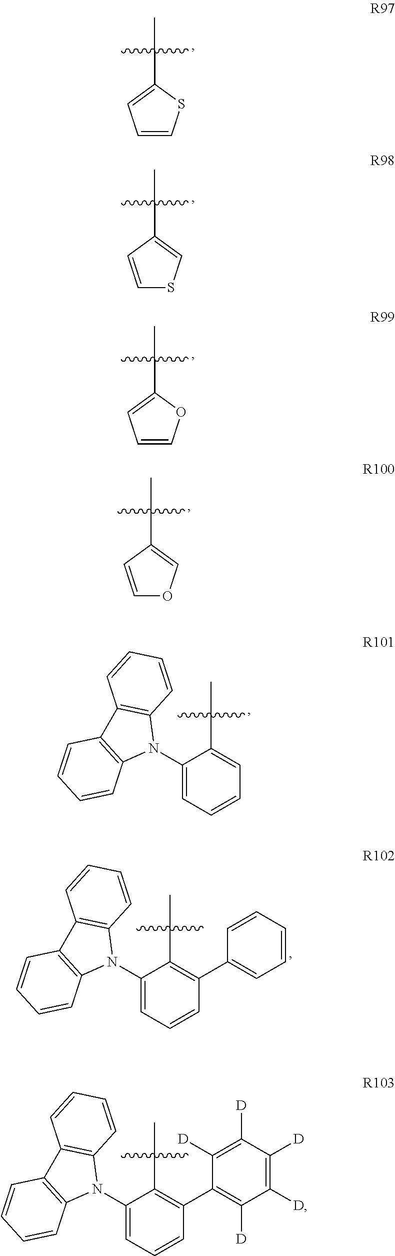

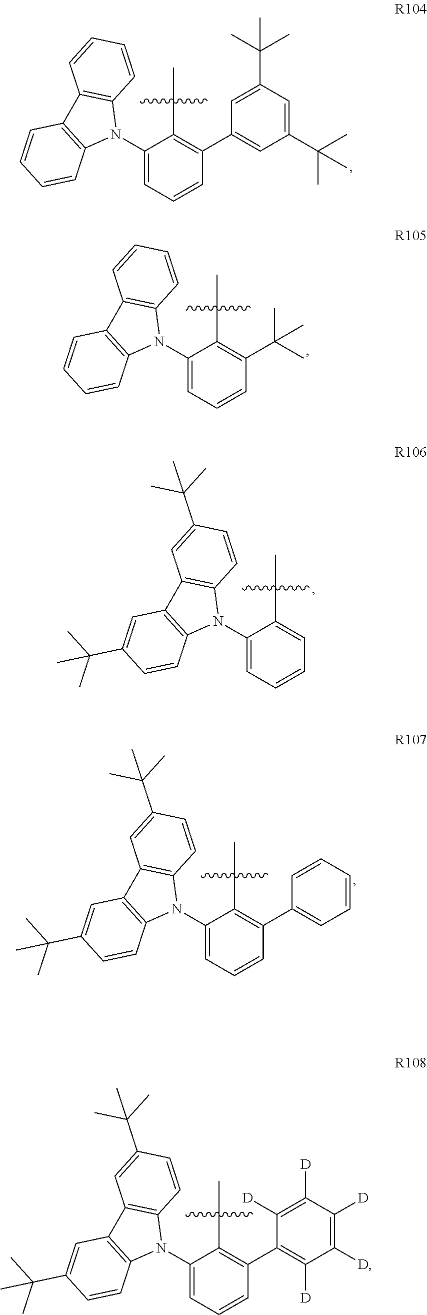

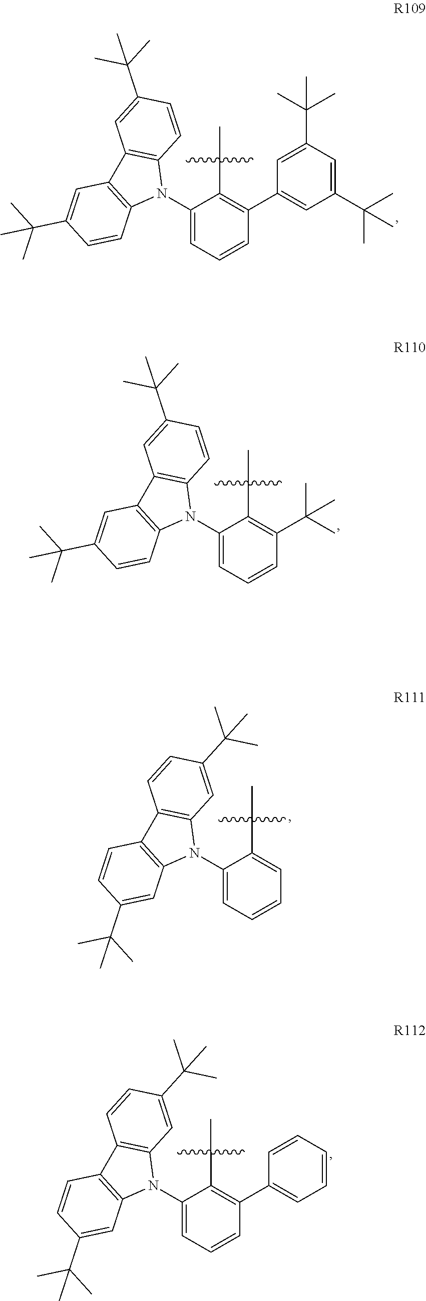

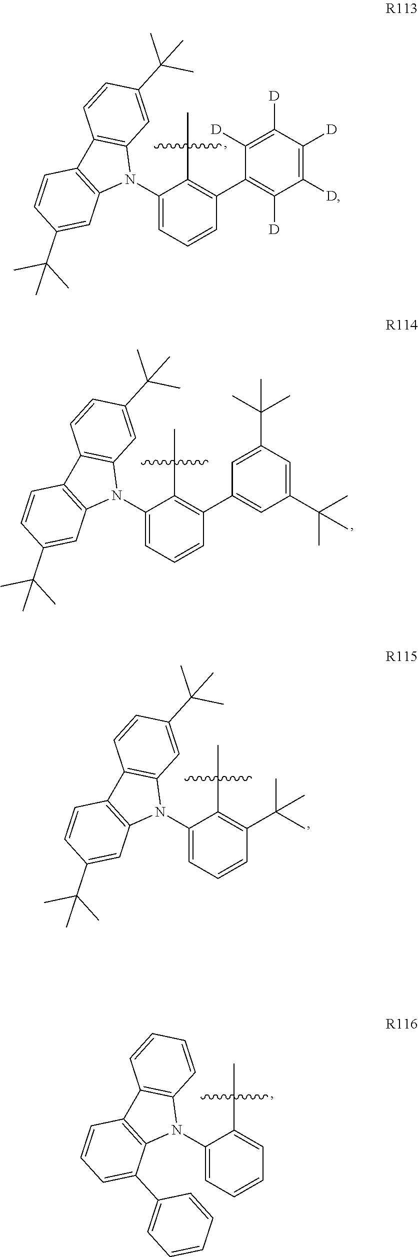

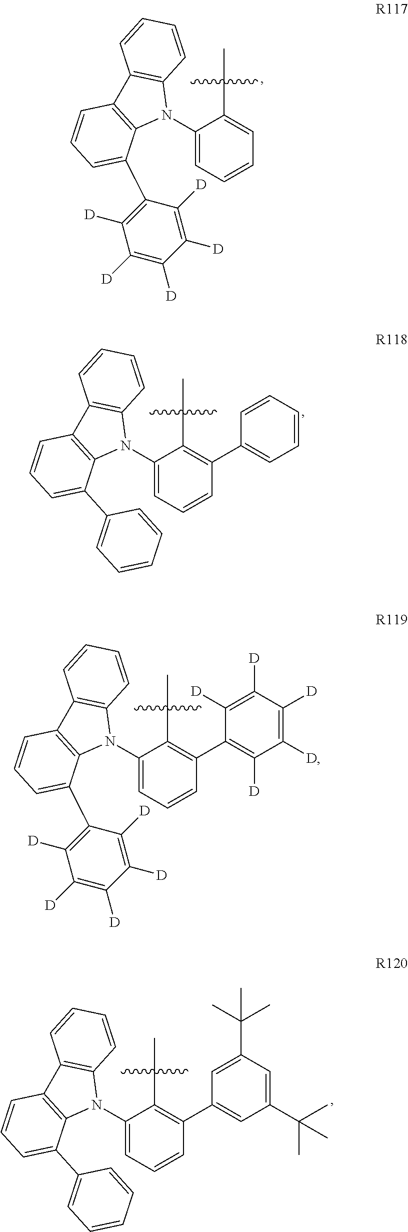

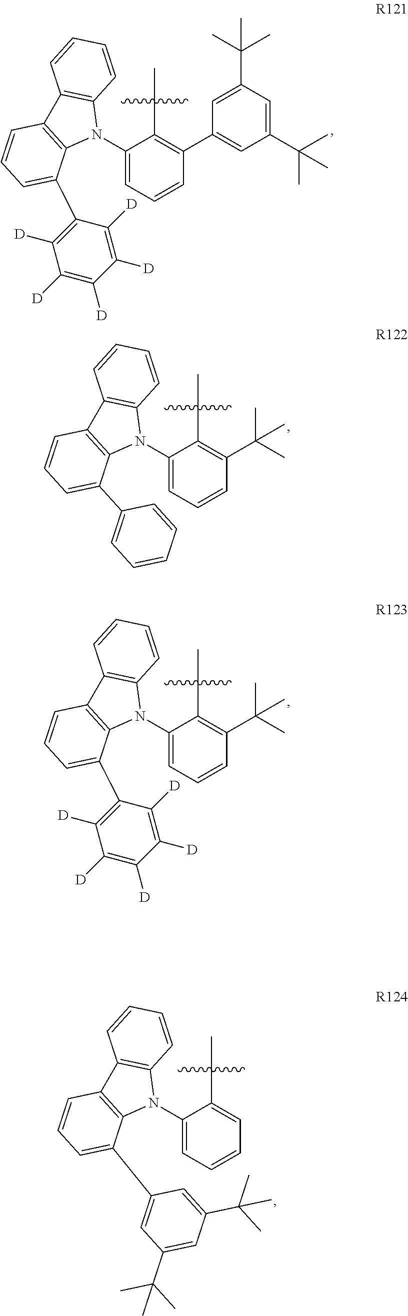

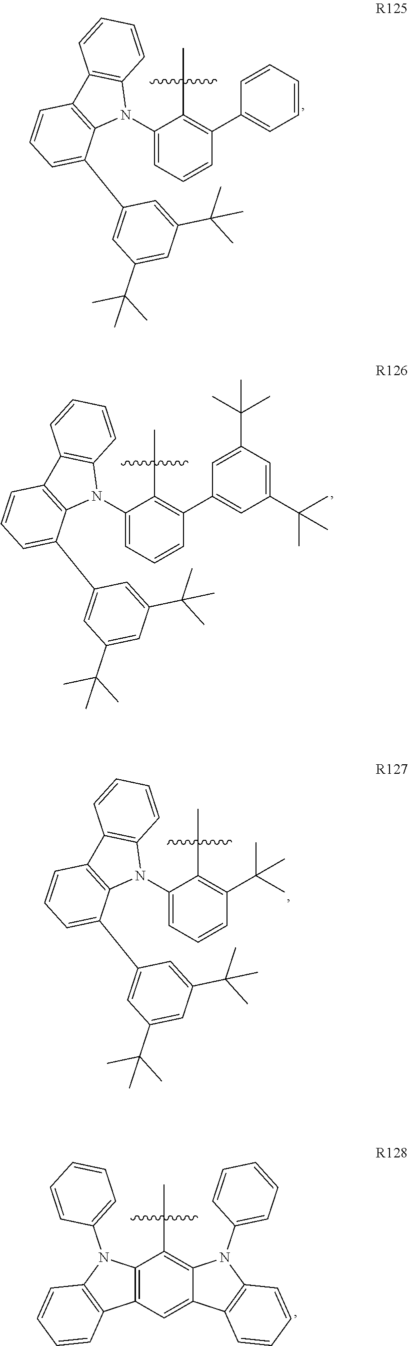 [SMILES: *c1c(-c2ccccc2)cccc1-n1c2ccccc2c2cccc(-c3cc(C(C)(C)C)cc(C(C)(C)C)c3)c21 ; *c1c(-c2cc(C(C)(C)C)cc(C(C)(C)C)c2)cccc1-n1c2ccccc2c2cccc(-c3cc(C(C)(C)C)cc(C(C)(C)C)c3)c21 ; *c1c(-n2c3ccccc3c3cccc(-c4cc(C(C)(C)C)cc(C(C)(C)C)c4)c32)cccc1C(C)(C)C ; *c1c2c(cc3c4ccccc4n(-c4ccccc4)c13)c1ccccc1n2-c1ccccc1]

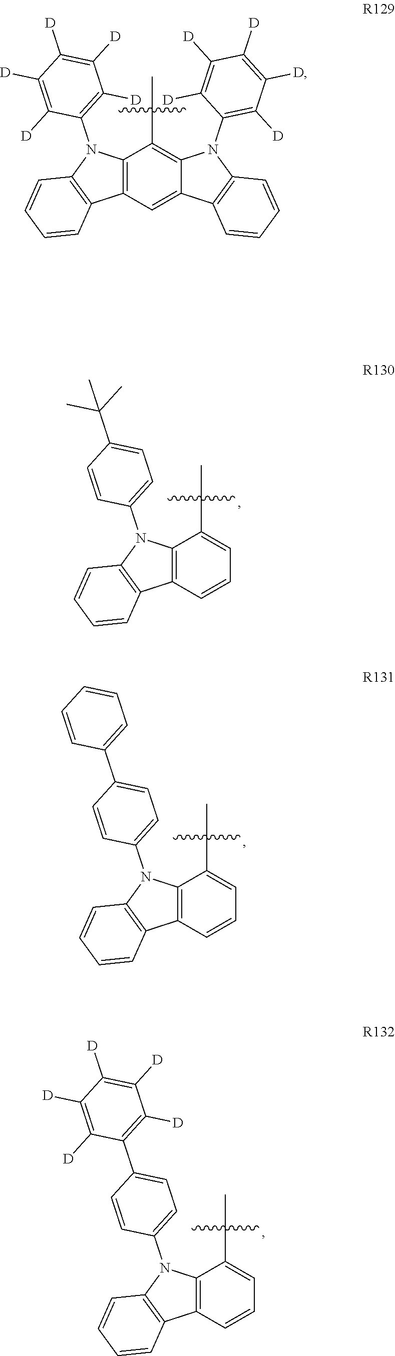

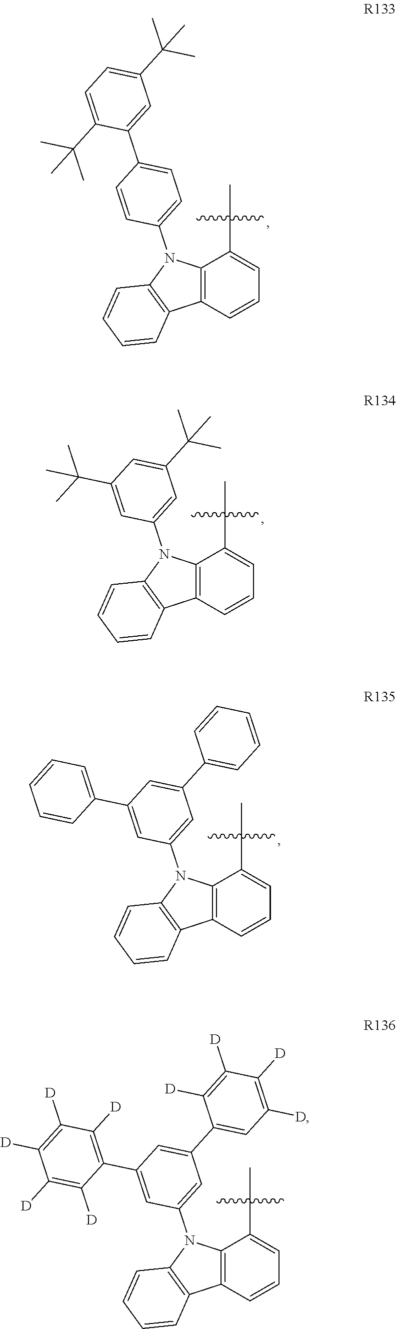

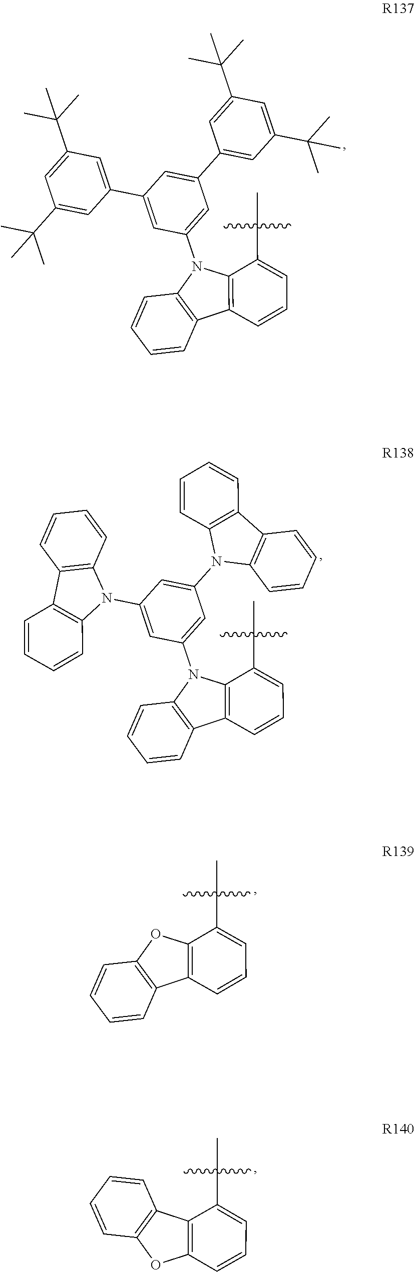 [SMILES: *c1cccc2c3ccccc3n(-c3cc(-c4cc(C(C)(C)C)cc(C(C)(C)C)c4)cc(-c4cc(C(C)(C)C)cc(C(C)(C)C)c4)c3)c12 ; *c1cccc2c3ccccc3n(-c3cc(-n4c5ccccc5c5ccccc54)cc(-n4c5ccccc5c5ccccc54)c3)c12 ; *c1cccc2c1oc1ccccc12 ; *c1cccc2oc3ccccc3c12]

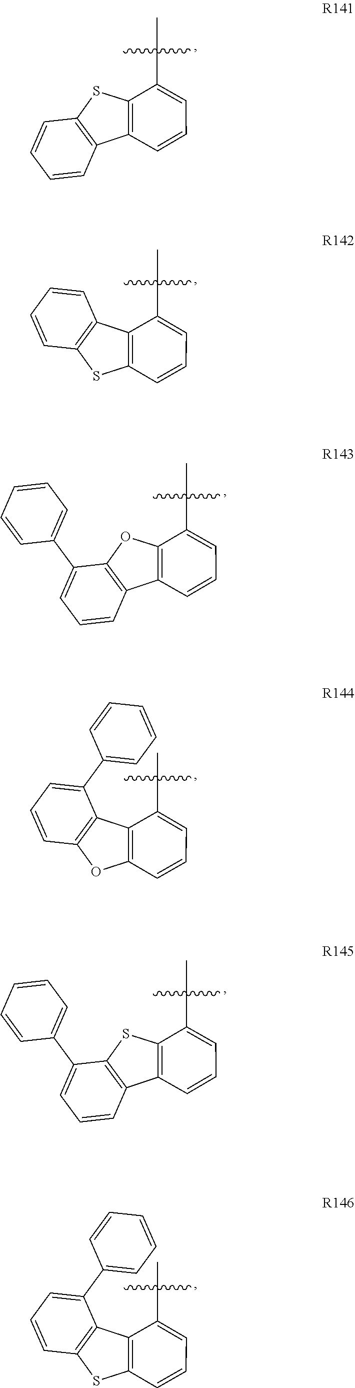 [SMILES: *c1cccc2c1sc1ccccc12 ; *c1cccc2sc3ccccc3c12 ; *c1cccc2c1oc1c(-c3ccccc3)cccc12 ; *c1cccc2oc3cccc(-c4ccccc4)c3c12 ; *c1cccc2c1sc1c(-c3ccccc3)cccc12 ; *c1cccc2sc3cccc(-c4ccccc4)c3c12]

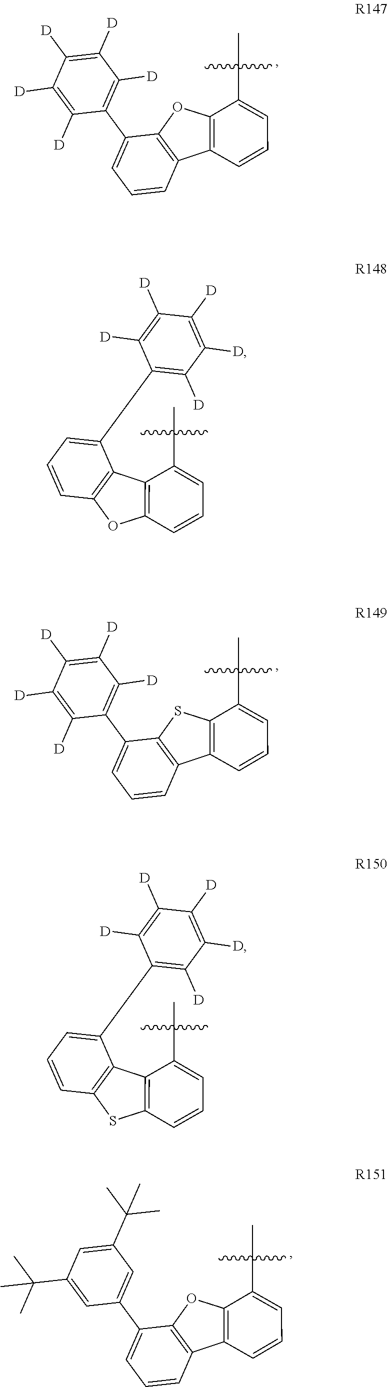

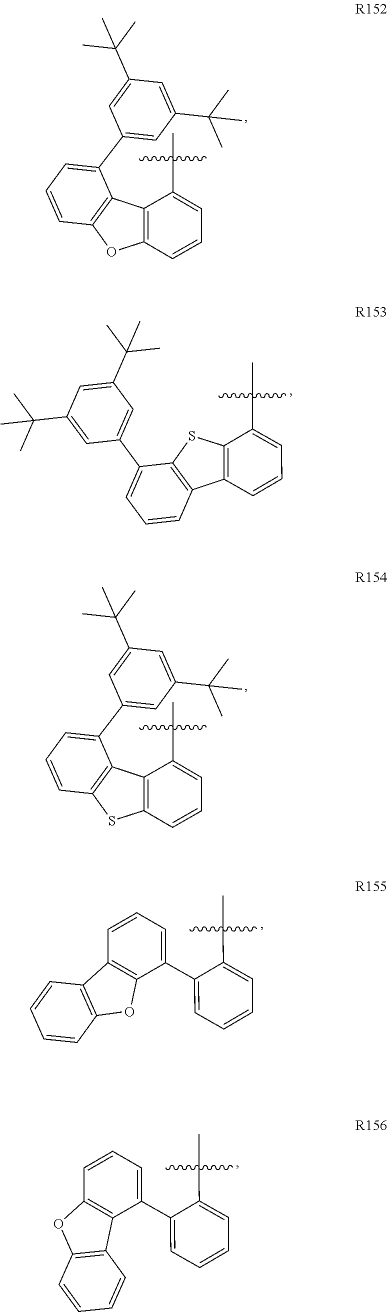

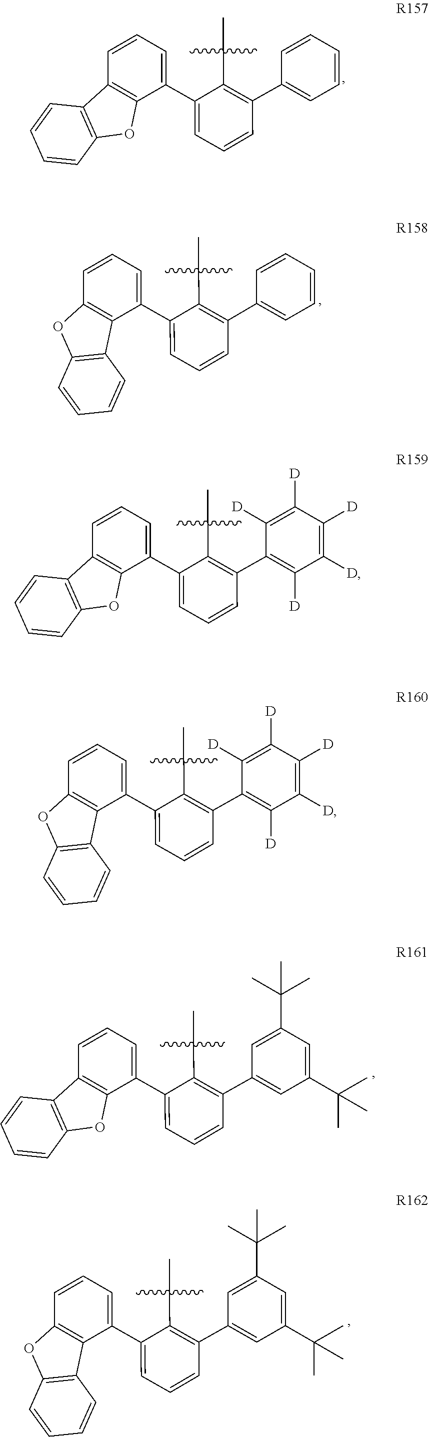

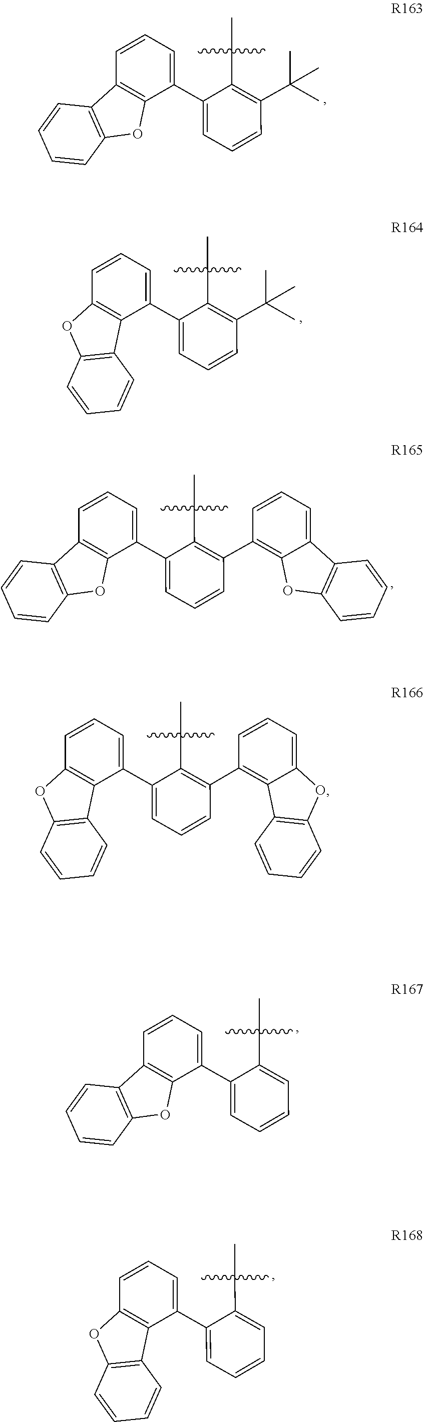 [SMILES: *c1c(-c2cccc3c2oc2ccccc23)cccc1C(C)(C)C ; *c1c(-c2cccc3oc4ccccc4c23)cccc1C(C)(C)C ; *c1c(-c2cccc3c2oc2ccccc23)cccc1-c1cccc2c1oc1ccccc12 ; *c1c(-c2cccc3oc4ccccc4c23)cccc1-c1cccc2oc3ccccc3c12 ; *c1ccccc1-c1cccc2c1oc1ccccc12 ; *c1ccccc1-c1cccc2oc3ccccc3c12]

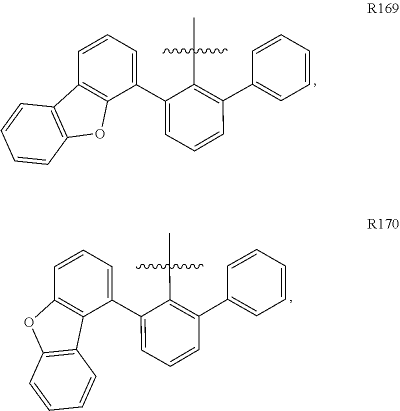 [SMILES: *c1c(-c2ccccc2)cccc1-c1cccc2c1oc1ccccc12 ; *c1c(-c2ccccc2)cccc1-c1cccc2oc3ccccc3c12]

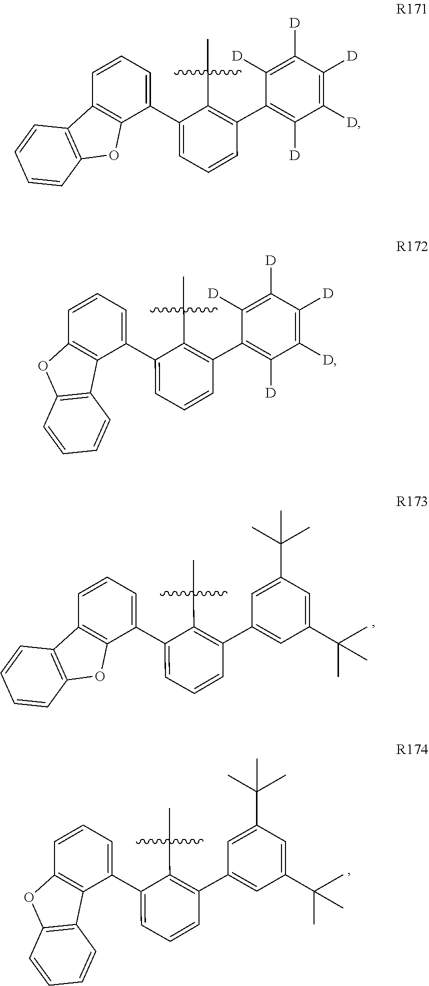

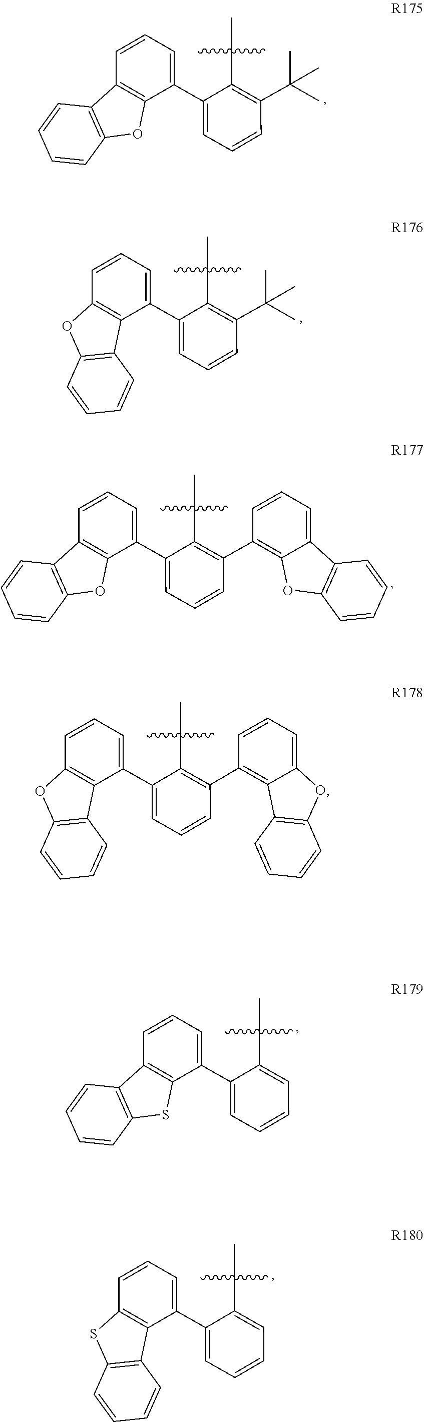 [SMILES: *c1c(-c2cccc3c2oc2ccccc23)cccc1C(C)(C)C ; *c1c(-c2cccc3oc4ccccc4c23)cccc1C(C)(C)C ; *c1c(-c2cccc3c2oc2ccccc23)cccc1-c1cccc2c1oc1ccccc12 ; *c1c(-c2cccc3oc4ccccc4c23)cccc1-c1cccc2oc3ccccc3c12 ; *c1ccccc1-c1cccc2c1sc1ccccc12 ; *c1ccccc1-c1cccc2sc3ccccc3c12]

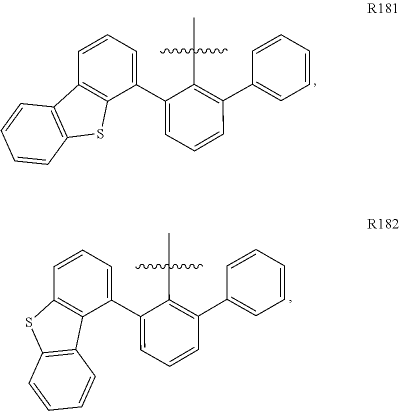 [SMILES: *c1c(-c2ccccc2)cccc1-c1cccc2c1sc1ccccc12 ; *c1c(-c2ccccc2)cccc1-c1cccc2sc3ccccc3c12]

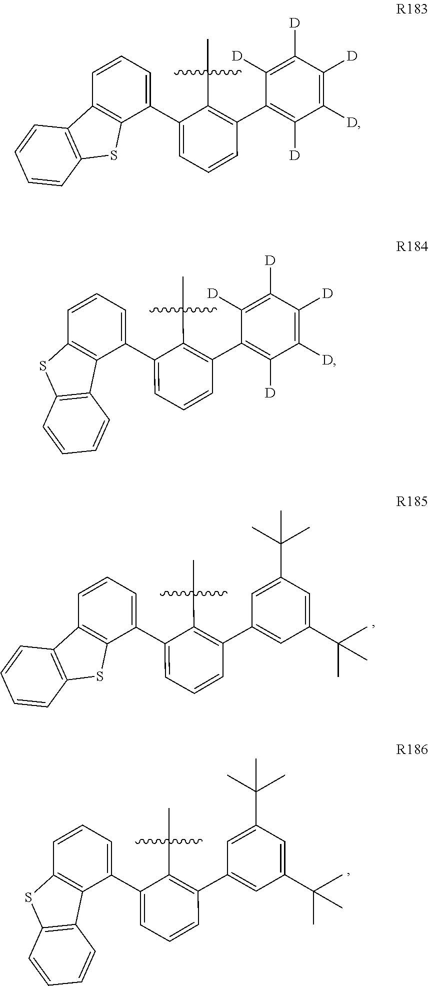

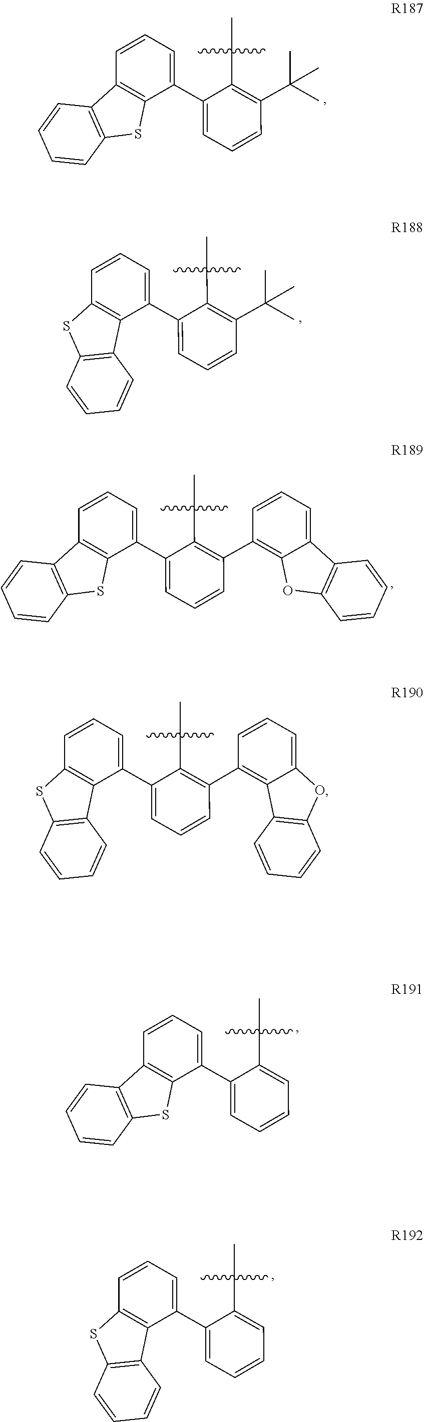 [SMILES: *c1c(-c2cccc3c2sc2ccccc23)cccc1C(C)(C)C ; *c1c(-c2cccc3sc4ccccc4c23)cccc1C(C)(C)C ; *c1c(-c2cccc3c2oc2ccccc23)cccc1-c1cccc2c1sc1ccccc12 ; *c1c(-c2cccc3oc4ccccc4c23)cccc1-c1cccc2sc3ccccc3c12 ; *c1ccccc1-c1cccc2c1sc1ccccc12 ; *c1ccccc1-c1cccc2sc3ccccc3c12]

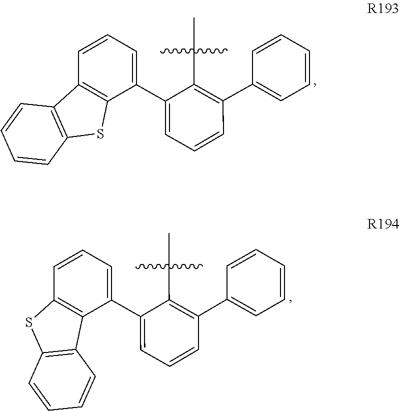 [SMILES: *c1c(-c2ccccc2)cccc1-c1cccc2c1sc1ccccc12 ; *c1c(-c2ccccc2)cccc1-c1cccc2sc3ccccc3c12]

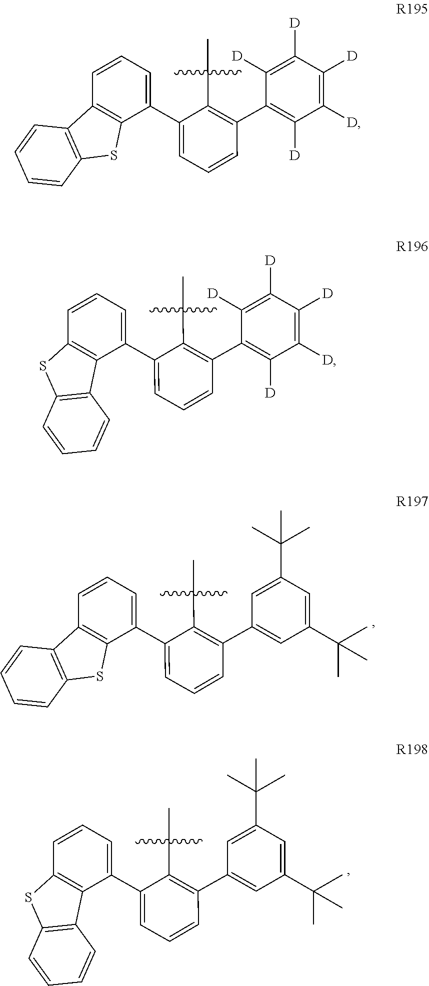

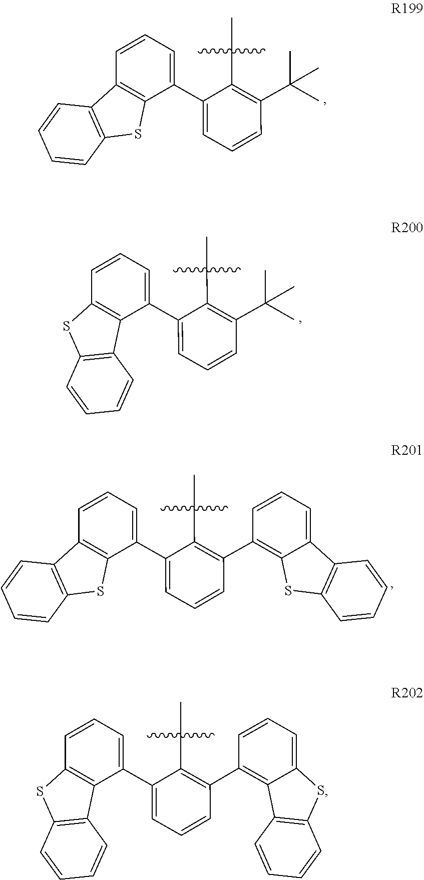 [SMILES: *c1c(-c2cccc3c2sc2ccccc23)cccc1C(C)(C)C ; *c1c(-c2cccc3sc4ccccc4c23)cccc1C(C)(C)C ; *c1c(-c2cccc3c2sc2ccccc23)cccc1-c1cccc2c1sc1ccccc12 ; *c1c(-c2cccc3sc4ccccc4c23)cccc1-c1cccc2sc3ccccc3c12]

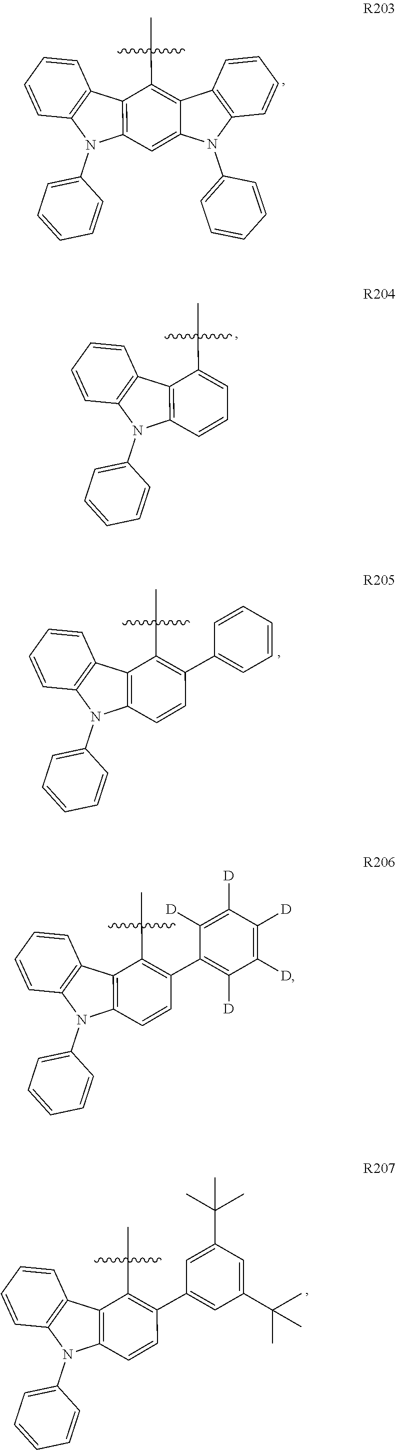

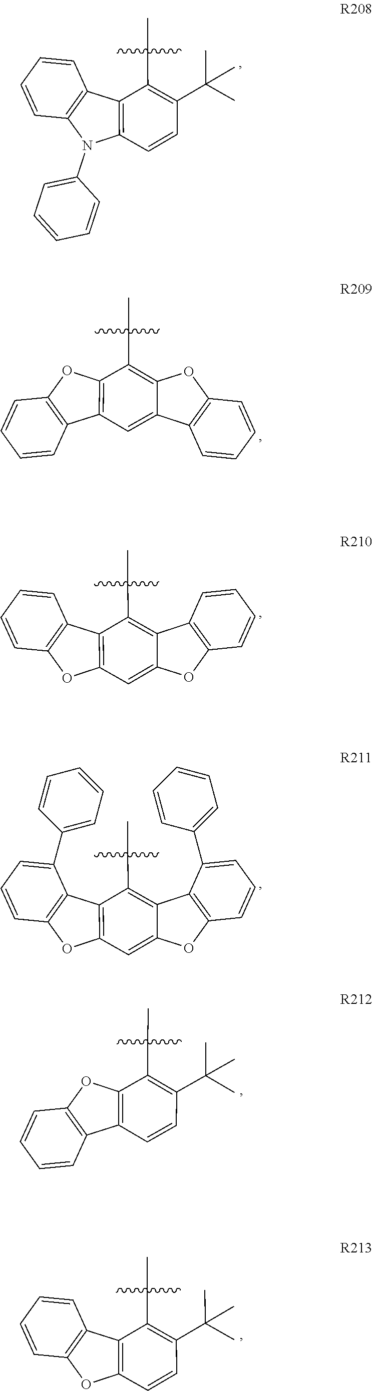 [SMILES: *c1c(C(C)(C)C)ccc2c1c1ccccc1n2-c1ccccc1 ; *c1c2oc3ccccc3c2cc2c1oc1ccccc12 ; *c1c2c(cc3oc4ccccc4c13)oc1ccccc12 ; *c1c2c(cc3oc4cccc(-c5ccccc5)c4c13)oc1cccc(-c3ccccc3)c12 ; *c1c(C(C)(C)C)ccc2c1oc1ccccc12 ; *c1c(C(C)(C)C)ccc2oc3ccccc3c12]

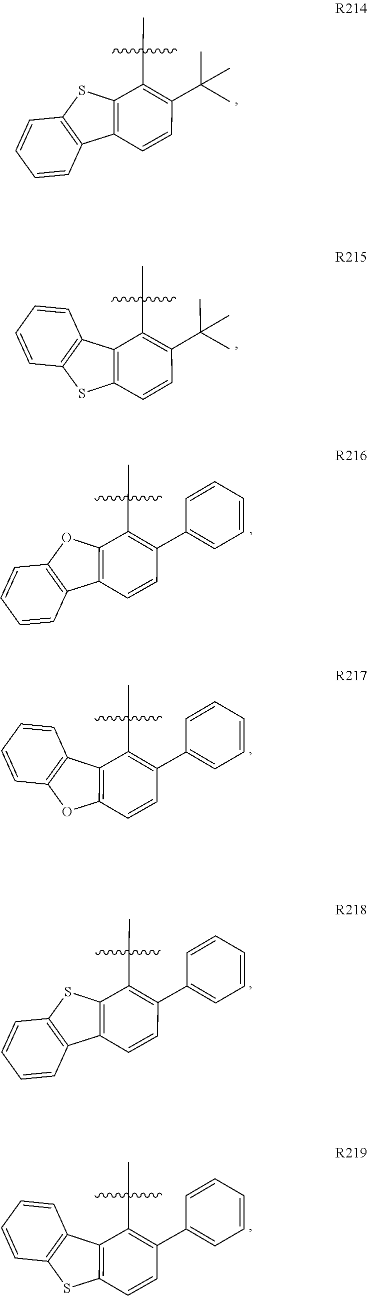 [SMILES: *c1c(C(C)(C)C)ccc2c1sc1ccccc12 ; *c1c(C(C)(C)C)ccc2sc3ccccc3c12 ; *c1c(-c2ccccc2)ccc2c1oc1ccccc12 ; *c1c(-c2ccccc2)ccc2oc3ccccc3c12 ; *c1c(-c2ccccc2)ccc2c1sc1ccccc12 ; *c1c(-c2ccccc2)ccc2sc3ccccc3c12]

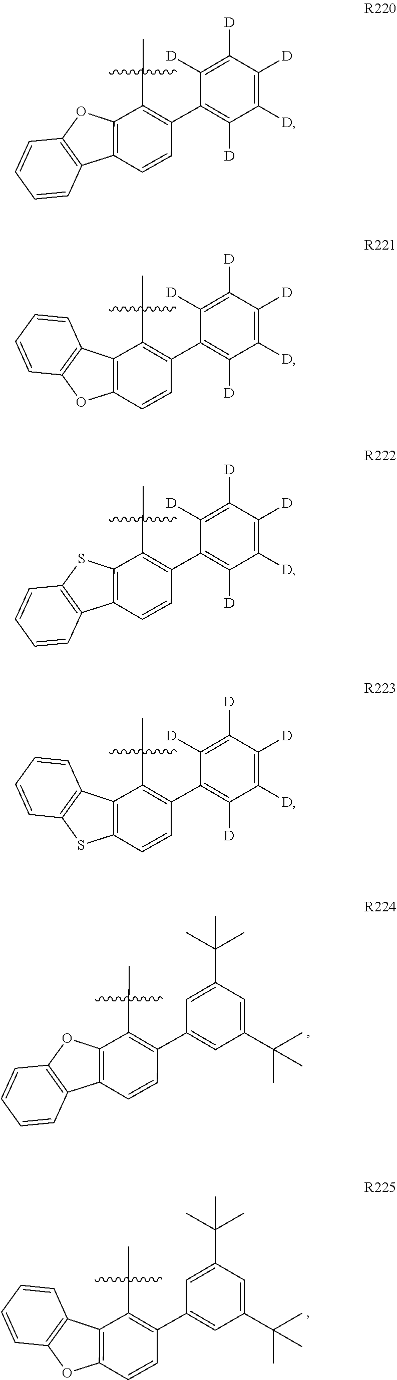

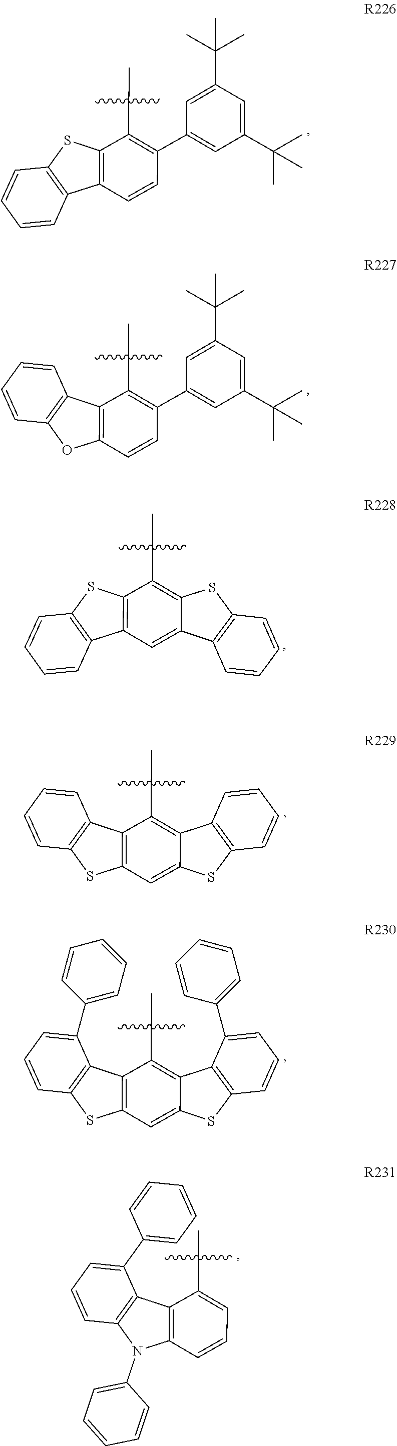 [SMILES: *c1c(-c2cc(C(C)(C)C)cc(C(C)(C)C)c2)ccc2c1sc1ccccc12 ; *c1c(-c2cc(C(C)(C)C)cc(C(C)(C)C)c2)ccc2oc3ccccc3c12 ; *c1c2sc3ccccc3c2cc2c1sc1ccccc12 ; *c1c2c(cc3sc4ccccc4c13)sc1ccccc12 ; *c1c2c(cc3sc4cccc(-c5ccccc5)c4c13)sc1cccc(-c3ccccc3)c12 ; *c1cccc2c1c1c(-c3ccccc3)cccc1n2-c1ccccc1]

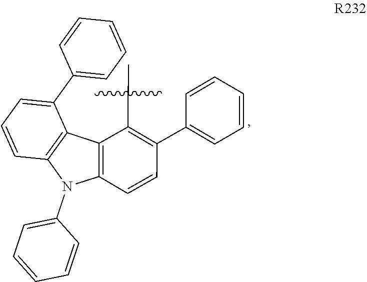 [SMILES: *c1c(-c2ccccc2)ccc2c1c1c(-c3ccccc3)cccc1n2-c1ccccc1]

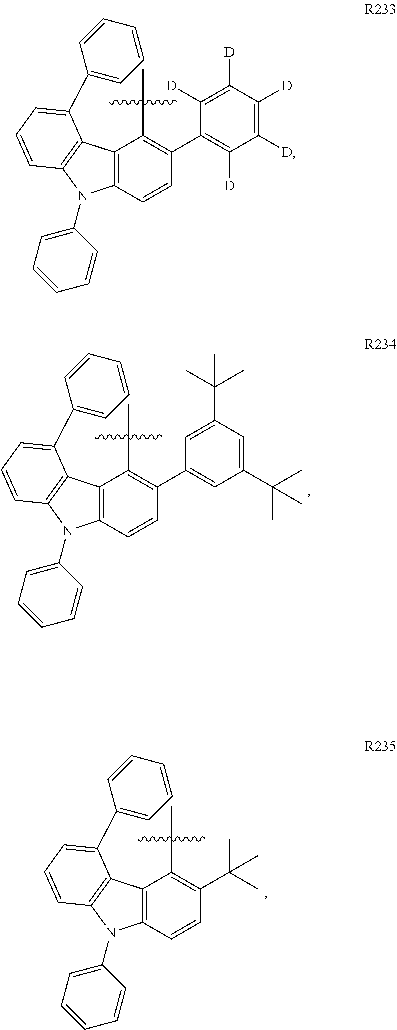

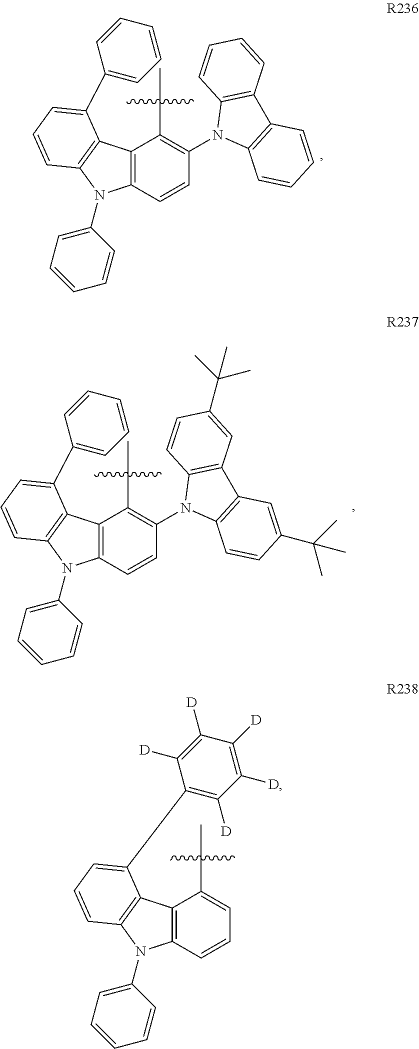

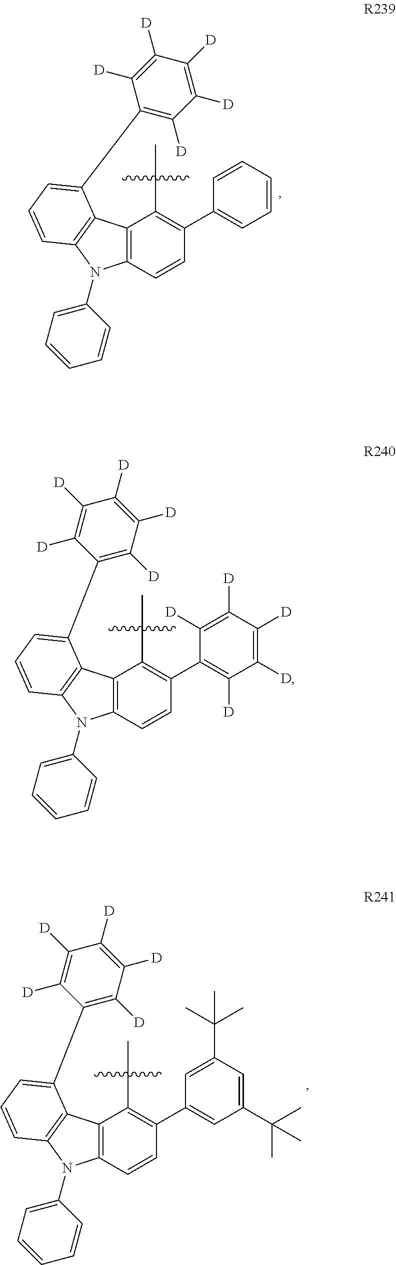

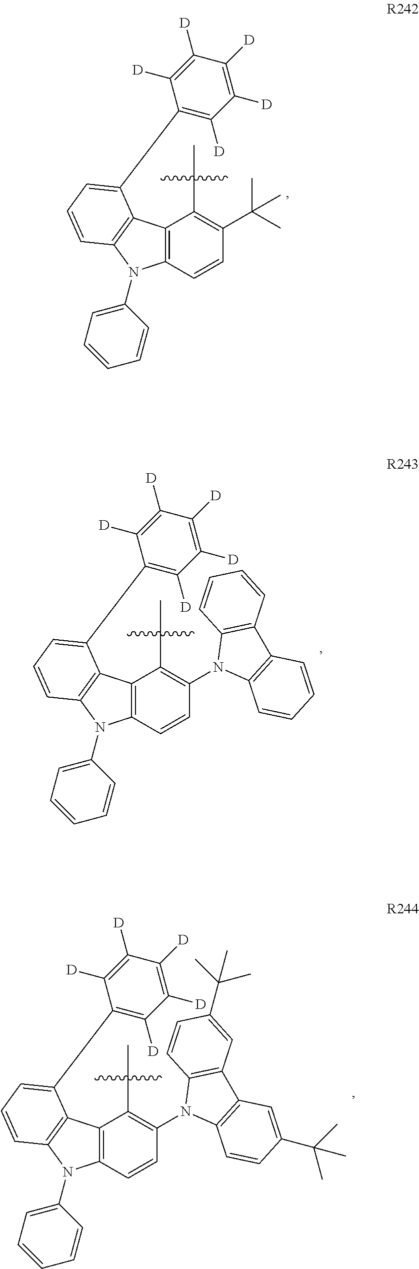 [SMILES: *c1c(C(C)(C)C)ccc2c1c1c(-c3c([2H])c([2H])c([2H])c([2H])c3[2H])cccc1n2-c1ccccc1 ; *c1c(-n2c3ccccc3c3ccccc32)ccc2c1c1c(-c3c([2H])c([2H])c([2H])c([2H])c3[2H])cccc1n2-c1ccccc1 ; *c1c(-n2c3ccc(C(C)(C)C)cc3c3cc(C(C)(C)C)ccc32)ccc2c1c1c(-c3c([2H])c([2H])c([2H])c([2H])c3[2H])cccc1n2-c1ccccc1]

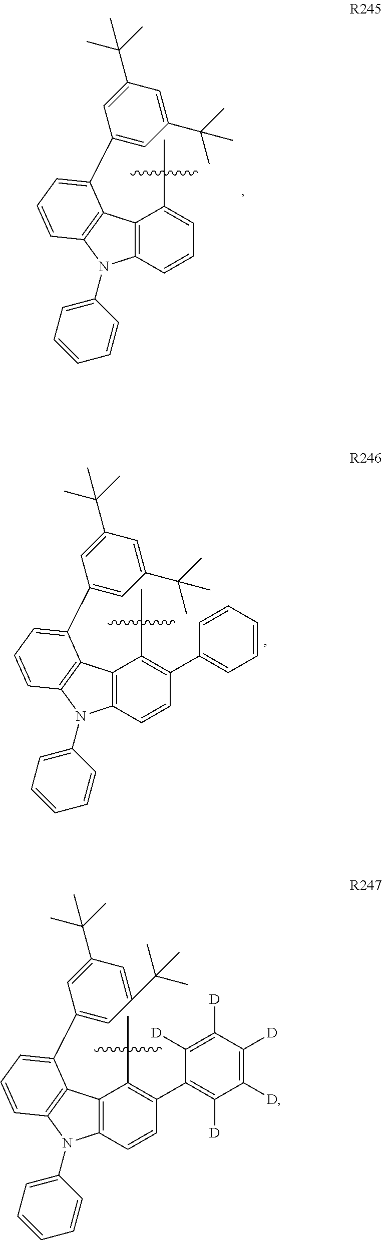

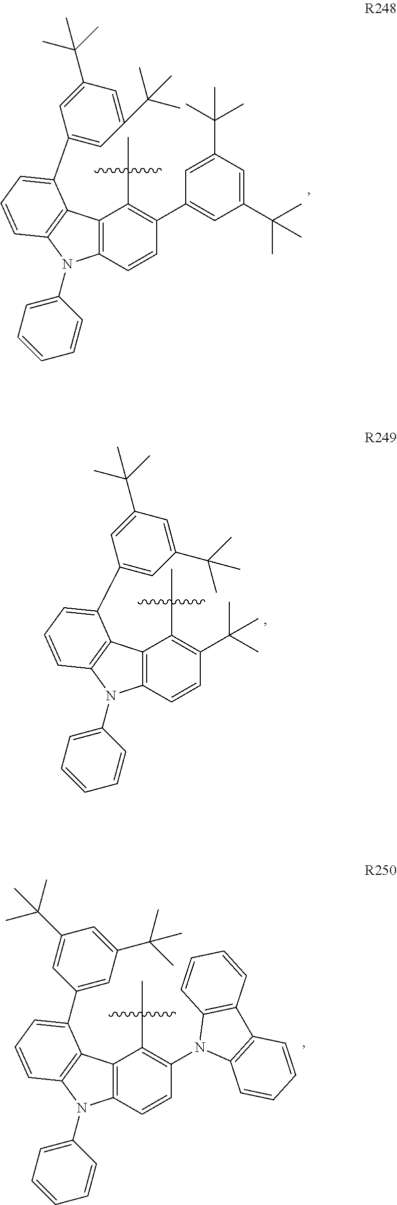

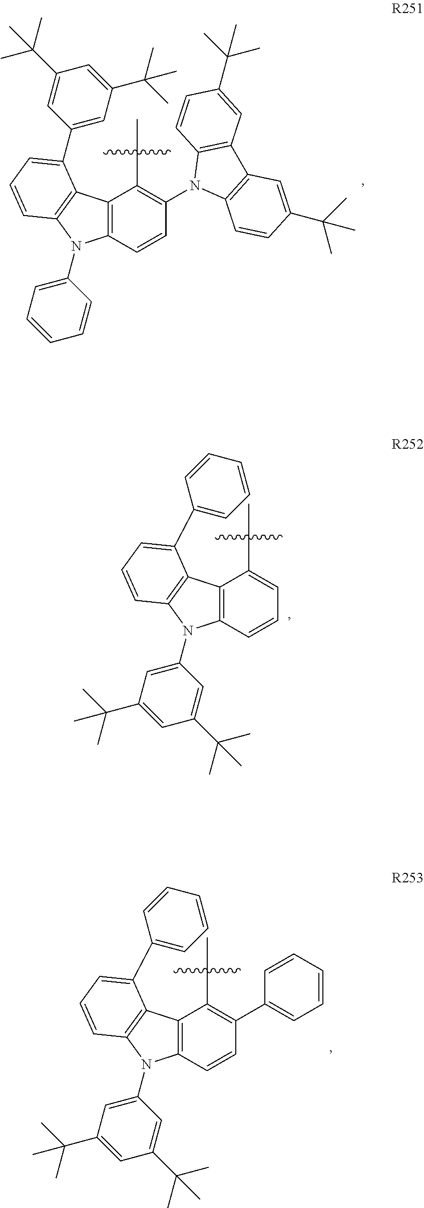

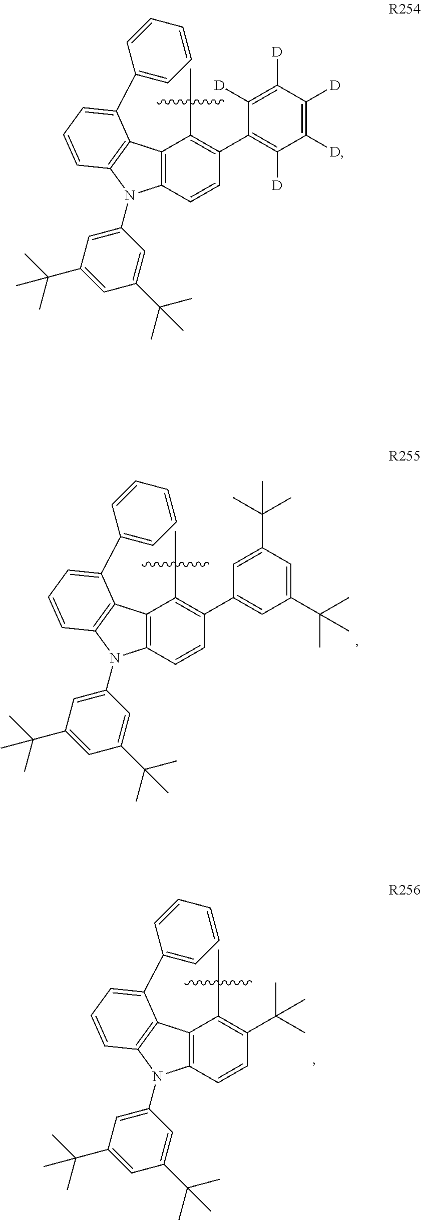

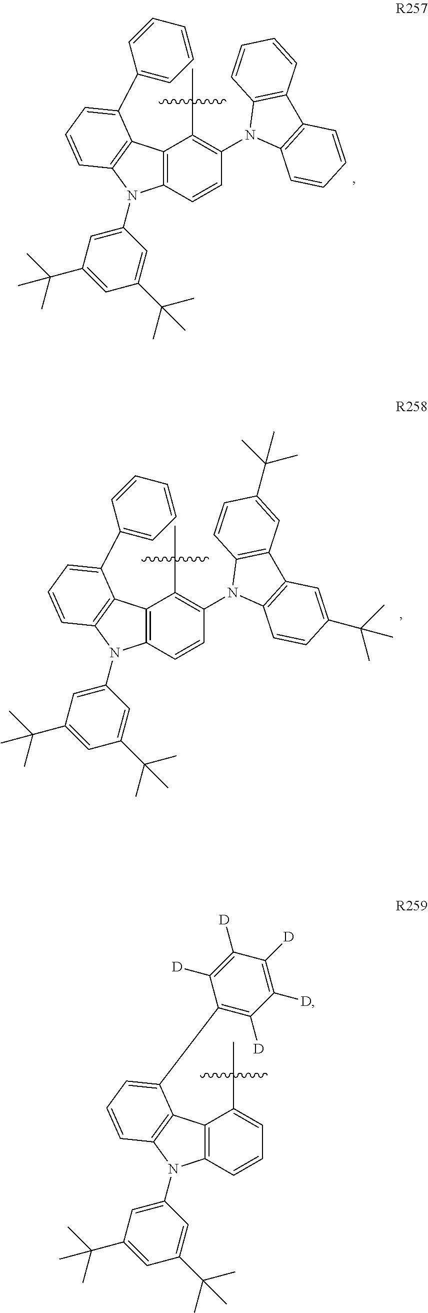

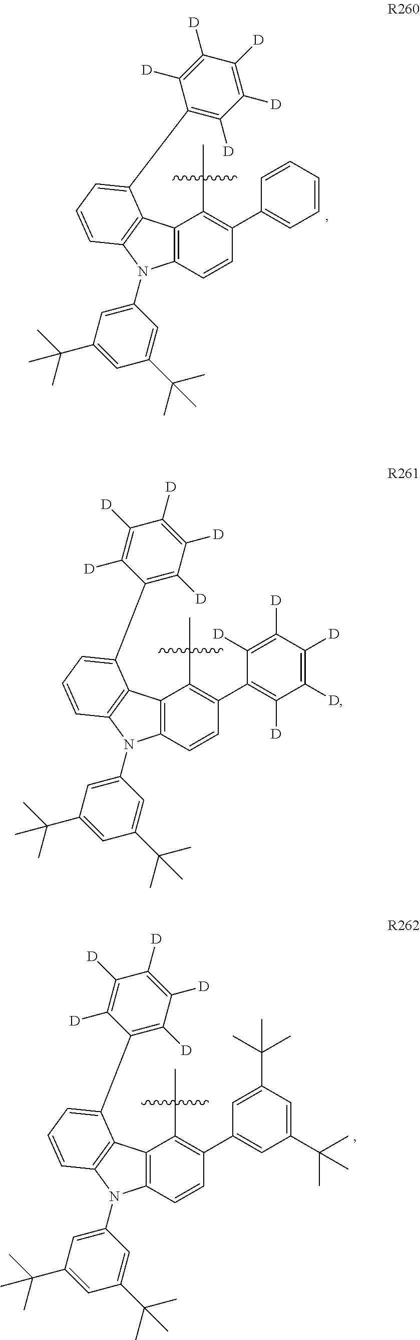

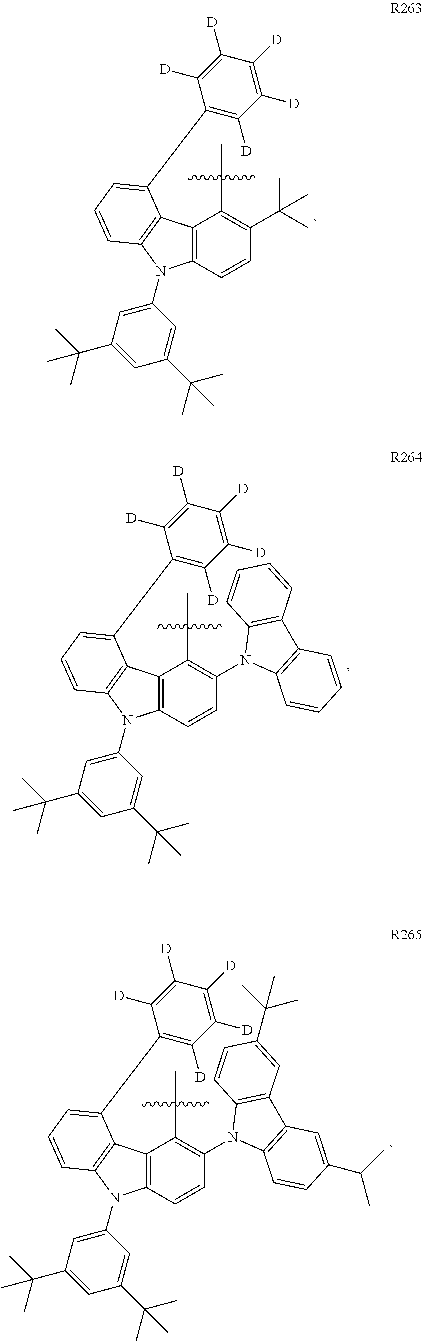

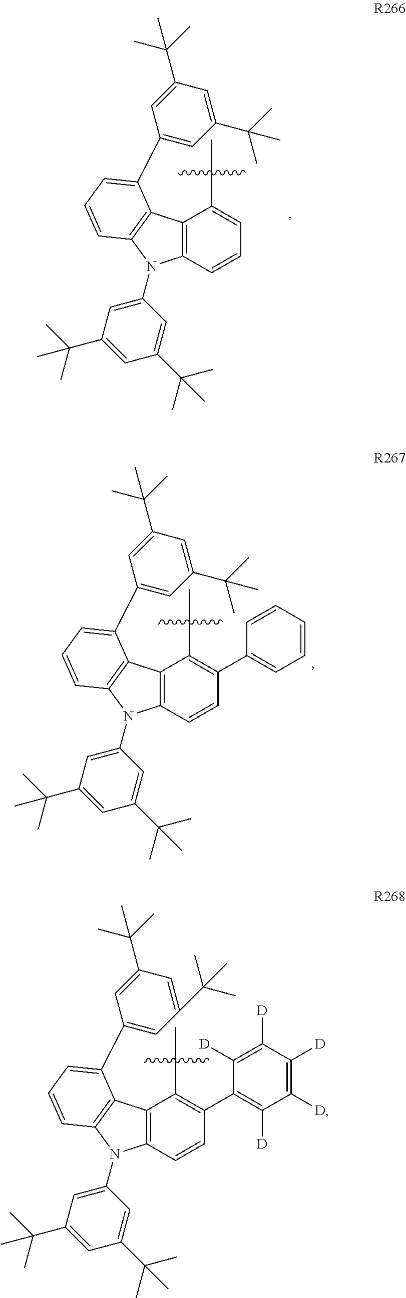

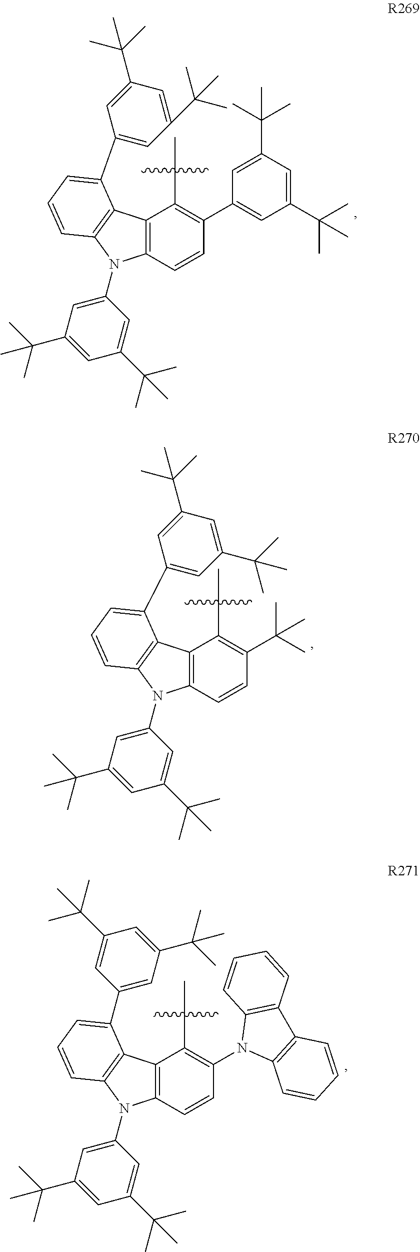

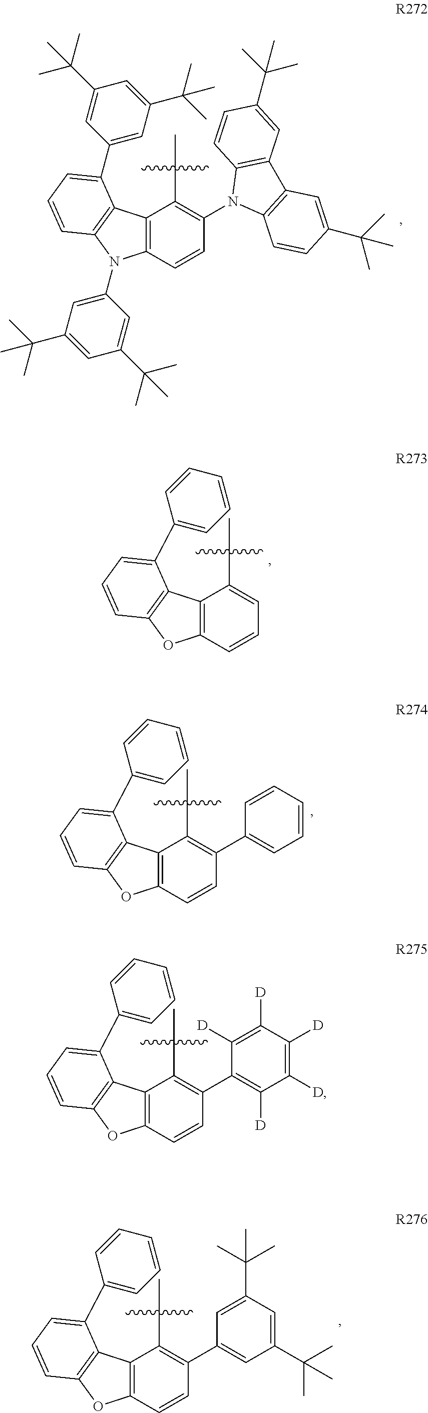

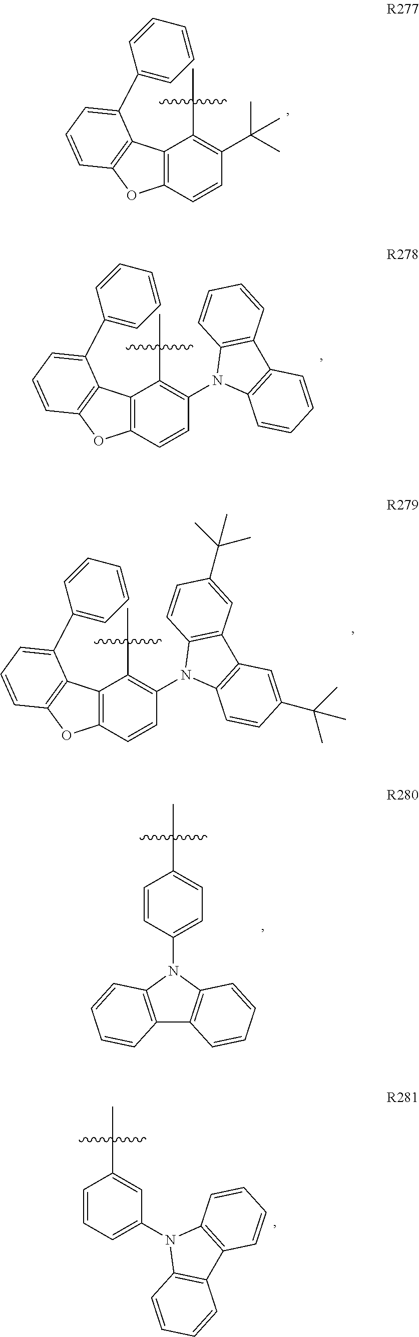 [SMILES: *c1c(C(C)(C)C)ccc2oc3cccc(-c4ccccc4)c3c12 ; *c1c(-n2c3ccccc3c3ccccc32)ccc2oc3cccc(-c4ccccc4)c3c12 ; *c1c(-n2c3ccc(C(C)(C)C)cc3c3cc(C(C)(C)C)ccc32)ccc2oc3cccc(-c4ccccc4)c3c12 ; *c1ccc(-n2c3ccccc3c3ccccc32)cc1 ; *c1cccc(-n2c3ccccc3c3ccccc32)c1]

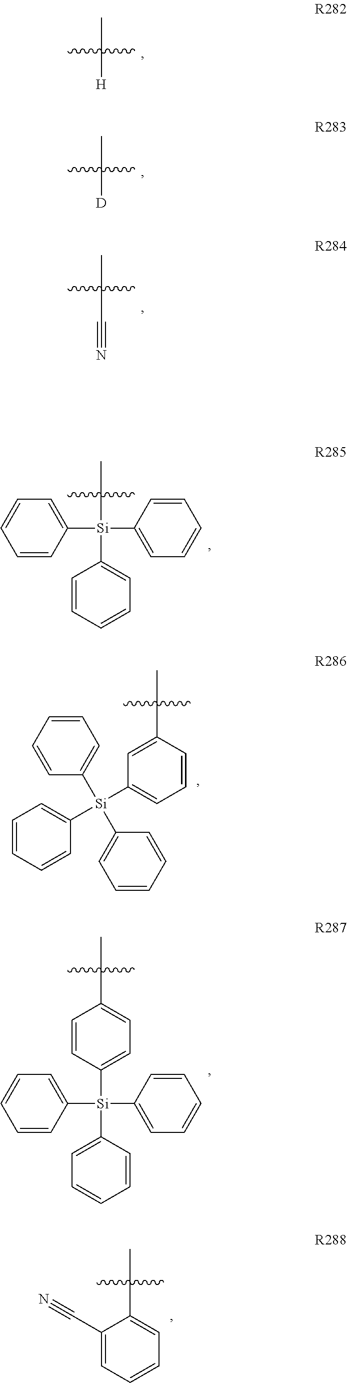

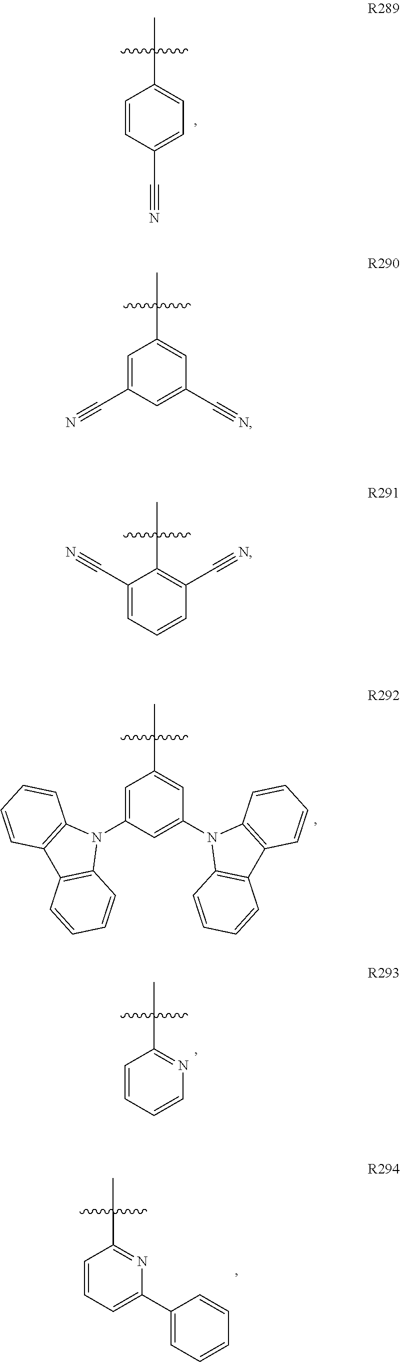 [SMILES: *c1ccc(C#N)cc1 ; *c1cc(C#N)cc(C#N)c1 ; *c1c(C#N)cccc1C#N ; *c1cc(-n2c3ccccc3c3ccccc32)cc(-n2c3ccccc3c3ccccc32)c1 ; *c1ccccn1 ; *c1cccc(-c2ccccc2)n1]

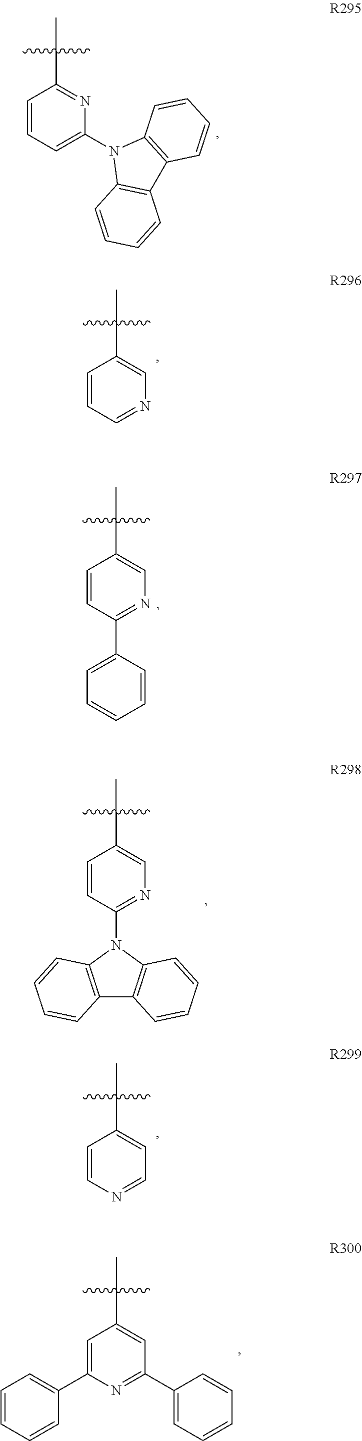 [SMILES: *c1cccc(-n2c3ccccc3c3ccccc32)n1 ; *c1cccnc1 ; *c1ccc(-c2ccccc2)nc1 ; *c1ccc(-n2c3ccccc3c3ccccc32)nc1 ; *c1ccncc1 ; *c1cc(-c2ccccc2)nc(-c2ccccc2)c1]

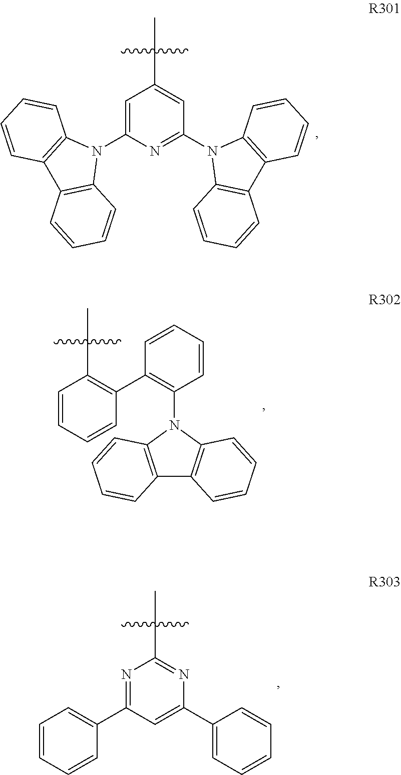 [SMILES: *c1cc(-n2c3ccccc3c3ccccc32)nc(-n2c3ccccc3c3ccccc32)c1 ; *c1ccccc1-c1ccccc1-n1c2ccccc2c2ccccc21 ; *c1nc(-c2ccccc2)cc(-c2ccccc2)n1]

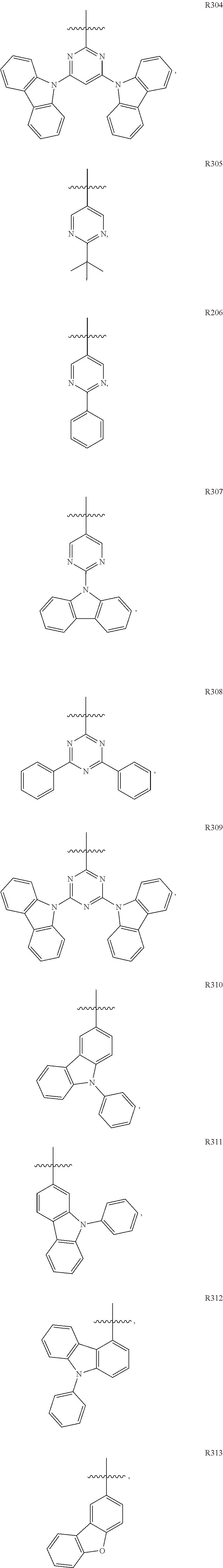

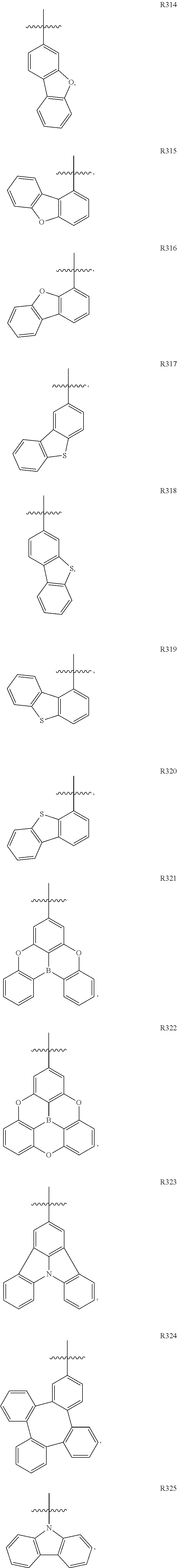

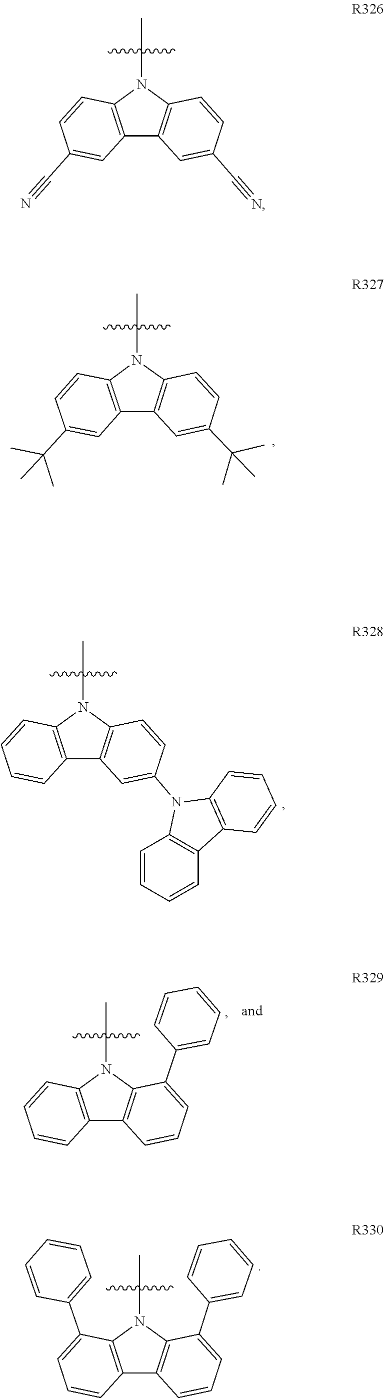 [SMILES: *n1c2ccc(C#N)cc2c2cc(C#N)ccc21 ; *n1c2ccc(C(C)(C)C)cc2c2cc(C(C)(C)C)ccc21 ; *n1c2ccccc2c2cc(-n3c4ccccc4c4ccccc43)ccc21 ; *n1c2ccccc2c2cccc(-c3ccccc3)c21 ; *n1c2c(-c3ccccc3)cccc2c2cccc(-c3ccccc3)c21]

In some embodiments of the compound, the compound is selected from the group consisting of those compounds from the compounds defined in LIST8 above, whose Ri, Rj, and Rk correspond to one of the following structures: B1, B2, B3, B9, B10, B16, B18, B20, B22, B23, B24, B25, B27, B29, B31, B32, B33, B34, B34, B40, B44, B45, and B46.

In some embodiments of the compound, the compound is selected from the group consisting of only those compounds comprising ligand L_{y} defined in LIST9 above, whose R^{B} corresponds to one of the following structures: R1, R2, R3, R10, R12, R20, R21, R22, R23, R27, R28, R29, R37, R38, R40, R41, R42, R52, R53, R54, R66, R67, R73, R74, R93, R94, R96, R101, R106, R130, R134, R135, R136, R137, R316, R317, R321, R322, R328, R329, R330, and R331.

What is claimed is:

1. A compound comprising a ligand L_{A} of Formula I 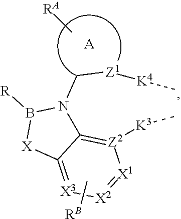
wherein:
A is a 5-membered or 6-membered carbocyclic or heterocyclic ring;
Z¹ and Z² are each independently C or N;
K³ and K⁴ are each independently a direct bond, O, or S;
X¹, X², and X³ are each independently C or N, at least one of X¹, X², and X³ is C;
X is O or NR′;
R^{A} and R^{B} each represents zero, mono, or up to the maximum number of allowed substitutions to its associated ring;
each of R, R′, R^{A}, and R^{B} is independently a hydrogen or a substituent selected from the group consisting of deuterium, halogen, alkyl, cycloalkyl, heteroalkyl, heterocycloalkyl, arylalkyl, alkoxy, aryloxy, amino, silyl, boryl, alkenyl, cycloalkenyl, heteroalkenyl, alkynyl, aryl, heteroaryl, acyl, carboxylic acid, ether, ester, nitrile, isonitrile, sulfanyl, sulfinyl, sulfonyl, phosphino, and combinations thereof; and
two adjacent groups can be joined or fused to form a ring wherever chemically feasible, wherein the ligand L_{A} is complexed to a metal M to form a chelate ring as indicated by the two dotted lines;
the metal M can be coordinated to other ligands;
the metal M is Pt; and
the ligand L_{A} can be linked with other ligands to form a tridentate, tetradentate, pentadentate, or hexadentate ligand.

2. The compound of claim 1, wherein the compound has Formula II 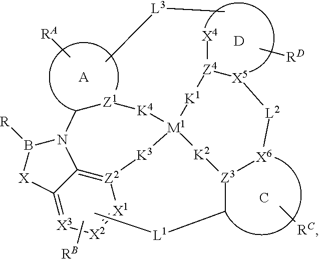
wherein:
M¹ is Pt;
rings C and D are each independently a 5-membered or 6-membered carbocyclic or heterocyclic ring;
Z³ and Z⁴ are each independently C or N;
K¹, K², K³, and K⁴ are each independently selected from the group consisting of a direct bond, O, and S, wherein at least two of them are direct bonds;
L¹, L², and L³ are each independently selected from the group consisting of a single bond, absent a bond, O, S, CR″R″′, SiR″R″′, BR″, and NR″,
at least one of L¹ and L² is not absent a bond;
X⁴-X⁶ are each independently C or N;
R^{C} and R^{D} each independently represent zero, mono, or up to a maximum allowed substitution to its associated ring;
each R″, R′″, R^{C}, and R^{D} is independently a hydrogen or a substituent selected from the group consisting of deuterium, fluorine, alkyl, cycloalkyl, heteroalkyl, alkoxy, aryloxy, amino, silyl, boryl, alkenyl, cycloalkenyl, heteroalkenyl, aryl, heteroaryl, nitrile, isonitrile, sulfanyl, and combinations thereof; and
two adjacent substituents can be joined or fused together to form a ring wherever chemically feasible.

3. The compound of claim 2, wherein ring C is a 5-membered or 6-membered aromatic ring.

4. The compound of claim 2, wherein L¹ is a direct bond.

5. The compound of claim 2, wherein L¹ is NR″.

6. The compound of claim 2, wherein L² is absent a bond.

7. The compound of claim 2, wherein L³ is a direct bond.

8. The compound of claim 2, wherein K¹, K², K³, and K⁴ are each a direct bond.

9. The compound of claim 2, wherein Z³ is N.

10. The compound of claim 2, wherein X⁴-X⁵ are both N, and X⁶ is C.

11. The compound of claim 2, wherein the compound is selected from the group consisting of compounds having the formula of Pt(L_{A}′)(Ly) with the following structure: 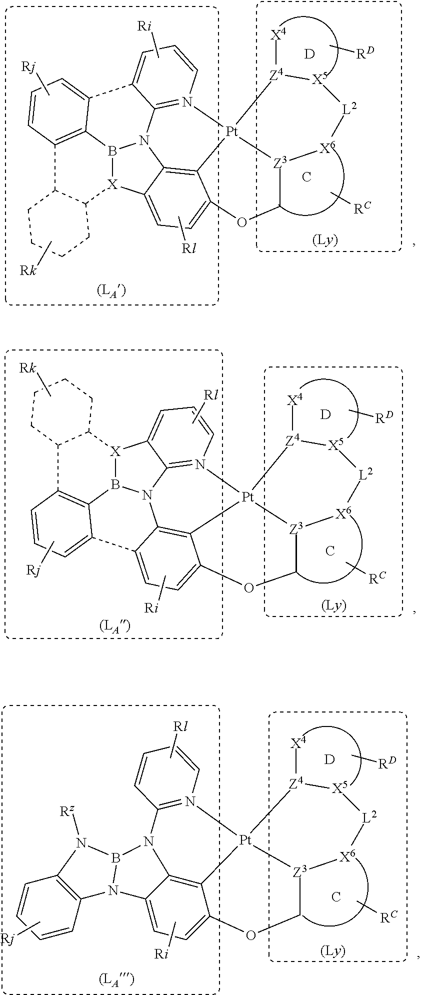 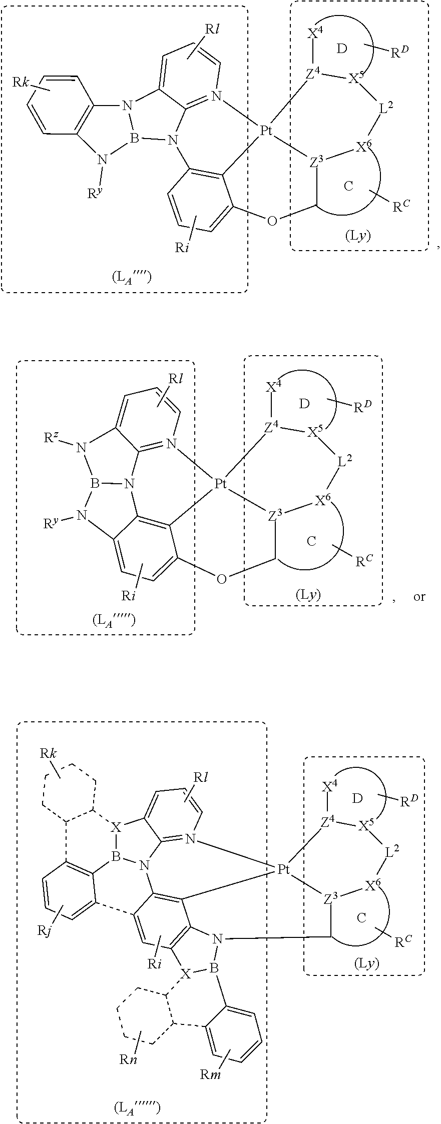
wherein L_{A}′ is selected from the group consisting of L_{A}′1-G to L_{A}′8-G whose structures are defined in LIST7A below, L_{A}″ is selected from the group consisting of L_{A}″9-G to L_{A}″16-G whose structures are defined in LIST7A below, L_{A}′″ is selected from the group consisting of L_{A}′″16-G whose structures are defined in LIST7A below, L_{A}″″ is selected from the group consisting of L_{A}″″17-G whose structures are defined in LIST7A below, and L_{A}″″′ is selected from the group consisting of L_{A}″″′18-G whose structures are defined in LIST7A below, and L_{A}″″″ is selected from the group consisting of L_{A}″″″19-G to L_{A}″″″21-G whose structures are defined in LIST7A below:
LIST7A
Ligand naming convention and structure
L_{A}'1-G having the structure 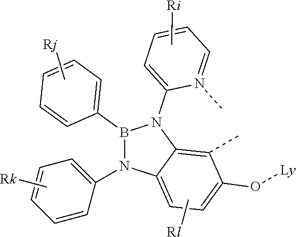
L_{A}′2-G having the structure 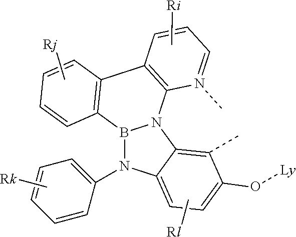
L_{A}′3-G having the structure 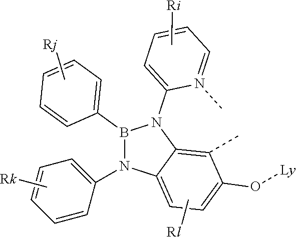
L_{A}′4-G having the structure 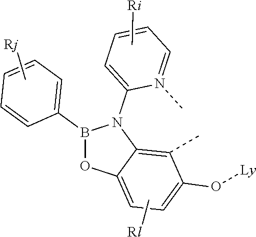
L_{A}′5-G having the structure 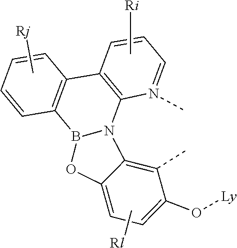
L_{A}′6-G having the structure 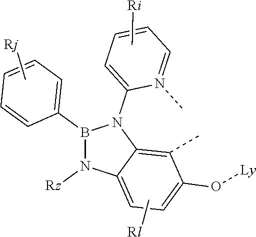
L_{A}′7-G having the structure 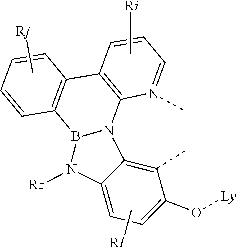
L_{A}′8-G having the structure 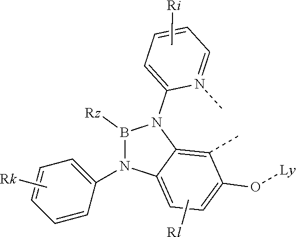
L_{A}″9-G having the structure 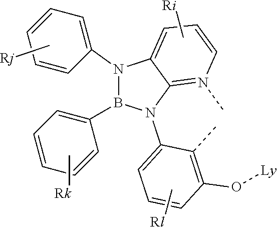
L_{A}″10-G having the structure 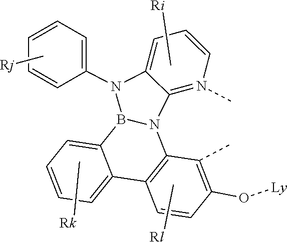
L_{A}″11-G having the structure 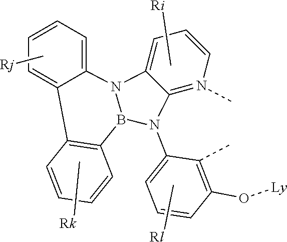
L_{A}″12-G having the structure 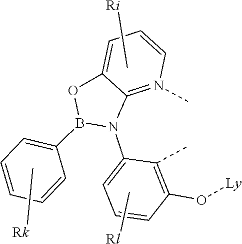
L_{A}″13-G having the structure 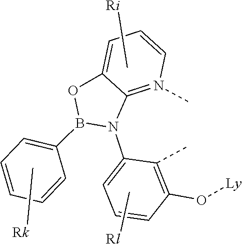
L_{A}″14-G having the structure 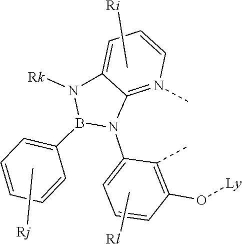
L_{A}″15-G having the structure 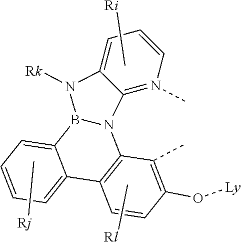
L_{A}″16-G having the structure 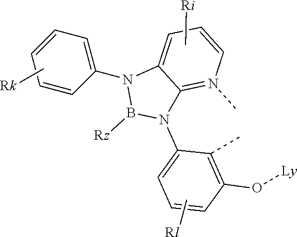
L_{A}′′′16-G having the structure 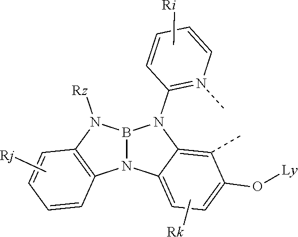
L_{A}′′′′17-G having the structure 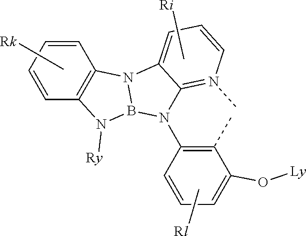
L_{A}′′′′′18-G having the structure 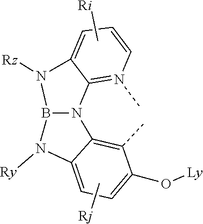
L_{A}′′′′′′19-G having the structure 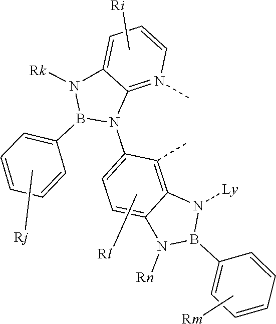
L_{A}′′′′′′20-G having the structure 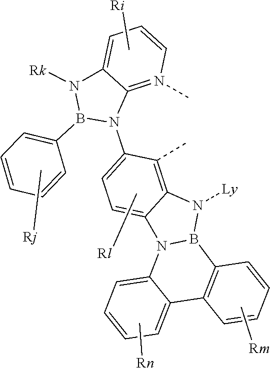
L_{A}′′′′′′21-G having the structure 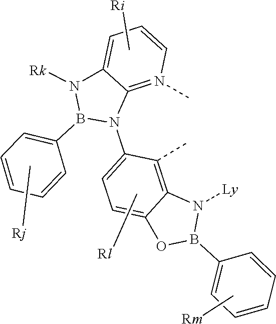
wherein i, j, k, l, z, and y are independently an integer from 1 to 55, Ri=Bi, Rj=Bj, Rk=Bk, Rl=Bl, and Rz=Bz, and
B1 to B55 have the following structures: 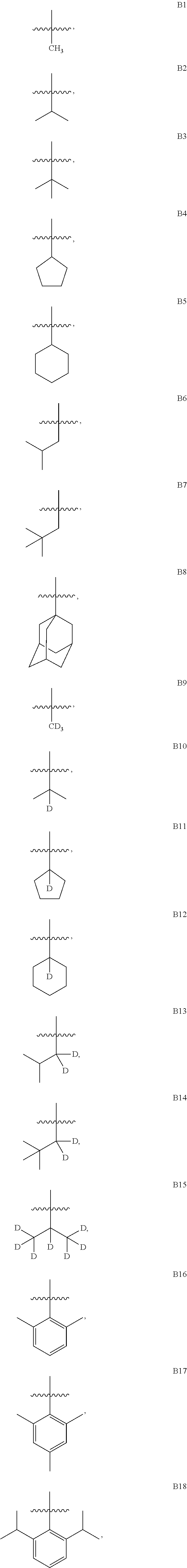 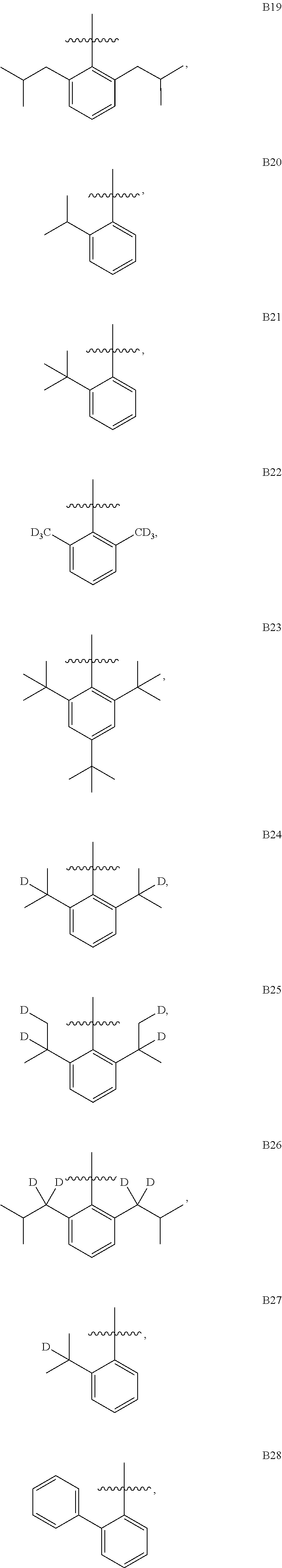 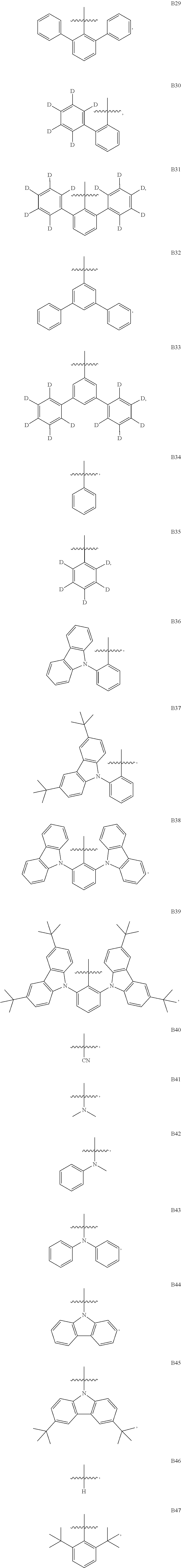 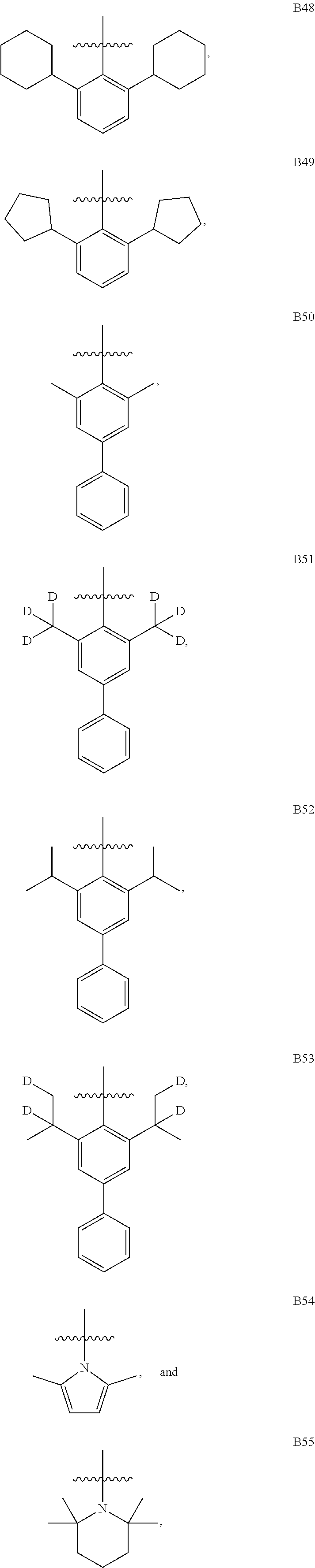
wherein L_{y} is selected from the group consisting of the structures shown in LIST7B below
LIST7B
L_{y}

| | | |
|---|---|---|
| L_{y}1-G having the structure | L_{y}14-G, having the structure | L_{y}27-G having the structure |
| 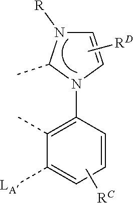 | 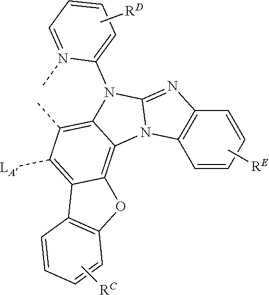 | 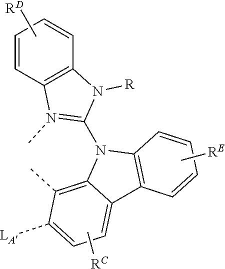 |
| L_{y}2-G having the structure | L_{y}15-G having the structure | L_{y}28-G having the structure |
| 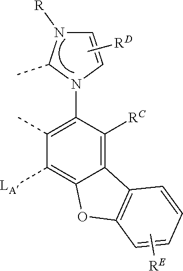 | 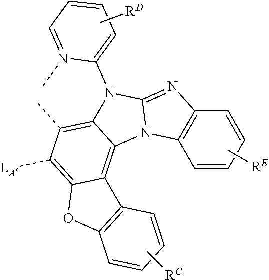 | 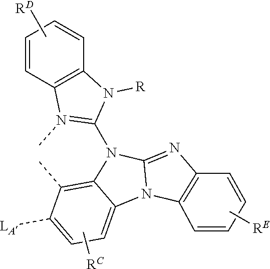 |
| L_{y}3-G having the structure | L_{y}16-G having the structure | L_{y}29-G having the structure |
| 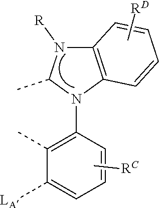 | 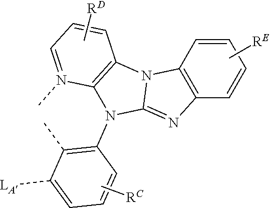 | 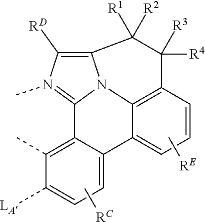 |
| L_{y}4-G having the structure | L_{y}17-G having the structure | L_{y}30-G having the structure |
| 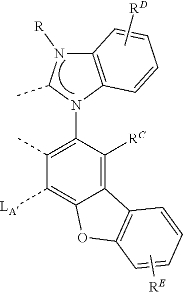 | 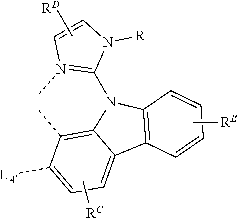 | 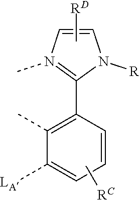 |
| L_{y}5-G having the structure | L_{y}18-G having the structure | L_{y}31-G having the structure |
| 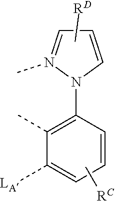 | 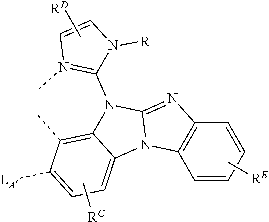 | 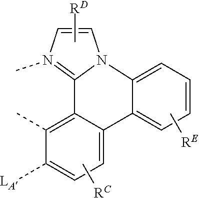 |
| L_{y}6-G having the structure | L_{y}19-G having the structure | L_{y}32-G having the structure |
| 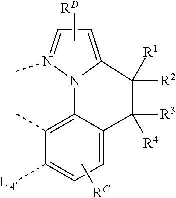 | 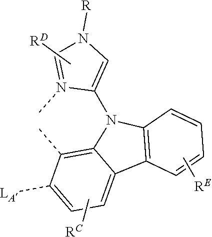 | 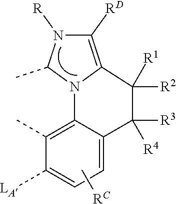 |
| L_{y}7-G having the structure | L_{y}20-G having the structure | L_{y}33-G having the structure |
| 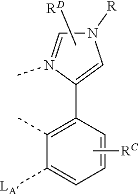 | 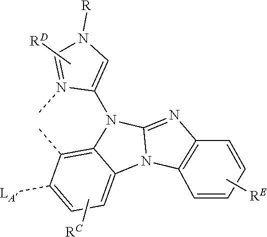 | 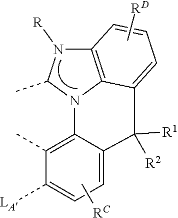 |
| L_{y}8-G having the structure | L_{y}21-G having the structure | L_{y}34-G having the structure |
| 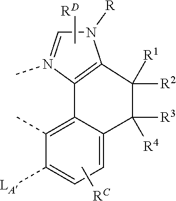 | 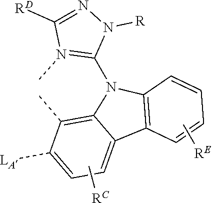 | 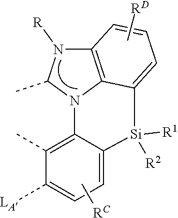 |
| L_{y}9-G having the structure | L_{y}22-G having the structure | L_{y}35-G having the structure |
| 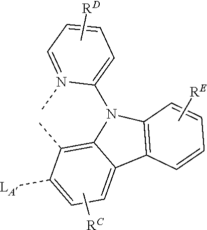 | 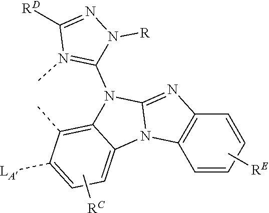 | 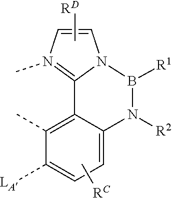 |
| L_{y}10-G having the structure | L_{y}23-G having the structure | L_{y}36-G having the structure |
| 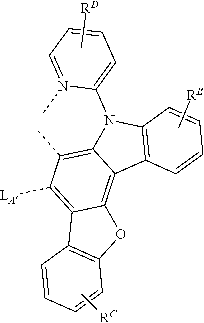 | 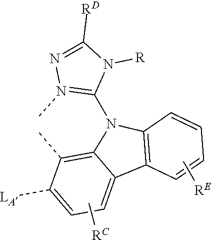 | 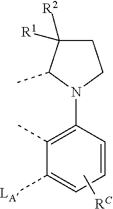 |
| L_{y}11-G having the structure | L_{y}24-G having the structure | L_{y}37-G having the structure |
| 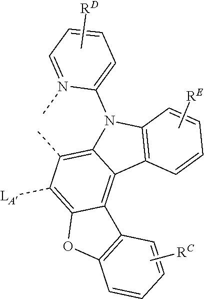 | 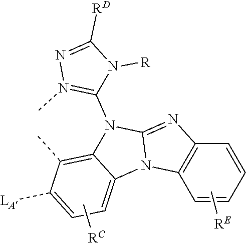 | 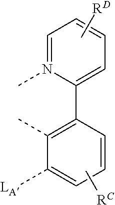 |
| L_{y}12-G having the structure | L_{y}25-G having the structure | L_{y}38-G having the structure |
| 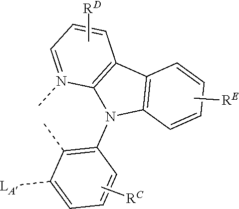 | 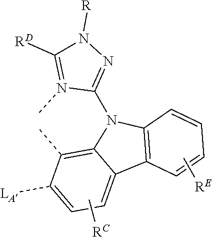 | 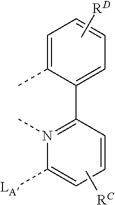 |
| L_{y}13-G having the structure | L_{y}26-G having the structure | L_{y}39-G having the structure |
| 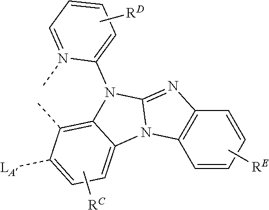 | 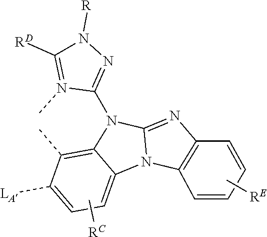 | 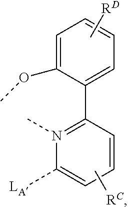 |

wherein R, R^{C}, R^{D}, and R^{E} each represents zero, mono, or up to the maximum number of allowed substitutions to its associated ring; each R¹, R², R³, R⁴, R, R′, R^{A}, and R^{B} are independently a hydrogen or a substituent selected from the group consisting of the general substituents defined herein; and two adjacent groups can be joined or fused to form a ring wherever chemically feasible.

12. The compound of claim 2, wherein the compound is selected from the group consisting of compounds having the formula of Pt(L_{A})(Ly) having the following structures: 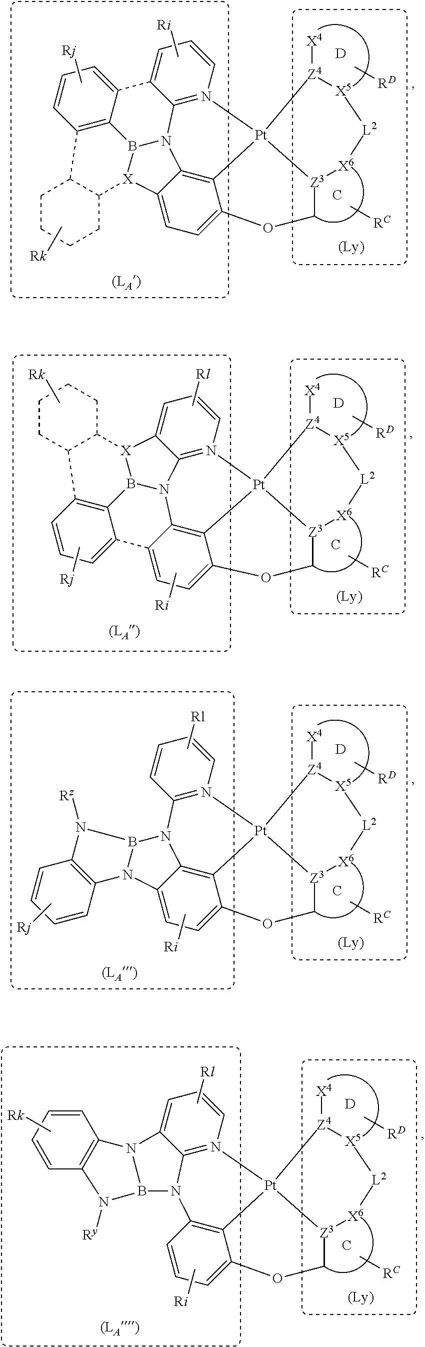 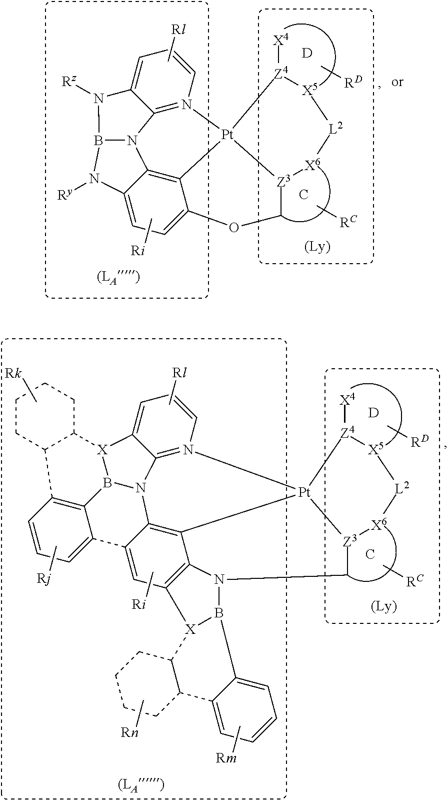
wherein L_{A}′ to L_{A}″″″ are selected from the group having the structures shown below:

| Ligand naming convention | Structure |
|---|---|
| L_{A}′1-(j)(k)(p)(z), wherein each of j, k, p, and z is independently an integer from 1 to 55, wherein L_{A}′1-(1)(1)(1)(1) to L_{A}′1-(55)(55)(55)(55) having the structure | 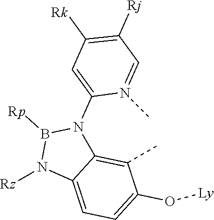 |
| L_{A}′2-(j)(k)(p), wherein each of j, k, p, is independently an integer from 1 to 55, wherein L_{A}′2-(1)(1)(1) to L_{A}′2-(55)(55)(55) having the structure | 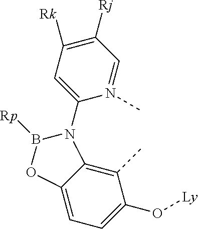 |
| L_{A}′3-(j)(z), wherein each of j, and z is independently an integer from 1 to 55, wherein L_{A}′3-(1)(1) to L_{A}′3-(55)(55) having the structure | 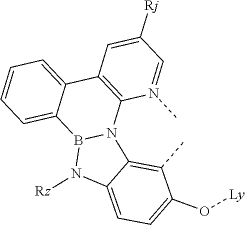 |
| L_{A}′4-(j), wherein each of j is an integer from 1 to 55, wherein L_{A}′4-(1) to L_{A}′4-(55) having the structure | 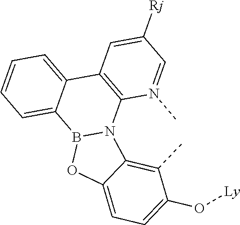 |
| L_{A}′5-(j)(k), wherein each of j, and k is independently an integer from 1 to 55, wherein L_{A}′5-(1)(1) to L_{A}′5-(55)(55) having the structure | 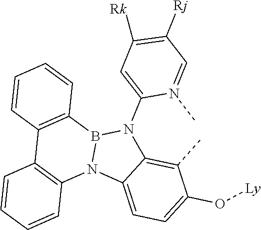 |
| L_{A}″6-(j)(k)(p)(z), wherein each of j, k, p, and z is independently an integer from 1 to 55, wherein L_{A}″6- (1)(1)(1)(1) to L_{A′}″6-(55)(55)(55)(55) having the structure | 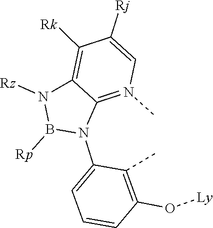 |
| L_{A}″7-(j)(k)(p), wherein each of j, k, and p is independently an integer from 1 to 55, wherein L_{A}″7-(1)(1)(1) to L_{A}″7-(55)(55)(55) having the structure | 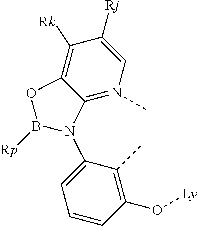 |
| L_{A}″8-(j)(k)(z), wherein each of j, k, and z is independently an integer from 1 to 55, wherein L_{A}″8-(1)(1)(1) to L_{A}″8- (55)(55)(55) having the structure | 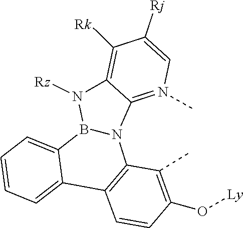 |
| L_{A}″9-(j)(k), wherein each of j, and k is independently an integer from 1 to 55, wherein L_{A}″9-(1)(1) to L_{A}″9-(55)(55) having the structure | 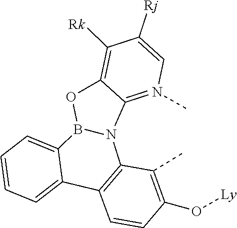 |
| L_{A}″10-(j), wherein j is an integer from 1 to 55, wherein L_{A}″10-(1) to L_{A}″10- (55) having the structure | 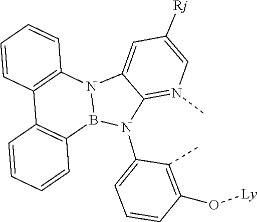 |
| L_{A}′′′11-(j)(k)(z), wherein each of j, k, and z is independently an integer from 1 to 55, wherein L_{A}′′′11-(1)(1)(1) to L_{A}′′′ 11-(55)(55)(55) having the structure | 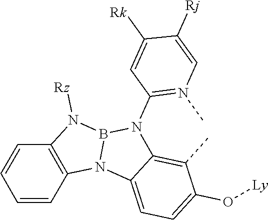 |
| L_{A}′′′′12-(j)(k)(z), wherein each of j, k, and z is independently an integer from 1 to 55, wherein L_{A}′′′′12-(1)(1)(1) to L_{A}′′′′12-(55)(55)(55) having the structure | 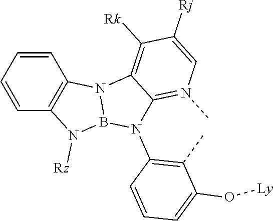 |
| LA′′′′′13-(j)(k)(p)(z), wherein each of j, k, p, and z is independently an integer from 1 to 55, wherein L_{A}′′′′′13- (1)(1)(1)(1) to L_{A}′′′′′13- (55)(55)(55)(55) having the structure | 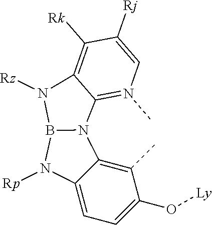 |
| L_{A}′′′′′′14-(j)(k)(p)(z), wherein each of j, k, p, and z is independently an integer from 1 to 55, wherein L_{A}′′′′′′14- (1)(1)(1)(1) to L_{A}′′′′′′14- (55)(55)(55)(55) having the structure | 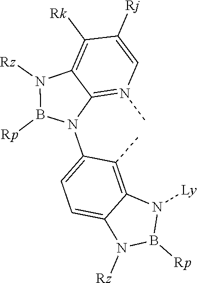 |
| L_{A}′′′′′′15-(j)(k)(p)(z), wherein each of j, k, p, and z is independently an integer from 1 to 55, wherein L_{A}′′′′′′15- (1)(1)(1)(1) to L_{A}′′′′′′15- (55)(55)(55)(55) having the structure | 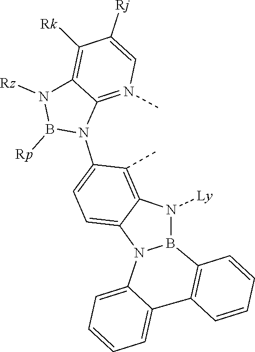 |
| L_{A}′′′′′′16-(j), wherein j is an integer from 1 to 55, wherein L_{A}′′′′′′16-(1) to L_{A}′′′′′′16-(55) having the structure | 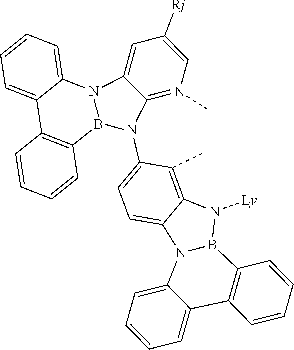 |
| L_{A}′′′′′′17-(j)(k)(p)(z), wherein each of j, k, p, and z is independently an integer from 1 to 55, wherein L_{A}′′′′′17- (1)(1)(1)(1) to L_{A}′′′′′′17- (55)(55)(55)(55) having the structure | 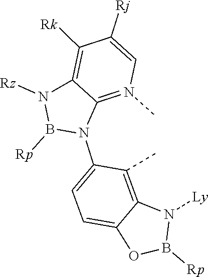 |
| L_{A}′18-(j)(k)(p)(z), wherein each of j, k, p, and z is independently an integer from 1 to 55, wherein L_{A}′18- (1)(1)(1)(1) to L_{A}′18-(55)(55)(55)(55) having the structure | 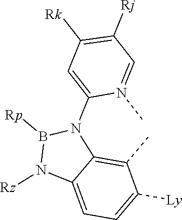 |
| L_{A}′19-(j)(k)(p), wherein each of j, k, and p is independently an integer from 1 to 55, wherein L_{A}′19-(1)(1)(1) to L_{A}′19-(55)(55)(55) having the structure | 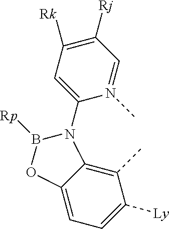 |
| L_{A}′20-(j)(z), wherein each of j, and z is independently an integer from 1 to 55, wherein L_{A}′20-(1)(1) to L_{A}′20-(55)(55) having the structure | 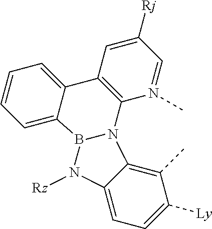 |
| L_{A}′21-(j), wherein j is an integer from 1 to 55, wherein L_{A}′21-(1) to L_{A}′21- (55) having the structure | 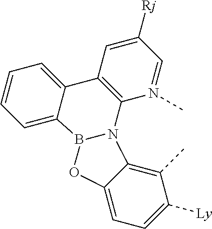 |
| L_{A}′22-(j)(k), wherein each of j, and k is independently an integer from 1 to 55, wherein L_{A}′22-(1)(1) to L_{A}′22-(55)(55) having the structure | 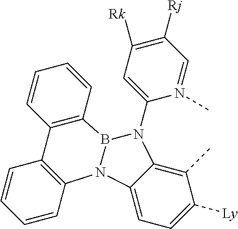 |
| L_{A}″23-(j)(k)(p)(z), wherein each of j, k, p, and z is independently an integer from 1 to 55, wherein L_{A}″23- (1)(1)(1)(1) to L_{A′}″23-(55)(55)(55)(55) having the structure | 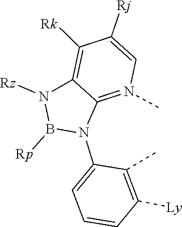 |
| L_{A}″24-(j)(k)(p), wherein each of j, k, and p is independently an integer from 1 to 55, wherein L_{A}″24-(1)(1)(1) to L_{A}″24-(55)(55)(55) having the structure | 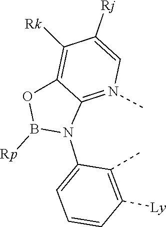 |
| L_{A}″25-(j)(k)(z), wherein each of j, k, and z is independently an integer from 1 to 55, wherein L_{A}″25-(1)(1)(1) to L_{A}″25-(55)(55)(55) having the structure | 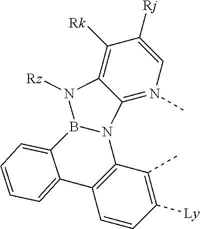 |
| L_{A}″26-(j)(k), wherein each of j, and k is independently an integer from 1 to 55, wherein L_{A}″26-(1)(1) to L_{A}″26- (55)(55) having the structure | 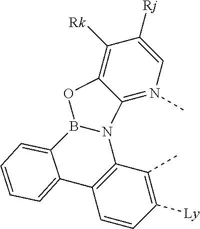 |
| L_{A}″27-(j), wherein j is an integer from 1 to 55, wherein L_{A}″27-(1) to L_{A}″27- (55) having the structure | 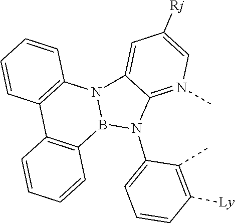 |
| L_{A}′′′28-(j)(k)(z), wherein each of j, k, and z is independently an integer from 1 to 55, wherein L_{A}′′′28-(1)(1)(1) to L_{A}′′′28-(55)(55)(55) having the structure | 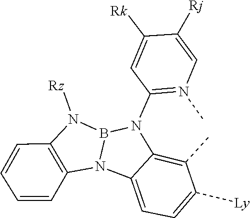 |
| L_{A}′′′′29-(j)(k)(z), wherein each of j, k, and z is independently an integer from 1 to 55, wherein L_{A}′′′′29-(1)(1)(1) to L_{A}′′′′29-(55)(55)(55) having the structure | 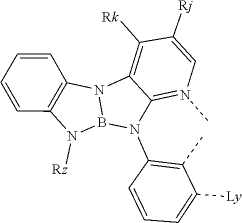 |
| L_{A}′′′′′30-(j)(k)(p)(z), wherein each of j, k, p, and z is independently an integer from 1 to 55, wherein L_{A}′′′′′30- (1)(1)(1)(1) to L_{A}′′′′′30- (55)(55)(55)(55) having the structure | 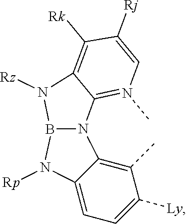 |

wherein Rj=Bj, Rk=Bk, Rp=Bp, and Rz=Bz, and
B1 to B55 have the following structures: 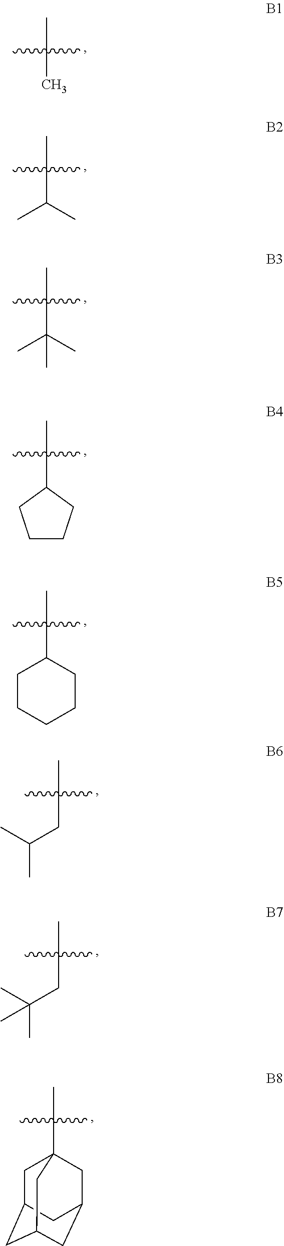 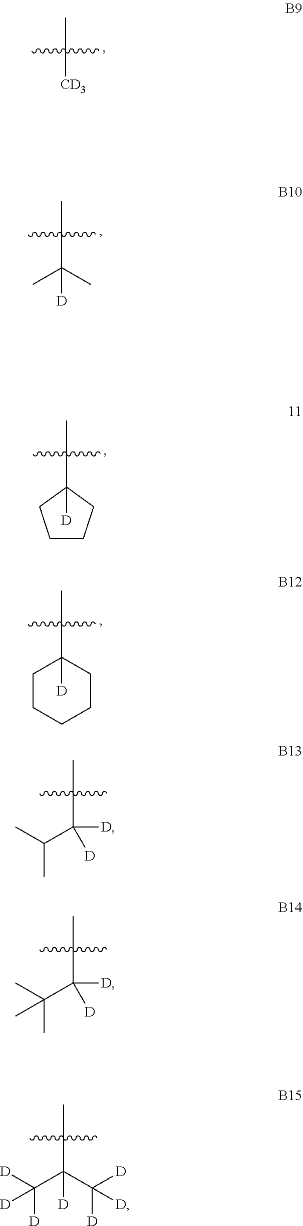 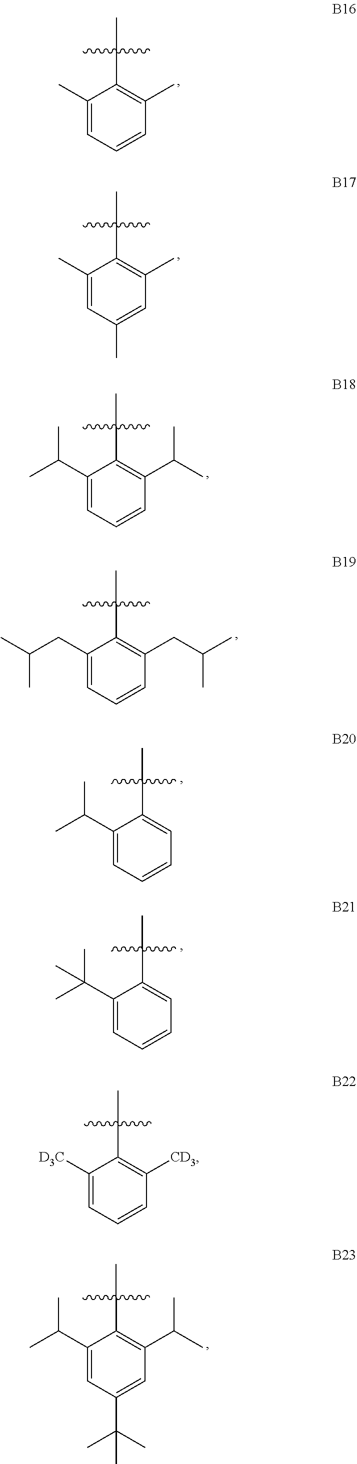 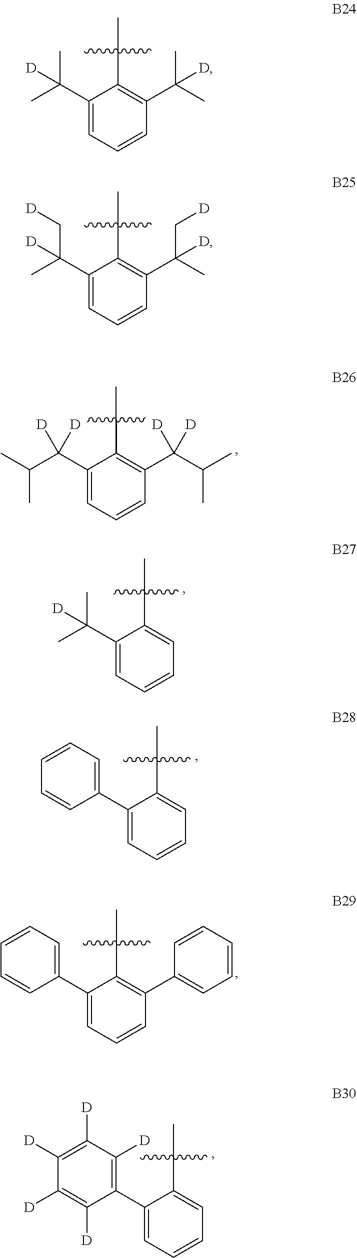 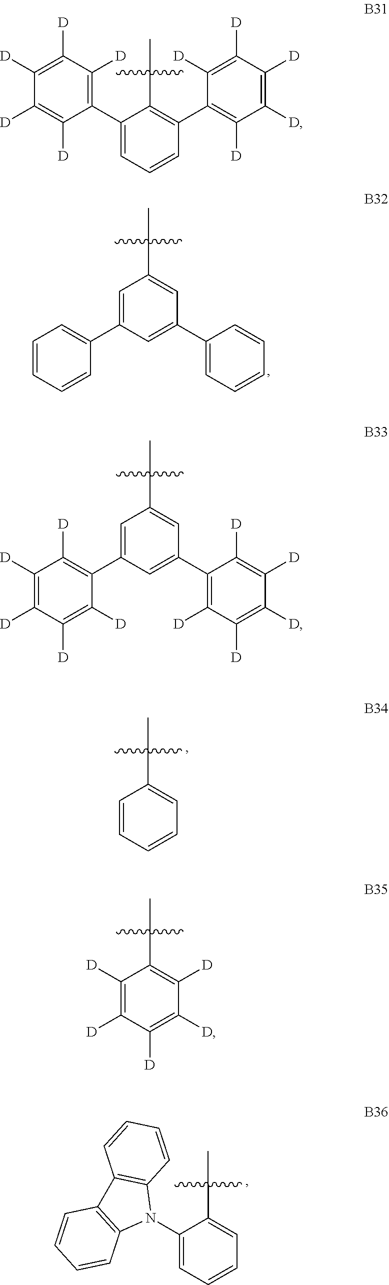 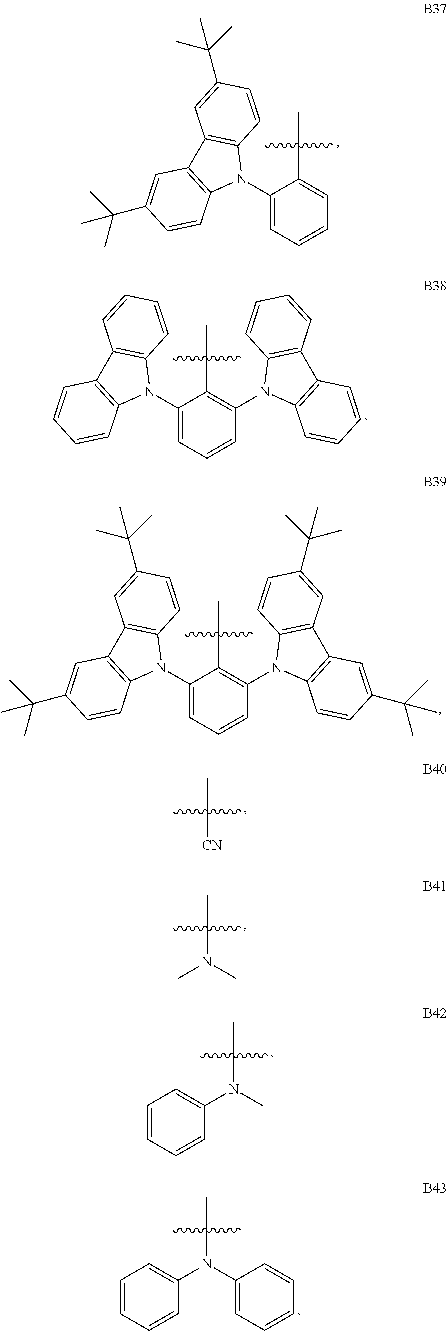 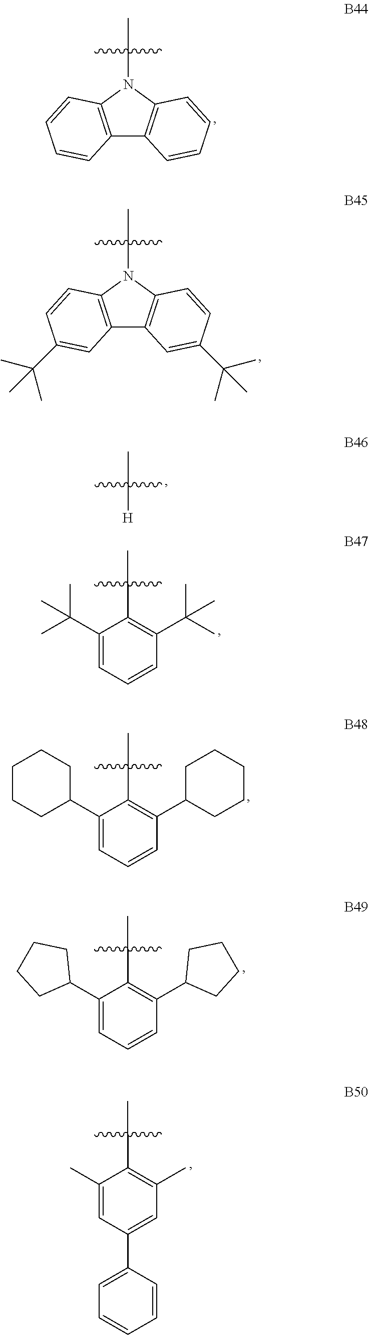 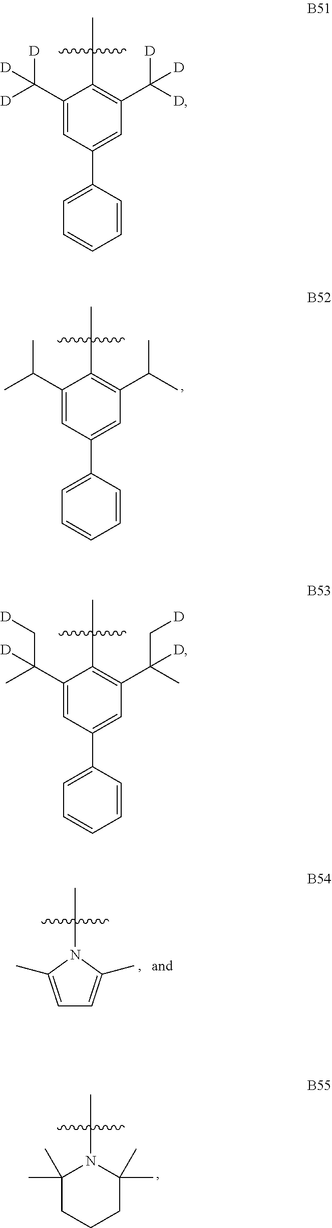
and L_{y} is selected from the group having the structures as shown below:

| L_{y} | Structure of L_{y} | R^{B1}-R^{B17} |
|---|---|---|
| L_{y}1-(i)(j)(k)(o), wherein i, j, k, and o are each independently an integer from 1 to 330, wherein L_{y}1- (1)(1)(1)(1) to L_{y}1- (330)(330)(330)(330), having the structure | 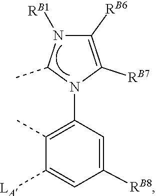 | wherein R^{B1} = Ri, R^{B6} = Rj, R^{B7} = Rk, and R^{B8} = Ro, |
| L_{y}2-(i)(j)(k), wherein i, j, and k are each independently an integer from 1 to 330, wherein L_{y}2-(1)(1)(1) to L_{y}2-(330)(330)(330), having the structure | 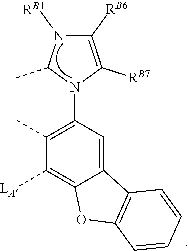 | wherein R^{B1} = Ri, R^{B6} = Rj, and R^{B7} = Rk, |
| L_{y}3-(i)(j)(k)(o), wherein i, j, k, and o are each an integer from 1 to 330, wherein L_{y}3-(1)(1)(1)(1) to L_{y}3- (330)(330)(330)(330), having the structure | 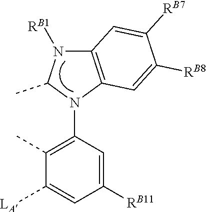 | wherein R^{B1} = Ri, R^{B7} = Rj, R^{B8} = Rk, and R^{B11} = Ro, |
| L_{y}4-(i)(j)(k), wherein i, j, and k are each an integer from 1 to 330, wherein L_{y}4-(1)(1)(1) to L_{y}4- (330)(330)(330), having the structure | 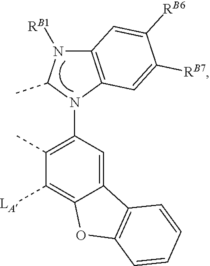 | wherein R^{B1} = Ri, R^{B6} = Rj, and R^{B7} = Rk, |
| L_{y}5-(i)(j)(k), wherein i, j, and k are each an integer from 1 to 330, wherein L_{y}5-(1)(1)(1) to L_{y}5- (330)(330)(330), having the structure | 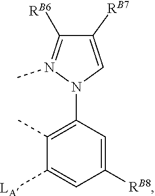 | wherein R^{B6} = Ri, R^{B7} = Rj, and R^{B8} = Rk, |
| L_{y}6-(i)(j), wherein i and j are each an integer from 1 to 330, wherein L_{y}6-(1)(1) to L_{y}6-(330)(330), having the structure | 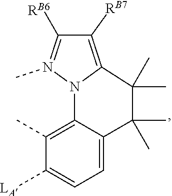 | wherein R^{B6} = Ri and R^{B7} = Rj, |
| L_{y}7-(i)(j)(k), wherein i, j, and k are each an integer from 1 to 330, wherein L_{y}7-(1)(1)(1) to L_{y}7- (330)(330)(330), having the structure | 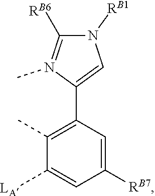 | wherein R^{B1} = Ri, R^{B6} = Rj, and R^{B7} = Rk, |
| L_{y}8-(i)(j), wherein i and j are each an integer from 1 to 330, wherein L_{y}8-(1)(1) to L_{y}8-(330)(330), having the structure | 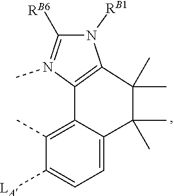 | wherein R^{B1} = Ri and R^{B6} = Rj, |
| L_{y}9-(i)(j)(k)(o), wherein i, j, k, and o are each an integer from 1 to 330, wherein L_{y}9-(1)(1)(1)(1) to L_{y}9- (330)(330)(330)(330), having the structure | 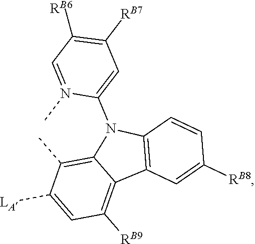 | wherein R^{B6} = Ri, R^{B7} = Rj, R^{B8} = Rk, and R^{B9} = Ro, |
| L_{y}10-(i)(j)(k), wherein i, j, and k are each an integer from 1 to 330, wherein L_{y}10-(1)(1)(1) to L_{y}10- (330)(330)(330), having the structure | 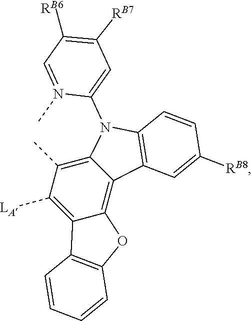 | wherein R^{B6} = Ri, R^{B7} = Rj, and R^{B8} = Rk, |
| L_{y}11-(i)(j)(k), wherein i, j, and k are each an integer from 1 to 330, wherein L_{y}11-(1)(1)(1) to L_{y}11- (330)(330)(330), having the structure | 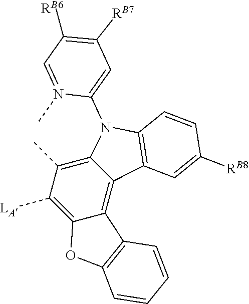 | wherein R^{B6} = Ri, R^{B7} = Rj, and R^{B8} = Rk, |
| L_{y}12-(i)(j)(k)(o), wherein i, j, k, and o are each an integer from 1 to 330, wherein L_{y}12-(1)(1)(1)(1) to L_{y}12- (330)(330)(330)(330), having the structure | 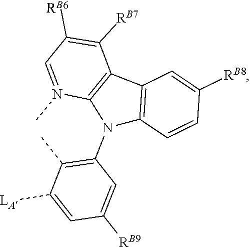 | wherein R^{B6} = Ri, R^{B7} = Rj, R^{B8} = Rk, and R^{B9} = Ro, |
| L_{y}13-(i)(j)(k), wherein i, j, and k are each an integer from 1 to 330, wherein L_{y}13-(1)(1)(1) to L_{y}13- (330)(330)(330), having the structure | 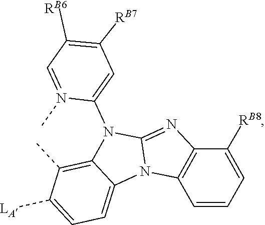 | wherein R^{B6} = Ri, R^{B7} = Rj, and R^{B8} = Rk, |
| L_{y}14-(i)(j)(k), wherein i, j, and k are each an integer from 1 to 330, wherein L_{y}14-(1)(1)(1) to L_{y}14- (330)(330)(330), having the structure | 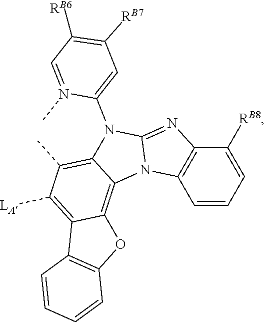 | wherein R^{B6} = Ri, R^{B7} = Rj, and R^{B8} = Rk, |
| L_{y}15-(i)(j)(k), wherein i, j, and k are each an integer from 1 to 330, wherein L_{y}15-(1)(1)(1) to L_{y}15- (330)(330)(330), having the structure | 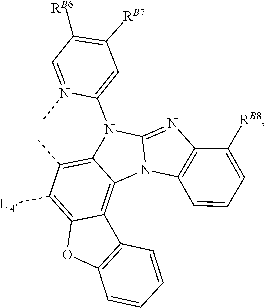 | wherein R^{B6} = Ri, R^{B7} = Rj, and R^{B8} = Rk, |
| L_{y}16-(i)(j)(k)(o), wherein i, j, k, and o are each an integer from 1 to 330, wherein L_{y}16-(1)(1)(1)(1) to L_{y}16- (330)(330)(330)(330), having the structure | 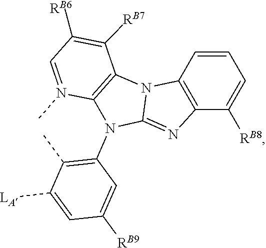 | wherein R^{B6} = Ri, R^{B7} = Rj, R^{B8} = Rk, and R^{B9} = Ro, |
| L_{y}17-(i)(j)(k), wherein i, j, and k are each an integer from 1 to 330, wherein L_{y}17-(1)(1)(1) to L_{y}17- (330)(330)(330), having the structure | 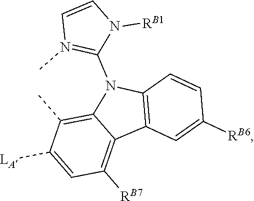 | wherein R^{B1} = Ri, R^{B6} = Rj, and R^{B7} = Rk, |
| L_{y}18-(i)(j), wherein i and j are each an integer from 1 to 330, wherein L_{y}18-(1)(1) to L_{y}18-(330)(330), having the structure | 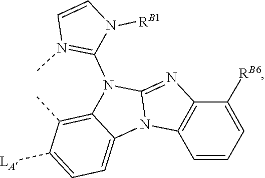 | wherein R^{B1} = Ri and R^{B6} = Rj, |
| L_{y}19-(i)(j)(k), wherein i, j, and k are each an integer from 1 to 330, wherein L_{y}19-(1)(1)(1) to L_{y}19- (330)(330)(330), having the structure | 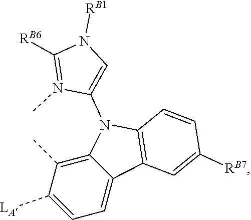 | wherein R^{B1} = Ri, R^{B6} = Rj, and R^{B7} = Rk, |
| L_{y}20-(i)(j)(k), wherein i, j, and k are each an integer from 1 to 330, wherein L_{y}20-(1)(1)(1) to L_{y}20- (330)(330)(330), having the structure | 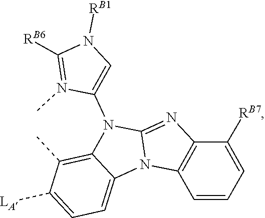 | wherein R^{B1} = Ri, R^{B6} = Rj, and R^{B7} = Rk, |
| L_{y}21-(i)(j)(k), wherein i, j, and k are each an integer from 1 to 330, wherein L_{y}21-(1)(1)(1) to L_{y}21- (330)(330)(330), having the structure | 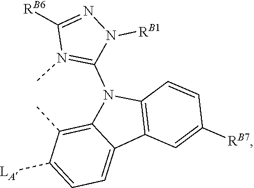 | wherein R^{B1} = Ri, R^{B6} = Rj, and R^{B7} = Rk, |
| L_{y}22-(i)(j)(k), wherein i, j, and k are each an integer from 1 to 330, wherein L_{y}22-(1)(1)(1) to L_{y}22- (330)(330)(330), having the structure | 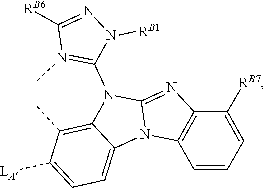 | wherein R^{B1} = Ri, R^{B6} = Rj, and R^{B7} = Rk, |
| L_{y}23-(i)(j)(k), wherein i, j, and k are each an integer from 1 to 330, wherein L_{y}23-(1)(1)(1) to L_{y}23- (330)(330)(330), having the structure | 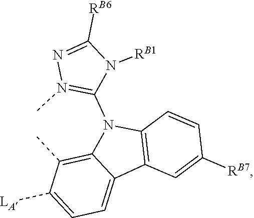 | wherein R^{B1} = Ri, R^{B6} = Rj, and R^{B7} = Rk, |
| L_{y}24-(i)(j)(k), wherein i, j, and k are each an integer from 1 to 330, wherein L_{y}24-(1)(1)(1) to L_{y}24- (330)(330)(330), having the structure | 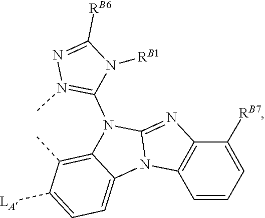 | wherein R^{B1} = Ri, R^{B6} = Rj, and R^{B7} = Rk, |
| L_{y}25-(i)(j)(k), wherein i, j, and k are each an integer from 1 to 330, wherein L_{y}25-(1)(1)(1) to L_{y}25- (330)(330)(330), having the structure | 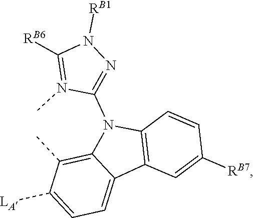 | wherein R^{B1} = Ri, R^{B6} = Rj, and R^{B7} = Rk, |
| L_{y}26-(i)(j)(k), wherein i, j, and k are each an integer from 1 to 330, wherein L_{y}26-(1)(1)(1) to L_{y}26- (330)(330)(330), having the structure | 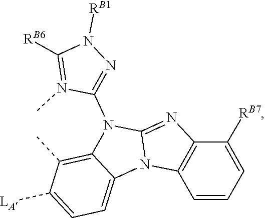 | wherein R^{B1} = Ri, R^{B6} = Rj, and R^{B7} = Rk, |
| L_{y}27-(i)(j)(k)(o), wherein i, j, k, and o are each an integer from 1 to 330, wherein L_{y}27-(1)(1)(1)(1) to L_{y}27- (330)(330)(330)(330), having the structure | 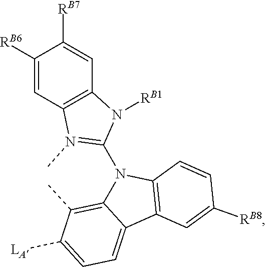 | wherein R^{B1} = Ri, R^{B6} = Rj, R^{B7} = Rk, and R^{B8} = Ro, |
| L_{y}28-(i)(j)(k)(o), wherein i, j, k, and o are each an integer from 1 to 330, wherein L_{y}28-(1)(1)(1)(1) to L_{y}28- (330)(330)(330)(330), having the structure | 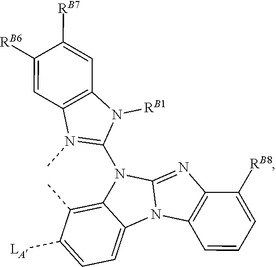 | wherein R^{B1} = Ri, R^{B6} = Rj, R^{B7} = Rk, and R^{B8} = Ro, |
| L_{y}29-(i)(j)(k), wherein i, j, and k are each an integer from 1 to 330, wherein L_{y}29-(1)(1)(1) to L_{y}29- (330)(330)(330), having the structure | 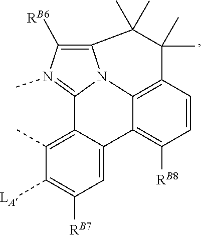 | wherein R^{B6} = Ri, R^{B7} = Rj, and R^{B8} = Rk, |
| L_{y}30-(i)(j)(k)(o), wherein i, j, k, and o are each an integer from 1 to 330, wherein L_{y}30-(1)(1)(1)(1) to L_{y}30- (330)(330)(330)(330), having the structure | 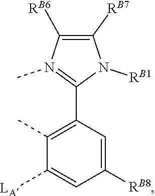 | wherein R^{B1} = Ri, R^{B6} = Rj, R^{B7} = Rk, and R^{B8} = Ro, |
| L_{y}31-(i)(j)(k), wherein i, j, and k are each an integer from 1 to 330, wherein L_{y}31-(1)(1)(1) to L_{y}31- (330)(330)(330), having the structure | 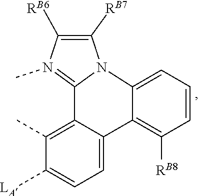 | wherein R^{B6} = Ri, R^{B7} = Rj, and R^{B8} = Rk. |
| L_{y}32-(i)(j)(k), wherein i, j, and k are each an integer from 1 to 330, wherein L_{y}32-(1)(1)(1) to L_{y}32- (330)(330)(330), having the structure | 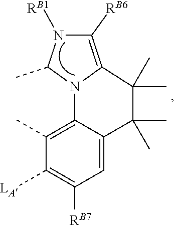 | wherein R^{B1} = Ri, R^{B6} = Rj, and R^{B7} = Rk, |
| L_{y}33-(i)(j), wherein i and j are each an integer from 1 to 330, wherein L_{y}33-(1)(1) to L_{y}33-(330)(330), having the structure | 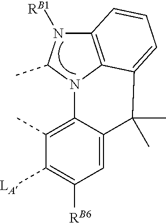 | wherein R^{B1} = Ri and R^{B6} = Rj, |
| L_{y}34-(i)(j), wherein i and j are each an integer from 1 to 330, wherein L_{y}34-(1)(1) to L_{y}34-(330)(330), having the structure | 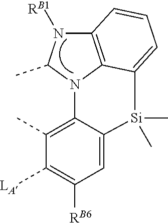 | wherein R^{B1} = Ri and R^{B6} = Rj, |
| L_{y}35-(i)(j)(k)(o), wherein i, j, k, and o are each an integer from 1 to 330, wherein L_{y}35-(1)(1)(1)(1) to L_{y}35- (330)(330)(330)(330), having the structure | 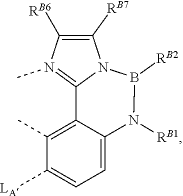 | wherein R^{B1} = Ri, R^{B2} = Rj, R^{B6} = Rk, and R^{B7} = Ro, |
| L_{y}36-(i)(j), wherein i and j are each an integer from 1 to 330, wherein L_{y}36-(1)(1) to L_{y}36-(330)(330), having the structure | 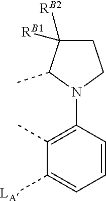 | wherein R^{B1} = Ri and R^{B2} = Rj, |
| L_{y}37-(i)(j)(k) wherein each of i, j, and k is independently an integer from 1 to 330, wherein L_{y}37- (1)(1)(1) to L_{y}37-(330)(330)(330) having the structure | 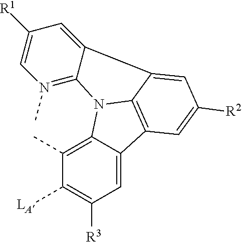 | wherein R¹ = Ri, R² = Rj, and R³ = Rk, and |
| L_{y}38-(i)(j) wherein each of i and j is independently an integer from 1 to 330, wherein L_{y}38-(1)(1) to L_{y}38- (330)(330) having the structure | 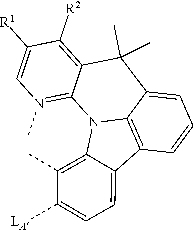 | wherein R¹ = Ri and R² = Rj, and |
| L_{y}39-(i)(j) wherein each of i and j is independently an integer from 1 to 330, wherein L_{y}39-(1)(1) to L_{y}39- (330)(330) having the structure | 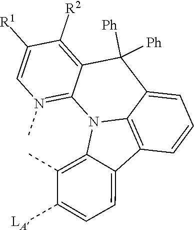 | wherein R¹ = Ri and R² = Rj, and |
| L_{y}40-(i)(j) wherein each of i and j is independently an integer from 1 to 330, wherein L_{y}40-(1)(1) to L_{y}40- (330)(330) having the structure | 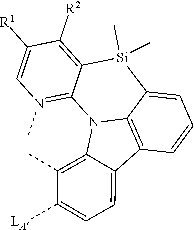 | wherein R¹ = Ri and R² = Rj, and |
| L_{y}41-(i)(j) wherein each of i and j is independently an integer from 1 to 330, wherein L_{y}41-(1)(1) to L_{y}41- (330)(330) having the structure | 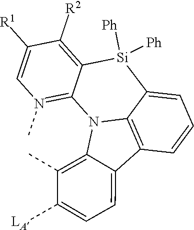 | wherein R¹ = Ri and R² = Rj, and |
| L_{y}42-(i)(j)(k)(1) wherein each of i, j, k, and / is independently an integer from 1 to 330, L_{y}42-(1)(1)(1)(1) to L_{y}42-(330)(330)(330)(330) having the structure | 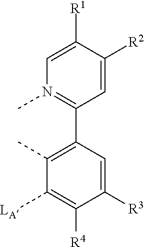 | wherein R¹ = Ri, R² = Rj, R³ = Rk, and R⁴ = Rl, and |
| L_{y}43-(i)(j)(k)(l) wherein each of i, j, k, and / is independently an integer from 1 to 330, wherein L_{y}43- (1)(1)(1)(1) to L_{y}43- (330)(330)(330)(330) having the structure | 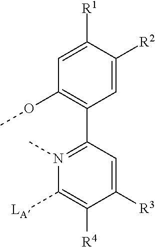 | wherein R¹ = Ri, R² = Rj, R³ = Rk, and R⁴ = Rl. |
| L_{y}44-(i)(j)(k)(I)(m), wherein i, j, k, l, and m are each independently an integer from 1 to 330, wherein L_{y}44- (1)(1)(1)(1)(1) to L_{y}44- (330)(330)(330)(330)(330), having the structure | 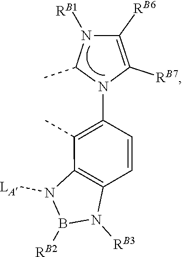 | wherein R^{B1} = Ri, R^{B2} = Rj, R^{B3} = Rk, R^{B6} = Rl, and R^{B7} = Rm, |
| L_{y}45-(i)(j)(k)(l)(m), wherein i, j, k, l, and m are each independently an integer from 1 to 330, wherein L_{y}45- (1)(1)(1)(1)(1) to L_{y}45- (330)(330)(330)(330)(330), having the structure | 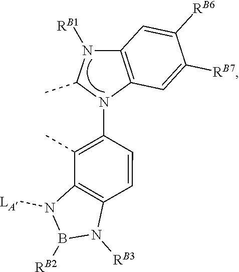 | wherein R^{B1} = Ri, R^{B2} = Rj, R^{B3} = Rk, R^{B6} = Rl, and R^{B7} = Rm, |
| L_{y}46-(i)(j)(k)(l)(m), wherein i, j, k, l, and m are each independently an integer from 1 to 330, wherein L_{y}46- (1)(1)(1)(1)(1) to L_{y}46- (330)(330)(330)(330)(330), having the structure | 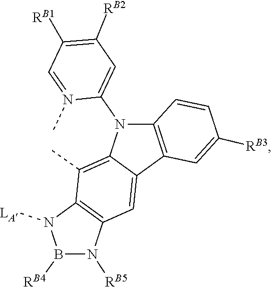 | wherein R^{B1} = Ri, R^{B2} = Rj, R^{B3} = Rk, R^{B4} = Rl, and R^{B5} = Rm, |
| L_{y}47-(i)(j)(k)(l)(m), wherein i, j, k, l, and m are each independently an integer from 1 to 330, wherein L_{y}47- (1)(1)(1)(1)(1) to L_{y}47- (330)(330)(330)(330)(330), having the structure | 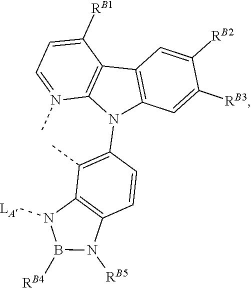 | wherein R^{B1} = Ri, R^{B2} = Rj, R^{B3} = Rk, R^{B4} = Rl, and R^{B5} = Rm, |
| L_{y}48-(i)(j)(k)(1) wherein i, j, k, and l are each independently an integer from 1 to 330, wherein L_{y}48- (1)(1)(1)(1) to L_{y}48- (330)(330)(330)(330), having the structure | 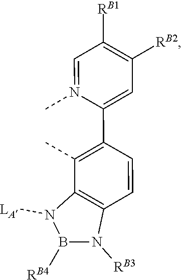 | wherein R^{B1} = Ri, R^{B2} = Rj, R^{B3} = Rk, and R^{B4} = Rl, |
| L_{y}49-(i)(j)(k)(l) wherein i, j, k, and l are each independently an integer from 1 to 330, wherein L_{y}49- (1)(1)(1)(1) to L_{y}49- (330)(330)(330)(330), having the structure | 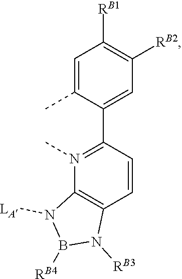 | wherein R^{B1} = Ri, R^{B2} = Rj, R^{B3} = Rk, and R^{B4} = Rl, |
| L_{y}50-(i)(j)(k)(1) wherein i, j, k, and l are each independently an integer from 1 to 330, wherein L_{y}50- (1)(1)(1)(1) to L_{y}50- (330)(330)(330)(330), having the structure | 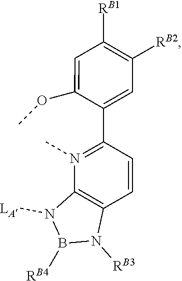 | wherein R^{B1} = Ri, R^{B2} = Rj, R^{B3} = Rk, and R^{B4} = Rl, |

wherein R¹ to R³³⁰ have the following structures:

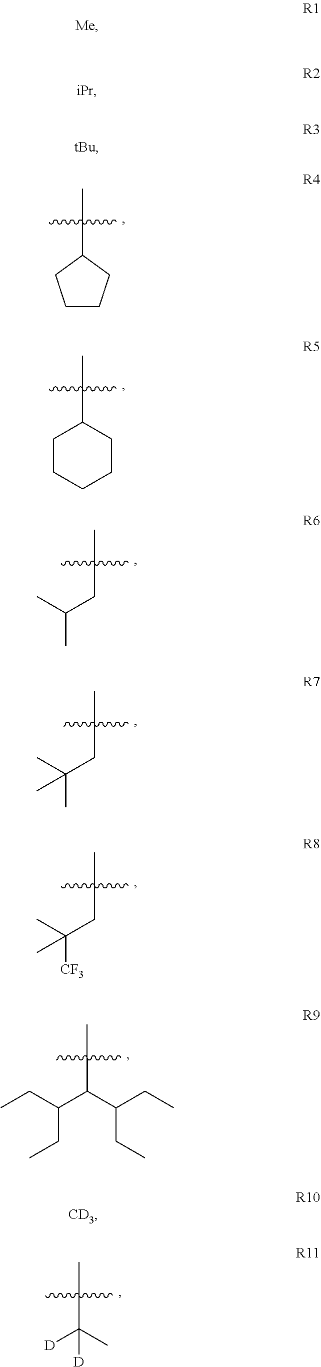

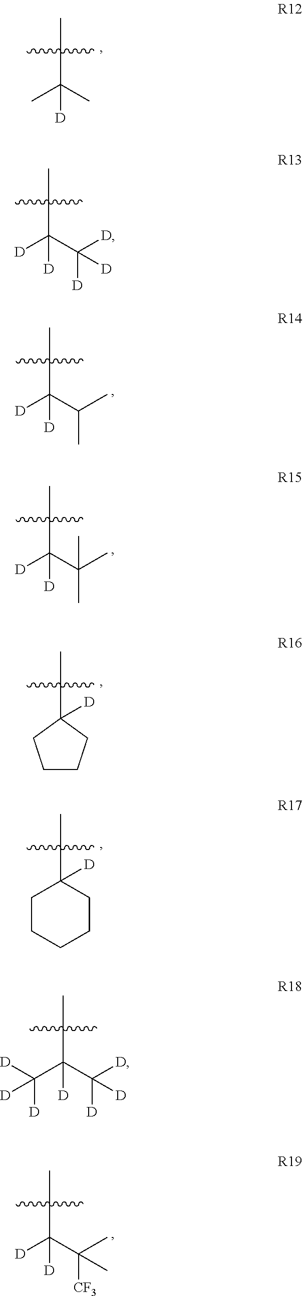

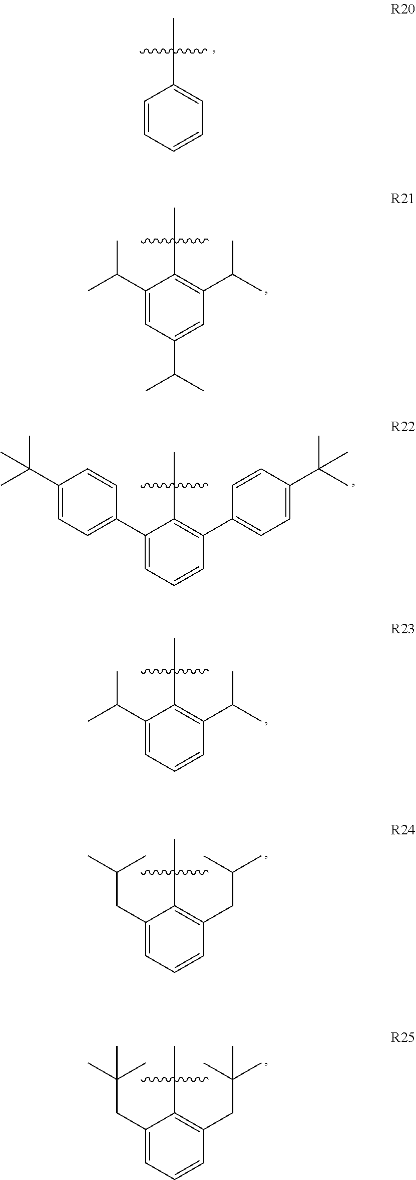

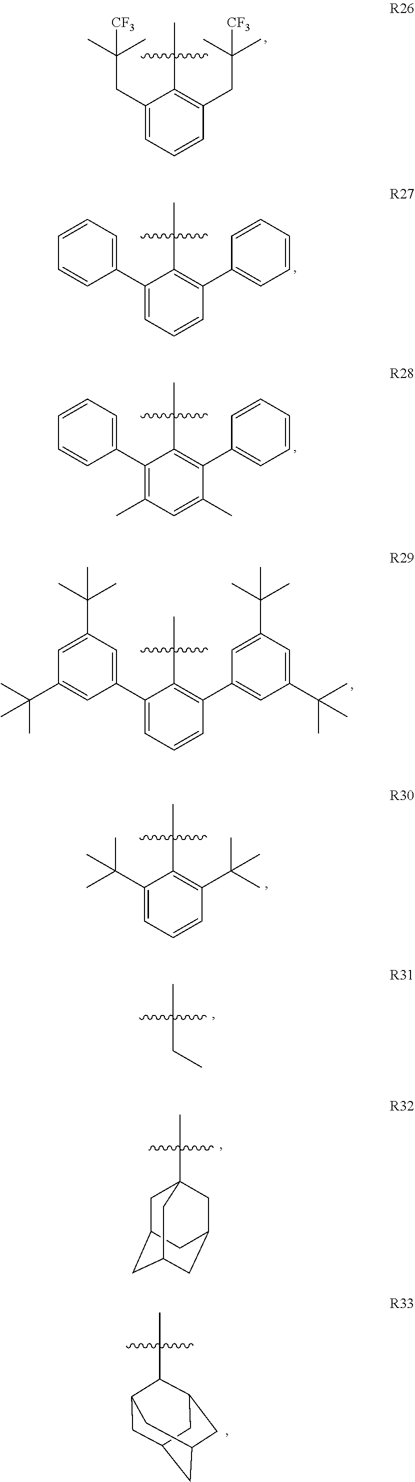

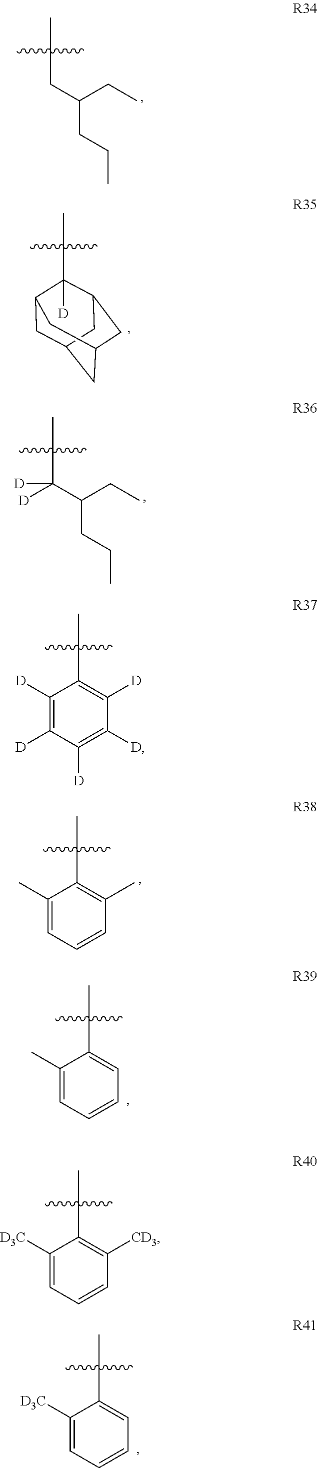

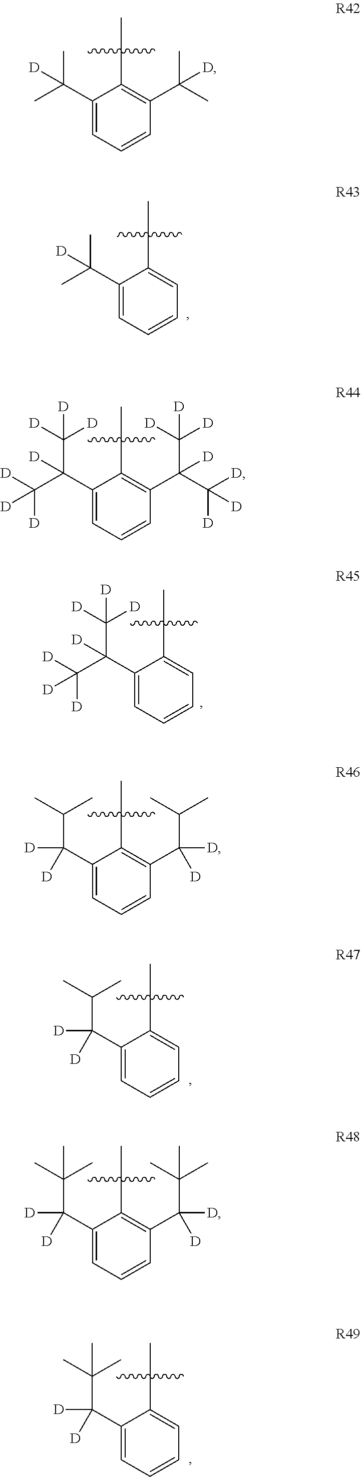

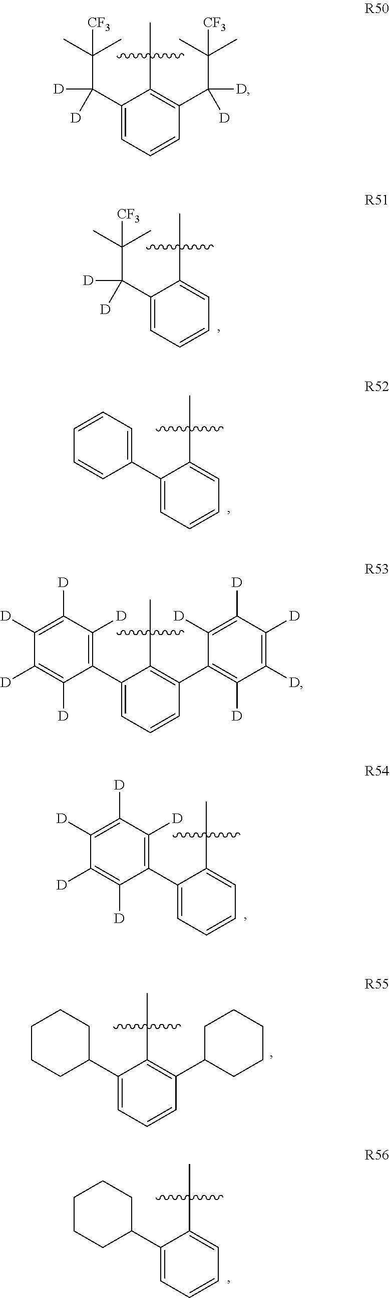

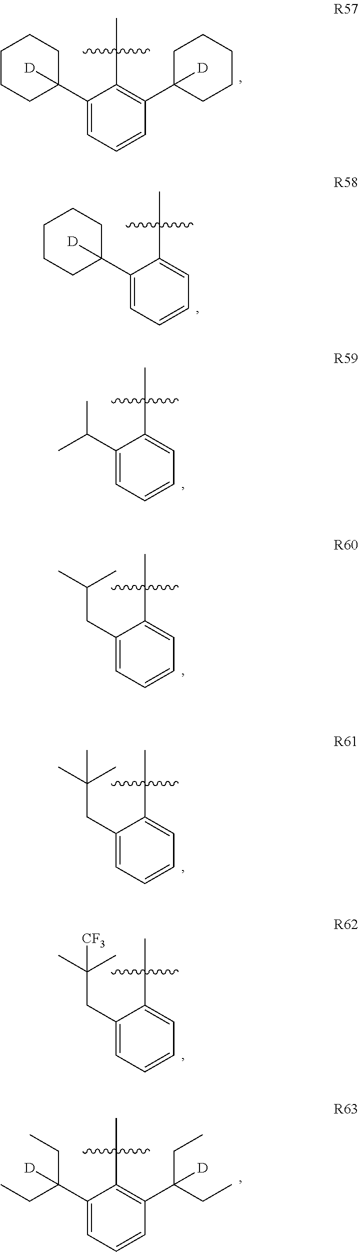

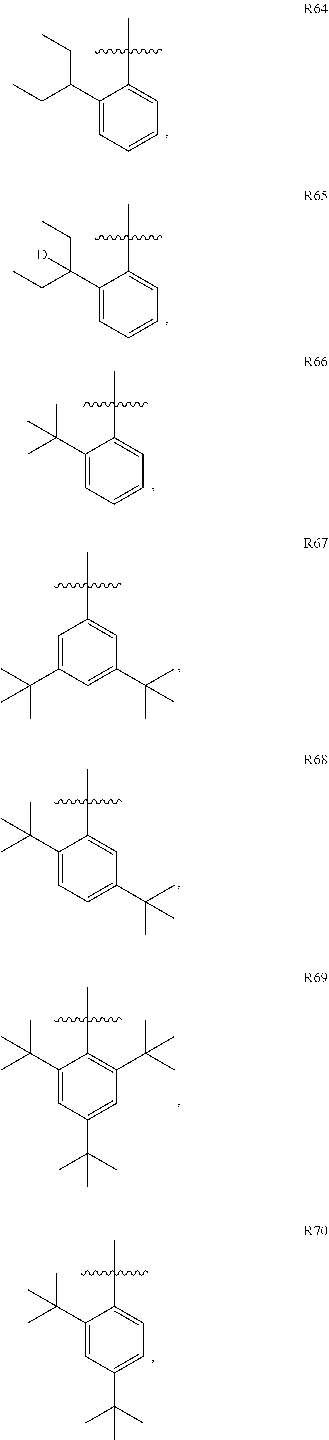

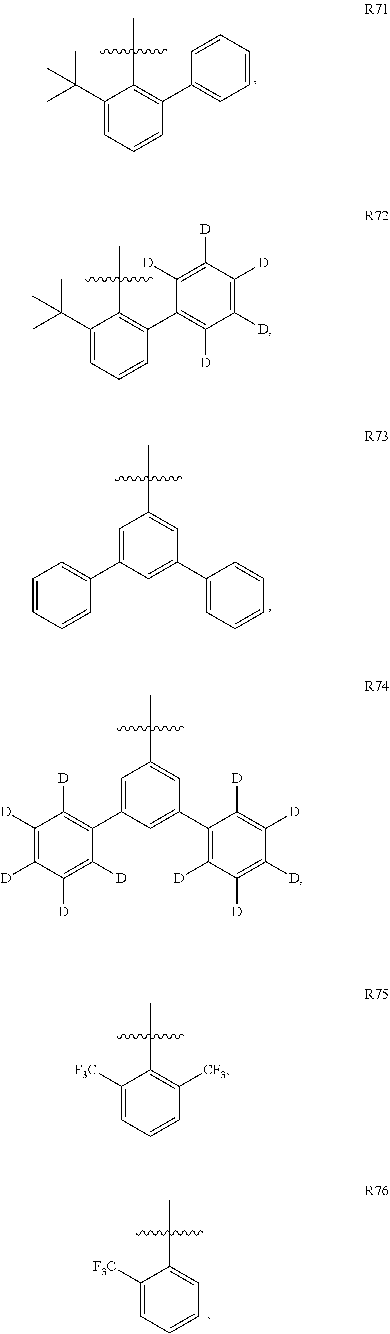

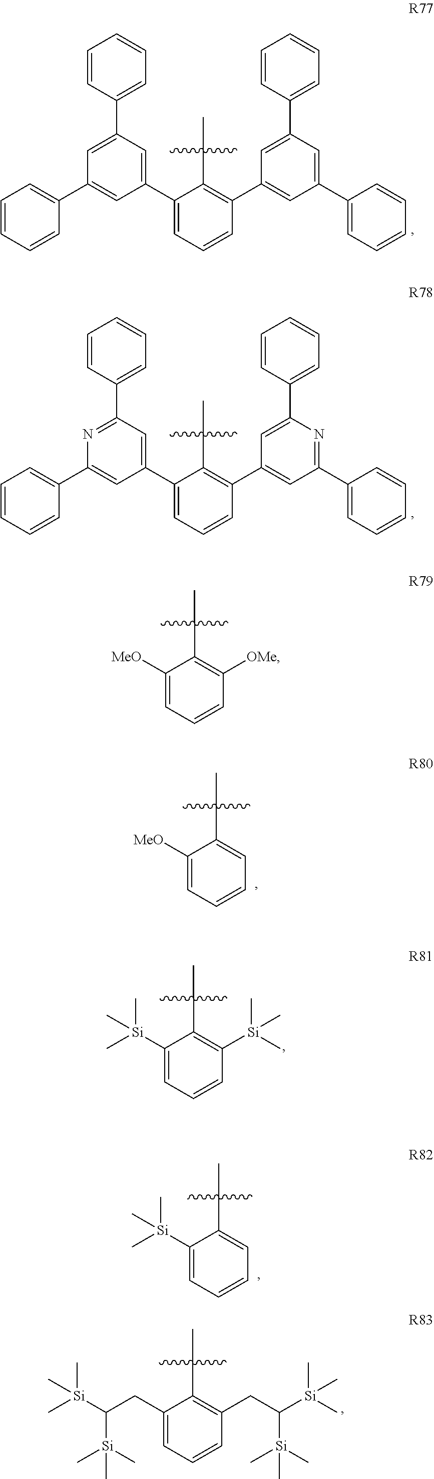

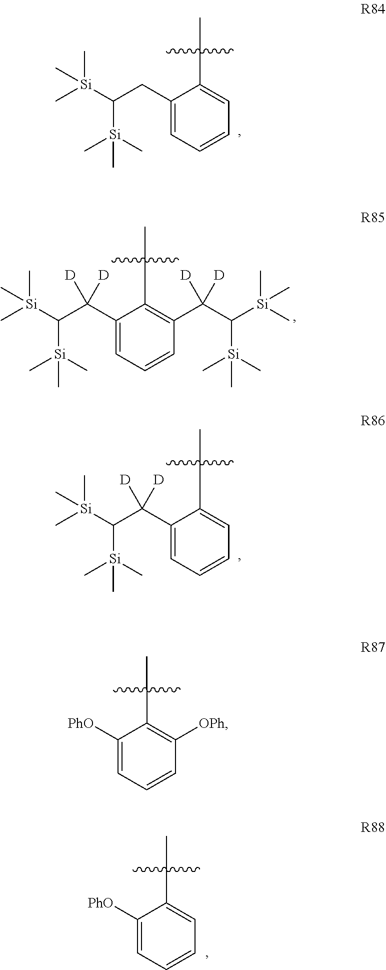

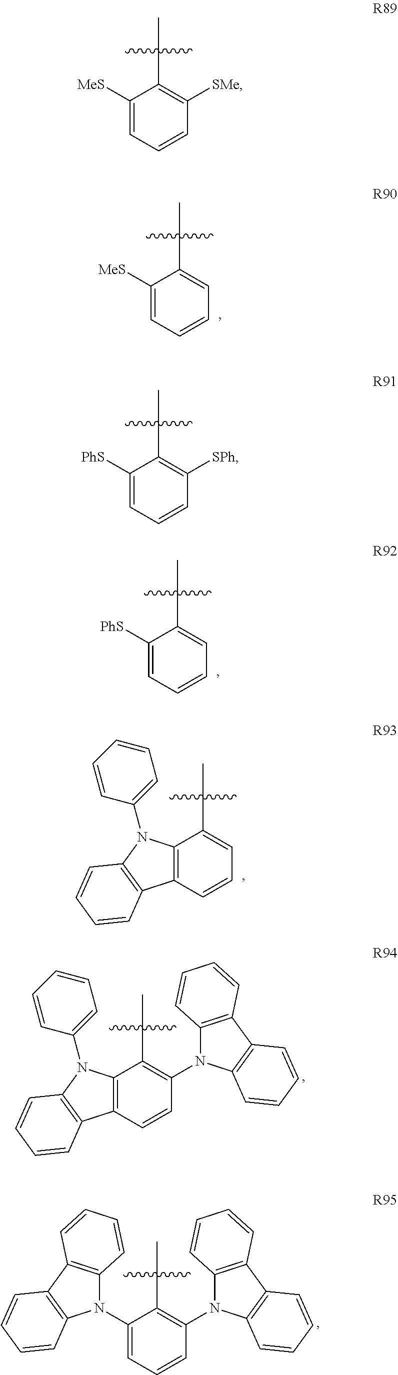

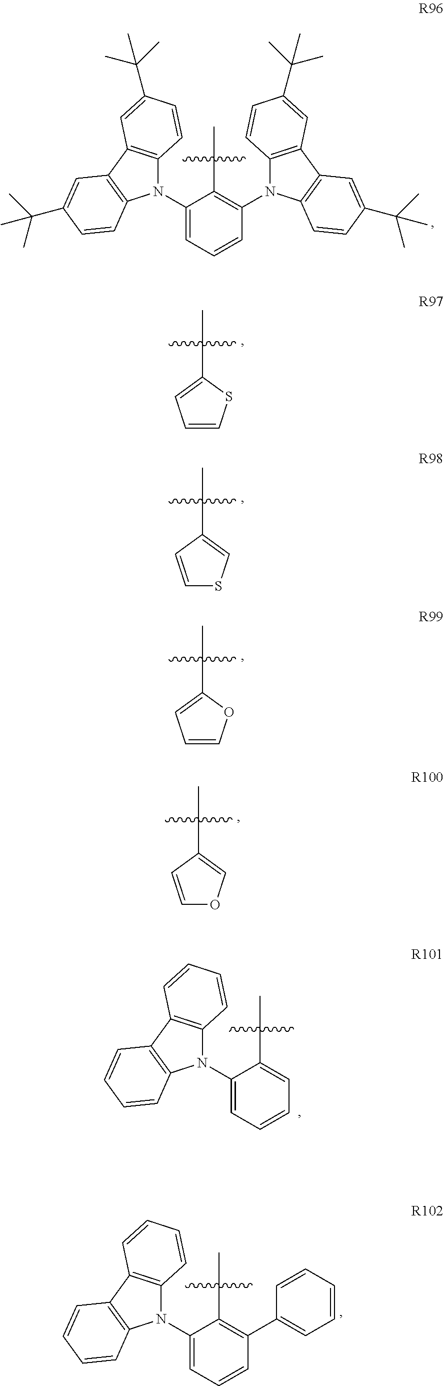

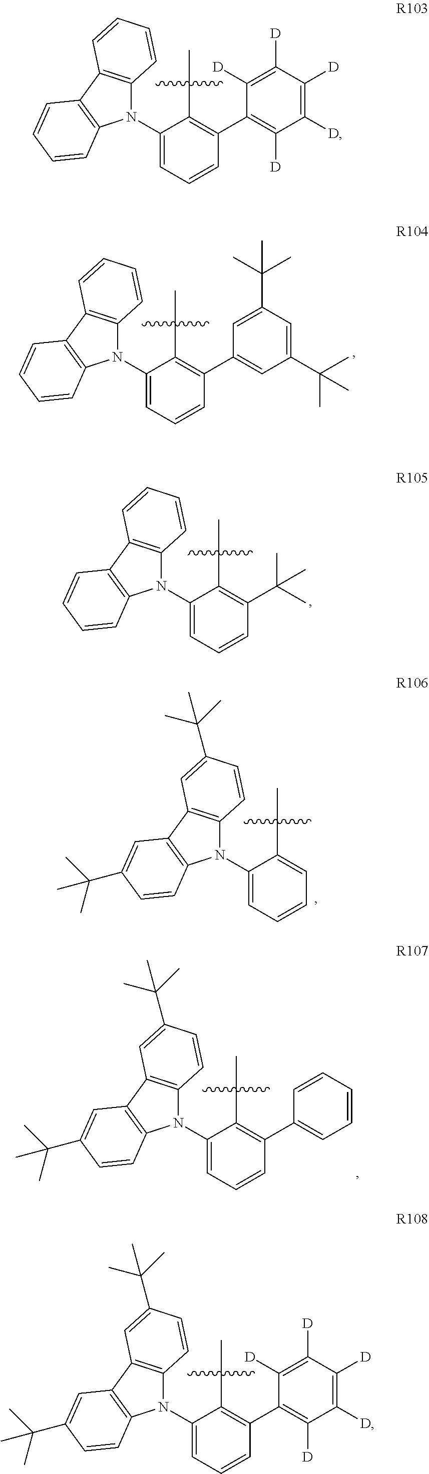

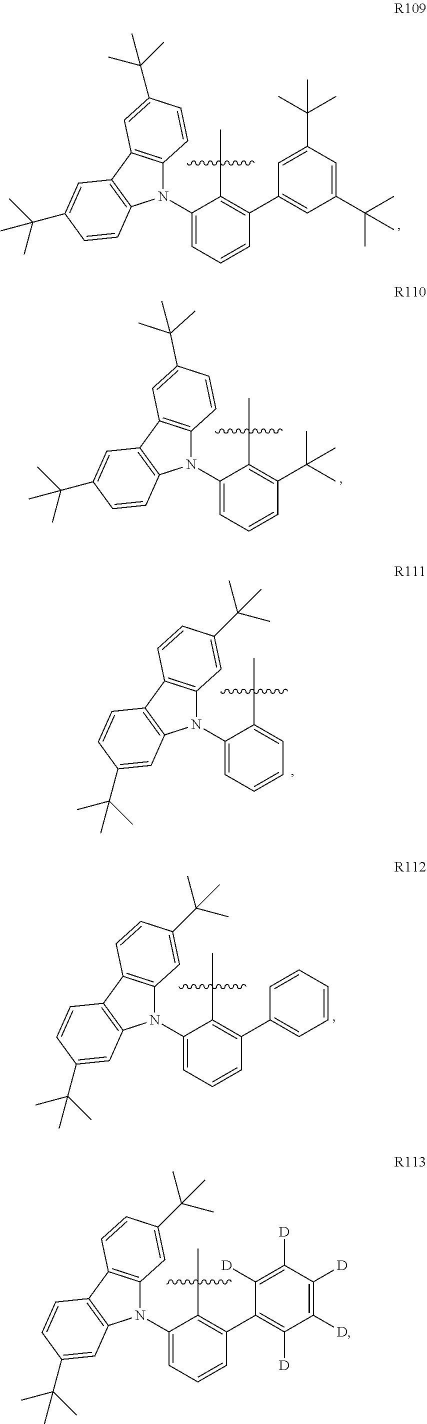

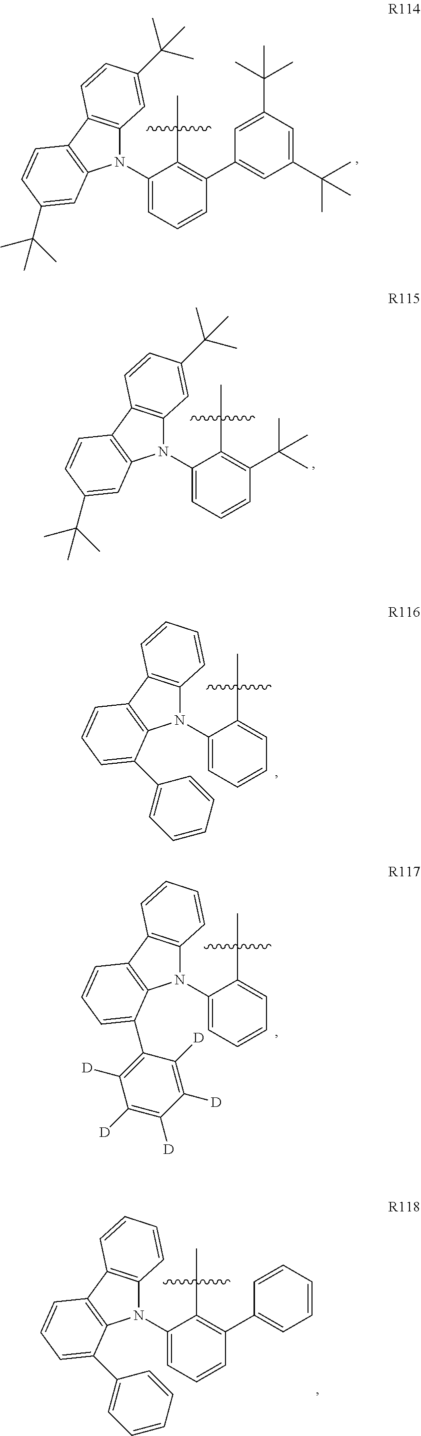

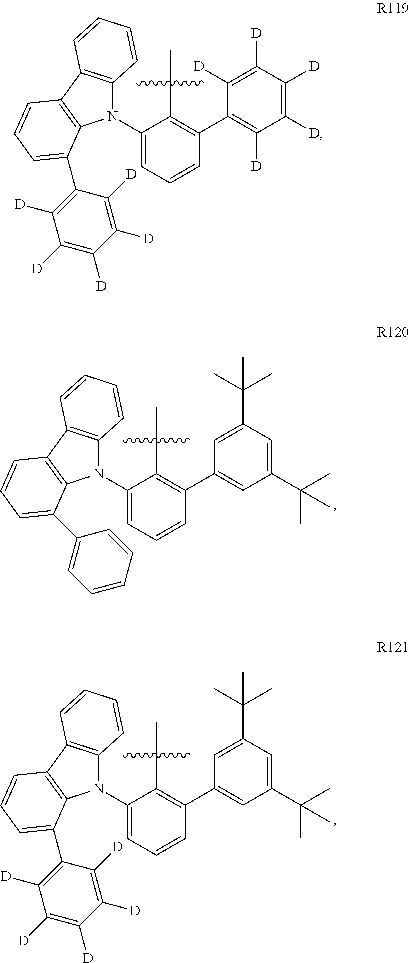

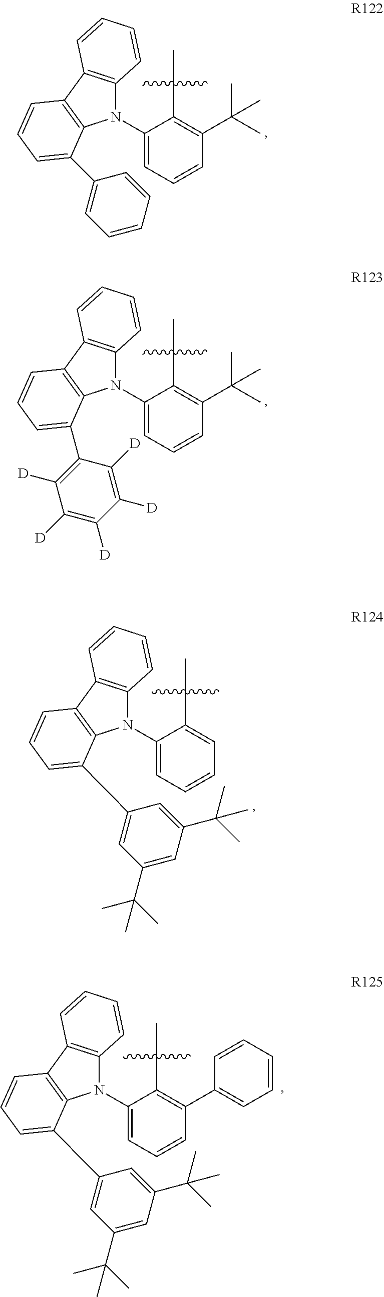 [SMILES: *c1c(-n2c3ccccc3c3cccc(-c4ccccc4)c32)cccc1C(C)(C)C ; *c1c(-n2c3ccccc3c3cccc(-c4c([2H])c([2H])c([2H])c([2H])c4[2H])c32)cccc1C(C)(C)C ; *c1ccccc1-n1c2ccccc2c2cccc(-c3cc(C(C)(C)C)cc(C(C)(C)C)c3)c21 ; *c1c(-c2ccccc2)cccc1-n1c2ccccc2c2cccc(-c3cc(C(C)(C)C)cc(C(C)(C)C)c3)c21]

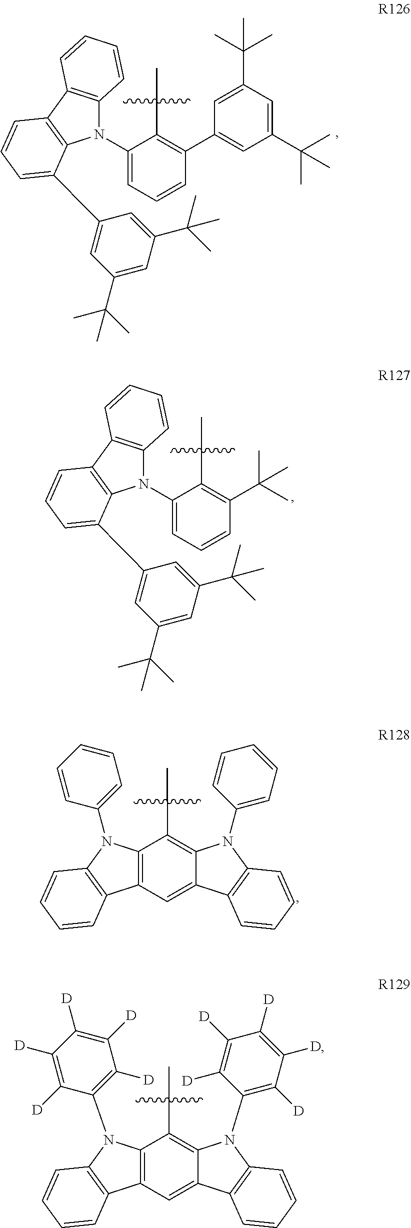

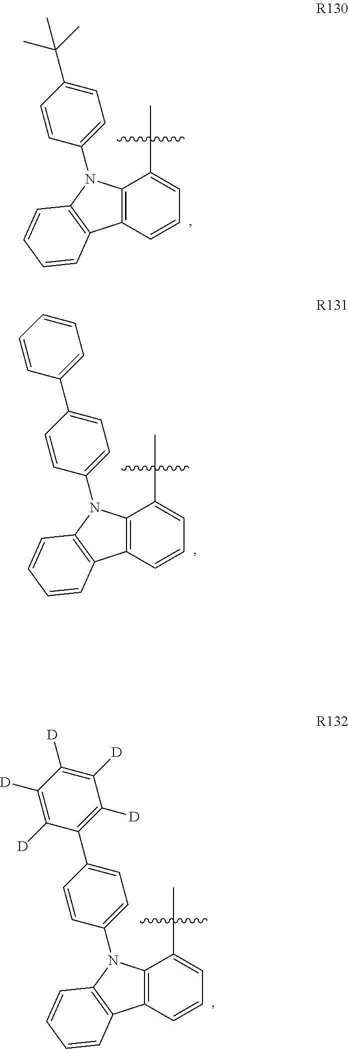 [SMILES: *c1cccc2c3ccccc3n(-c3ccc(C(C)(C)C)cc3)c12 ; *c1cccc2c3ccccc3n(-c3ccc(-c4ccccc4)cc3)c12 ; *c1cccc2c3ccccc3n(-c3ccc(-c4c([2H])c([2H])c([2H])c([2H])c4[2H])cc3)c12]

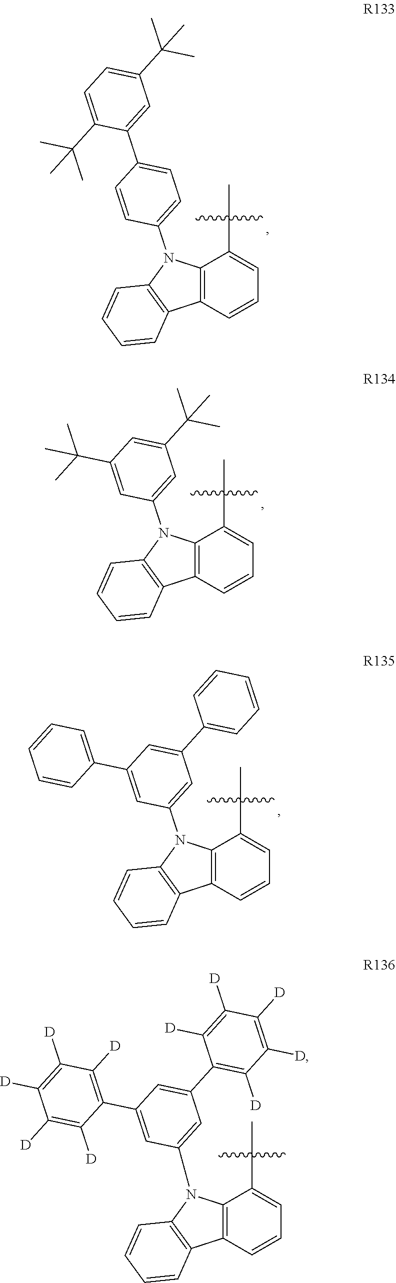

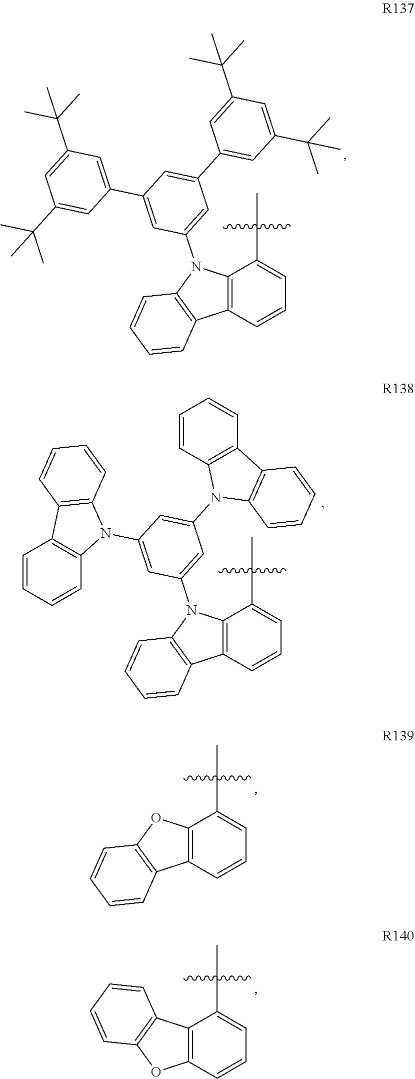 [SMILES: *c1cccc2c3ccccc3n(-c3cc(-c4cc(C(C)(C)C)cc(C(C)(C)C)c4)cc(-c4cc(C(C)(C)C)cc(C(C)(C)C)c4)c3)c12 ; *c1cccc2c3ccccc3n(-c3cc(-n4c5ccccc5c5ccccc54)cc(-n4c5ccccc5c5ccccc54)c3)c12 ; *c1cccc2c1oc1ccccc12 ; *c1cccc2oc3ccccc3c12]

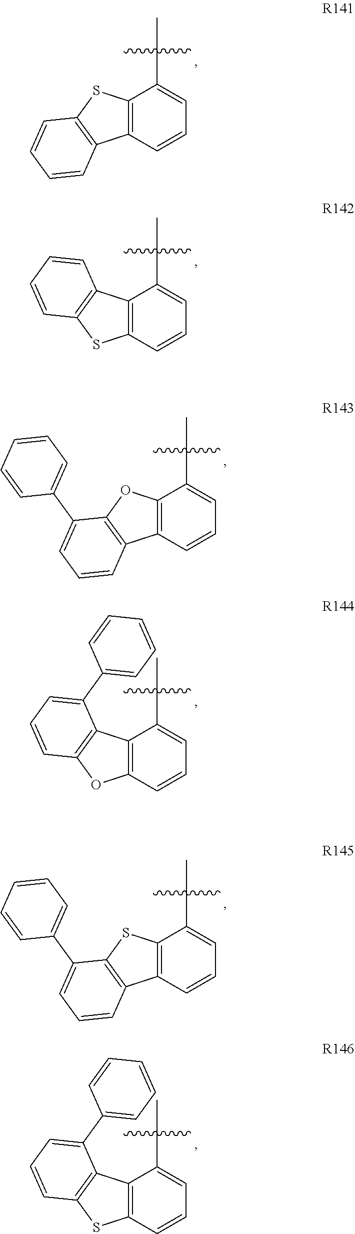

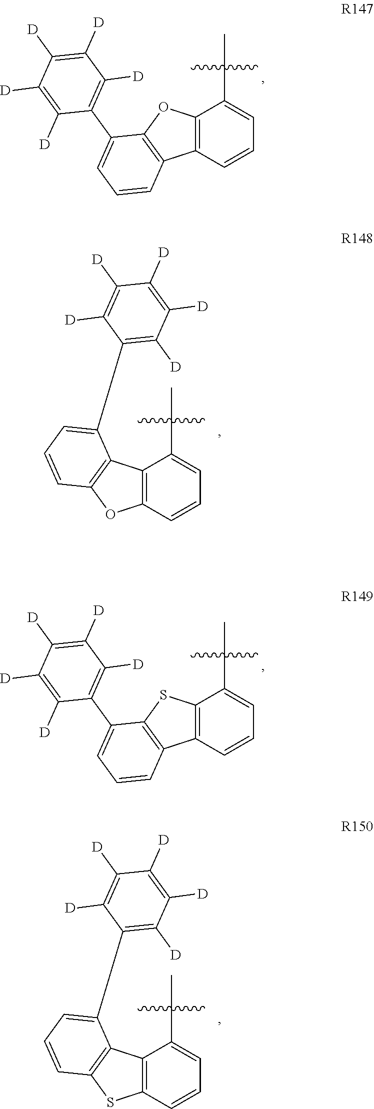 [SMILES: *c1cccc2c1oc1c(-c3c([2H])c([2H])c([2H])c([2H])c3[2H])cccc12 ; *c1cccc2oc3cccc(-c4c([2H])c([2H])c([2H])c([2H])c4[2H])c3c12 ; *c1cccc2c1sc1c(-c3c([2H])c([2H])c([2H])c([2H])c3[2H])cccc12 ; *c1cccc2sc3cccc(-c4c([2H])c([2H])c([2H])c([2H])c4[2H])c3c12]

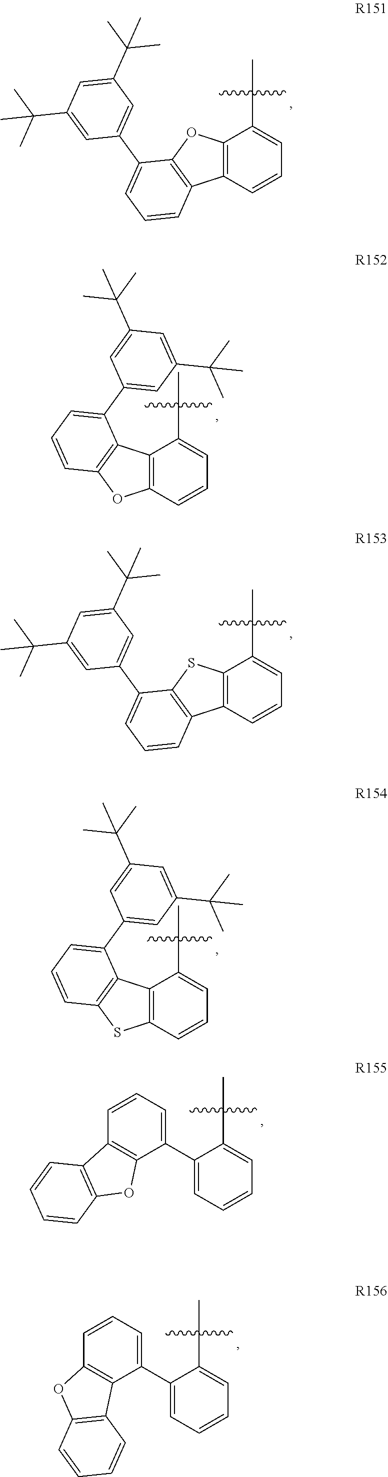

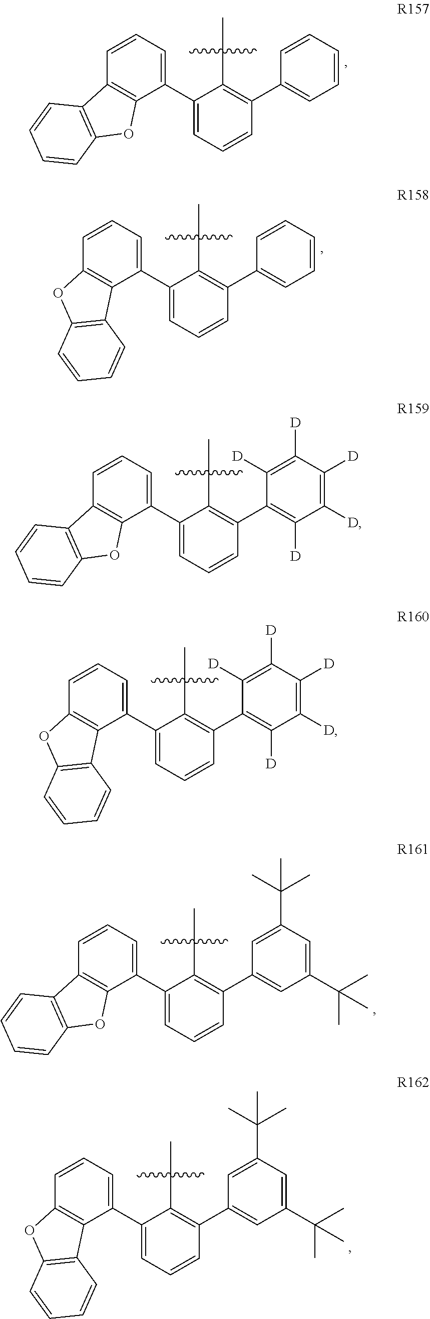

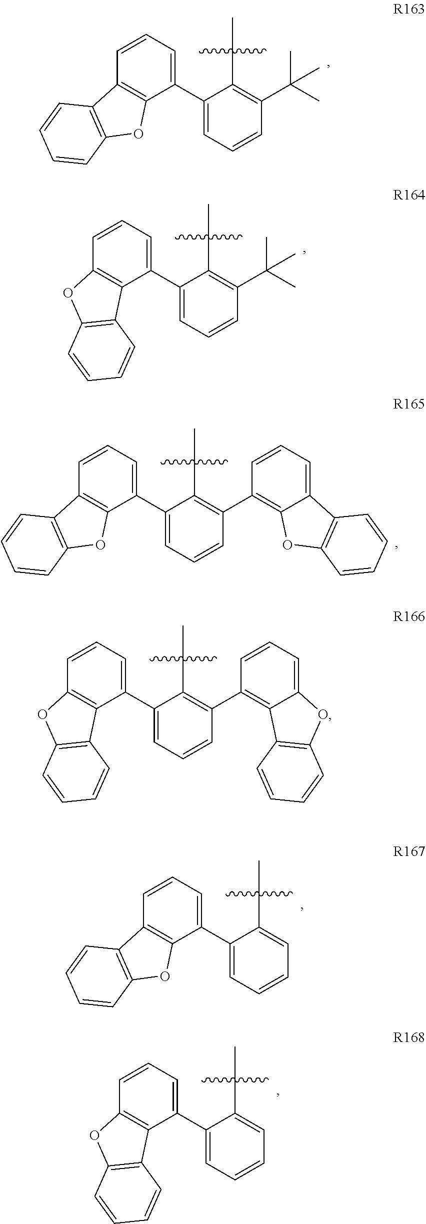 [SMILES: *c1c(-c2cccc3c2oc2ccccc23)cccc1C(C)(C)C ; *c1c(-c2cccc3oc4ccccc4c23)cccc1C(C)(C)C ; *c1c(-c2cccc3c2oc2ccccc23)cccc1-c1cccc2c1oc1ccccc12 ; *c1c(-c2cccc3oc4ccccc4c23)cccc1-c1cccc2oc3ccccc3c12 ; *c1ccccc1-c1cccc2c1oc1ccccc12 ; *c1ccccc1-c1cccc2oc3ccccc3c12]

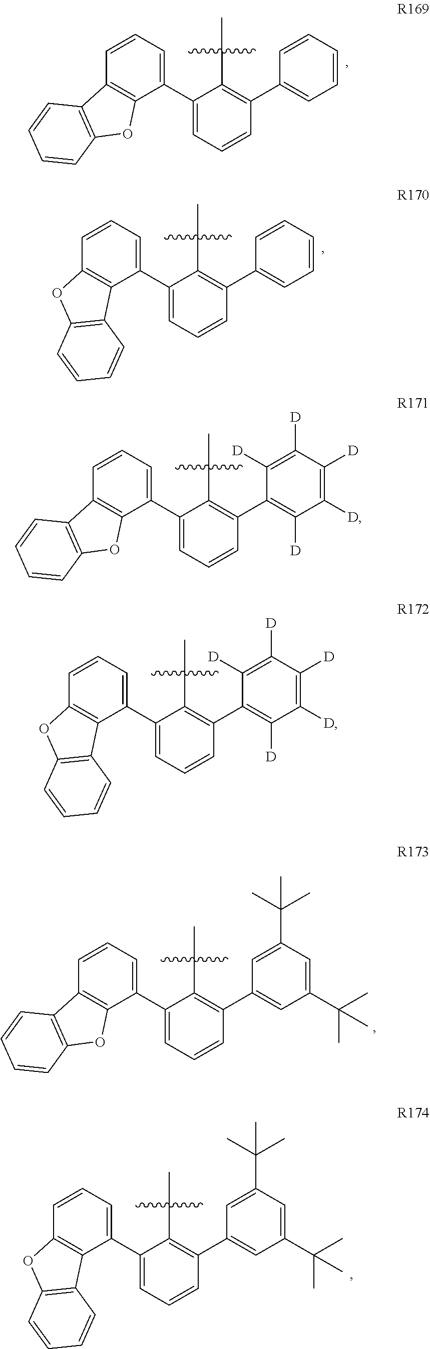

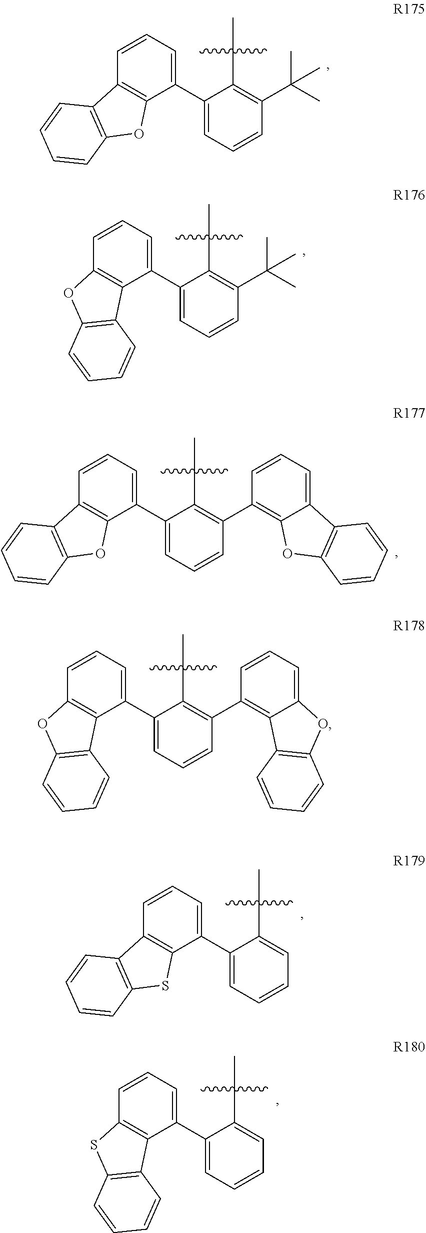 [SMILES: *c1c(-c2cccc3c2oc2ccccc23)cccc1C(C)(C)C ; *c1c(-c2cccc3oc4ccccc4c23)cccc1C(C)(C)C ; *c1c(-c2cccc3c2oc2ccccc23)cccc1-c1cccc2c1oc1ccccc12 ; *c1c(-c2cccc3oc4ccccc4c23)cccc1-c1cccc2oc3ccccc3c12 ; *c1ccccc1-c1cccc2c1sc1ccccc12 ; *c1ccccc1-c1cccc2sc3ccccc3c12]

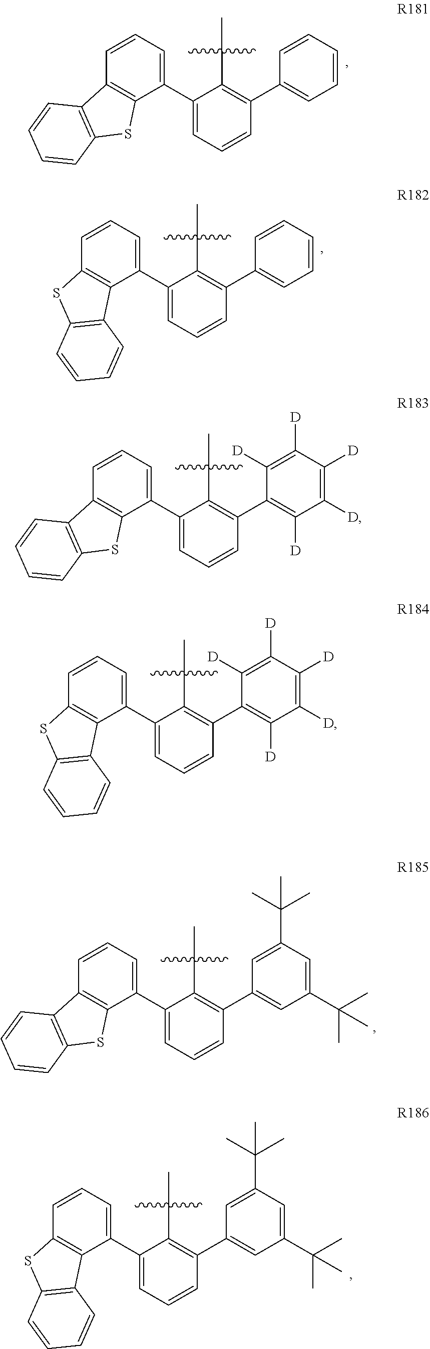

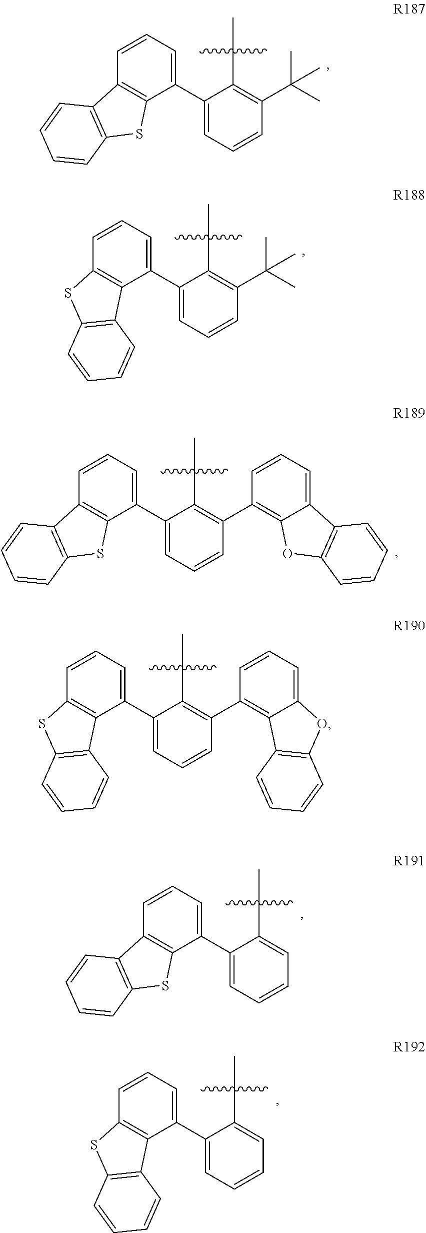 [SMILES: *c1c(-c2cccc3c2sc2ccccc23)cccc1C(C)(C)C ; *c1c(-c2cccc3sc4ccccc4c23)cccc1C(C)(C)C ; *c1c(-c2cccc3c2oc2ccccc23)cccc1-c1cccc2c1sc1ccccc12 ; *c1c(-c2cccc3oc4ccccc4c23)cccc1-c1cccc2sc3ccccc3c12 ; *c1ccccc1-c1cccc2c1sc1ccccc12 ; *c1ccccc1-c1cccc2sc3ccccc3c12]

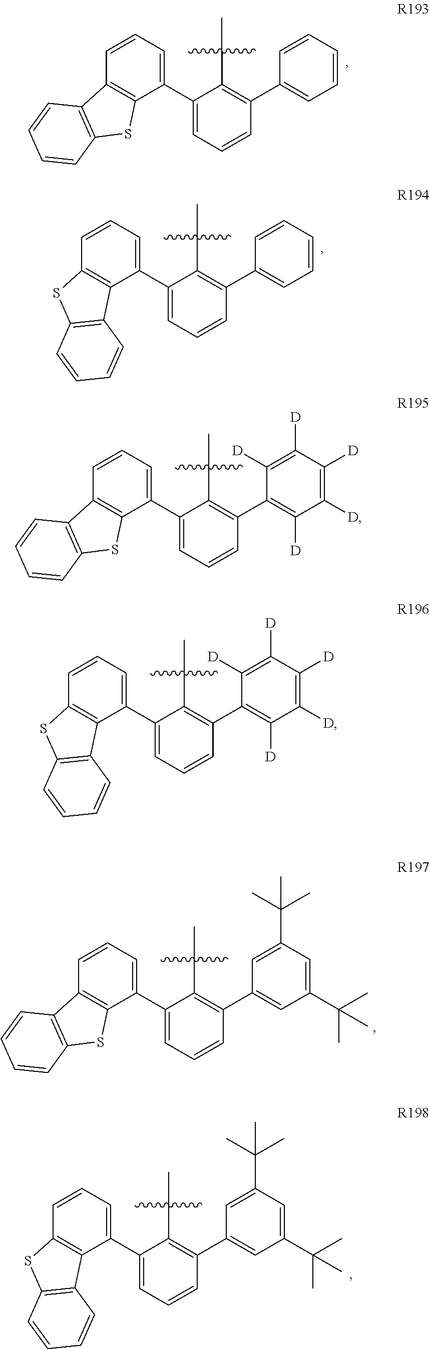

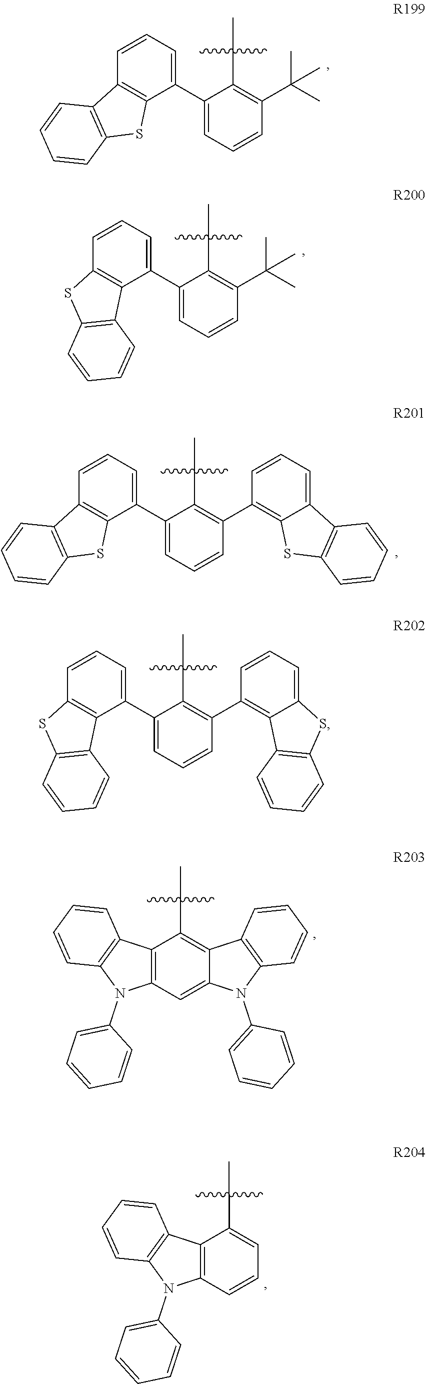 [SMILES: *c1c(-c2cccc3c2sc2ccccc23)cccc1C(C)(C)C ; *c1c(-c2cccc3sc4ccccc4c23)cccc1C(C)(C)C ; *c1c(-c2cccc3c2sc2ccccc23)cccc1-c1cccc2c1sc1ccccc12 ; *c1c(-c2cccc3sc4ccccc4c23)cccc1-c1cccc2sc3ccccc3c12 ; *c1c2c3ccccc3n(-c3ccccc3)c2cc2c1c1ccccc1n2-c1ccccc1 ; *c1cccc2c1c1ccccc1n2-c1ccccc1]

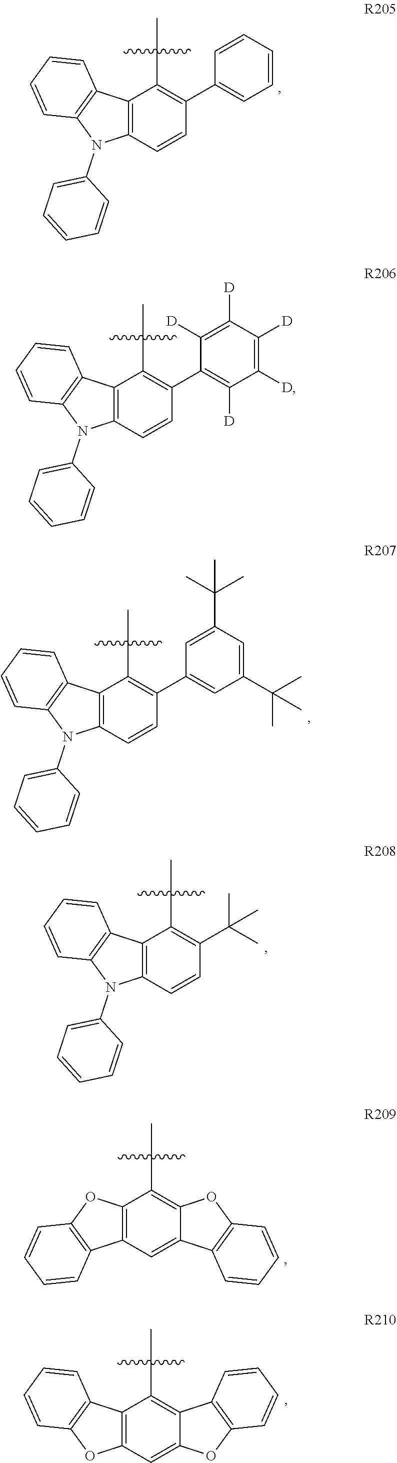

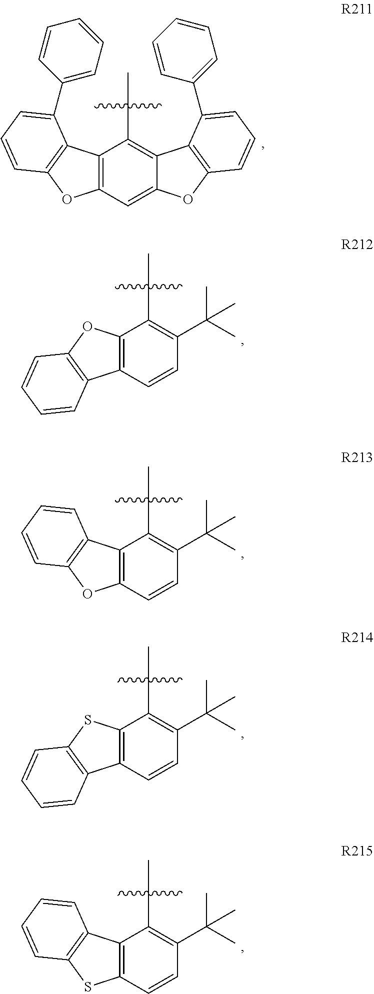 [SMILES: *c1c2c(cc3oc4cccc(-c5ccccc5)c4c13)oc1cccc(-c3ccccc3)c12 ; *c1c(C(C)(C)C)ccc2c1oc1ccccc12 ; *c1c(C(C)(C)C)ccc2oc3ccccc3c12 ; *c1c(C(C)(C)C)ccc2c1sc1ccccc12 ; *c1c(C(C)(C)C)ccc2sc3ccccc3c12]

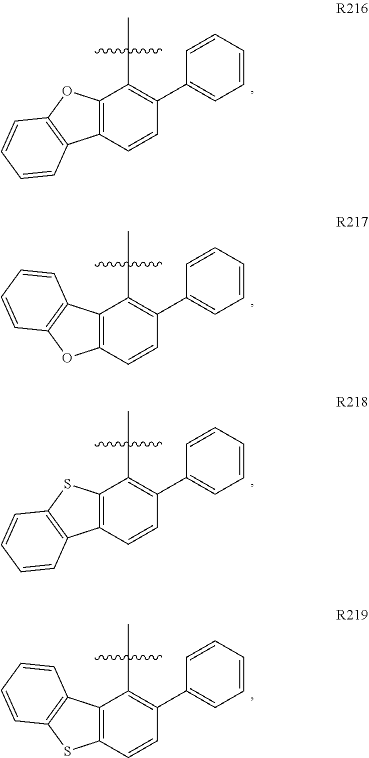 [SMILES: *c1c(-c2ccccc2)ccc2c1oc1ccccc12 ; *c1c(-c2ccccc2)ccc2oc3ccccc3c12 ; *c1c(-c2ccccc2)ccc2c1sc1ccccc12 ; *c1c(-c2ccccc2)ccc2sc3ccccc3c12]

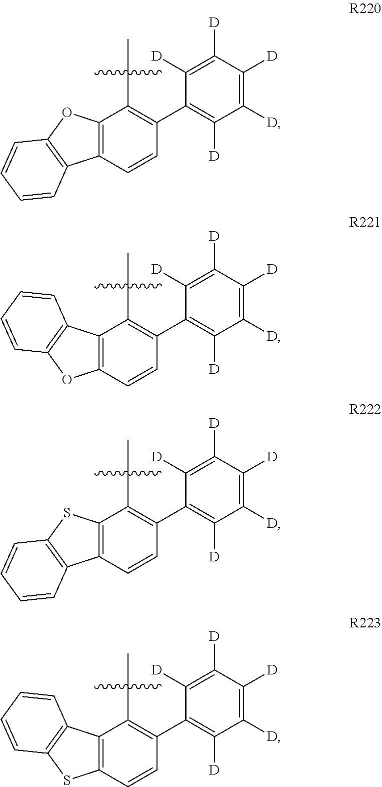

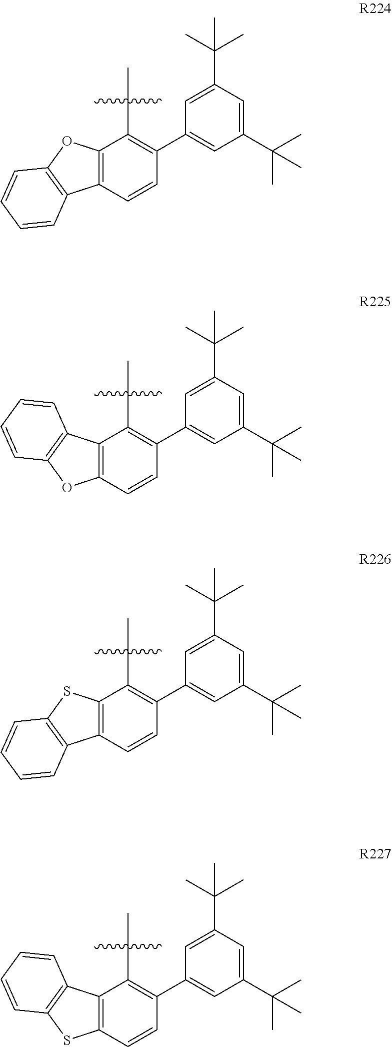 [SMILES: *c1c(-c2cc(C(C)(C)C)cc(C(C)(C)C)c2)ccc2c1oc1ccccc12 ; *c1c(-c2cc(C(C)(C)C)cc(C(C)(C)C)c2)ccc2oc3ccccc3c12 ; *c1c(-c2cc(C(C)(C)C)cc(C(C)(C)C)c2)ccc2c1sc1ccccc12 ; *c1c(-c2cc(C(C)(C)C)cc(C(C)(C)C)c2)ccc2sc3ccccc3c12]

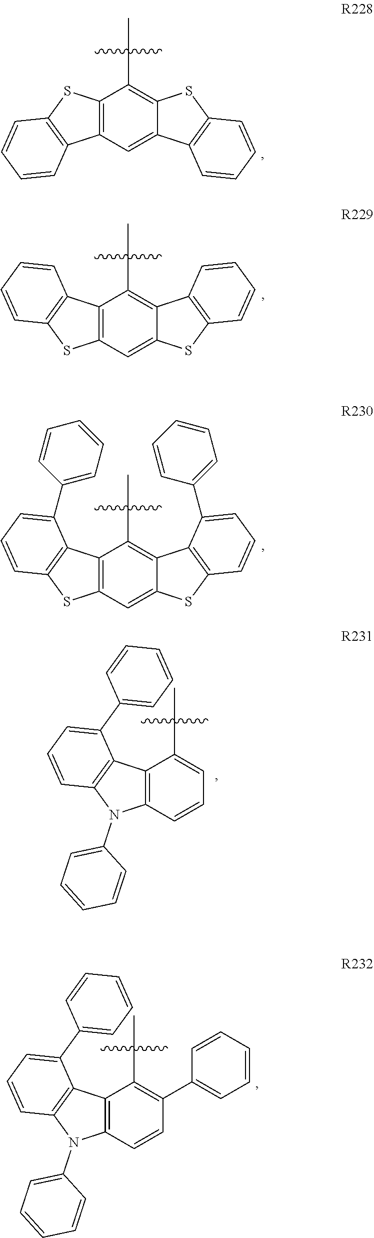

[chemical structure]

[chemical structure]

[chemical structure]

[chemical structure]

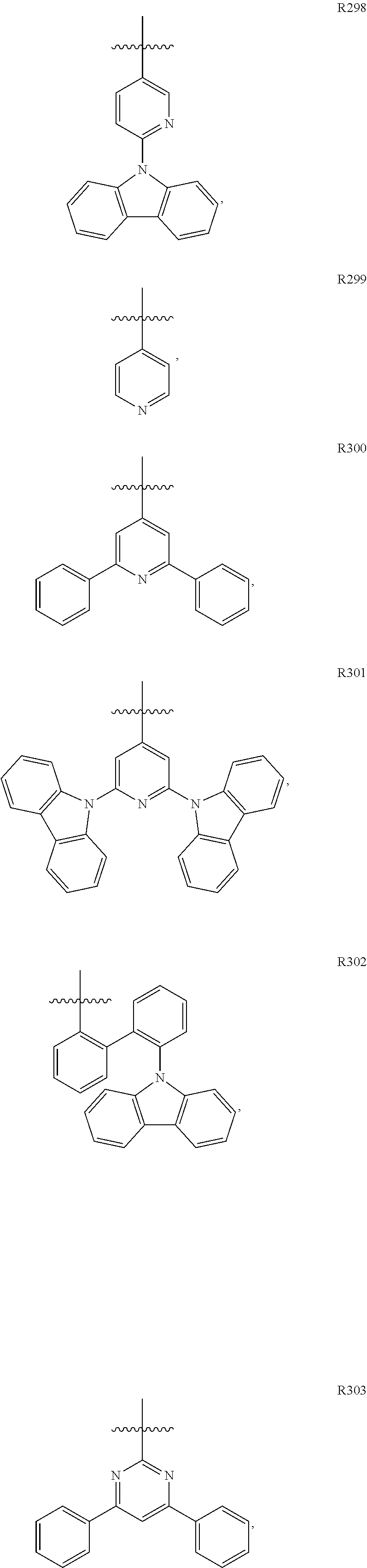 [SMILES: *c1ccc(-n2c3ccccc3c3ccccc32)nc1 ; *c1ccncc1 ; *c1cc(-c2ccccc2)nc(-c2ccccc2)c1 ; *c1cc(-n2c3ccccc3c3ccccc32)nc(-n2c3ccccc3c3ccccc32)c1 ; *c1ccccc1-c1ccccc1-n1c2ccccc2c2ccccc21 ; *c1nc(-c2ccccc2)cc(-c2ccccc2)n1]

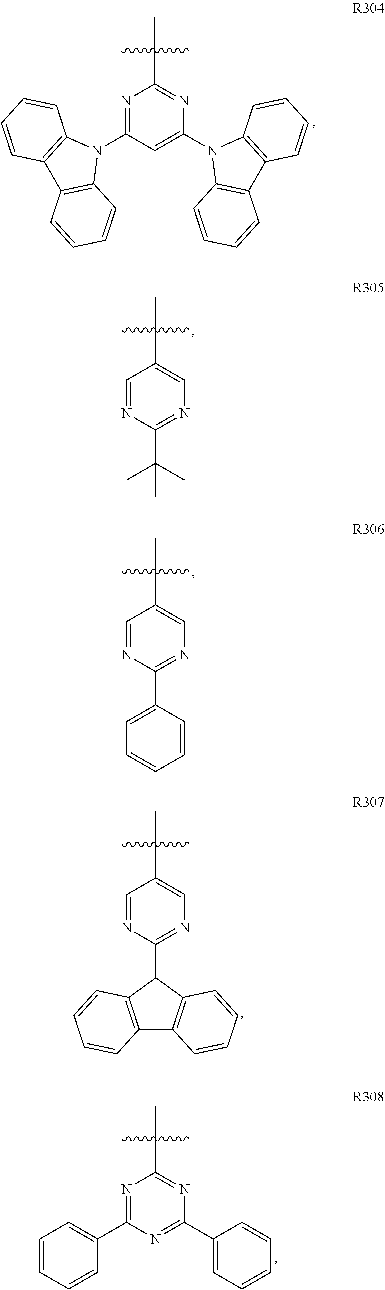 [SMILES: *c1nc(-n2c3ccccc3c3ccccc32)cc(-n2c3ccccc3c3ccccc32)n1 ; *c1cnc(C(C)(C)C)nc1 ; *c1cnc(-c2ccccc2)nc1 ; *c1cnc(C2c3ccccc3-c3ccccc32)nc1 ; *c1nc(-c2ccccc2)nc(-c2ccccc2)n1]

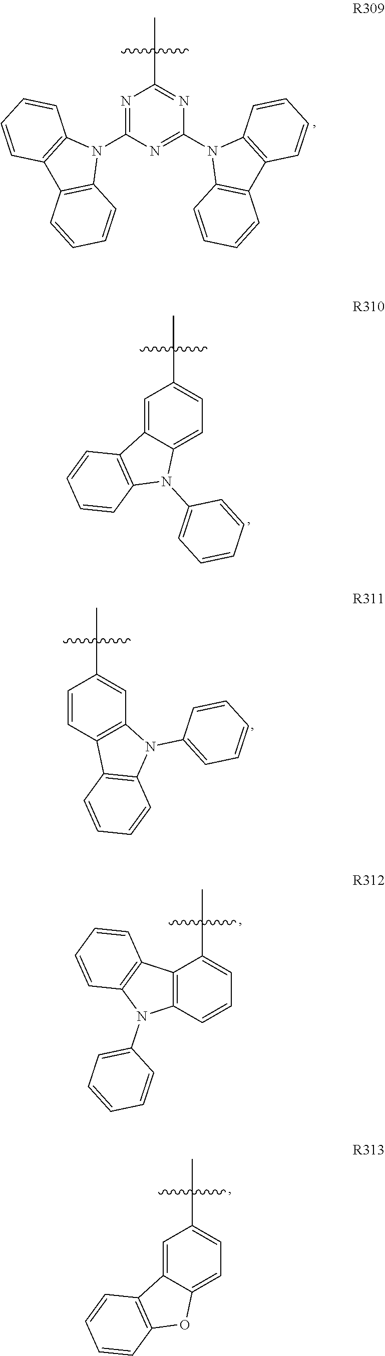

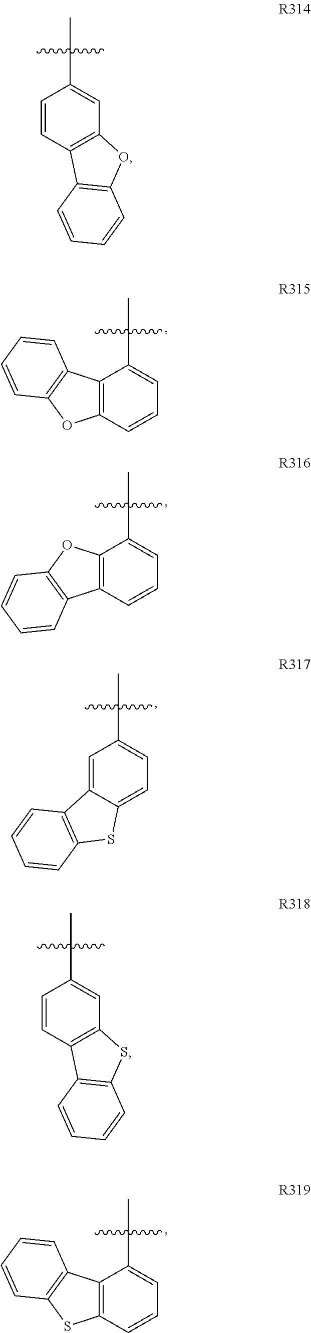 [SMILES: *c1ccc2c(c1)oc1ccccc12 ; *c1cccc2oc3ccccc3c12 ; *c1cccc2c1oc1ccccc12 ; *c1ccc2sc3ccccc3c2c1 ; *c1ccc2c(c1)sc1ccccc12 ; *c1cccc2sc3ccccc3c12]

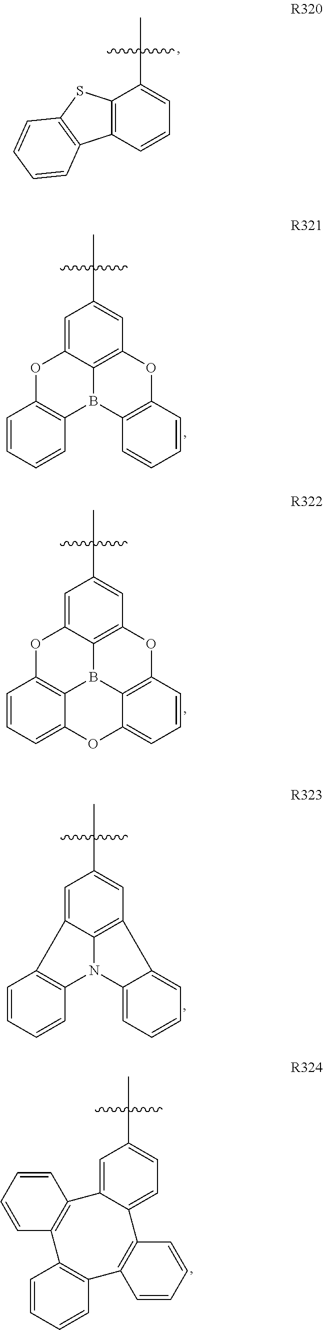 [SMILES: *c1cccc2c1sc1ccccc12 ; *c1cc2c3c(c1)Oc1ccccc1B3c1ccccc1O2 ; *c1cc2c3c(c1)Oc1cccc4c1B3c1c(cccc1O2)O4 ; *c1cc2c3ccccc3n3c4ccccc4c(c1)c23 ; *c1ccc2c(c1)-c1ccccc1-c1ccccc1-c1ccccc1-2]

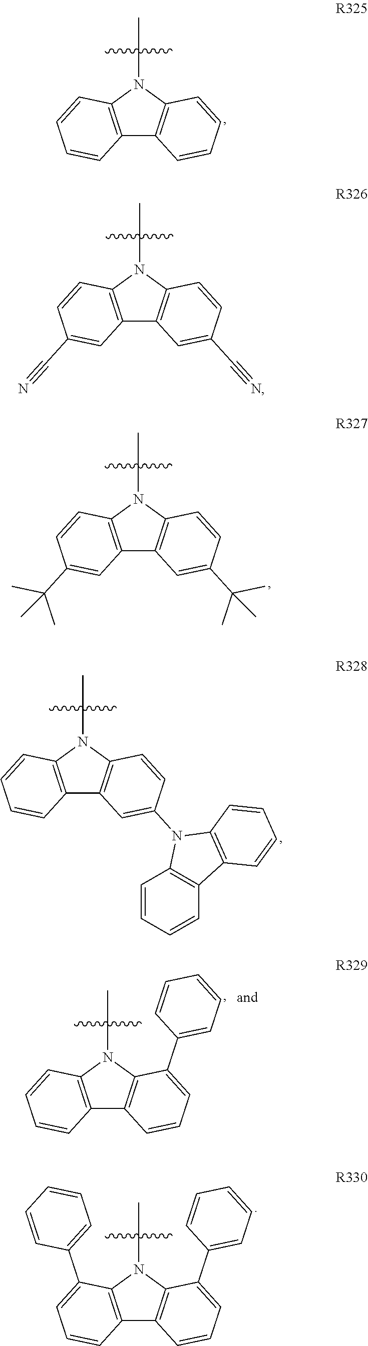 [SMILES: *n1c2ccccc2c2ccccc21 ; *n1c2ccc(C#N)cc2c2cc(C#N)ccc21 ; *n1c2ccc(C(C)(C)C)cc2c2cc(C(C)(C)C)ccc21 ; *n1c2ccccc2c2cc(-n3c4ccccc4c4ccccc43)ccc21 ; *n1c2ccccc2c2cccc(-c3ccccc3)c21 ; *n1c2c(-c3ccccc3)cccc2c2cccc(-c3ccccc3)c21]

13. The compound of claim 12, wherein the compound is selected from the group consisting of those compounds whose Ri, Rj, and Rk correspond to one of the following structures: B1, B2, B3, B9, B10, B16, B18, B20, B22, B23, B24, B25, B27, B29, B31, B32, B33, B34, B34, B40, B44, B45, and B46.

14. The compound of claim 12, wherein the compound is selected from the group consisting of those compounds comprising ligand Ly, whose R¹ corresponds to one of the following structures: R1, R2, R3, R10, R12, R20, R21, R22, R23, R27, R28, R29, R37, R38, R40, R41, R42, R52, R53, R54, R66, R67, R73, R74, R93, R94, R96, R101, R106, R130, R134, R135, R136, R137, R316, R317, R321, R322, R328, R329, R330, and R331.

15. The compound of claim 12, wherein the compound is selected from the group consisting of:

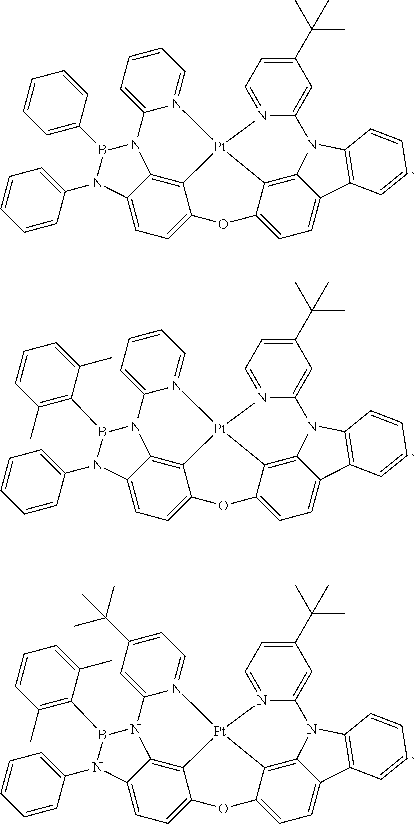

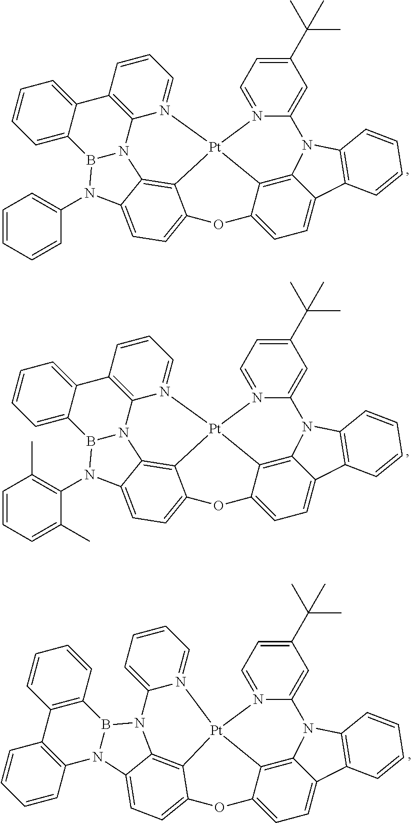

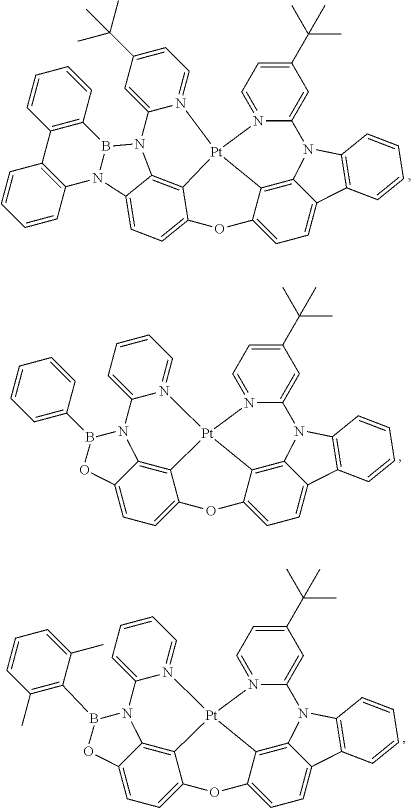

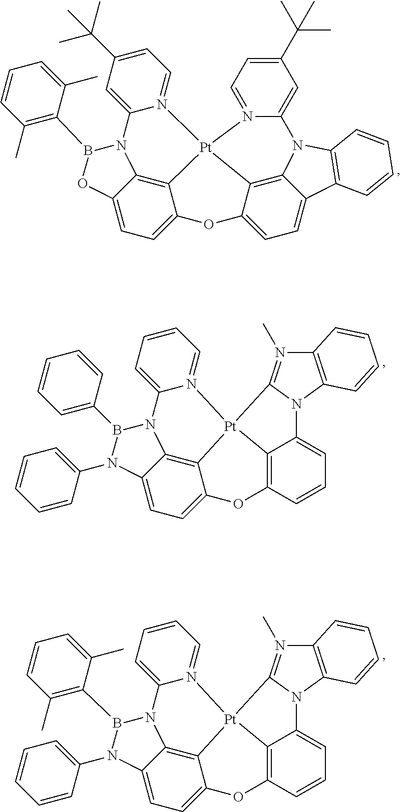

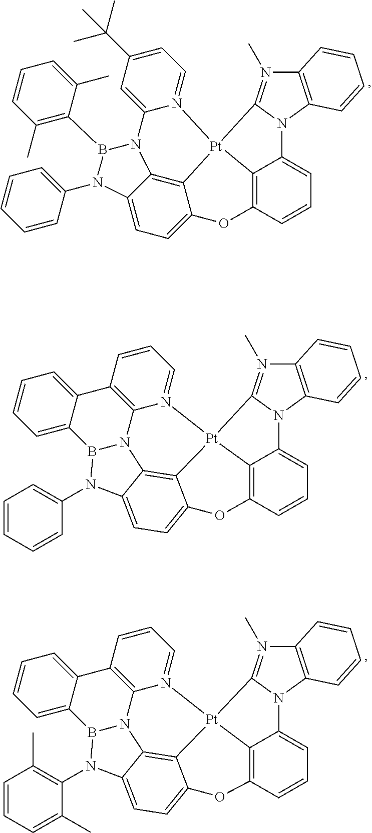

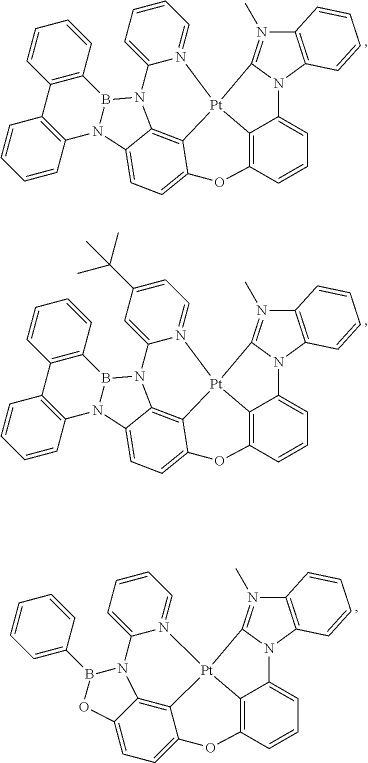

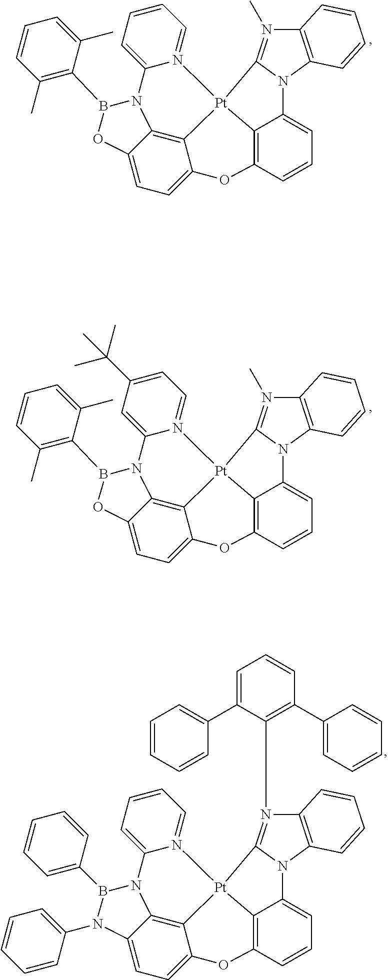

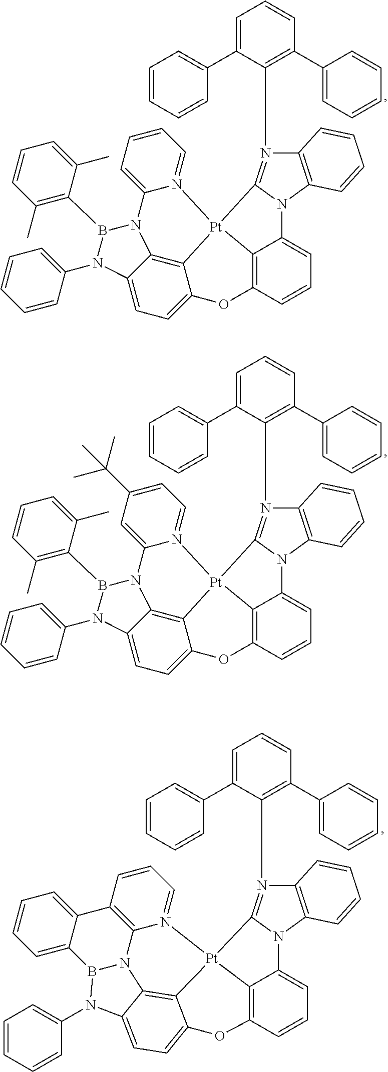

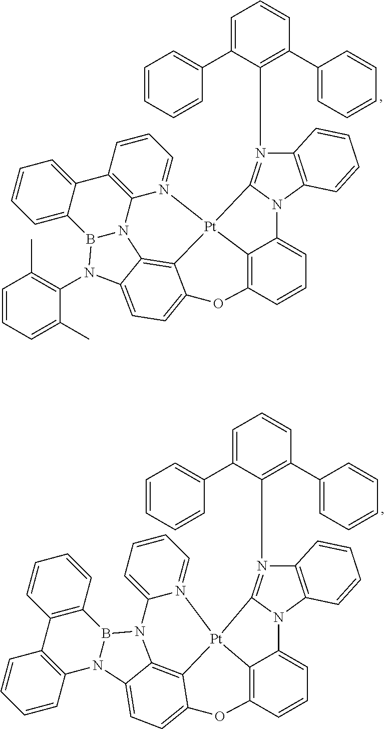

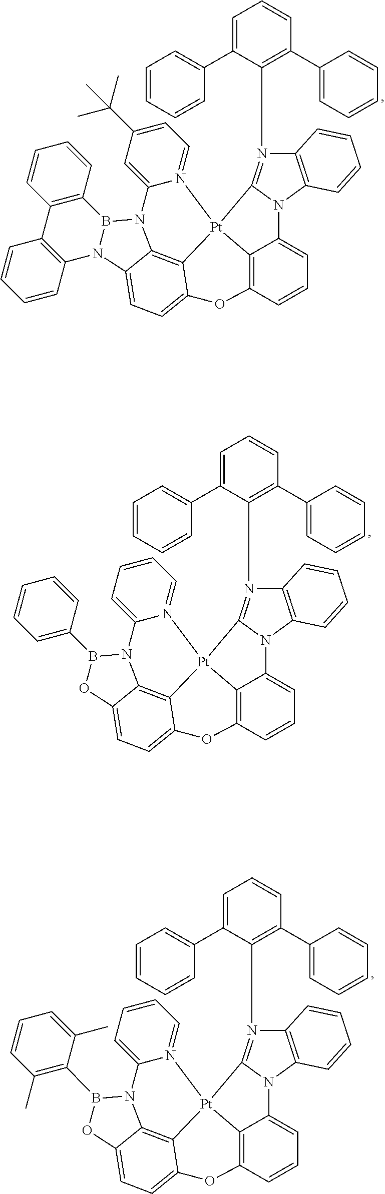

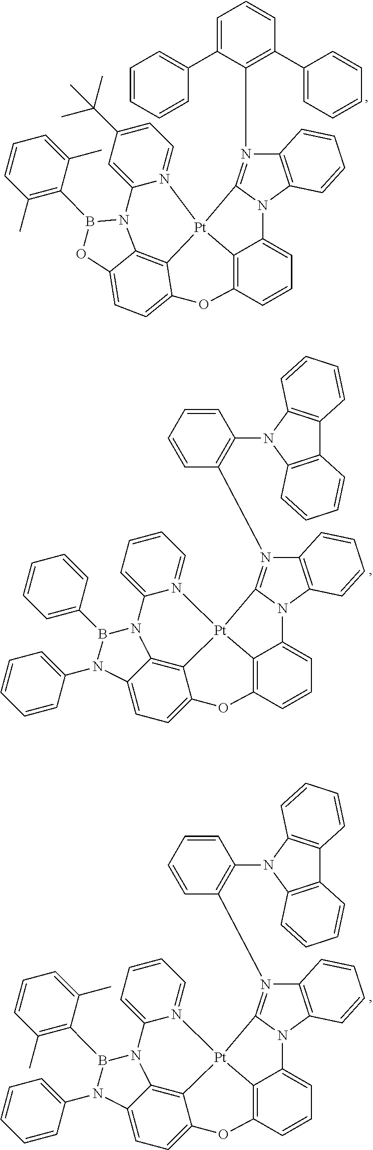

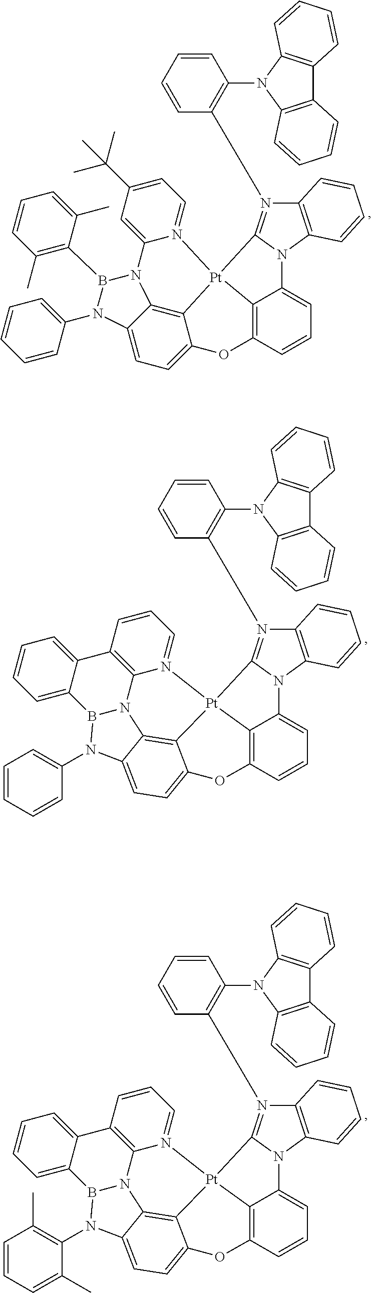

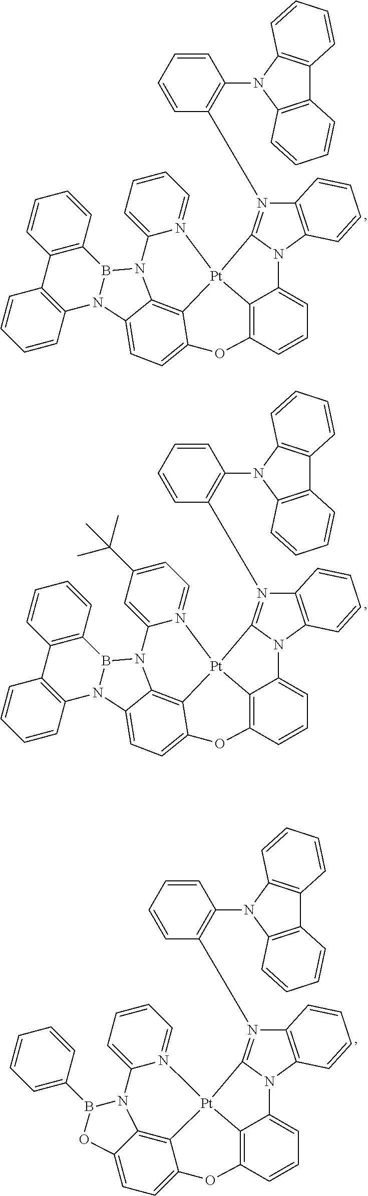

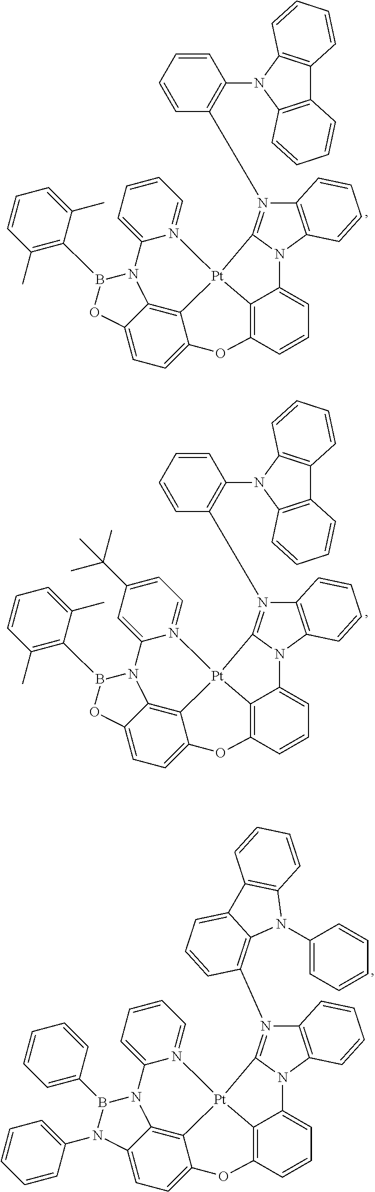

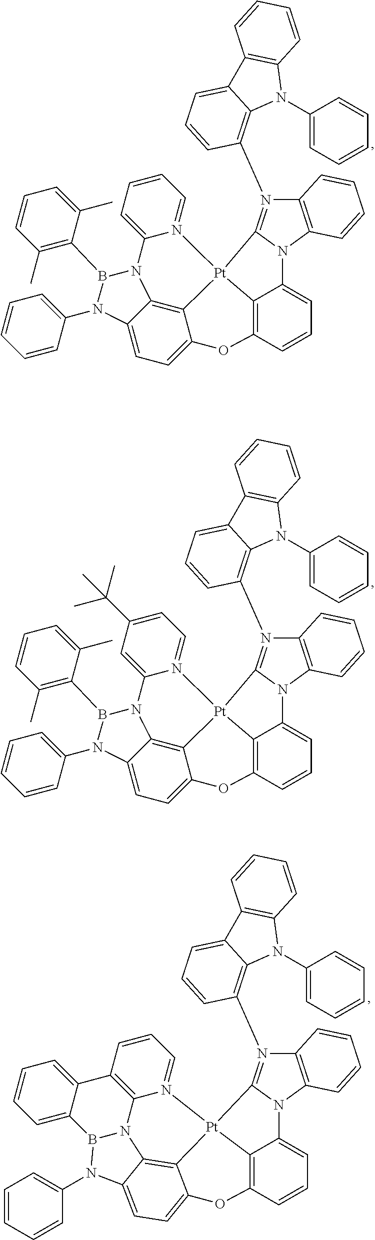

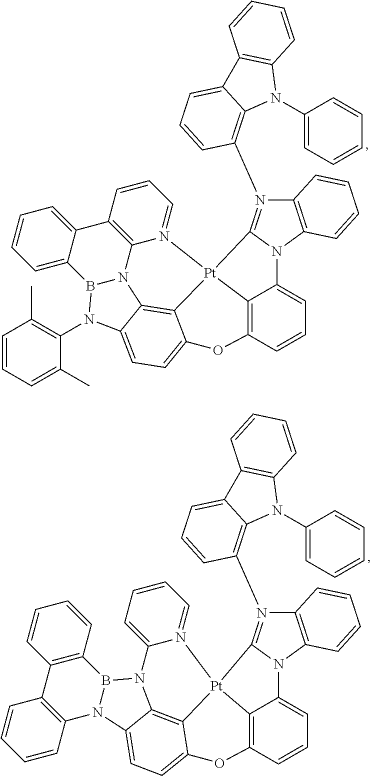

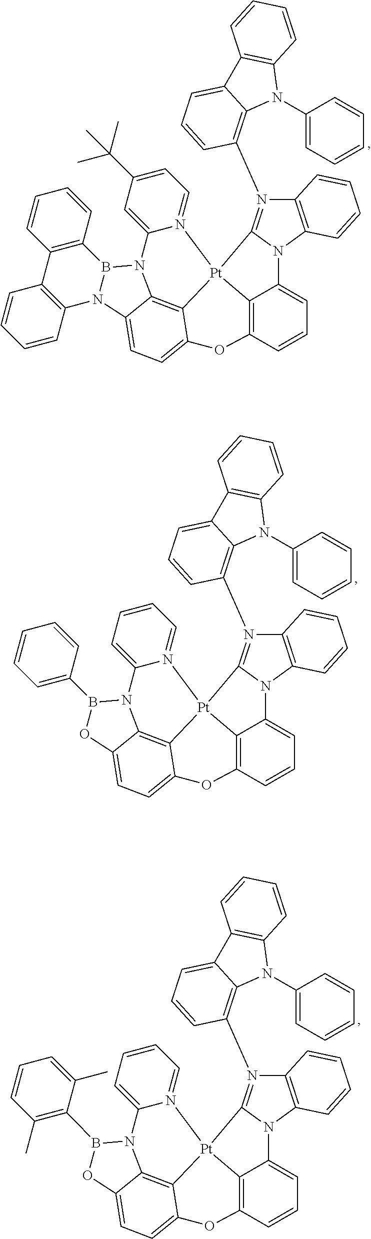

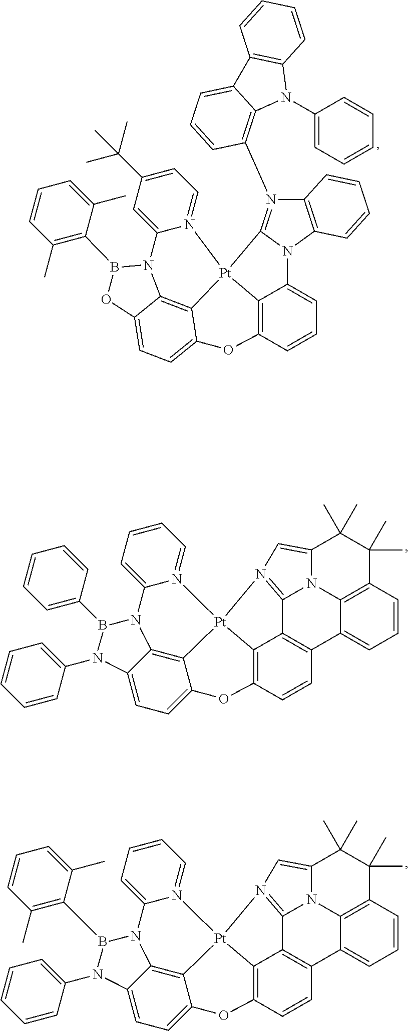

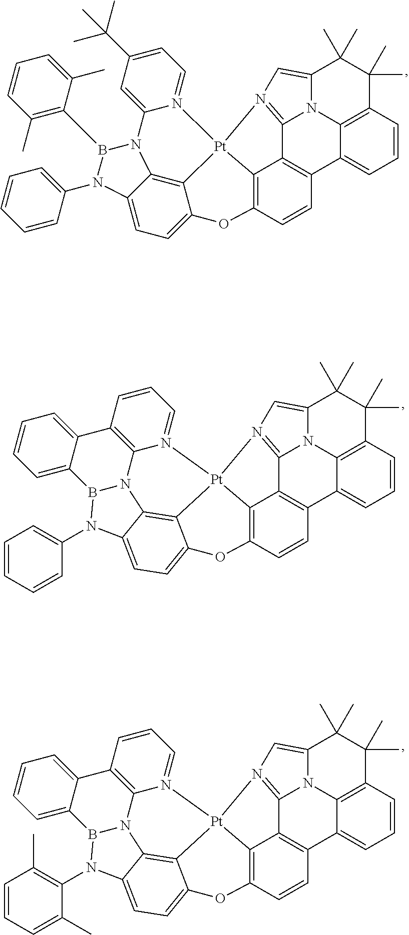

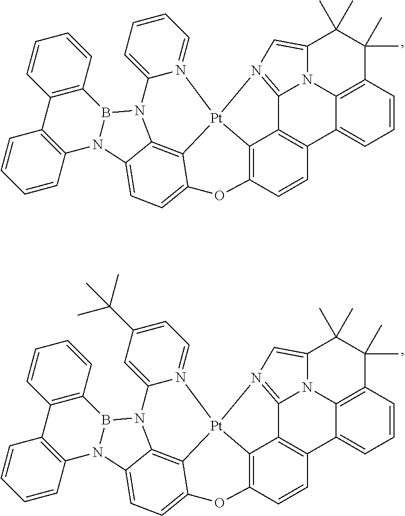

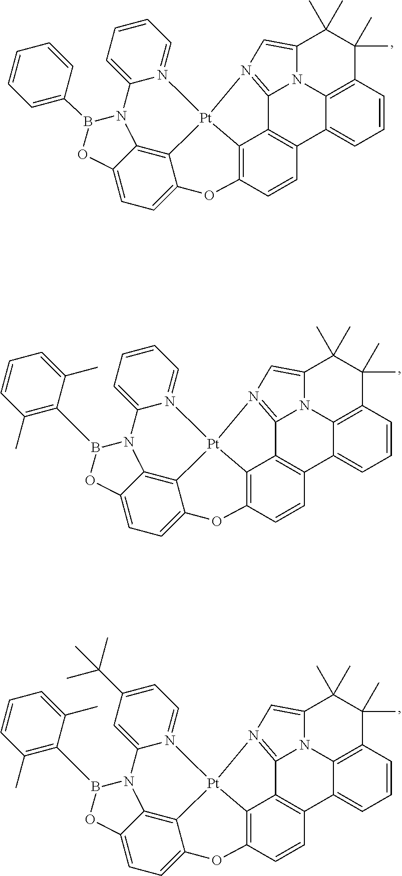

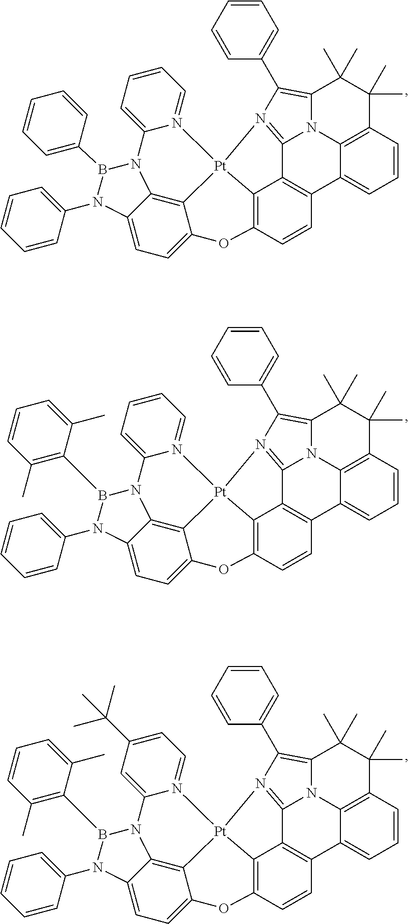

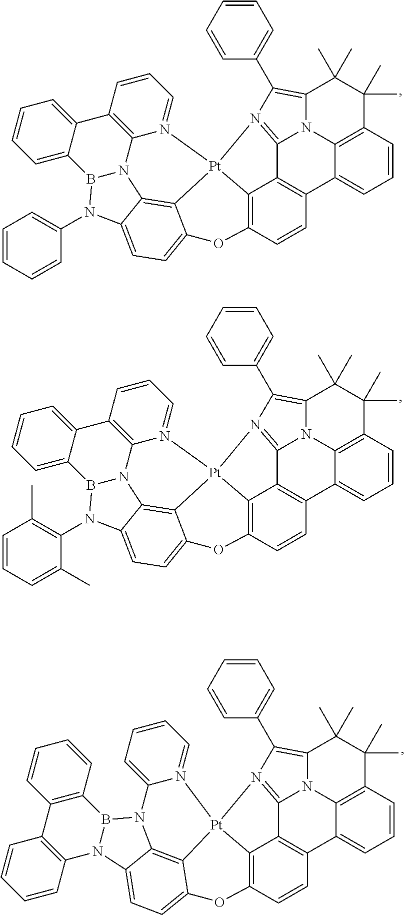

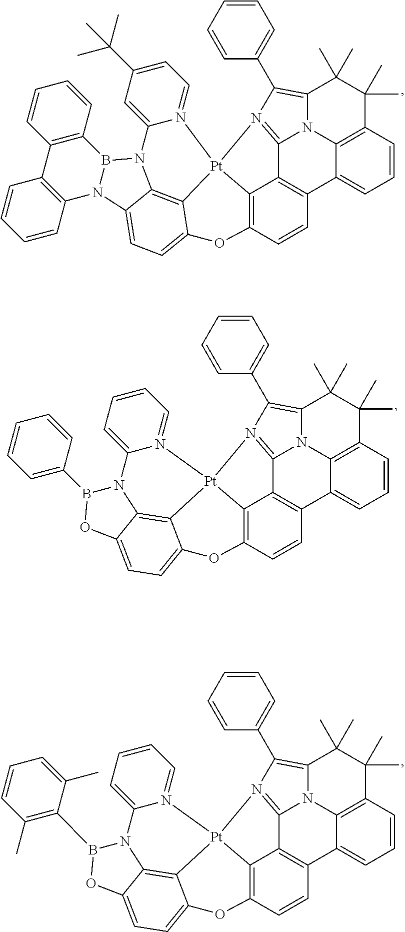

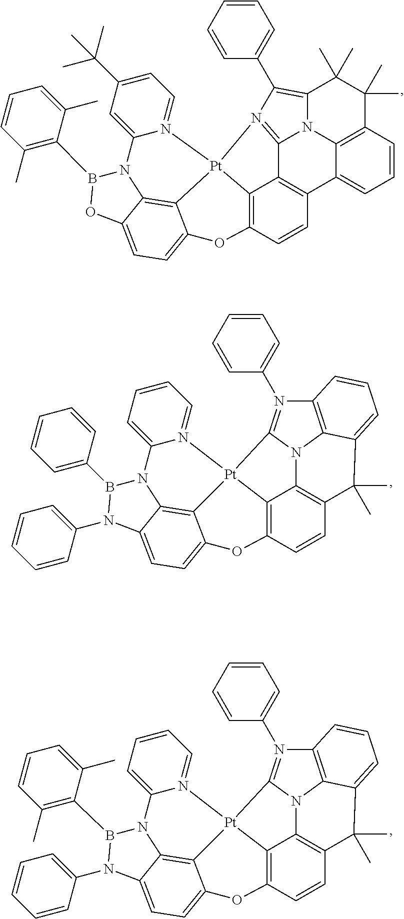

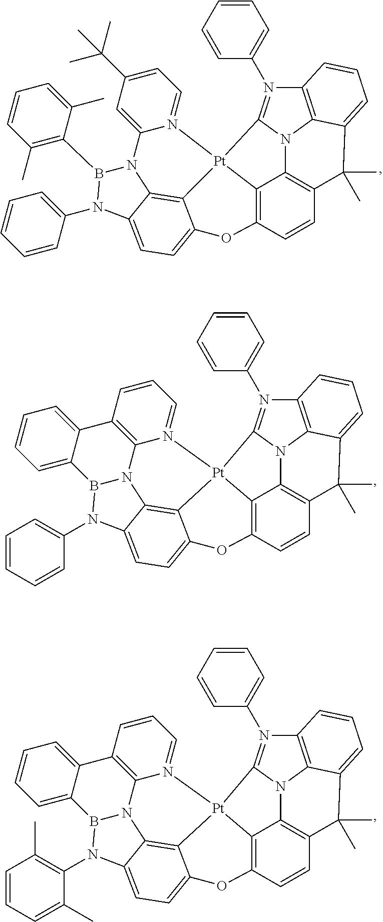

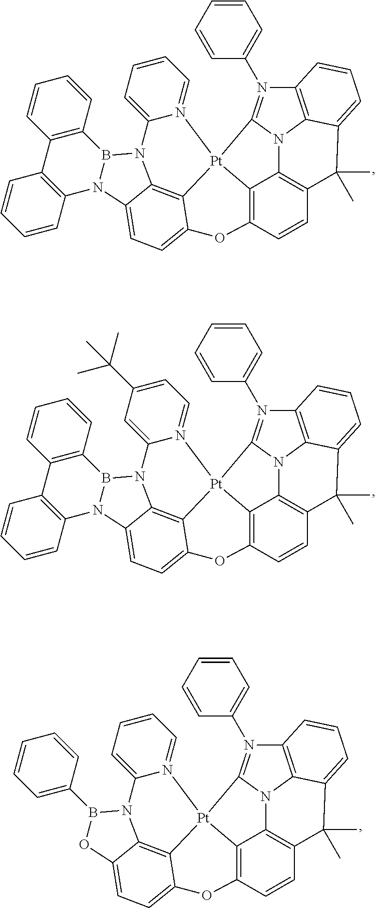

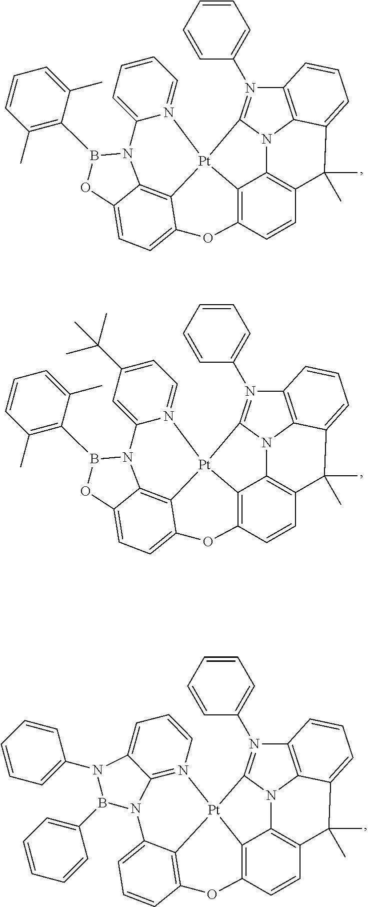

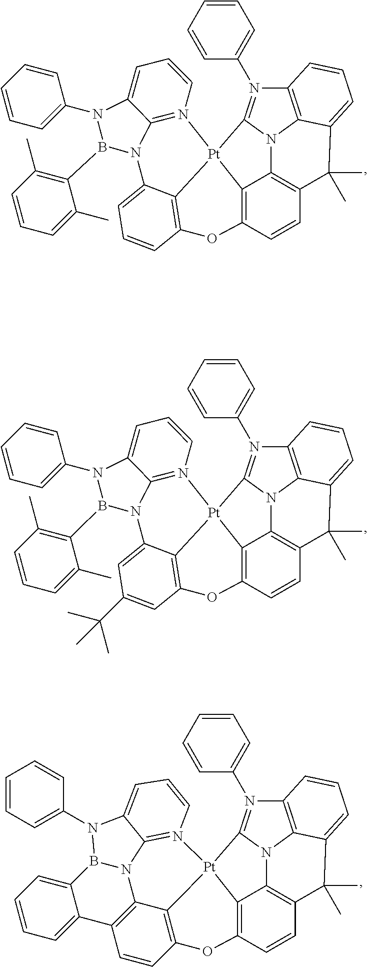

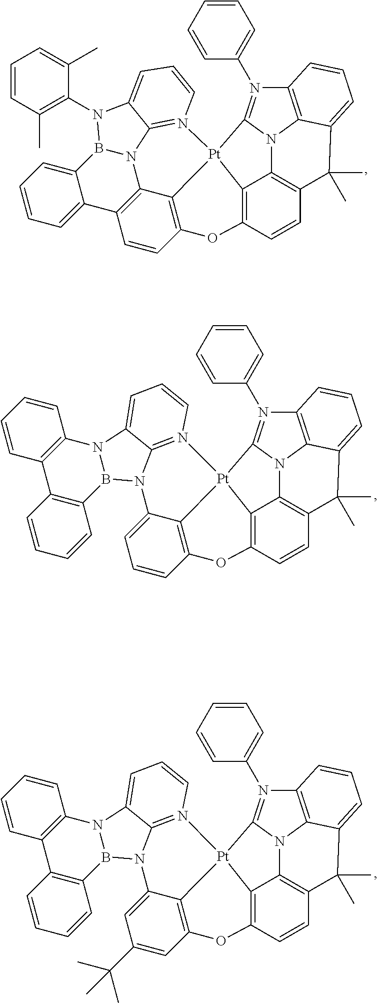

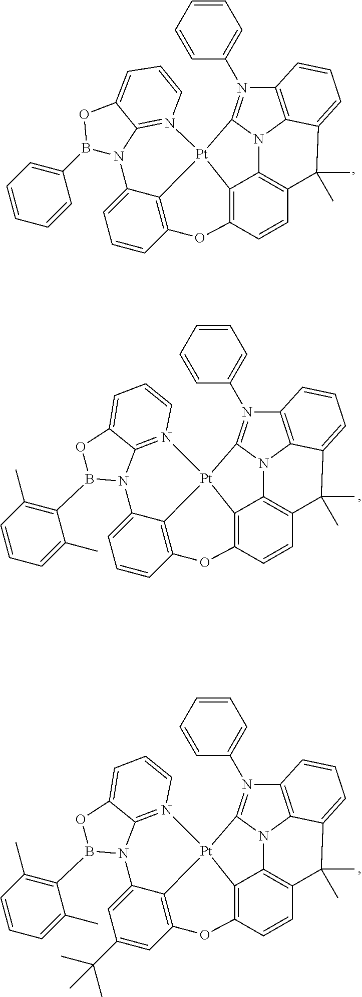

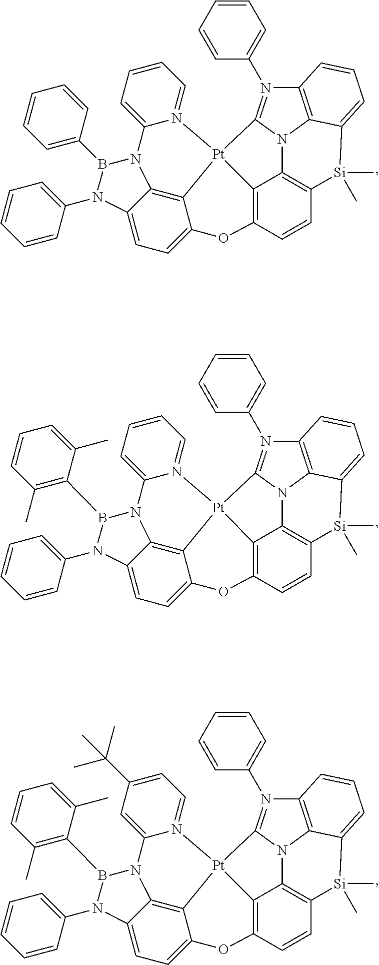

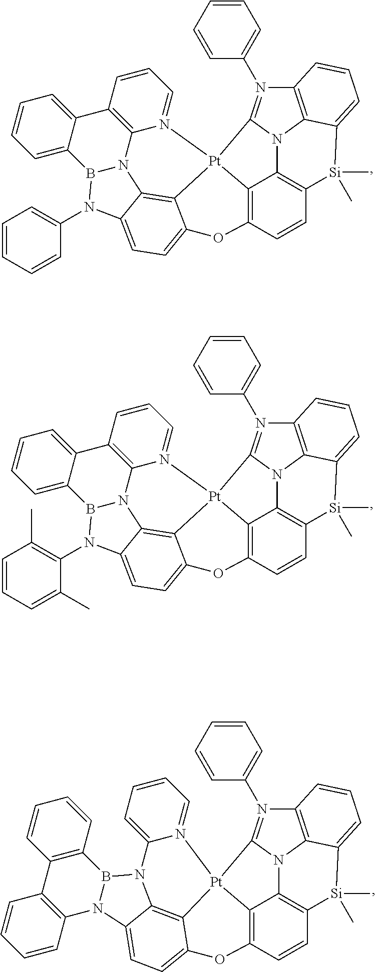

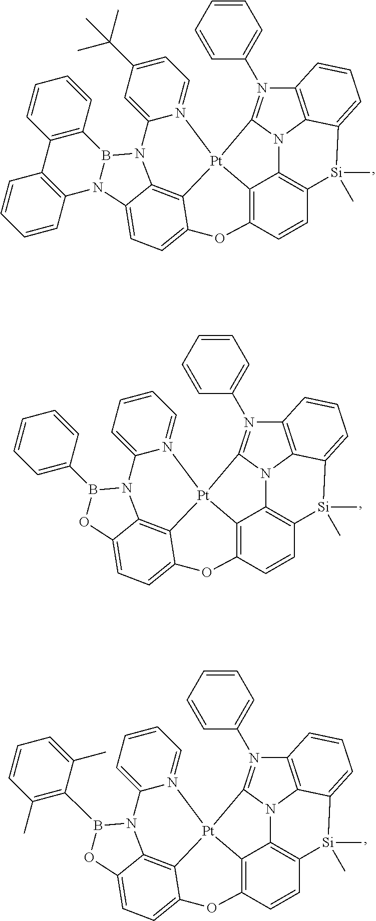

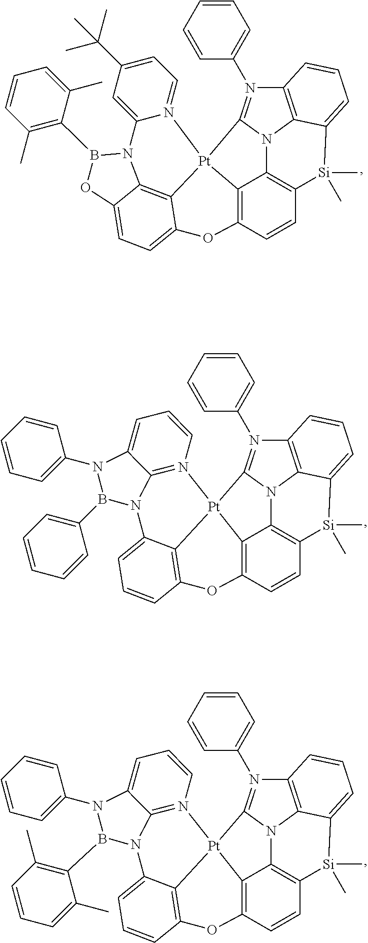

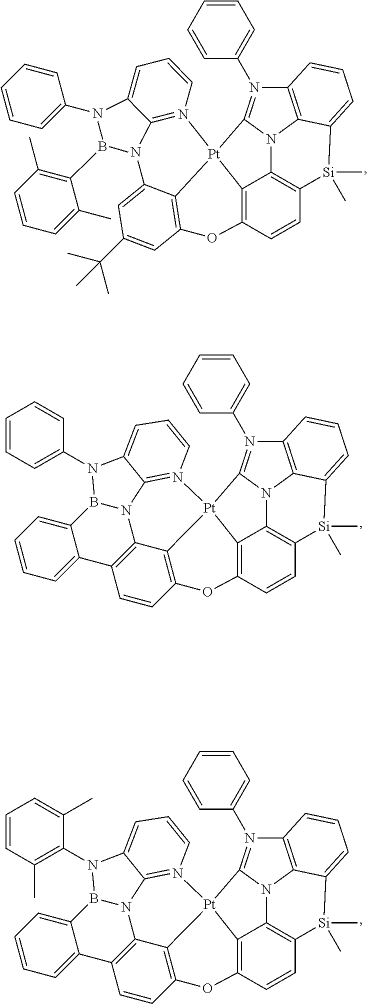

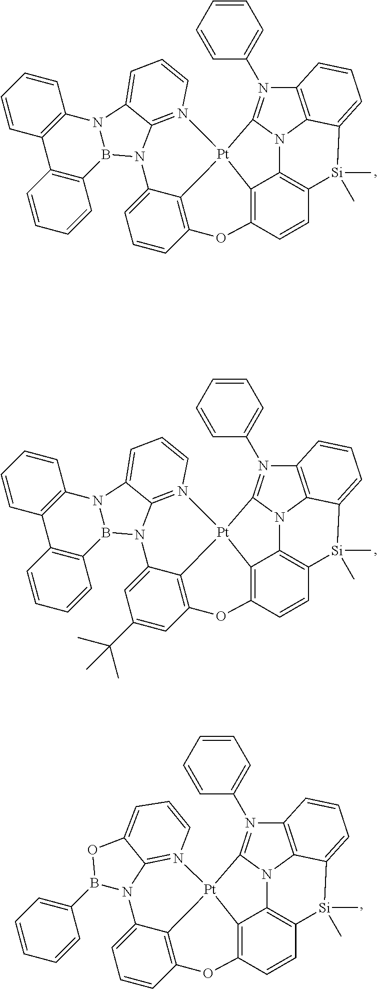

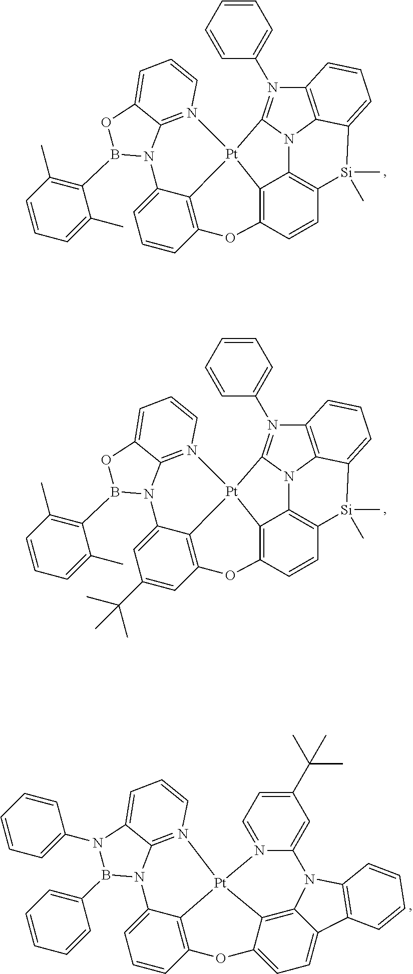

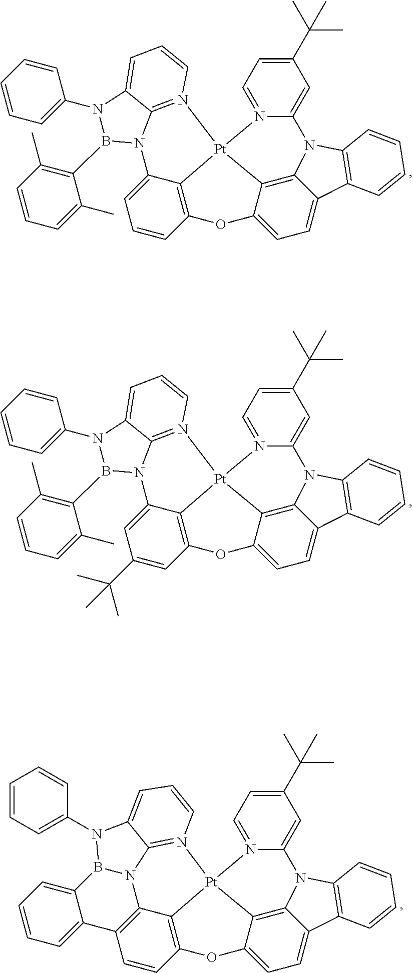

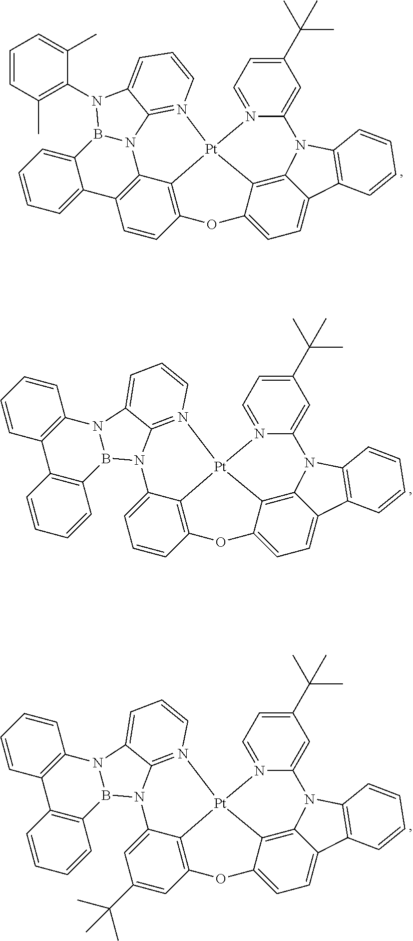

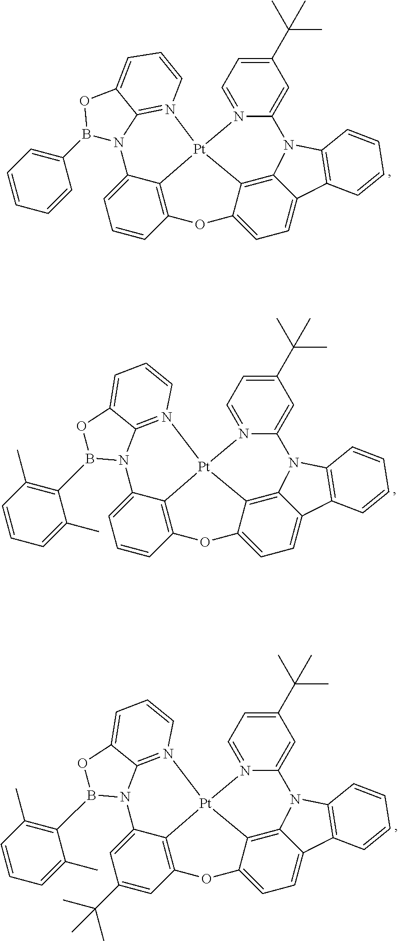

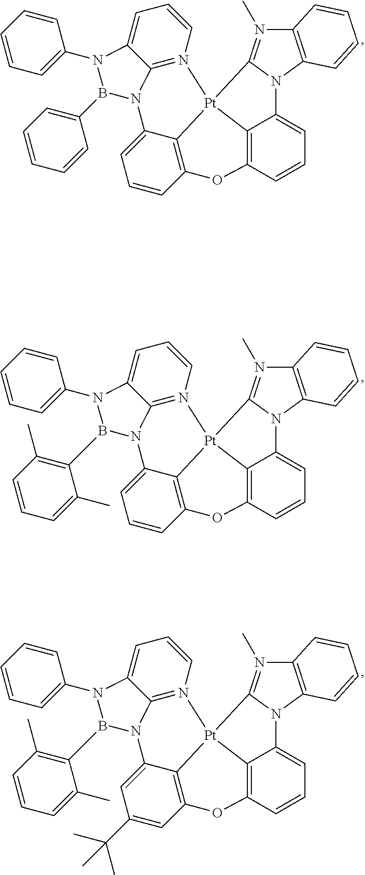

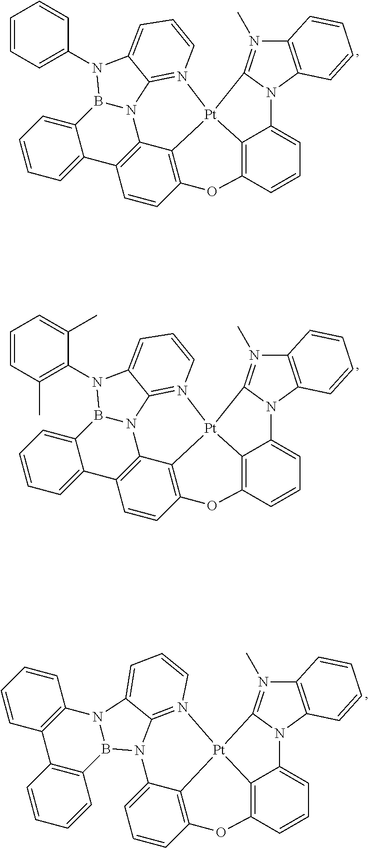

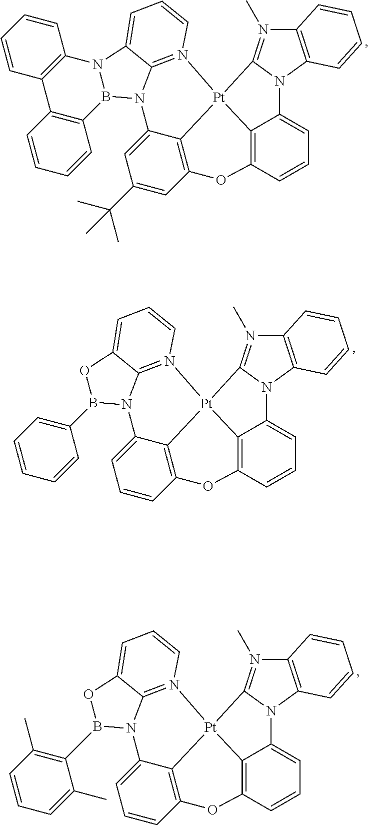

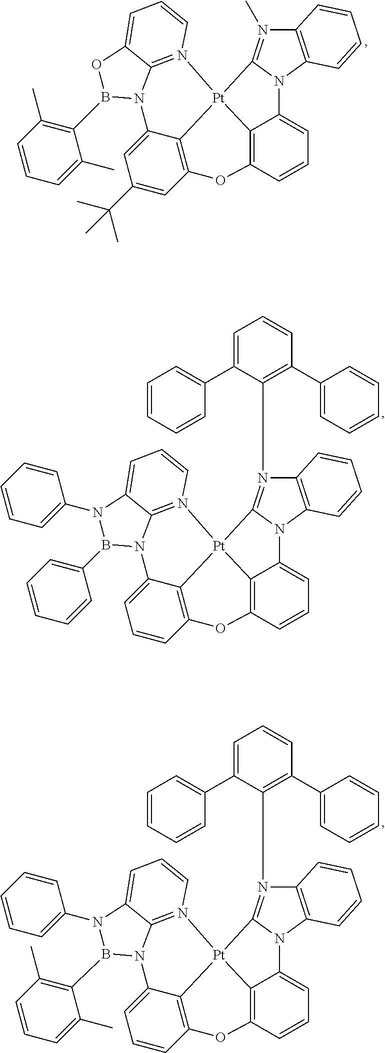

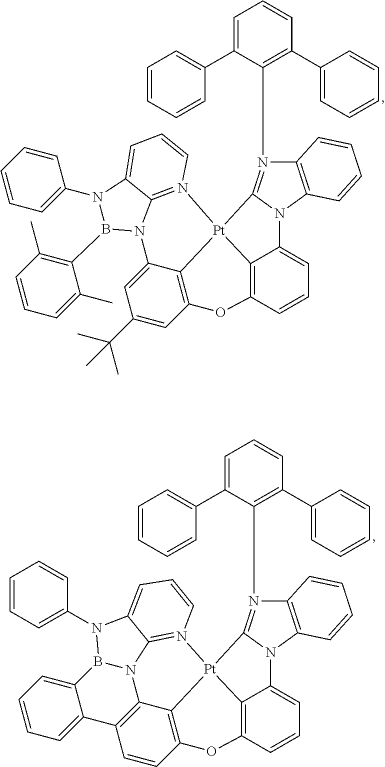

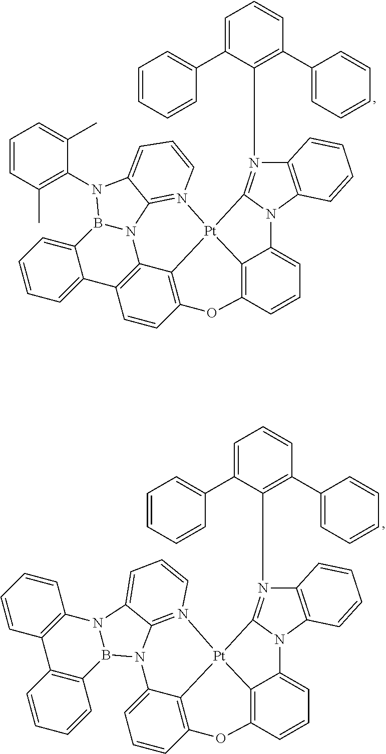

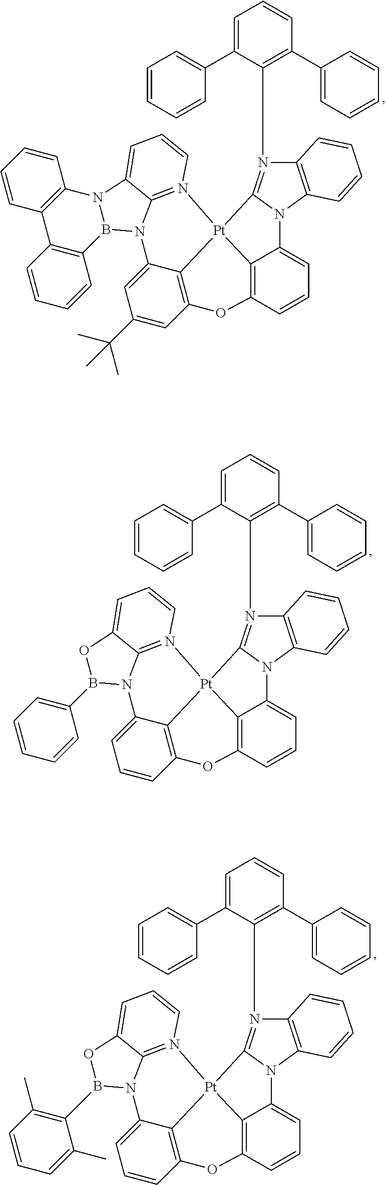

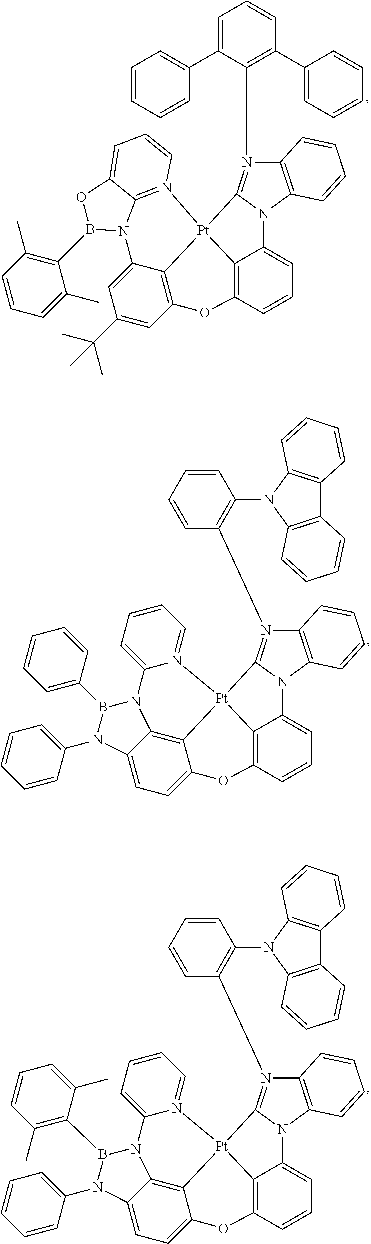

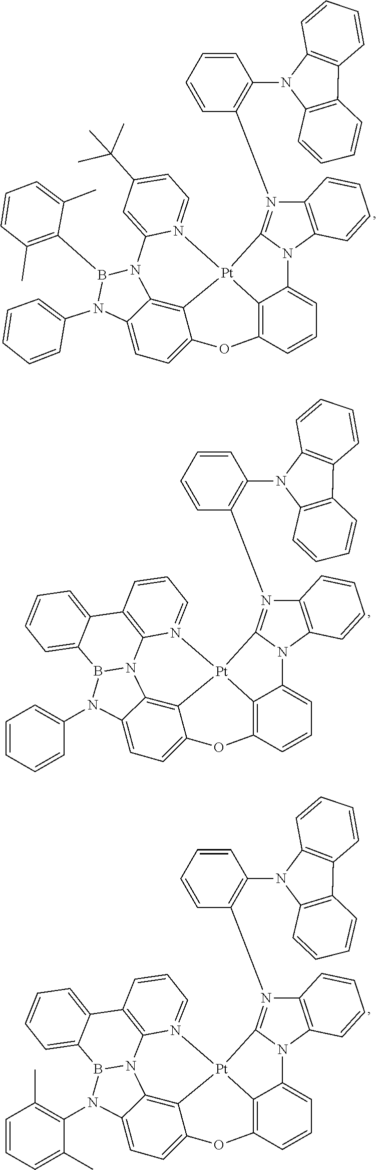

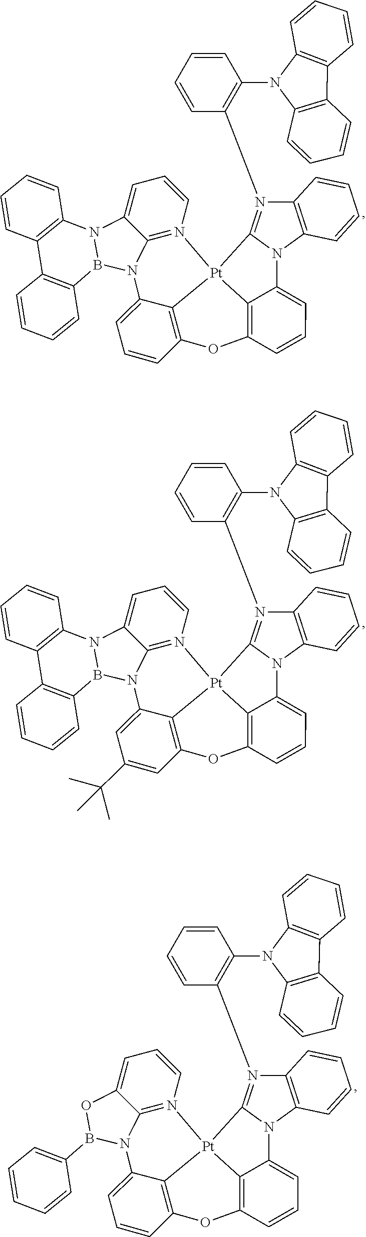

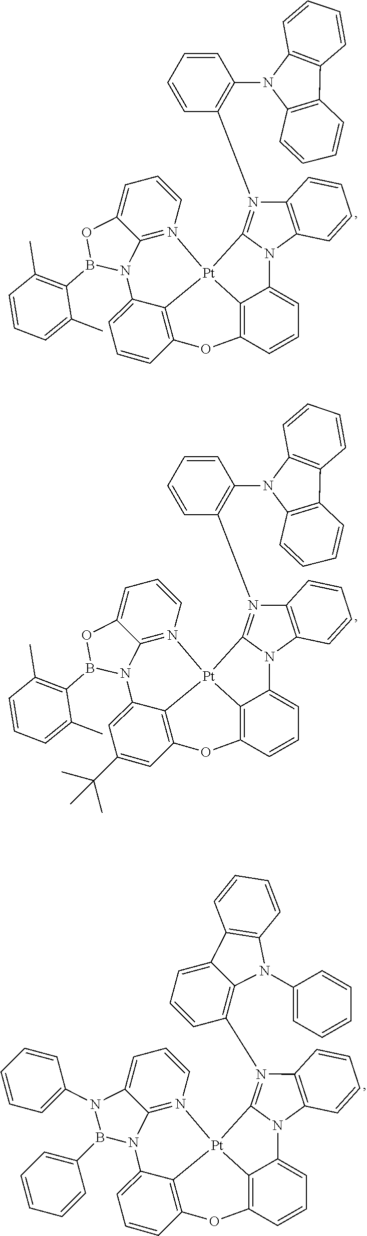

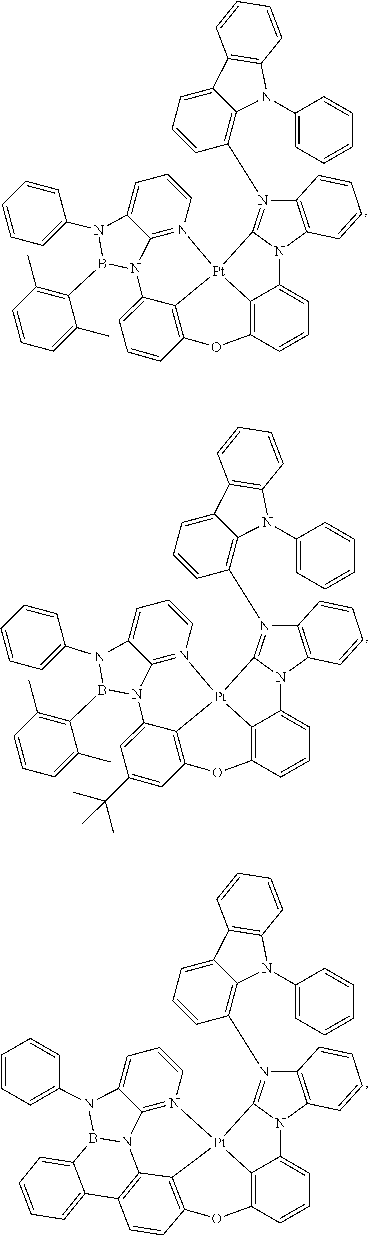

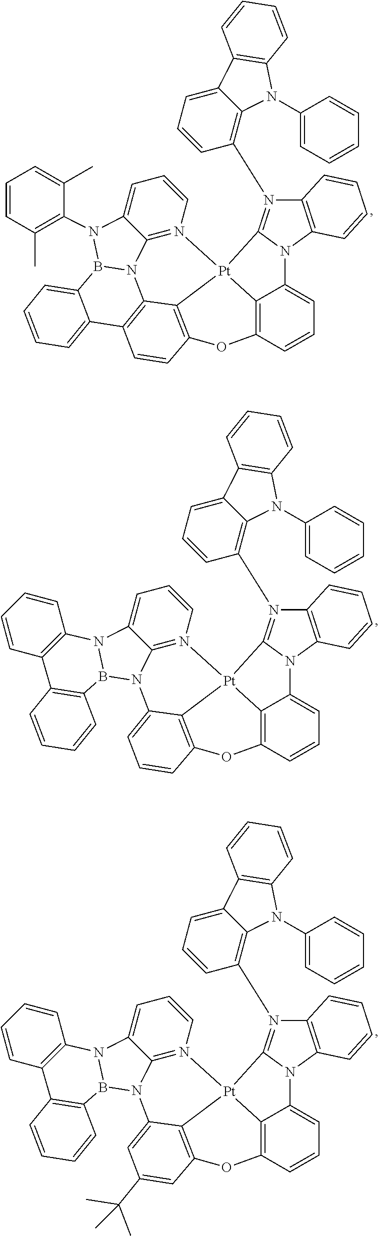

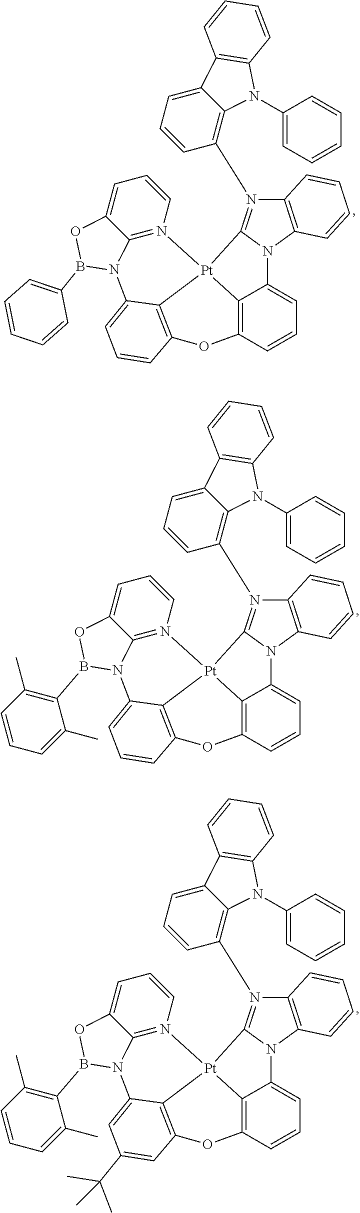

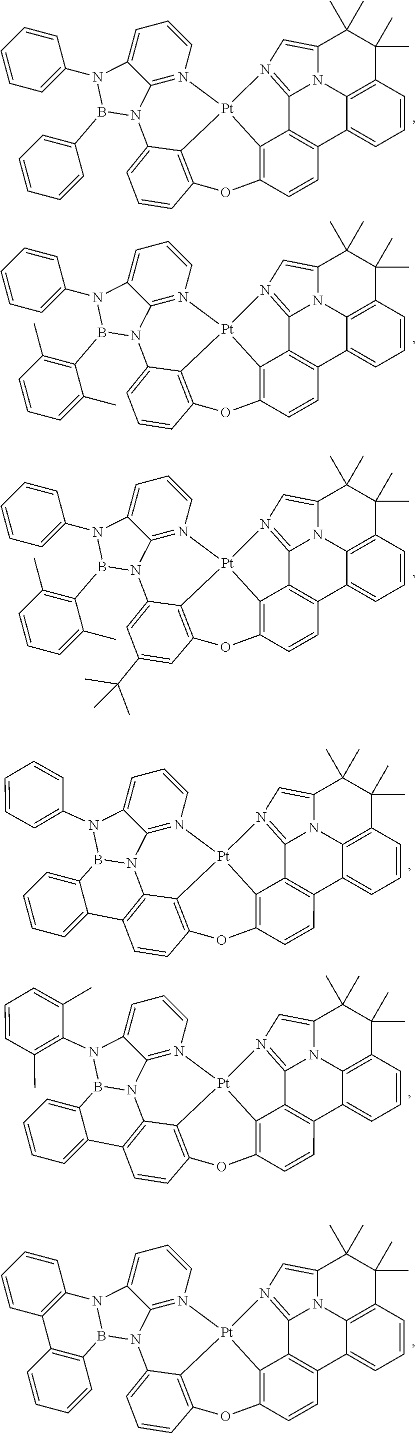

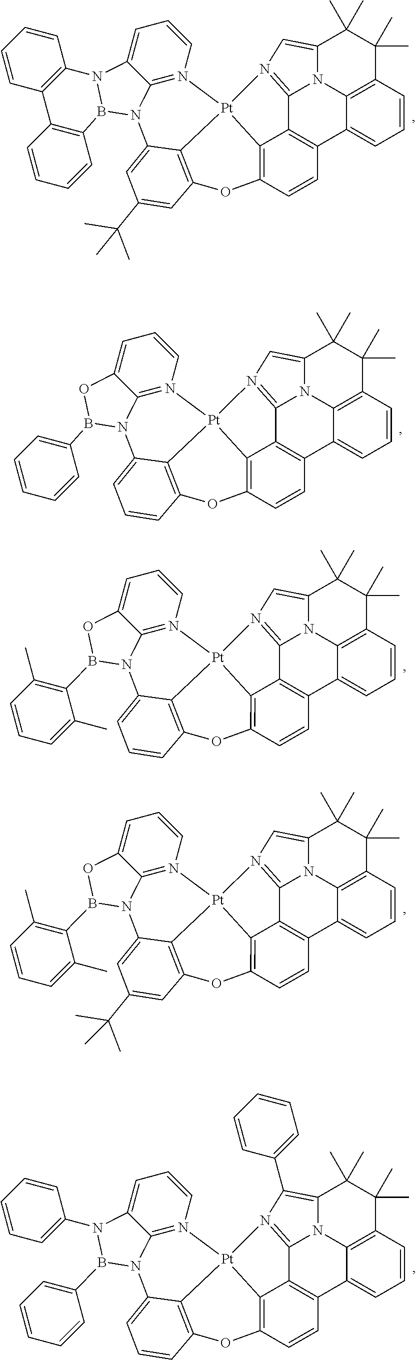

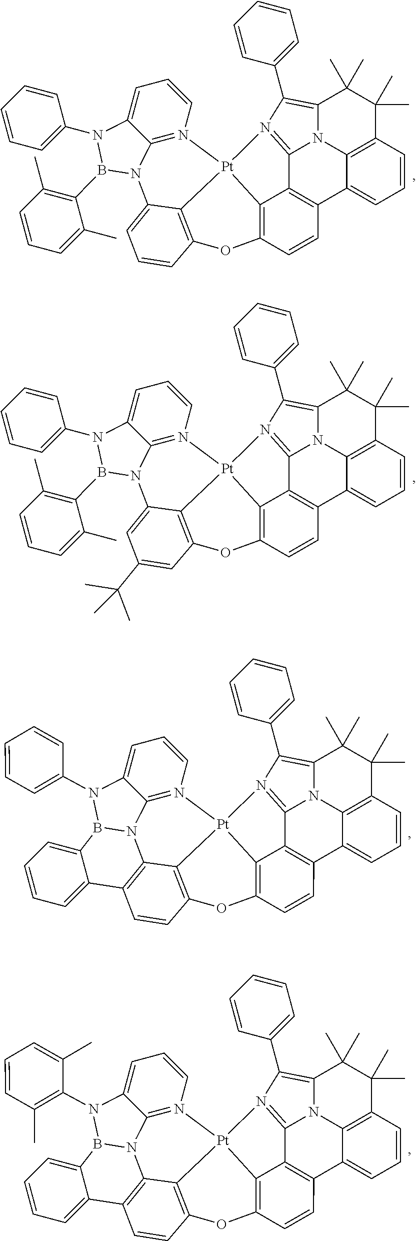

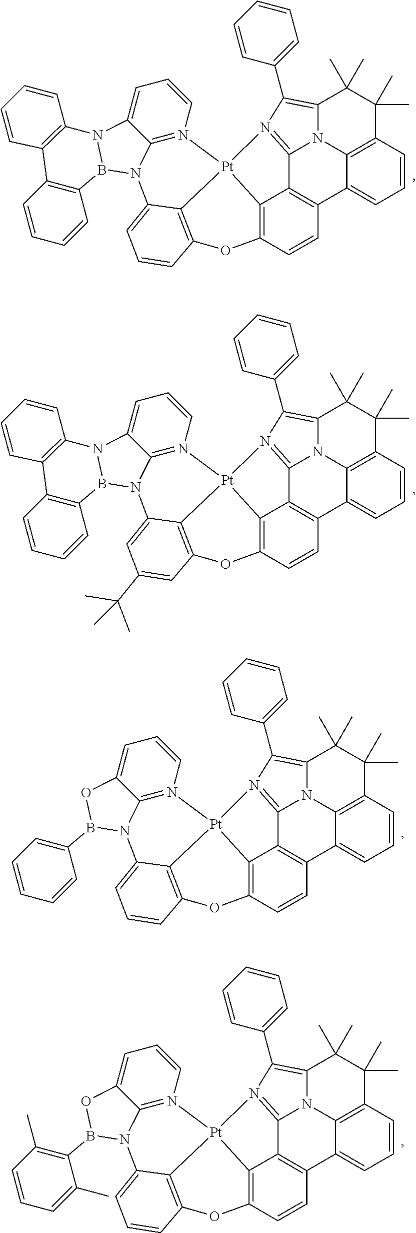

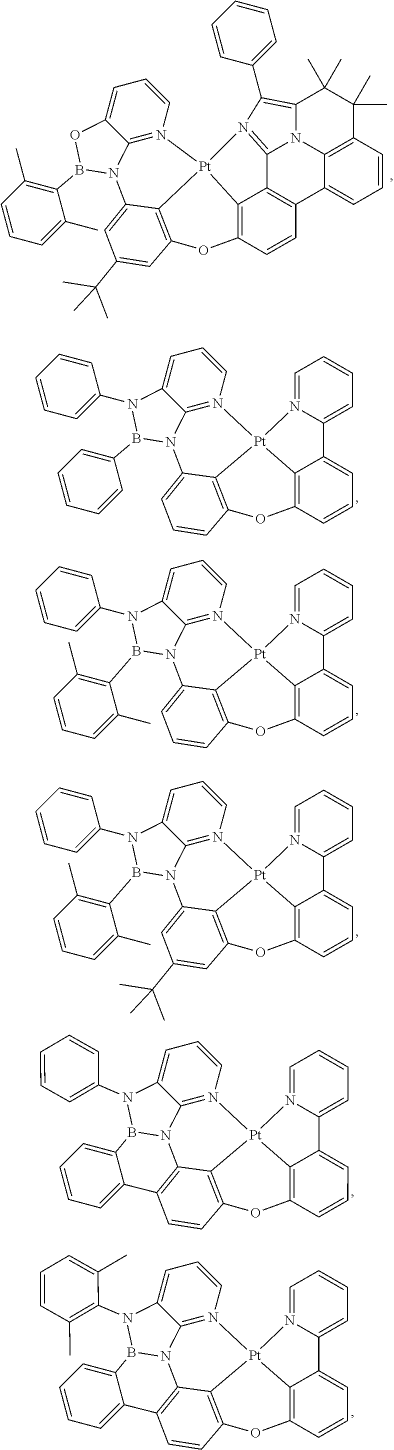

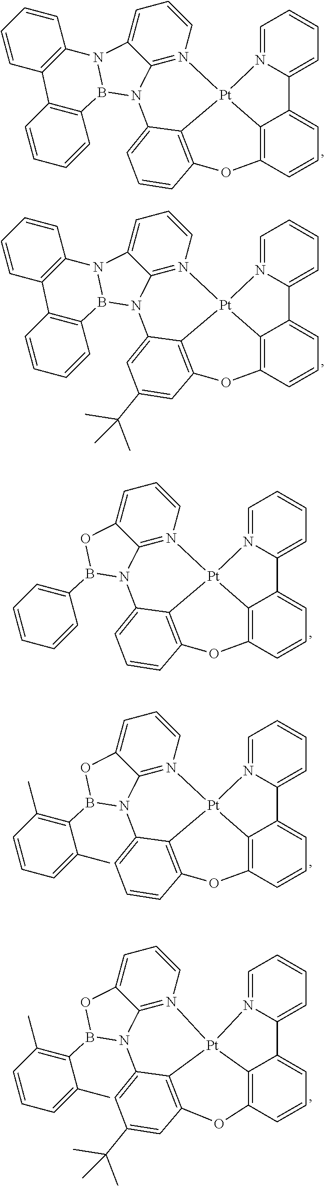

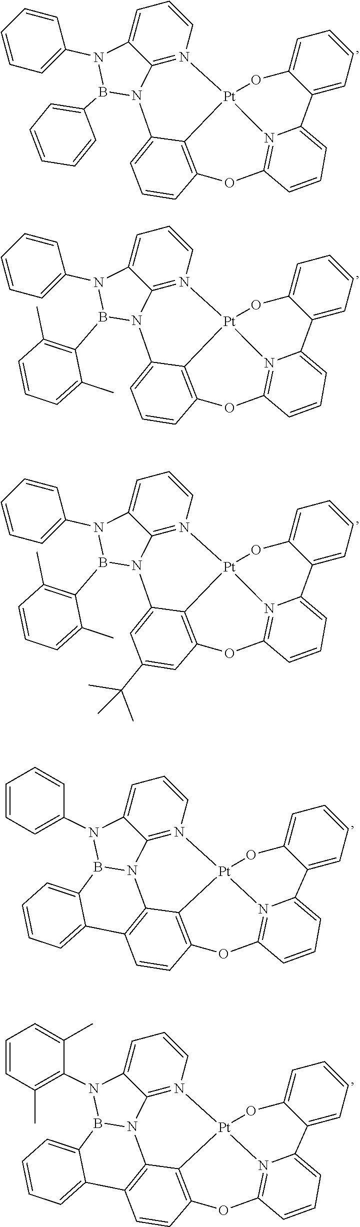

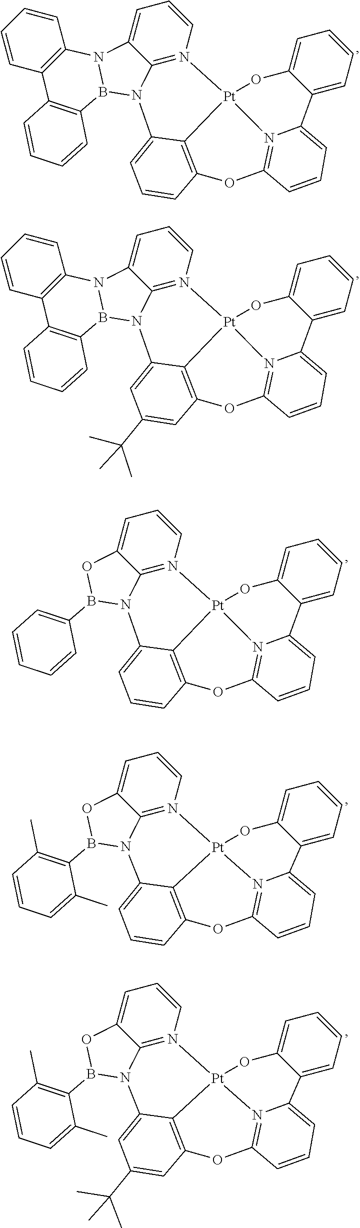

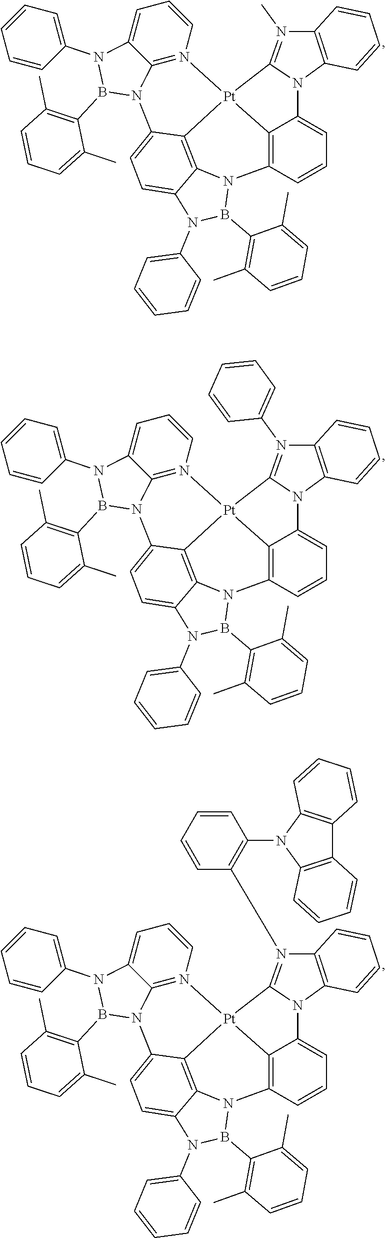

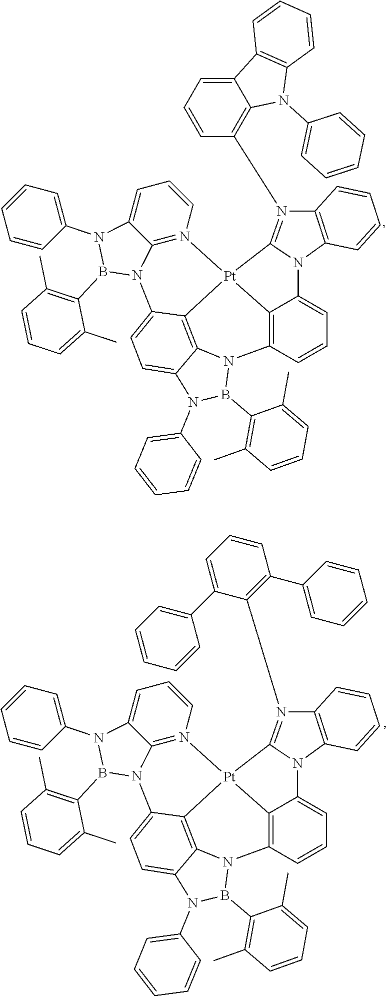

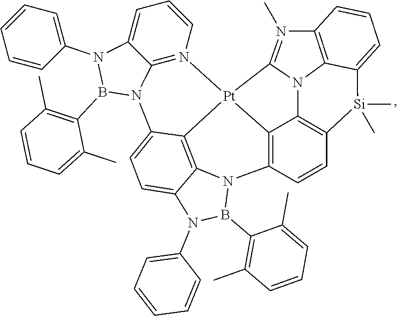

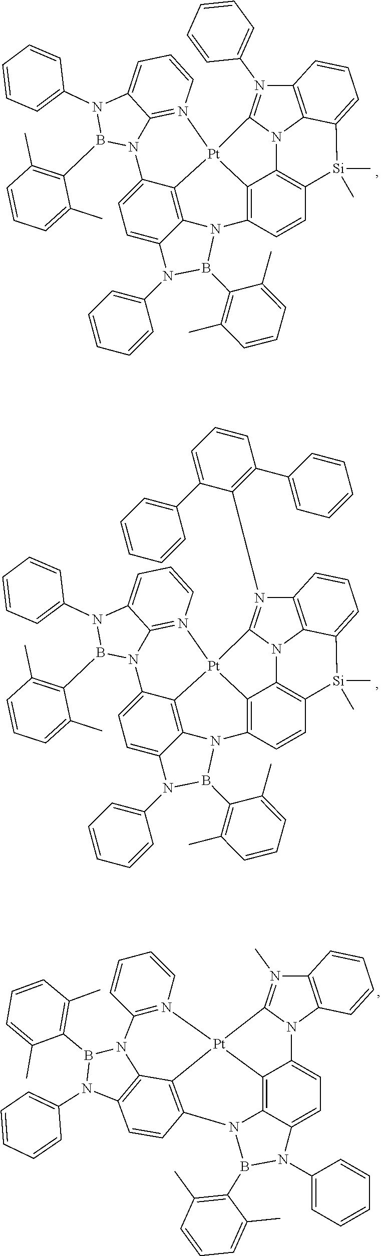

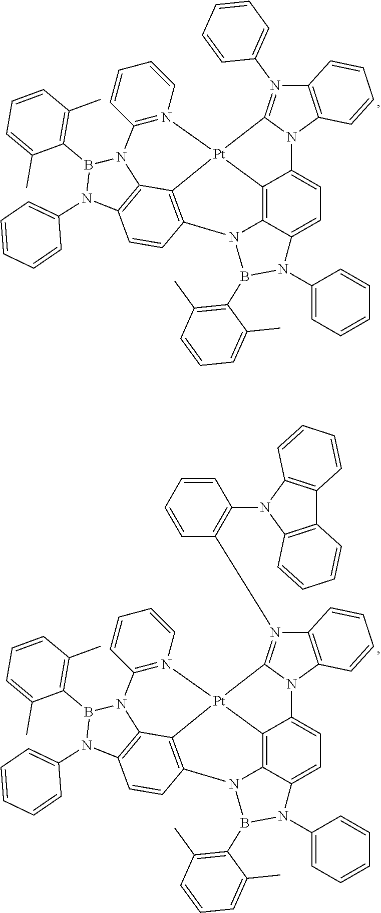

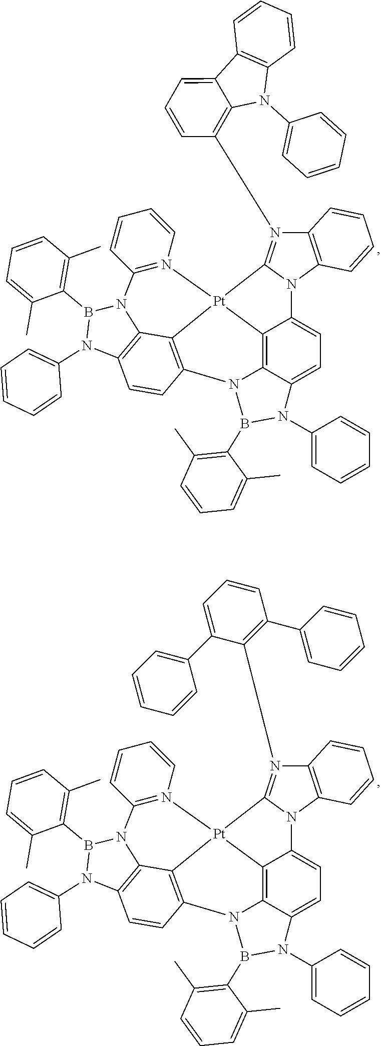

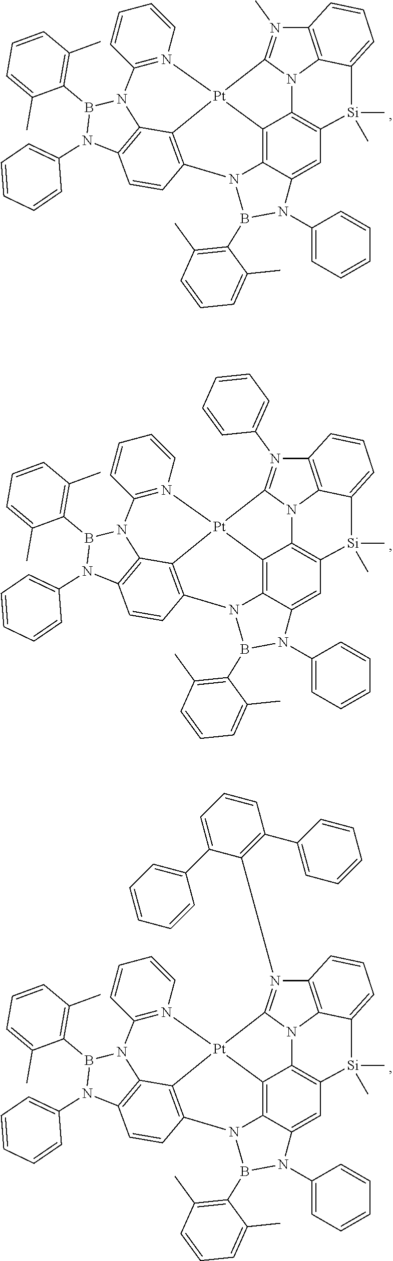

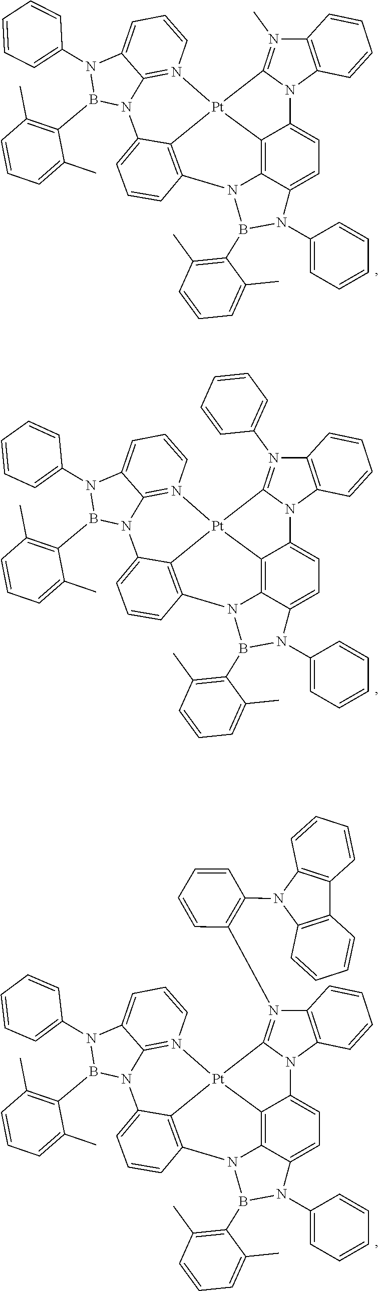

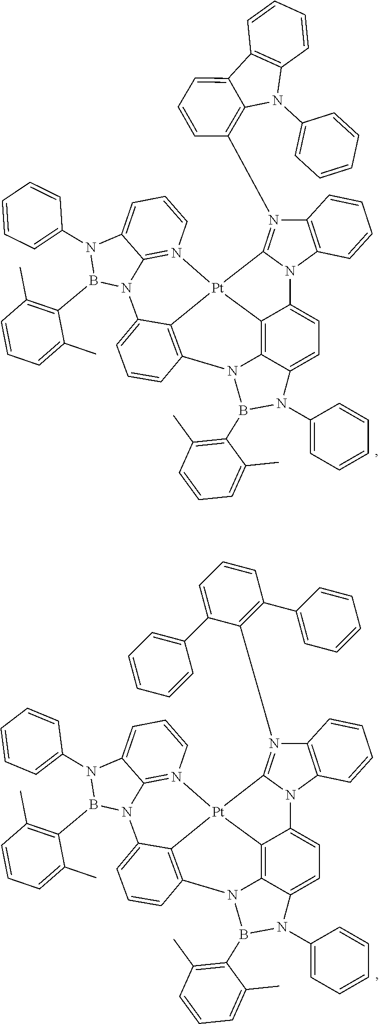

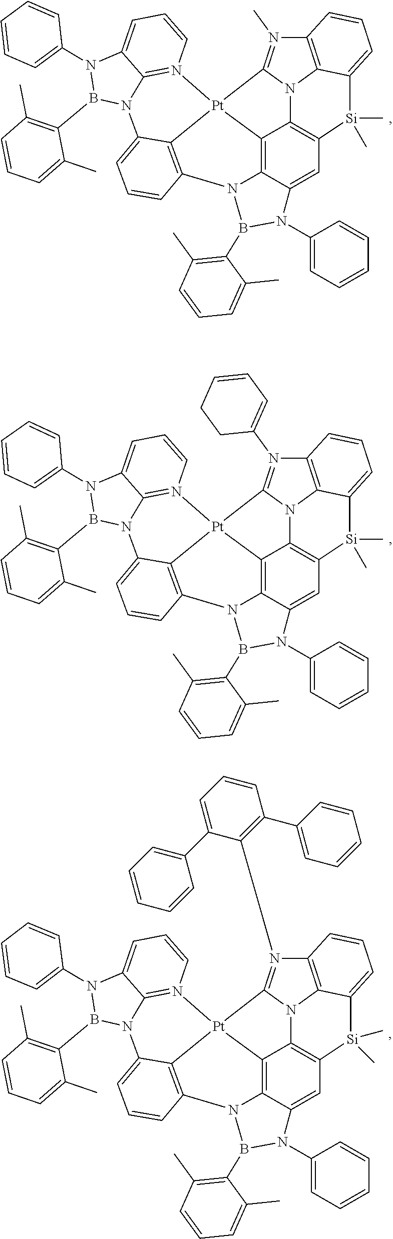

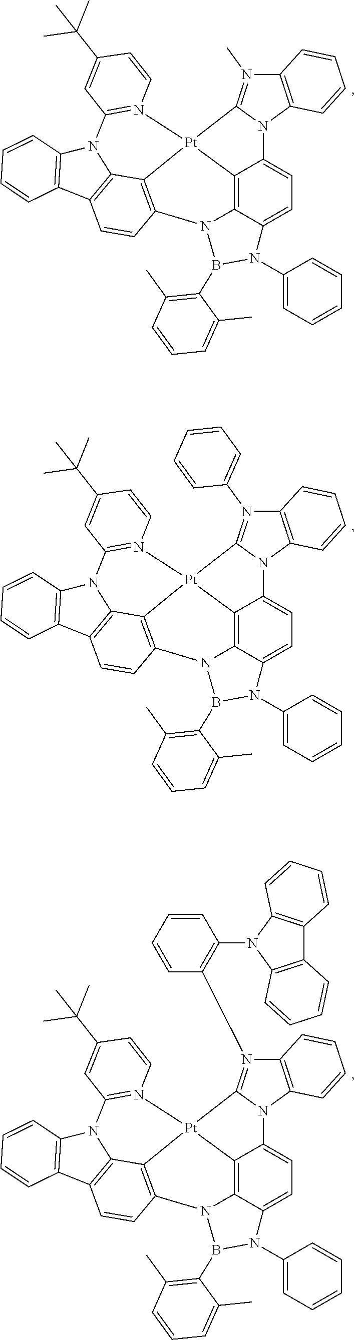

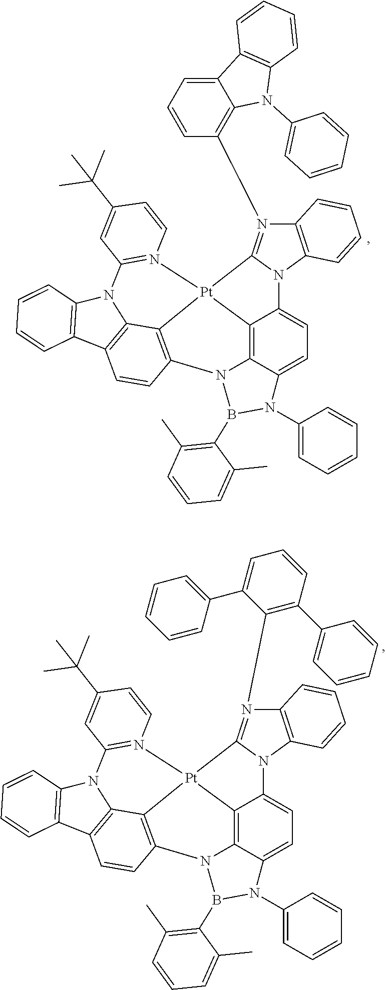

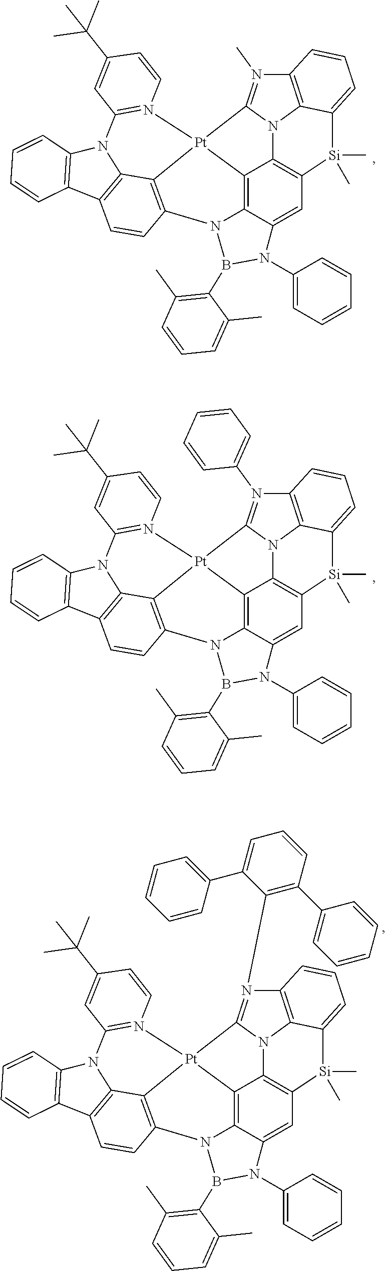

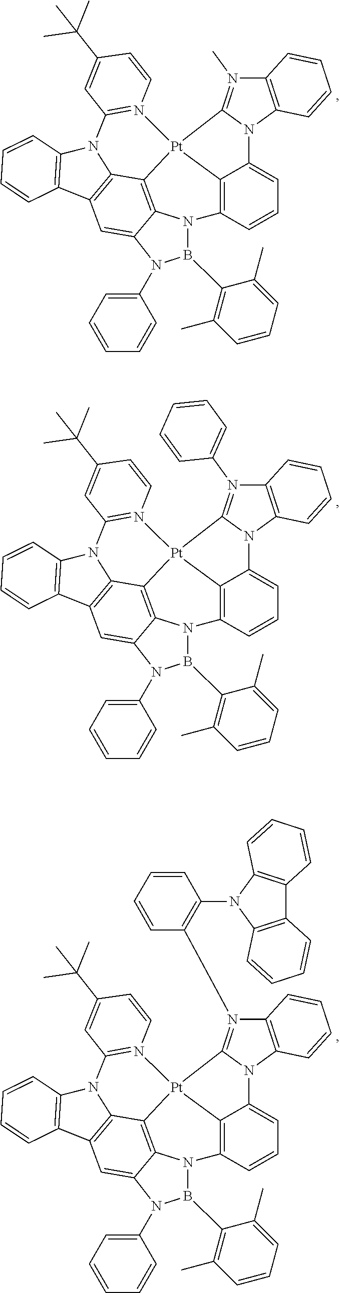

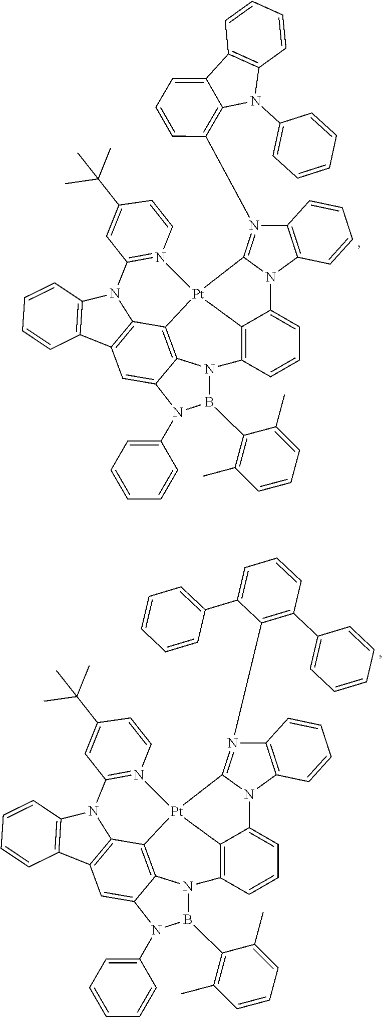

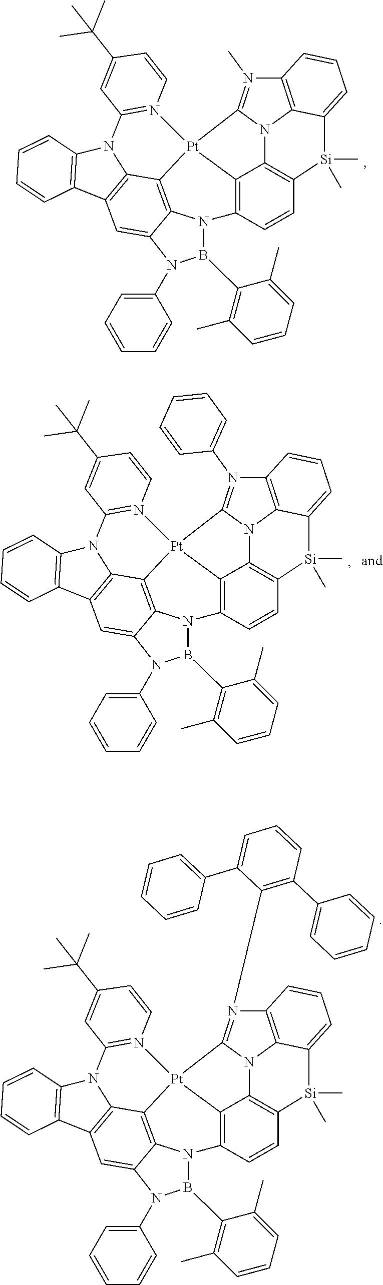

16. An organic light emitting device (OLED) comprising:
an anode;
a cathode; and
an organic layer disposed between the anode and the cathode, wherein the organic layer comprises a compound comprising a ligand L_{A} of Formula I 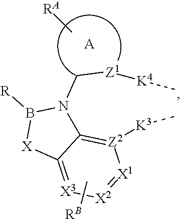
wherein:
A is a 5-membered or 6-membered carbocyclic or heterocyclic ring;
Z¹ and Z² are each independently C or N;
K³ and K⁴ are each independently a direct bond, O, or S;
X¹, X², and X³ are each independently C or N, at least one of X¹, X², and X³ is C;
X is O or NR′;
R^{A} and R^{B} each represents zero, mono, or up to the maximum number of allowed substitutions to its associated ring;
each of R, R′, R^{A}, and R^{B} is independently a hydrogen or a substituent selected from the group consisting of deuterium, halogen, alkyl, cycloalkyl, heteroalkyl, heterocycloalkyl, arylalkyl, alkoxy, aryloxy, amino, silyl, boryl, alkenyl, cycloalkenyl, heteroalkenyl, alkynyl, aryl, heteroaryl, acyl, carboxylic acid, ether, ester, nitrile, isonitrile, sulfanyl, sulfinyl, sulfonyl, phosphino, and combinations thereof; and
two adjacent groups can be joined or fused to form a ring wherever chemically feasible, wherein the ligand L_{A} is complexed to a metal M to form a chelate ring as indicated by the two dotted lines;
the metal M can be coordinated to other ligands;
the metal M is Pt; and
the ligand L_{A} can be linked with other ligands to form a tridentate, tetradentate, pentadentate, or hexadentate ligand.

17. The OLED of claim 16, wherein the organic layer further comprises a host, wherein host comprises at least one chemical group selected from the group consisting of triphenylene, carbazole, indolocarbazole, dibenzothiophene, dibenzofuran, dibenzoselenophene, 5,9-dioxa-13b-boranaphtho[3,2,1-de]anthracene, aza-triphenylene, aza-carbazole, aza-indolocarbazole, aza-dibenzothiophene, aza-dibenzofuran, aza-dibenzoselenophene, and aza-(5,9-dioxa-13b-boranaphtho[3,2,1-de]anthracene).

18. The OLED of claim 16, wherein the host is selected from the group consisting of: 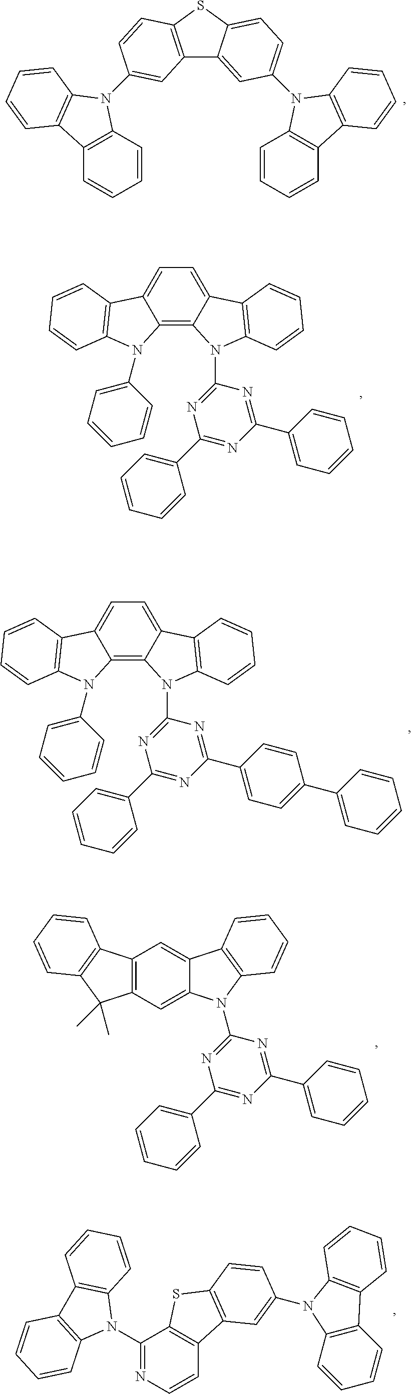 [SMILES: c1ccc2c(c1)c1ccccc1n2-c1ccc2sc3ccc(-n4c5ccccc5c5ccccc54)cc3c2c1 ; c1ccc(-c2nc(-c3ccccc3)nc(-n3c4ccccc4c4ccc5c6ccccc6n(-c6ccccc6)c5c43)n2)cc1 ; c1ccc(-c2ccc(-c3nc(-c4ccccc4)nc(-n4c5ccccc5c5ccc6c7ccccc7n(-c7ccccc7)c6c54)n3)cc2)cc1 ; CC1(C)c2ccccc2-c2cc3c4ccccc4n(-c4nc(-c5ccccc5)nc(-c5ccccc5)n4)c3cc21 ; c1ccc2c(c1)c1ccccc1n2-c1ccc2sc3c(-n4c5ccccc5c5ccccc54)nccc3c2c1] 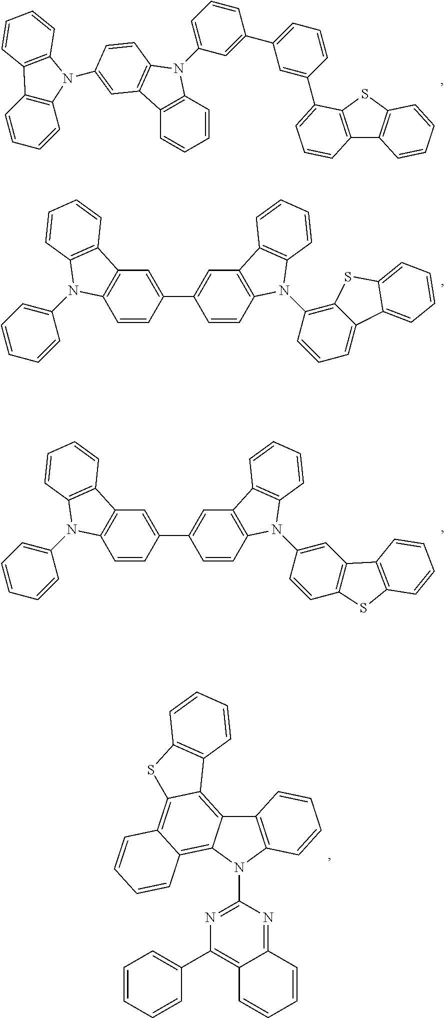 [SMILES: c1cc(-c2cccc(-n3c4ccccc4c4cc(-n5c6ccccc6c6ccccc65)ccc43)c2)cc(-c2cccc3c2sc2ccccc23)c1 ; c1ccc(-n2c3ccccc3c3cc(-c4ccc5c(c4)c4ccccc4n5-c4cccc5c4sc4ccccc45)ccc32)cc1 ; c1ccc(-n2c3ccccc3c3cc(-c4ccc5c(c4)c4ccccc4n5-c4ccc5sc6ccccc6c5c4)ccc32)cc1 ; c1ccc(-c2nc(-n3c4ccccc4c4c5c6ccccc6sc5c5ccccc5c43)nc3ccccc23)cc1] 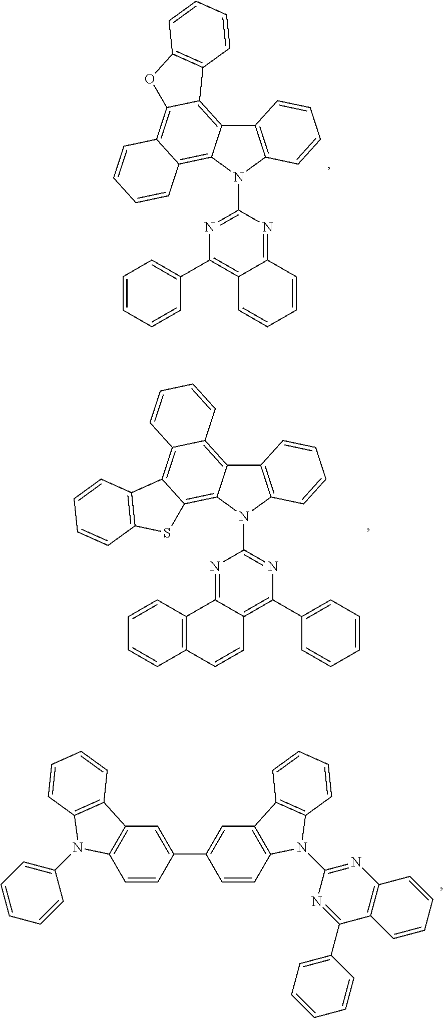 [SMILES: c1ccc(-c2nc(-n3c4ccccc4c4c5c6ccccc6oc5c5ccccc5c43)nc3ccccc23)cc1 ; c1ccc(-c2nc(-n3c4ccccc4c4c5ccccc5c5c6ccccc6sc5c43)nc3c2ccc2ccccc23)cc1 ; c1ccc(-c2nc(-n3c4ccccc4c4cc(-c5ccc6c(c5)c5ccccc5n6-c5ccccc5)ccc43)nc3ccccc23)cc1] 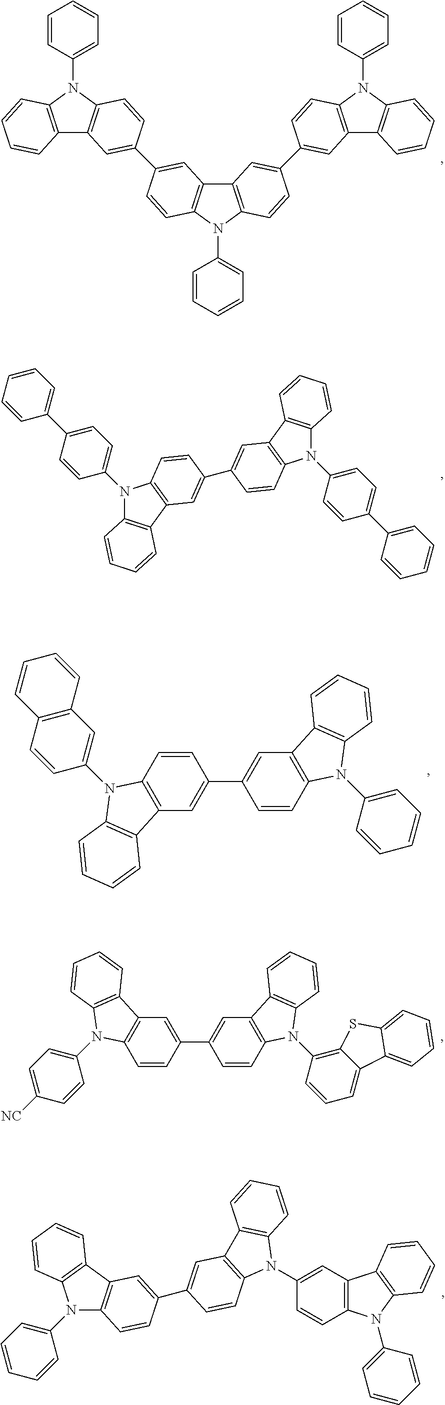 [SMILES: c1ccc(-n2c3ccccc3c3cc(-c4ccc5c(c4)c4cc(-c6ccc7c(c6)c6ccccc6n7-c6ccccc6)ccc4n5-c4ccccc4)ccc32)cc1 ; c1ccc(-c2ccc(-n3c4ccccc4c4cc(-c5ccc6c(c5)c5ccccc5n6-c5ccc(-c6ccccc6)cc5)ccc43)cc2)cc1 ; c1ccc(-n2c3ccccc3c3cc(-c4ccc5c(c4)c4ccccc4n5-c4ccc5ccccc5c4)ccc32)cc1 ; N#Cc1ccc(-n2c3ccccc3c3cc(-c4ccc5c(c4)c4ccccc4n5-c4cccc5c4sc4ccccc45)ccc32)cc1 ; c1ccc(-n2c3ccccc3c3cc(-c4ccc5c(c4)c4ccccc4n5-c4ccc5c(c4)c4ccccc4n5-c4ccccc4)ccc32)cc1] 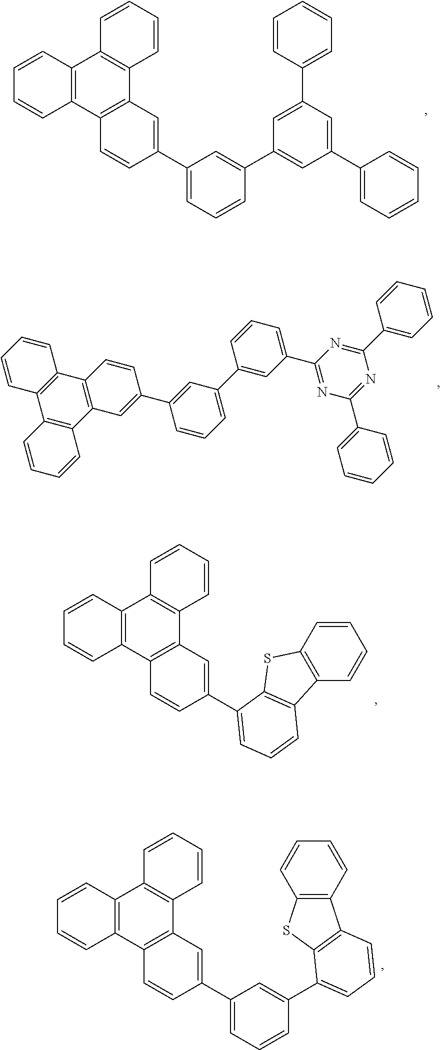 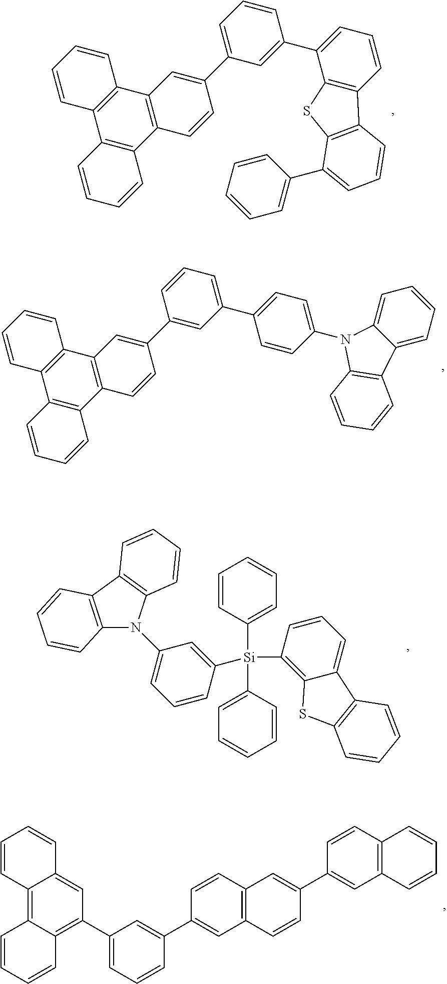 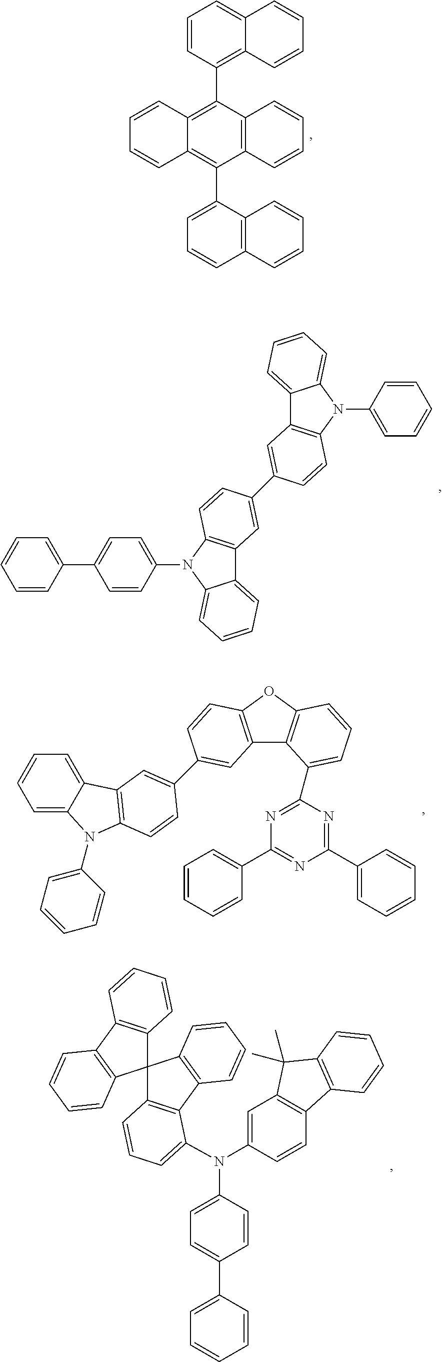 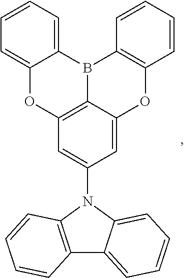 [SMILES: c1ccc2c(c1)Oc1cc(-n3c4ccccc4c4ccccc43)cc3c1B2c1ccccc1O3]
and combinations thereof.

19. A consumer product comprising an organic light-emitting device (OLED) comprising:
an anode;
a cathode; and
an organic layer disposed between the anode and the cathode, wherein the organic layer comprises a compound comprising a ligand L_{A} of Formula I 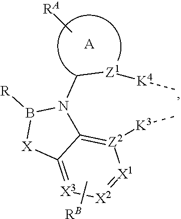
wherein:
A is a 5-membered or 6-membered carbocyclic or heterocyclic ring;
Z¹ and Z² are each independently C or N;
K³ and K⁴ are each independently a direct bond, O, or S;
X¹, X², and X³ are each independently C or N, at least one of X¹, X², and X³ is C;
X is O or NR′;
R^{A} and R^{B} each represents zero, mono, or up to the maximum number of allowed substitutions to its associated ring;
each of R, R′, R^{A}, and R^{B} is independently a hydrogen or a substituent selected from the group consisting of deuterium, halogen, alkyl, cycloalkyl, heteroalkyl, heterocycloalkyl, arylalkyl, alkoxy, aryloxy, amino, silyl, boryl, alkenyl, cycloalkenyl, heteroalkenyl, alkynyl, aryl, heteroaryl, acyl, carboxylic acid, ether, ester, nitrile, isonitrile, sulfanyl, sulfinyl, sulfonyl, phosphino, and combinations thereof; and
two adjacent groups can be joined or fused to form a ring wherever chemically feasible, wherein the ligand L_{A} is complexed to a metal M to form a chelate ring as indicated by the two dotted lines;
the metal M can be coordinated to other ligands;
the metal M is Pt; and
the ligand L_{A} can be linked with other ligands to form a tridentate, tetradentate, pentadentate, or hexadentate ligand.

20. A formulation comprising a compound according to claim 1.
